(19) United States
(12) Patent Application Publication
(10) Pub. No.: US 2019/0245152 A1
(43) Pub. Date: Aug. 8, 2019

(54) ORGANIC ELECTROLUMINESCENCE DEVICE AND ELECTRONIC DEVICE

(71) Applicant: IDEMITSU KOSAN CO., LTD., Chiyoda-ku (JP)

(72) Inventors: Masatoshi SAITO, Sondegaura-shi (JP); Toshinari OGIWARA, Sondegaura-shi (JP); Kei YOSHIZAKI, Sondegaura-shi (JP); Yuichiro KAWAMURA, Sondegaura-shi (JP)

(73) Assignee: IDEMITSU KOSAN CO., LTD., Chiyoda-ku (JP)

(21) Appl. No.: 16/268,713

(22) Filed: Feb. 6, 2019

(30) Foreign Application Priority Data
Feb. 7, 2018 (JP) 2018-020479

(51) Int. Cl. H01L 51/00; C09K 11/06

(52) U.S. Cl. CPC H01L 51/0072; H01L 51/5016; C09K 11/06; H01L 51/0058

(57) ABSTRACT

An organic electroluminescence device includes an anode, an emitting layer, and a cathode. The emitting layer contains a first compound, a second compound, and a third compound, the first compound being a fluorescent compound, the second compound being a delayed fluorescent compound, the third compound being a compound represented by a formula (3). A singlet energy S₁(M1) of the first compound, a singlet energy S₁(M2) of the second compound, and a singlet energy S₁(M3) of the third compound satisfy a relationship of a Numerical Formula 1. In the formula (3), X¹ to X¹⁴ each independently represent a nitrogen atom or CR₈₀. XA is NR⁹⁵, a sulfur atom or an oxygen atom.

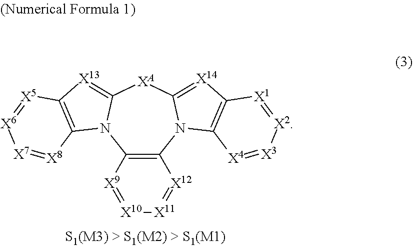

The entire disclosure of Japanese Patent Application No. 2018-020479 filed Feb. 7, 2018 is expressly incorporated by reference herein.

### TECHNICAL FIELD

The present invention relates to an organic electroluminescence device and an electronic device.

### BACKGROUND ART

When a voltage is applied to an organic electroluminescence device (hereinafter, occasionally referred to as “organic EL device”), holes are injected from an anode and electrons are injected from a cathode into an emitting layer. The injected electrons and holes are recombined in the emitting layer to form excitons. Specifically, according to the electron spin statistics theory, singlet excitons and triplet excitons are generated at a ratio of 25%:75%.

A fluorescent organic EL device with emission caused by singlet excitons, which has been applied to a full-color display for a mobile phone, TV and the like, is inferred to exhibit an internal quantum efficiency of 25% at a maximum. Theoretically, it is believed that a phosphorescent organic EL device with emission caused by triplet excitons in addition to the emission caused by singlet excitons can exhibit an internal quantum efficiency at a maximum of 100% by using a heavy metal atom (e.g. iridium).

For instance, Patent Literature 1 (EP 3070144 A1) discloses a seven-membered-ring compound represented by a predetermined formula as a material for a phosphorescent organic EL device, and an organic EL device containing the seven-membered-ring compound as a phosphorescent host material.

Meanwhile, a highly efficient fluorescent organic EL device with thermally activated delayed fluorescence (sometimes referred to as “delayed fluorescence, hereinafter) has been proposed and studied.

For instance, a thermally activated delayed fluorescence (TADF) mechanism has been studied. The TADF mechanism uses a phenomenon where inverse intersystem crossing from triplet excitons to singlet excitons thermally occurs when a material having a small energy difference (ΔST) between singlet energy level and triplet energy level is used. As for thermally activated delayed fluorescence, refer to, for instance, ADACHI, Chihaya, ed. (Apr. 1, 2012), “Yuki Hando-tai no Debaisu Bussei (Device Physics of Organic Semiconductors)”, Kodansha, pp. 261-268.

Non-patent Literature 2 (Mallesham Godumala, Suna Choi, Min Ju Cho and Dong Hoon Choi, “Thermally activated delayed fluorescence Blue dopants and hosts: from the design strategy to organic light-emitting diode applications,” Journal of Materials Chemistry C, 2016, 4, 11355-11381) discloses a plurality of TADF dopant materials (light-emitting material) and host materials. Specifically, Literature 2 discloses an organic EL device containing a triazine TADF compound (blue dopant material) and N,N-carbazolyl-3,5-benzene (mCP) (blue-emission host material) in an emitting layer, an organic EL device containing a cyan TADF compound (blue dopant material) and 9-(4-tert-butylphenyl)-3,6-bis(triphenylsilyl)-9H-carbazole (SiCz) (blue-emission host material) in an emitting layer, and the like.

Though mCP and SiCz used as host materials in Literature 2 are compounds having relatively high singlet energy, mCP or SiCz contained in an emitting layer as a third component is insufficient for improving luminous efficiency.

The organic EL device based on TADF mechanism emits light through a mechanism different from those in the typical fluorescent and phosphorescent organic EL device s. Accordingly, the third component to be contained in the emitting layer has to be selected based on a concept different from the known fluorescent and phosphorescent organic-EL-device materials.

It should be noted that the seven-membered-ring compound disclosed in Patent Literature 1 is used as a typical phosphorescent host material. The phosphorescent organic EL device containing the seven-membered-ring compound does not use the TADF mechanism.

### SUMMARY OF THE INVENTION

An object of the invention is to provide an organic electroluminescence device capable of improving luminous efficiency and an electronic device including the organic EL device.

An organic electroluminescence device according to an aspect of the invention includes: an anode; an emitting layer; and a cathode, in which:

the emitting layer contains a first compound, a second compound, and a third compound; the first compound is a fluorescent compound; the second compound is a delayed fluorescent compound; the third compound is a compound represented by a formula (3) below; and a singlet energy S₁(M1) of the first compound, a singlet energy S₁(M2) of the second compound and a singlet energy S₁(M3) of the third compound satisfy a relationship of a Numerical Formula 1 below.

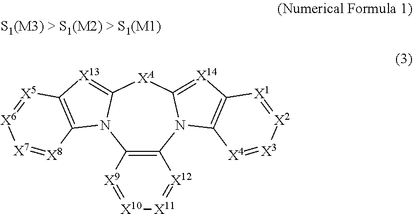

In the formula (3): X¹ to X¹⁴ each independently represent a nitrogen atom or CR₈₀;

X^{A} represents NR⁹⁵, a sulfur atom, or an oxygen atom;

R⁸⁰ is a hydrogen atom or a substituent; R⁸⁰ as the substituent being each independently a fluorine atom, a cyano group, a substituted or unsubstituted alkyl group having 1 to 25 carbon atoms, a substituted or unsubstituted alkyl group having 1 to 25 carbon atoms with a linking group D interposed, a substituted or unsubstituted aryl group having 6 to 24 ring carbon atoms, a substituted or unsubstituted heteroaryl group having 2 to 30 ring carbon atoms, or a group represented by -(A⁵)s-(A⁶)t-(A⁷)u-(A⁸)v-R¹⁷;

R⁹⁵ in NR⁹⁵ is a group represented by -(A¹)o-(A²)p-(A³)q(A⁴)r-R¹⁶, such that s, t, u, v, o, p, q and r are each independently 0 or 1, in which a plurality of R⁸⁰ are mutually the same or different;

R¹⁶ and R¹⁷ each independently represent a hydrogen atom or a substituent, R¹⁶ and R¹⁷ as the substituent being each independently —NR10R¹¹, —SiR¹²R¹³R¹⁴, —C(═O)R¹⁵, —CN, a substituted or unsubstituted aryl group having 6 to 24 ring carbon atoms, or a substituted or unsubstituted heteroaryl group having 2 to 30 ring carbon atoms;

R¹⁰, R¹¹ and R¹⁵ each independently represent a substituted or unsubstituted aryl group having 6 to 24 ring carbon atoms, or a substituted or unsubstituted heteroaryl group having 2 to 30 ring carbon atoms;

A¹ to A⁸ are each independently —SiR¹²AR^{13A}—, a substituted or unsubstituted arylene group having 6 to 24 ring carbon atoms, or a substituted or unsubstituted heteroarylene group having 2 to 30 ring carbon atoms;

R¹², R¹³, R^{12A}, R^{13A} and R¹⁴ each independently represent a substituted or unsubstituted alkyl group having 1 to 25 carbon atoms, a substituted or unsubstituted alkyl group having 1 to 25 carbon atoms with a linking group D interposed, a substituted or unsubstituted aryl group having 6 to 24 ring carbon atoms, or a substituted or unsubstituted heteroaryl group having 2 to 30 ring carbon atoms;

the linking group D is —CO—, —COO—, —S—, —SO—, —SO₂—, —O—, —NR⁶⁵—, —SiR⁷⁰R⁷¹—, —POR⁷²—, —CR⁶³═CR⁶⁴—, or —C═C—;

R⁶³ and R⁶⁴ each independently represent a hydrogen atom or a substituent, R⁶³ and R⁶⁴ as the substituent being each independently an unsubstituted aryl group having 6 to 18 ring carbon atoms, an aryl group having 6 to 18 ring carbon atoms substituted by a substituted or unsubstituted alkyl group having 1 to 18 carbon atoms, an aryl group having 6 to 18 ring carbon atoms substituted by a substituted or unsubstituted alkoxy group having 1 to 18 carbon atoms, a substituted or unsubstituted alkyl group having 1 to 18 carbon atoms, or a substituted or unsubstituted alkyl group having 1 to 18 carbon atoms with an oxygen atom interposed;

R⁶⁵ is an unsubstituted aryl group having 6 to 18 ring carbon atoms, a substituted or unsubstituted heteroaryl group having 2 to 30 ring carbon atoms, an aryl group having 6 to 18 ring carbon atoms substituted by a substituted or unsubstituted alkyl group having 1 to 18 carbon atoms, an aryl group having 6 to 18 ring carbon atoms substituted by a substituted or unsubstituted alkoxy group having 1 to 18 carbon atoms, a substituted or unsubstituted alkyl group having 1 to 18 carbon atoms, or a substituted or unsubstituted alkyl group having 1 to 18 carbon atoms with an oxygen atom interposed;

R⁷⁰ to R⁷¹ and R⁷² each independently represent a substituted or unsubstituted alkyl group having 1 to 18 carbon atoms, an unsubstituted aryl group having 6 to 18 ring carbon atoms, or an aryl group having 6 to 18 ring carbon atoms substituted by a substituted or unsubstituted alkyl group having 1 to 18 carbon atoms;

in the formula (3), when 0 or 1 of X¹ to X⁴ is a nitrogen atom, 0 or 1 of X⁵ to X⁸ is a nitrogen atom and o, p, q, and r are 0, R¹⁶ is neither a hydrogen atom nor —NR¹⁰R¹¹; and when a plurality of substituents are present, the plurality of substituents are mutually the same or different.

According to another aspect of the invention, an electronic device including the organic electroluminescence device according to the above aspect of the invention is provided.

According to the above aspects of the invention, an organic electroluminescence device capable of improving a luminous efficiency and an electronic device including the organic electroluminescence device can be provided.

### BRIEF EXPLANATION OF DRAWING(S)

FIG. 1 schematically illustrates an arrangement of an organic electroluminescence device according to an exemplary embodiment of the invention.

FIG. 2A illustrates a three-dimensional molecular structure of a third compound according to the exemplary embodiment.

FIG. 2B illustrates the three-dimensional molecular structure of the third compound viewed in a direction different from FIG. 2A.

FIG. 3 illustrates a three-dimensional molecular structure of a typical organic-EL-device material (mCP).

FIG. 4 illustrates a three-dimensional molecular structure of another typical organic-EL-device material (SiCz).

FIG. 5 schematically illustrates a transient-PL measuring machine.

FIG. 6 is an example of a decay curve of the transient PL.

FIG. 7 is an illustration showing a relationship between an energy level and energy transfer for each of first, second and third compounds in an emitting layer of an example of an organic EL device according to the exemplary embodiment.

### DESCRIPTION OF EMBODIMENT(S)

### Organic EL Device

### Device Arrangement of Organic EL Device

Arrangement(s) of an organic EL device according to an exemplary embodiment will be described below.

The organic EL device in the exemplary embodiment includes a pair of electrodes and an organic layer between the pair of electrodes. The organic layer includes at least one layer formed of an organic compound. Alternatively, the organic layer includes a plurality of layers formed of an organic compound. The organic layer may further include an inorganic compound. In the organic EL device of the exemplary embodiment, at least one of the organic layers is an emitting layer. Specifically, for instance, the organic layer may consist of a single emitting layer, or may include layers usable in a typical organic EL device. The layer(s) usable for the organic EL device is not particularly limited but is at least one layer selected from the group consisting of a hole injecting layer, a hole transporting layer, an electron injecting layer, an electron transporting layer, and a blocking layer.

Typical device arrangements of an organic EL device include the following arrangements (a) to (f) and the like:

(a) anode/emitting layer/cathode;

(b) anode/hole injecting⋅transporting layer/emitting layer/cathode;

(c) anode/emitting layer/electron injecting⋅transporting layer/cathode;

(d) anode/hole injecting⋅transporting layer/emitting layer/electron injecting˜transporting layer/cathode;

(e) anode/hole injecting⋅transporting layer/emitting layer/blocking layer/electron injecting⋅transporting layer/cathode; and

(f) anode/hole injecting⋅transporting layer/blocking layer/emitting layer/blocking layer/electron injecting⋅transporting layer/cathode.

The arrangement (d) is preferably used among the above arrangements. However, the arrangement according to the exemplary embodiment is not limited to the above arrangements. It should be noted that the above-described “emitting layer” is an organic layer having an emission function. The above-described “hole injecting⋅transporting layer” means at least one of a hole injecting layer and a hole transporting layer.” The above-described “electron injecting⋅transporting layer” means at least one of an electron injecting layer and an electron transporting layer.” When the organic EL device includes the hole injecting layer and the hole transporting layer, the hole injecting layer is preferably provided between the hole transporting layer and the anode. When the organic EL device includes the electron injecting layer and the electron transporting layer, the electron injecting layer is preferably provided between the electron transporting layer and the cathode. The hole injecting layer, the hole transporting layer, the electron transporting layer and the electron injecting layer may each consist of a single layer or a plurality of layers.

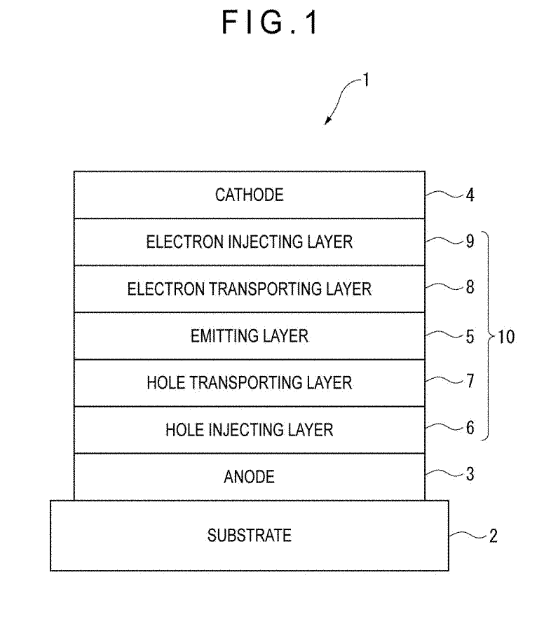

FIG. 1 schematically shows an arrangement of the organic EL device of the exemplary embodiment.

An organic EL device 1 includes a light-transmissive substrate 2, an anode 3, a cathode 4, and an organic layer 10 provided between the anode 3 and the cathode 4. The organic layer 10 includes a hole injecting layer 6, a hole transporting layer 7, an emitting layer 5, an electron transporting layer 8, and an electron injecting layer 9. The organic layer 10 includes the hole injecting layer 6, the hole transporting layer 7, the emitting layer 5, the electron transporting layer 8, and the electron injecting layer 9, which are sequentially laminated on the anode 3.

The emitting layer 5 of the organic EL device 1 in the exemplary embodiment contains a first compound, a second compound and a third compound.

The first compound is a fluorescent compound. The second compound is a delayed fluorescent compound. The third compound is a compound represented by a formula (3) below.

The emitting layer 5 may include a metal complex.

The emitting layer 5 preferably includes no phosphorescent metal complex. Moreover, the emitting layer 5 preferably includes no metal complex.

A singlet energy S₁(M1) of the first compound, a singlet energy S₁(M2) of the second compound and a singlet energy S₁(M3) of the third compound preferably satisfy a relationship of a numerical formula (Numerical Formula 1) below.

S₁(M3)>S₁(M2)>S₁(M1) (Numerical Formula 1).

The inventors have found that luminous efficiency is improved when the third compound (the compound represented by the formula (3)) of a unique structure is contained in the emitting layer as a third component.

In the organic EL device of the exemplary embodiment, it is believed that the improvement in the luminous efficiency is attributable to the unique structure of the third compound. The reason is speculated as follows.

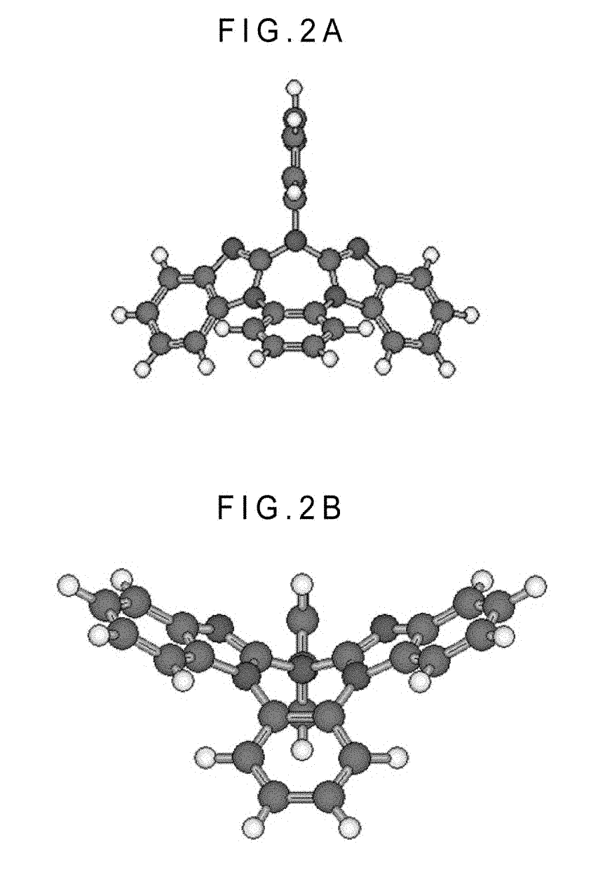

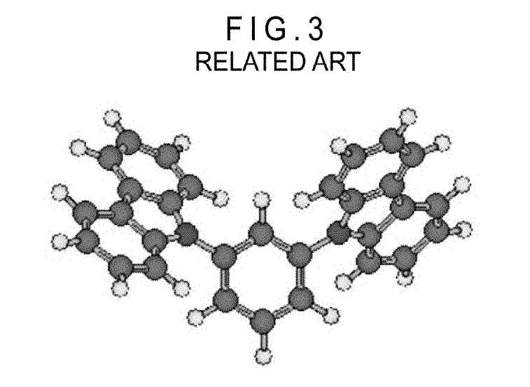

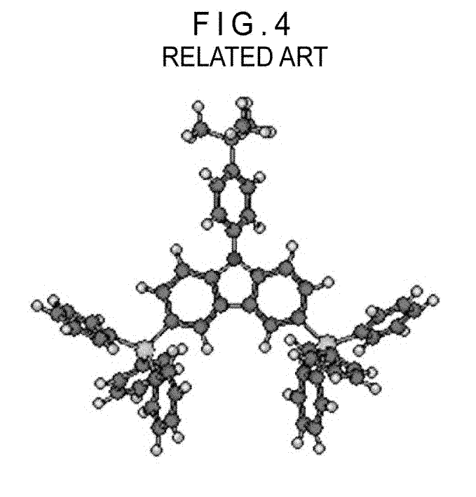

FIGS. 2A and 2B show three-dimensional molecular structures of the third compounds according to the exemplary embodiment. FIG. 3 shows a three-dimensional molecular structure of a typical organic-EL-device material (mCP). FIG. 4 shows a three-dimensional molecular structure of another typical organic-EL-device material (SiCz). It should be noted these three-dimensional molecular structures are calculated with B3LYP/6-31G* using Gaussian09 (by Gaussian, Inc.).

As shown in FIGS. 2A and 2B, the third compounds according to the exemplary embodiment each have a distortion in a plane formed by a π electron conjugated system. In other words, it is believed that the third compound has a structure whose molecules are greatly distorted.

As shown in FIGS. 2A and 2B, the third compounds according to the exemplary embodiment each have a distortion in a plane formed by a π electron conjugated system. In other words, it is believed that the third compound has a structure whose molecules are greatly distorted.

It is believed that an intermolecular interaction is reduced by the unique structure (i.e. large distortion) of the third compound of the exemplary embodiment.

In contrast, it is believed that carbazolyl groups (sometimes abbreviated as Cz hereinafter) in mCP shown in FIG. 3 cause an intermolecular interaction. SiCz shown in FIG. 4 has bulky silyl groups and a t-butylphenyl group in order to prevent the intermolecular interaction of Cz. However, as demonstrated by the results in later-described Comparative 2, it is believed that SiCz contained in the emitting layer as the third component does not sufficiently improve the luminous efficiency. In other words, it is believed that mere presence of a bulky substituent does not result in a sufficient improvement in the luminous efficiency.

It is believed that the organic EL device of the exemplary embodiment, which contains the third compound with greatly distorted structure and thus capable of reducing intermolecular interaction as the third component in the emitting layer, can effectively trap triplet energy of a delayed fluorescent compound (the second compound in the exemplary embodiment) within the emitting layer.

The organic EL device of the exemplary embodiment can thus improve the luminous efficiency.

It is said in the field of the organic EL device that emission control of blue-emission region (usually wavelength region in a range from 430 nm to 480 nm) is difficult. However, the organic EL device of the exemplary embodiment improves the luminous efficiency in blue-emission region.

### Emitting Layer

### Third Compound

The third compound of the exemplary embodiment is a compound represented by a formula (3) below.

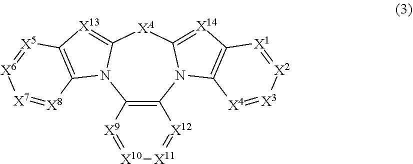

In the formula (3), X₁ to X₁₄ each independently represent a nitrogen atom or CR⁸⁰;

X^{A} represents NR⁹⁵, a sulfur atom, or an oxygen atom;

R⁸⁰ is a hydrogen atom or a substituent;

R⁸⁰ as the substituent is each independently selected from the group consisting of a fluorine atom, a cyano group, a substituted or unsubstituted alkyl group having 1 to 25 carbon atoms, a substituted or unsubstituted alkyl group having 1 to 25 carbon atoms with a linking group D interposed, a substituted or unsubstituted aryl group having 6 to 24 ring carbon atoms, a substituted or unsubstituted heteroaryl group having 2 to 30 ring carbon atoms, and a group represented by -(A⁵)s-(A⁶)t-(A⁷)u-(A⁸)v-R¹⁷;

R⁹⁵ in NR⁹⁵ is a group represented by -(A¹)o-(A²)p-(A³)q-(A⁴)r-R¹⁶;

s, t, u, v, o, p, q and r are each independently 0 or 1, in which a plurality of R⁸⁰ are mutually the same or different;

R¹⁶ and R¹⁷ each independently represent a hydrogen atom or a substituent;

R¹⁶ and R¹⁷ as the substituent are each independently selected from the group consisting of —NR¹⁰R¹¹, SiR¹²R¹³R¹⁴, —C(═O)R¹⁵, —CN, a substituted or unsubstituted aryl group having 6 to 24 ring carbon atoms, and a substituted or unsubstituted heteroaryl group having 2 to 30 ring carbon atoms;

R¹⁰, R¹¹ and R¹⁵ each independently represent a substituted or unsubstituted aryl group having 6 to 24 ring carbon atoms, or a substituted or unsubstituted heteroaryl group having 2 to 30 ring carbon atoms;

A¹ to A⁸ are each independently —SiR^{12A}R^{13A}—, a substituted or unsubstituted arylene group having 6 to 24 ring carbon atoms, or a substituted or unsubstituted heteroarylene group having 2 to 30 ring carbon atoms;

R¹², R¹³, R^{12A}, R^{13A} and R¹⁴ each independently represent a substituted or unsubstituted alkyl group having 1 to 25 carbon atoms, a substituted or unsubstituted alkyl group having 1 to 25 carbon atoms with a linking group D interposed, a substituted or unsubstituted aryl group having 6 to 24 ring carbon atoms, or a substituted or unsubstituted heteroaryl group having 2 to 30 ring carbon atoms;

the linking group D is —CO—, —COO—, —S—, —SO—, —SO₂—, —O—, —NR⁶⁵—, —SiR⁷⁶R⁷¹—, —POR⁷²—, —CR⁶³═CR⁶⁴—, or —C═C—;

R⁶³ and R⁶⁴ each independently represent a hydrogen atom or a substituent;

R⁶³ and R⁶⁴ as the substituent are each independently selected from the group consisting of an unsubstituted aryl group having 6 to 18 ring carbon atoms, an aryl group having 6 to 18 ring carbon atoms substituted by a substituted or unsubstituted alkyl group having 1 to 18 carbon atoms, an aryl group having 6 to 18 ring carbon atoms substituted by a substituted or unsubstituted alkoxy group having 1 to 18 carbon atoms, a substituted or unsubstituted alkyl group having 1 to 18 carbon atoms, or a substituted or unsubstituted alkyl group having 1 to 18 carbon atoms with an oxygen atom interposed;

R⁶⁵ is an unsubstituted aryl group having 6 to 18 ring carbon atoms, a substituted or unsubstituted heteroaryl group having 2 to 30 ring carbon atoms, an aryl group having 6 to 18 ring carbon atoms substituted by a substituted or unsubstituted alkyl group having 1 to 18 carbon atoms; an aryl group having 6 to 18 ring carbon atoms substituted by a substituted or unsubstituted alkoxy group having 1 to 18 carbon atoms, a substituted or unsubstituted alkyl group having 1 to 18 carbon atoms, or a substituted or unsubstituted alkyl group having 1 to 18 carbon atoms with an oxygen atom interposed;

R⁷⁰ to R⁷¹ and R⁷² each independently represent a substituted or unsubstituted alkyl group having 1 to 18 carbon atoms, an unsubstituted aryl group having 6 to 18 ring carbon atoms, or an aryl group having 6 to 18 ring carbon atoms substituted by a substituted or unsubstituted alkyl group having 1 to 18 carbon atoms;

in the formula (3), when 0 or 1 of X¹ to X⁴ is a nitrogen atom, 0 or 1 of X⁵ to X⁸ is a nitrogen atom and when o, p, q, and r are 0, R¹⁶ is neither a hydrogen atom nor —NR¹⁰R¹¹; and when a plurality of substituents are present, the plurality of substituents are mutually the same or different.

### Substituent G

In the third compound, the substituent meant by “substituted or unsubstituted” in each of R⁸⁰, R¹⁶, R¹⁷, R¹⁰, R¹¹, R¹⁵, A¹ to A⁸, R¹², R¹³, R^{12A}, R^{13A}, and R¹⁴ is each dependently a substituent G defined below.

When a plurality of substituents G are present, the plurality of substituents G are mutually the same or different; and

the substituent G is specifically —OR^{69B}, —SR^{69C}, —NR^{65C}R^{66B}, —COR^{68A}, —COOR^{67A}, —CONR^{65D}R^{66C}, —CN, a fluorine atom, —SiR⁷³R⁷⁴R⁷⁵, a substituted or unsubstituted alkyl group having 1 to 18 carbon atoms, an unsubstituted aryl group having 6 to 24 ring carbon atoms, an aryl group having 6 to 24 ring carbon atoms substituted by a fluorine atom, an aryl group having 6 to 24 ring carbon atoms substituted by a substituted or unsubstituted alkyl group having 1 to 18 carbon atoms, an aryl group having 6 to 24 ring carbon atoms substituted by a substituted or unsubstituted alkyl group having 1 to 18 carbon atoms with an oxygen atom interposed, an unsubstituted heteroaryl group having 2 to 30 ring carbon atoms, a heteroaryl group having 2 to 30 ring carbon atoms substituted by a fluorine atom, a heteroaryl group having 2 to 30 ring carbon atoms substituted by a substituted or unsubstituted alkyl group having 1 to 18 carbon atoms, or a heteroaryl group having 2 to 30 ring carbon atoms substituted by a substituted or unsubstituted alkyl group having 1 to 18 carbon atoms with an oxygen atom interposed; R^{65C}, R^{66B}, R^{65D} and R^{66C} each independently represent an unsubstituted aryl group having 6 to 18 ring carbon atoms, an alkyl group having 6 to 18 ring carbon atoms substituted by a substituted or unsubstituted alkyl group having 1 to 18 carbon atoms, an aryl group having 6 to 18 ring carbon atoms substituted by a substituted or unsubstituted alkoxy group having 1 to 18 carbon atoms, a substituted or unsubstituted alkyl group having 1 to 18 carbon atoms, or a substituted or unsubstituted alkyl group having 1 to 18 carbon atoms with an oxygen atom interposed;

a pair of R^{65D} and R^{66B} and a pair of R^{65D} and R^{66C} are each independently mutually bonded to form a five-membered ring or a six-membered ring, or are not bonded;

R^{67A}, R^{69B} and R^{69C} each independently represent an unsubstituted aryl group having 6 to 18 ring carbon atoms, an aryl group having 6 to 18 ring carbon atoms substituted by a substituted or unsubstituted alkyl group having 1 to 18 carbon atoms, an aryl group having 6 to 18 ring carbon atoms substituted by a substituted or unsubstituted alkoxy group having 1 to 18 carbon atoms, a substituted or unsubstituted alkyl group having 1 to 18 carbon atoms, or a substituted or unsubstituted alkyl group having 1 to 18 carbon atoms with an oxygen atom interposed;

R^{68A} is a hydrogen atom or a substituent, R^{68A} as the substituent being selected from the group consisting of an unsubstituted aryl group having 6 to 18 ring carbon atoms, an aryl group having 6 to 18 ring carbon atoms substituted by a substituted or unsubstituted alkyl group having 1 to 18 carbon atoms, an aryl group having 6 to 18 ring carbon atoms substituted by a substituted or unsubstituted alkoxy group having 1 to 18 carbon atoms, a substituted or unsubstituted alkyl group having 1 to 18 carbon atoms, or a substituted or unsubstituted alkyl group having 1 to 18 carbon atoms with an oxygen atom interposed; and

R⁷³, R⁷⁴ and R⁷⁵ each independently represent a substituted or unsubstituted alkyl group having 1 to 25 carbon atoms, a substituted or unsubstituted alkyl group having 1 to 25 carbon atoms with an oxygen atom interposed, an unsubstituted aryl group having 6 to 24 ring carbon atoms, an aryl group having 6 to 24 ring carbon atoms substituted by a substituted or unsubstituted alkyl group having 1 to 18 carbon atoms, an unsubstituted heteroaryl group having 2 to 30 ring carbon atoms, or a heteroaryl group having 2 to 30 ring carbon atoms substituted by a substituted or unsubstituted alkyl group having 1 to 18 carbon atoms.

In the formula (1), “with a linking group D interposed” in “a substituted or unsubstituted alkyl group having 1 to 25 carbon groups with a linking group D interposed” means that at least one (preferably one) divalent linking group D is present between two carbon atoms in the alkyl group, the two carbon atoms being bonded via the divalent linking group D or one of bonds of the linking group D is bonded to a terminal methylene group near a bond of the alkyl group (-(linking group D)-(alkyl group)).

Preferable substituents for the compound represented by the formula (3) will be described below.

In the third compound, when R⁸⁹ is a “substituted alkyl group having 1 to 25 carbon atoms,” the substituent G is preferably —OR^{69B}, —SR^{68C}, —NR^{65C}R^{66B}, —COR^{88A}, —COOR^{67A}, —CONR^{65D}R^{66C}, —CN, or a fluorine atom, more preferably —OR^{69B}, —SR^{69C}, —NR^{65C}R^{66B}, —COR^{68A}, —COOR^{67A}, —CONR^{65D}R^{66C}, or —CN.

the R^{65C}, R^{65D}, R^{66B}, R^{66C}, R^{67A}, R^{68A}, R^{69B}, and R^{69C} are preferably each independently an unsubstituted alkyl group having 1 to 18 carbon atoms (e.g. methyl group, ethyl group, n-propyl group, isopropyl group, n-butyl group, isobutyl group, sec-butyl group, hexyl group, octyl group, and 2-ethylhexyl group), or an unsubstituted aryl group having 6 to 14 ring carbon atoms (e.g. phenyl group, tolyl group, naphthyl group, and biphenyl group).

### X^{A}

In the third compound, X^{A} is preferably NR⁹⁵ or a sulfur atom, more preferably NR⁹⁵.

### R⁹⁵

In the third compound, R⁹⁵ for NR⁹⁵ is preferably a group represented by -(A¹)o-(A²)p-(A³)q-(A⁴)r-R¹⁶.

X¹³ and X¹⁴

In the third compound, X¹³ is preferably a nitrogen atom.

In the third compound, X¹⁴ is preferably a nitrogen atom.

In the third compound, X¹³ and X¹⁴ are preferably nitrogen atoms.

X¹ to X⁹ and X¹²

In the third compound, it is preferable that X¹ to X⁹ and X¹² are CR⁸⁰, and R⁸⁰ in CR⁸⁰ are each independently a hydrogen atom or a group represented by -(A⁵)s-(A⁶)t-(A⁷)u-(A⁸)v-R¹⁷, and R⁸⁰ for CR⁸⁰ are each more preferably a hydrogen atom.

X¹⁰ and X¹¹

In the third compound, it is preferable that X¹⁰ and X¹¹ are CR⁸⁰, and R⁸⁰ for CR⁸⁰ are each independently a hydrogen atom or a cyano group.

### Linking Group D

In the third compound, the linking group D is preferably —CO—, —COO—, —S—, —SO—, —SO₂—, —O— or —NR⁶⁵—, more preferably —NR⁶⁵—.

R⁶⁵ for —NR⁶⁵— is preferably an unsubstituted alkyl group having 1 to 18 carbon atoms (e.g. a methyl group, ethyl group, n-propyl group, isopropyl group, n-butyl group, isobutyl group, and sec-butyl group), an unsubstituted aryl group having 6 to 14 ring carbon atoms (e.g. a phenyl group, tolyl group, naphthyl group, and biphenyl group), or a substituted or unsubstituted heteroaryl group having 2 to 30 ring carbon atoms (e.g. a group represented by a formula (65A) below (benzimidazo[1,2-a]benzimidazo-2-yl), carbazolyl group, and dibenzofuranyl group).

The heteroaryl group having 2 to 30 ring carbon atoms for R⁶⁵ may preferably be substituted by a substituted or unsubstituted aryl group having 6 to 10 ring carbon atoms.

The heteroaryl group having 2 to 30 ring carbon atoms for R⁶⁵ may preferably be substituted by an aryl group having 6 to 10 ring carbon atoms substituted by a substituted or unsubstituted alkyl group having 1 to 4 carbon atoms.

The heteroaryl group having 2 to 30 ring carbon atoms for R⁶⁵ may preferably be substituted by a substituted or unsubstituted heteroaryl group having 2 to 14 ring carbon atoms.

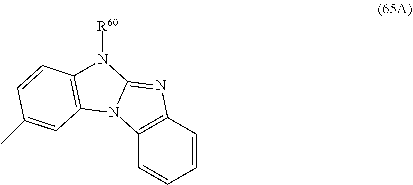

In the formula (65A), R⁶⁰ is an unsubstituted aryl group having 6 to 10 ring carbon atoms, a substituted or unsubstituted aryl group having 6 to 10 ring carbon atoms substituted by a substituted or unsubstituted alkyl group having 1 to 4 carbon atoms, or a substituted or unsubstituted heteroaryl group having 2 to 14 ring carbon atoms.

### Substituent G

The substituent G is —OR^{69B}, —SR^{69C}, —NR⁶⁵CR^{66B}, —CN, a substituted or unsubstituted alkyl group having 1 to 18 carbon atoms (e.g. a methyl group, ethyl group, n-propyl group, isopropyl group, n-butyl group, isobutyl group, sec-butyl group, hexyl group, octyl group, 2-ethylhexyl group, and —CF₃), an unsubstituted aryl group having 6 to 14 ring carbon atoms (e.g. a phenyl group, 1-naphthyl group, and 2-naphthyl group), an aryl group having 6 to 14 ring carbon atoms substituted by a fluorine atom, an aryl group having 6 to 14 ring carbon atoms substituted by a substituted or unsubstituted alkyl group having 1 to 18 carbon atoms, an aryl group having 6 to 14 ring carbon atoms substituted by a substituted or unsubstituted heteroaryl group having 2 to 14 ring carbon atoms, an unsubstituted heteroaryl group having 2 to 14 ring carbon atoms (e.g. benzimidazo[1,2-a]benzimidazo-5-yl, benzimidazo[1,2-a]benzimidazo-2-yl, carbazolyl group, and dibenzofuranyl group).

a heteroaryl group having 2 to 14 ring carbon atoms substituted by a fluorine atom, a heteroaryl group having 2 to 14 ring carbon atoms substituted by a substituted or unsubstituted alkyl group having 1 to 18 carbon atoms, or —SiR⁷³R⁷⁴R⁷⁵ (e.g. triphenylsilyl group).

R^{65C}, R^{66B}, R^{69B} and R^{69C} each independently represent an unsubstituted alkyl group having 1 to 18 carbon atoms (e.g. a methyl group, ethyl group, n-propyl group, isopropyl group, n-butyl group, isobutyl group, sec-butyl group, hexyl group, octyl group, and 2-ethylhexyl group), or an unsubstituted aryl group having 6 to 14 ring carbon atoms (e.g. a phenyl group, tolyl group, naphthyl group, and biphenyl group).

R⁷³, R⁷⁴ and R⁷⁵ in —SiR⁷³R⁷⁴R⁷⁵ preferably each independently represent an aryl group having 6 to 14 ring carbon atoms substituted by a substituted or unsubstituted alkyl group having 1 to 18 carbon atoms, a heteroaryl group having 2 to 10 ring carbon atoms substituted by a substituted or unsubstituted alkyl group having 1 to 18 carbon atoms, or a heteroaryl group having 2 to 10 ring carbon atoms substituted by a phenyl group.

The heteroaryl group having 2 to 14 ring carbon atoms for the substituent G is preferably the group represented by the formula (65A) (benzimidazo[1,2-a]benzimidazo-2-yl), the group represented by the formula (65B) (benzimidazo[1,2-a]benzimidazo-5-yl), benzimidazolo[2,1-b][1,3]benzothiazolyl, a carbazolyl group, or a dibenzofuranyl group.

These heteroaryl groups (e.g. the group represented by the formula (65A), the group represented by the formula (65B) (benzimidazo[1,2-a]benzimidazo-5-yl), benzimidazolo[2,1-b][1,3]benzothiazolyl, a carbazolyl group, a dibenzofuranyl group or the like) are also preferably substituted by an unsubstituted aryl group having 6 to 10 ring carbon atoms, by an aryl group having 6 to 10 ring carbon atoms substituted by a substituted or unsubstituted alkyl group having 1 to 4 carbon atoms, or by a substituted or unsubstituted heteroaryl group having 2 to 10 ring carbon atoms.

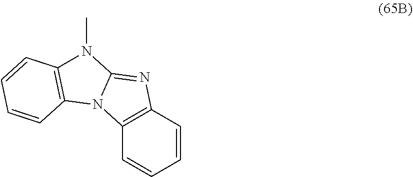 [SMILES: Cn1c2ccccc2n2c3ccccc3nc12]

A¹ to A⁸

In the third compound, A¹ to A⁸ are preferably each independently a substituted or unsubstituted arylene group having 6 to 24 ring carbon atoms, or a substituted or unsubstituted heteroarylene group having 2 to 30 ring carbon atoms.

The “substituted or unsubstituted arylene group having 6 to 24 ring carbon atoms” for A¹ to A⁸ are each independently a phenylene group, a naphthylene group (preferably 1-naphthylene group or 2-naphthylene group), a biphenylene group, a terphenylene group, a pyrenylene group, a 2-fluorenylene group, a 9-fluorenylene group, a phenanthrenylene group, or an anthranylene (anthrylene) group.

The “substituted or unsubstituted arylene group having 6 to 24 ring carbon atoms” in A¹ to A⁸ are each independently a 1,2-phenylene group, a 1,3-phenylene group, a 1,4-phenylene group, a 1,1′-biphenyl-4,4′-diyl group (—C₆H₄—C₆H₄—),

a 3,3′-m-terphenylene group, a 2-fluorenylene group, a 9-fluorenylene group, or a phenanthrenylene group.

These arylene groups (e.g. 1,2-phenylene group, 1,3-phenylene group, 1,4-phenylene group, 1,1′-biphenyl-4,4′-diyl group (—C₆H₄—C₆H₄—), 3,3′-m-terphenylene group, 2-fluorenylene group, 9-fluorenylene group, and phenanthrenylene group) are also preferably substituted by a triphenylsilyl group, an unsubstituted aryl group having 6 to 10 ring carbon atoms, an aryl group having 6 to 10 ring carbon atoms substituted by a substituted or unsubstituted alkyl group having 1 to 4 carbon atoms, or a substituted or unsubstituted heteroaryl group having 2 to 14 ring carbon atoms.

The “substituted or unsubstituted heteroarylene group having 2 to 30 ring carbon atoms” for A¹ to A⁸ each independently contains a nitrogen atom, an oxygen atom or a sulfur atom as a hetero atom, and is preferably a heterocyclic group formed by 5 to 30 atoms, the heterocyclic group at least having a fused six-membered ring of π-electron system.

Specifically, the “substituted or unsubstituted heteroarylene group having 2 to 30 ring carbon atoms” in A¹ to A⁸ are preferably each independently a group represented by a formula (3A) below (benzofuro[2,3-b]pyridylene), a group represented by a formula (3B) below (benzothiopheno[2,3-b]pyridylene), a group represented by a formula (3C) below (pyrido[2,3-b]indolylene), a group represented by a formula (3D) below (benzofuro[2,3-c]pyridylene), a group represented by a formula (3E) below (benzothiopheno[2,3-c]pyridylene), a group represented by a formula (3F) below (pyrido[2,3-c]indolylene), a group represented by a formula (3G) below, a group represented by a formula (3H) below (furo[3,2-b:4,5-b′]dipyridylene,benzofuro[3,2-b]pyridylene), a group represented by a formula (3I) below (benzothiopheno[3,2-b]pyridylene), a group represented by a formula (3J) below (thieno[3,2-b:4,5-b′]dipyridylene), a group represented by a formula (3K) below (pyrrolo[3,2-b:4,5-b′]dipyridylene), a thienylene group, a benzothiophenylene group, a thianthrenylene group, a furylene group, a furfurylene group, a 2H-pyranylene group, a benzofuranylene group, an isobenzofuranylene group, a group represented by a formula (3L) below (dibenzofuranylene), a group represented by a formula (3M) below (dibenzothiophenylene), a phenoxythienylene group, a pyrrolylene group, an imidazolylene group, a pyrazolylene group, a pyridylene group, a bipyridylene group, a triazinylene group, a pyrimidinylene group, a pyrazinylene group, a pyridazinylene group, an indolizinylene group, an isoindolylene group, an indolylene group, an indazolylene group, a purinylene group, a quinolizinylene group, a quinolylene group, an isoquinolylene group, a phthalazinylene group, an naphthyridinylene group, a quinoxalinylene group, a quinazolinylene group, a quinolinylene group, a pteridinylene group, a carbolinylene group, a benzotriazolylene group, a benzoxazolylene group, a phenanthridinylene group, an acridinylene group, a pyrimidinylene group, a phenanthrolinylene group, a phenazinylene group, an isothiazolylene group, a group represented by a formula (3N) below (phenothiazinylene), an isoxazolylene group, a furazanylene group, a group represented by a formula (3O) below (carbazolylene), a group represented by a formula (3P) below (carbazolylene), a group represented by a formula (3Q) below (benzimidazo[1,2-a]benzimidazo-2,5-ylene), a group represented by a formula (3R) below (benzimidazo-1,2-ylene), a group represented by a formula (3S) below (9,9-dialkylacridinylen), or a group represented by a formula (3T) below (phenoxazinylene).

It is more preferable that the “substituted or unsubstituted heteroarylene group having 2 to 30 ring carbon atoms” in A¹ to A⁸ are each independently a thienylene group, a benzothiophenylene group, a thianthrenylene group, a furylene group, a furfurylene group, a 2H-pyranylene group, a benzofuranylene group, an isobenzofuranylene group, a group represented by a formula (3L) below (dibenzofuranylene), a group represented by a formula (3M) below (dibenzothiophenylene), a phenoxythienylene group, a pyrrolylene group, an imidazolylene group, a pyridinylene group, an indolizinylene group, an isoindolylene group, an indolylene group, an indazolylene group, a carbazolylene group, phenothiazin-10-ylene, a group represented by a formula (3Q) below (benzimidazo[1,2-a]benzimidazo-2,5-ylene), phenoxazin-10-ylene, or 9,9-dialkylacridin-10-ylene.

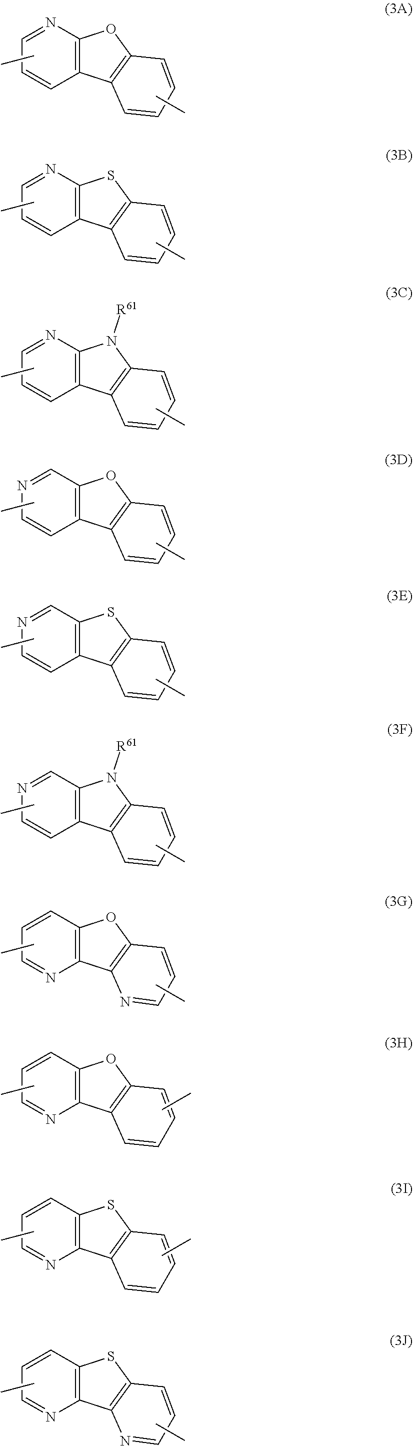

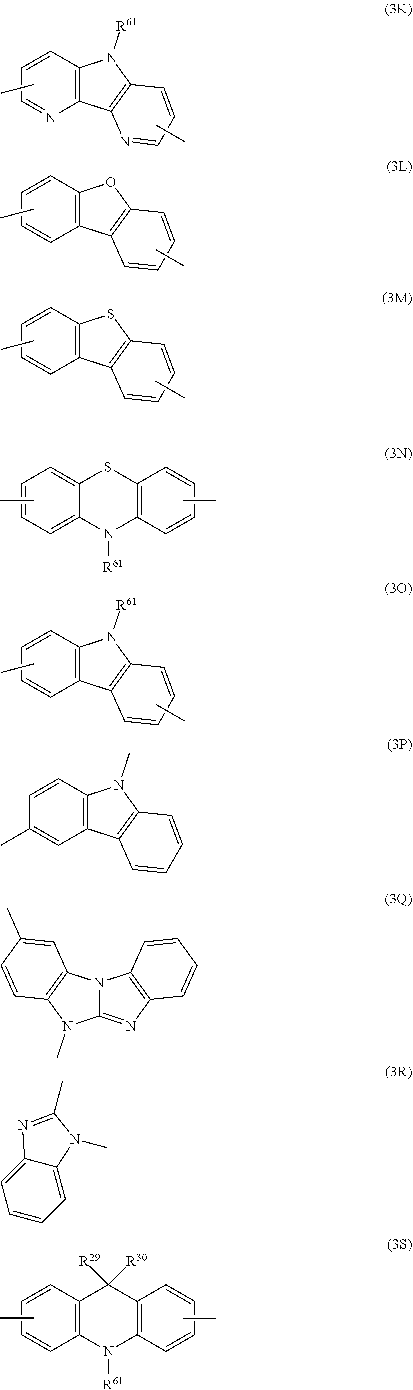

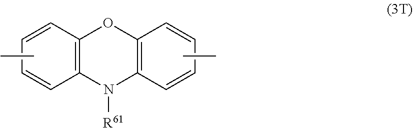

In the formula (3S), R²⁹ and R³⁰ are each a substituted or unsubstituted alkyl group having 1 to 25 carbon atoms. The substituent meant by “substituted or unsubstituted” in R²⁹ and R³⁰ represents the same as the substituent G.

R⁶¹ in the formulae (3C), (3F), (3K), (3N), (3O), (3S) and (3T) each independently represent a substituted or unsubstituted arylene group having 6 to 24 ring carbon atoms, or a substituted or unsubstituted heteroarylene group having 2 to 30 ring carbon atoms.

The substituent meant by “substituted or unsubstituted” in R⁶¹ represents the same as the substituent G.

Examples of the arylene group having 6 to 24 ring carbon atoms for R⁶¹ include a 1,3-phenylene group, a 1,1′-biphenyl-4,4′-diyl group (—C₆H₄—C₆H₄—), a 3,3′-m-terphenylene group, a 2-fluorenylene group, a 9-fluorenylene group, and a phenanthrylene group.

These arylene groups (e.g. 1,3-phenylene group, 1,1′-biphenyl-4,4′-diyl group (—C₆H₄—C₆H₄—), 3,3′-m-terphenylene group, 2-fluorenylene group, 9-fluorenylene group, and phenanthrenylene group) are also preferably substituted by an unsubstituted aryl group having 6 to 10 ring carbon atoms, an aryl group having 6 to 10 ring carbon atoms substituted by a substituted or unsubstituted alkyl group having 1 to 4 carbon atoms, or a substituted or unsubstituted heteroaryl group having 2 to 14 ring carbon atoms.

The substituent (i.e. the substituent G) in A¹ to A⁸ meant by “substituted arylene group having 6 to 24 ring carbon atoms” and “substituted heteroarylene group having 2 to 30 ring carbon atoms” is preferably a substituted or unsubstituted alkyl group having 1 to 18 carbon atoms (e.g. a methyl group, ethyl group, n-propyl group, isopropyl group, n-butyl group, isobutyl group, sec-butyl group, hexyl group, octyl group, 2-ethylhexyl group, and —CF₃), —CN, a triphenylsilyl group, an unsubstituted aryl group having 6 to 14 ring carbon atoms (e.g. a phenyl group, 1-naphthyl group, and 2-naphthyl group), an aryl group having 6 to 14 ring carbon atoms substituted by a fluorine atom, an aryl group having 6 to 14 ring carbon atoms substituted by a substituted or unsubstituted alkyl group having 1 to 18 carbon atoms, an unsubstituted heteroaryl group having 2 to 14 ring carbon atoms (e.g. benzimidazo[1,2-a]benzimidazo-5-yl, benzimidazo[1,2-a]benzimidazo-2-yl, carbazolyl group, and dibenzofuranyl group).

a heteroaryl group having 2 to 14 ring carbon atoms substituted by a fluorine atom, or a heteroaryl group having 2 to 14 ring carbon atoms substituted by a substituted or unsubstituted alkyl group having 1 to 18 carbon atoms.

A¹ to A⁸ in the formula (3) are more preferably each independently represented by any one of formulae (A11) to (A23), or (A25) to (A26).

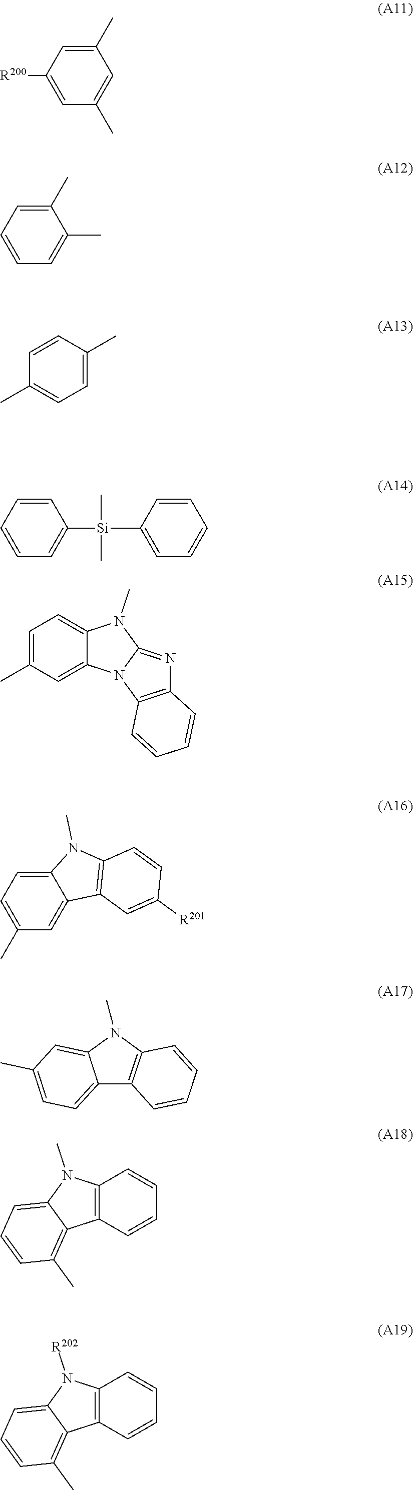

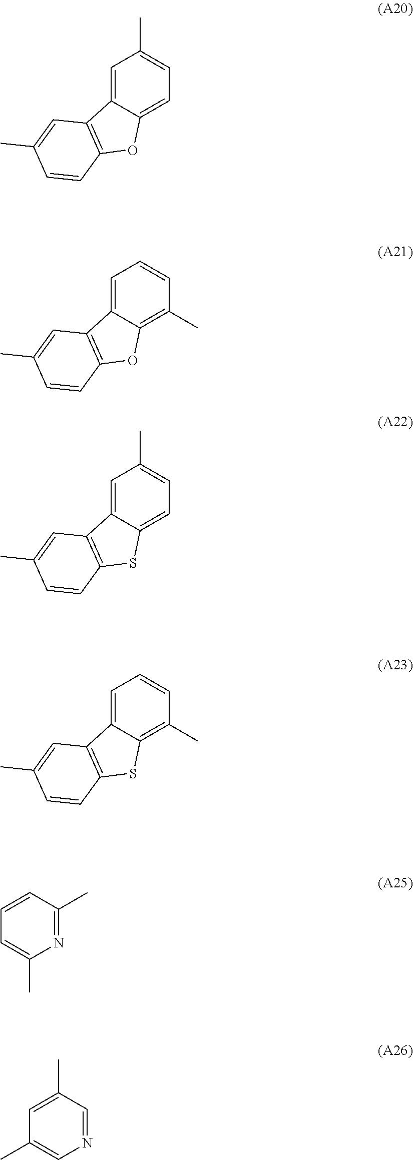

In the formula (A1), R²⁰⁰ is a hydrogen atom, S₁(Ph)³ (Ph represents a phenyl group) or a group represented by a formula (A24) below.

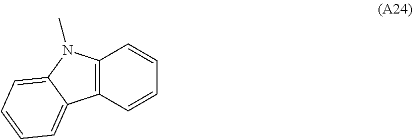

R²⁰¹ in the formula (A16) is a hydrogen atom or a cyano group.

R²⁰² in the formula (A19) is a phenyl group.

R¹⁶ and R¹⁷

Examples of the group represented by —SiR¹²R¹³R¹⁴ in the third compound include a trimethylsilyl group, a triethylsilyl group, a tert-butyldimethylsilyl group, a propyldimethylsilyl group, a triisopropylsilyl group, a triphenylsilyl group, a phenyldimethylsilyl group, a tert-butyldiphenylsilyl group, a tritolylsilyl group, a trixylylsilyl group, and a trinaphthylsilyl group.

In the third compound, examples of the group represented by —NR¹⁰R¹¹ include diphenylamino group and phenylnaphthylamino group.

In the third compound, examples of the group represented by —C(═O)R¹⁵ include 1-phenylcarbonyl group and naphthylcarbonyl group.

Examples of the unsubstituted aryl group having 6 to 24 ring carbon atoms” in R¹⁶ and R¹⁷ each independently include a phenyl group, 4-methylphenyl group, 4-methoxyphenyl group, naphthyl group (preferably 1-naphthyl group or 2-naphthyl group), biphenyl group, terphenyl group, pyrenyl group, 2-fluorenyl group, 9-fluorenyl group, phenanthryl group, anthryl group, and triphenylenyl group (preferably triphenylene-2-yl).

The “substituted or unsubstituted heteroarylene group having 2 to 30 ring carbon atoms” in R¹⁶ and R¹⁷ each independently includes a nitrogen atom, oxygen atom or a sulfur atom as a hetero atom, and is preferably a heterocyclic group formed by 5 to 30 atoms, the heterocyclic group at least having a fused six-membered ring of π-electron system.

Specifically, the “substituted or unsubstituted heteroaryl group having 2 to 30 ring carbon atoms” in each of R¹⁶ and R¹⁷ is independently 9H-pyrido[2,3-b]indolyl, benzofuro[2,3-b]pyridyl, benzothiopheno[2,3-b]pyridyl, 9H-pyrido[2,3-c]indolyl, benzofuro[2,3-c]pyridyl, benzothiopheno[2,3-c]pyridyl, furo[3,2-b:4,5-b′]dipyridyl, pyrrolo[3,2-b:4,5-b′]dipyridyl, thieno[3,2-b:4,5-b′]dipyridyl, thienyl group, benzothiophenyl group, dibenzothiophenyl group, thianthrenyl group, furyl group, furfuryl group, 2H-pyranyl group, benzofuranyl group, isobenzofuranyl group, dibenzofuranyl group, phenoxythienyl(phenoxythienyl) group, pyrrolyl group, imidazolyl group, pyrazolyl group, pyridyl group, bipyridyl group, triazinyl group, pyrimidinyl group, pyrazinyl group, pyridazynyl group, indolizinyl group, isoindolyl group, indolyl group, indazolyl group, purinyl group, quinolidinyl group, quinolyl group, isoquinolyl group, phthalazinyl(phthalazinyl) group, naphthyridinyl group, quinoxalinyl group, quinazolinyl(quinazolinyl) group, quinolinyl group, pteridinyl group, carbolinyl group, benzotriazolyl group, benzoxazolyl group, phenanthridinyl(phenanthridinyl) group, acridinyl group, pyrimidinyl group, phenanthrolinyl group, phenazinyl group, isothiazolyl group, phenothiazinyl group, isoxazolyl group, furazanyl group, benzimidazolyl group, benzimidazo[1,2-a]benzimidazo-5-yl, benzimidazo[1,2-a]benzimidazo-2-yl, benzimidazo[1,2-b][1,3]benzothiazolyl, carbazolyl group, 9-phenylcarbazolyl, azabenzimidazo[1,2-a]benzimidazolyl, phenoxazinyl group, or a group represented by a formula (G1) below.

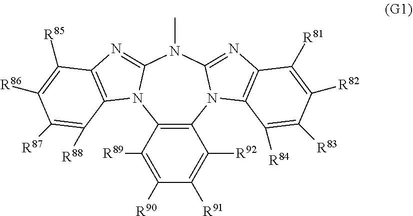

In the formula (G1), R⁸¹ to R⁹² each independently represent the same as R⁸⁰ in the formula (3).

The substituent (i.e. the substituent G) meant by the “substituted aryl group having 6 to 24 ring carbon atoms” in R¹⁶ is preferably a substituted or unsubstituted alkyl group having 1 to 18 carbon atoms (e.g. a methyl group, ethyl group, n-propyl group, isopropyl group, n-butyl group, isobutyl group, sec-butyl group, hexyl group, octyl group, 2-ethylhexyl group, and —CF₃), an unsubstituted aryl group having 6 to 14 ring carbon atoms, an aryl group having 6 to 14 ring carbon atoms substituted by a fluorine atom, an aryl group having 6 to 14 ring carbon atoms substituted by a substituted or unsubstituted alkyl group having 1 to 18 carbon atoms, or an aryl group having 6 to 14 ring carbon atoms substituted by a substituted or unsubstituted heteroaryl group having 2 to 14 ring carbon atoms.

The substituent (i.e. the substituent G) meant by the “substituted heteroaryl group having 2 to 30 ring carbon atoms” in R¹⁷ is preferably an unsubstituted heteroaryl group having 2 to 14 ring carbon atoms, a heteroaryl group having 2 to 14 ring carbon atoms substituted by a fluorine atom, or a heteroaryl group having 2 to 14 ring carbon atoms substituted by a substituted or unsubstituted alkyl group having 1 to 18 carbon atoms.

It is preferable that the “substituted or unsubstituted heteroaryl group having 2 to 30 ring carbon atoms” in R¹⁶ and R¹⁷ are each independently a pyridyl group, a triazinyl group, a pyrimidinyl group, 9h-pyrido[2,3-b]indolyl, benzofuro[2,3-b]pyridyl, benzothiopheno[2,3-b]pyridyl, 9H-pyrido[2,3-c]indolyl, benzofuro[2,3-c]pyridyl, benzothiopheno[2,3-c]pyridyl, furo[3,2-b:4,5-b′]dipyridyl, pyrrolo[3,2-b:4,5-b′]dipyridyl, thieno[3,2-b:4,5-b′]dipyridyl, a group represented by a formula (C1) below (benzimidazol-2-yl), a group represented by a formula (C2) below (benzimidazol-1-yl), a group represented by a formula (C3) below (benzimidazo[1,2-a]benzimidazo-5-yl), a group represented by a formula (C4) below (benzimidazo[1,2-a]benzimidazo-2-yl), a group represented by a formula (C5-1) below (benzimidazo[2,1-b][1,3]benzothiazolyl), a group represented by a formula (C5-2) below (benzimidazo[2,1-b][1,3]benzothiazolyl), a carbazolyl group, a dibenzofuranyl group, a dibenzothiophenyl group, a group represented by a formula (C6) below (4-azabenzimidazo[1,2-a]benzimidazo-6-yl), a group represented by a formula (C7) below (3-azabenzimidazo[1,2-a]benzimidazo-6-yl), a group represented by a formula (C8) below (2-azabenzimidazo[1,2-a]benzimidazo-6-yl), a group represented by a formula (C9) below (1-azabenzimidazo[1,2-a]benzimidazo-6-yl), a group represented by a formula (C10) below (4-azabenzimidazo[1,2-a]benzimidazo-5-yl), a group represented by a formula (C11) below (3-azabenzimidazo[1,2-a]benzimidazo-5-yl), a group represented by a formula (C12) below (2-azabenzimidazo[1,2-a]benzimidazo-5-yl), a group represented by a formula (C13) below (1-azabenzimidazo[1,2-a]benzimidazo-5-yl), or a group represented by a formula (C14) below.

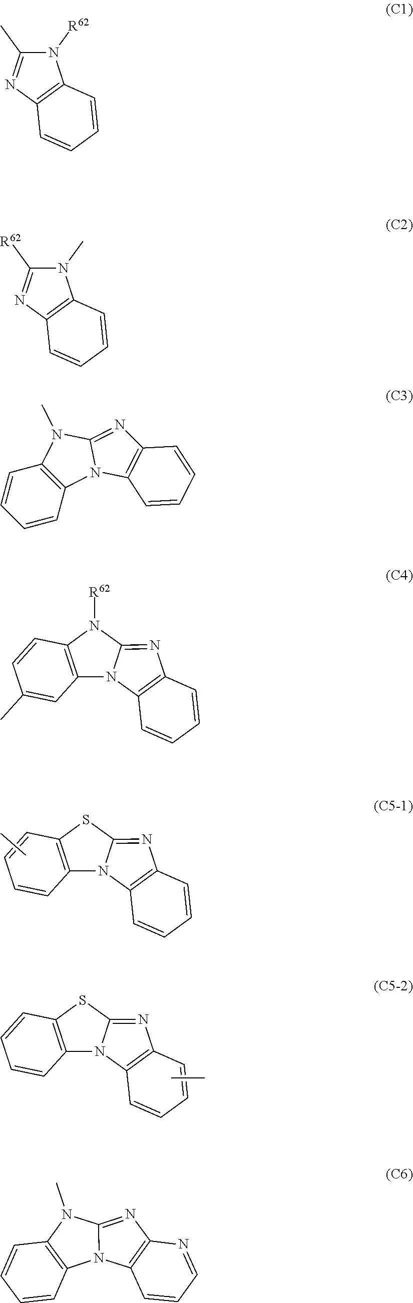

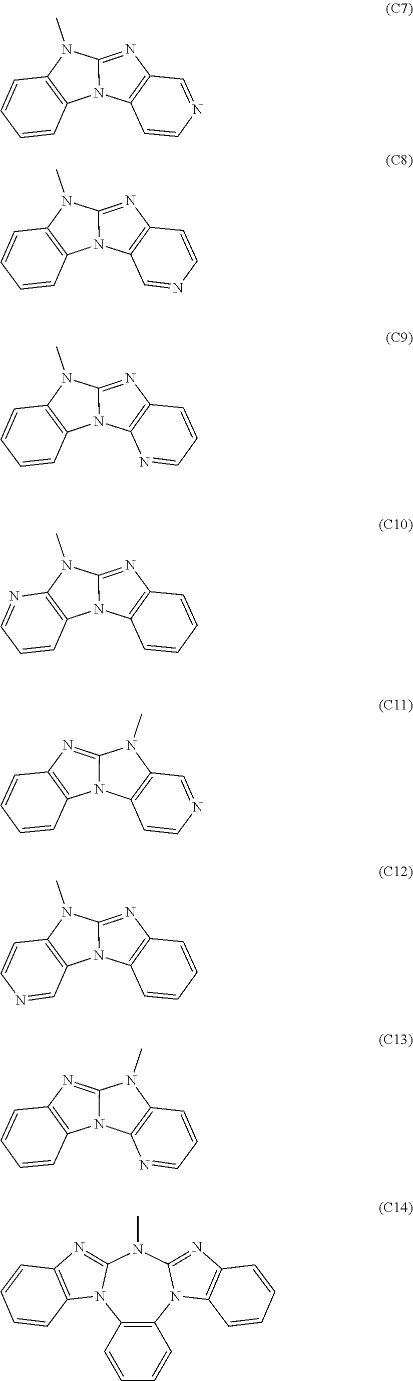

In the formulae (C1), (C2) and (C4), R⁶² each independently represent: an unsubstituted aryl group having 6 to 10 ring carbon atoms, an aryl group having 6 to 10 ring carbon atoms substituted by a substituted or unsubstituted alkyl group having 1 to 4 carbon atoms, or a heteroaryl group having 2 to 14 ring carbon atoms.

The group represented by the formula (C14) is substituted or unsubstituted, the substituent for the group represented by the formula (C14) being an unsubstituted aryl group having 6 to 10 ring carbon atoms, an aryl group having 6 to 10 ring carbon atoms substituted by a substituted or unsubstituted alkyl group having 1 to 4 carbon atoms, or a heteroaryl group having 2 to 14 ring carbon atoms.

In the third compound, it is more preferable that R¹⁶ is —CN or a group represented by any one of formulae (B11) to (B27) below.

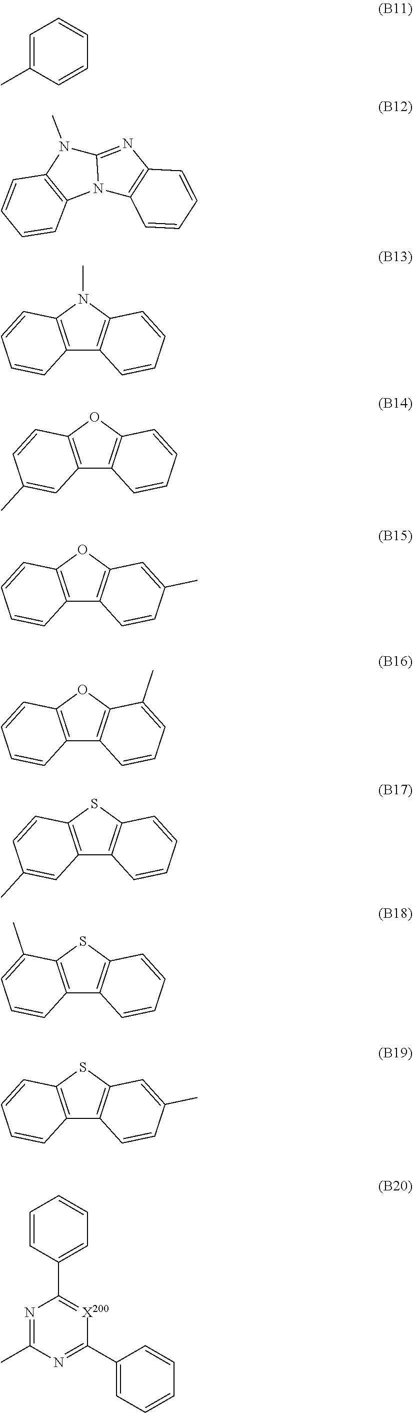

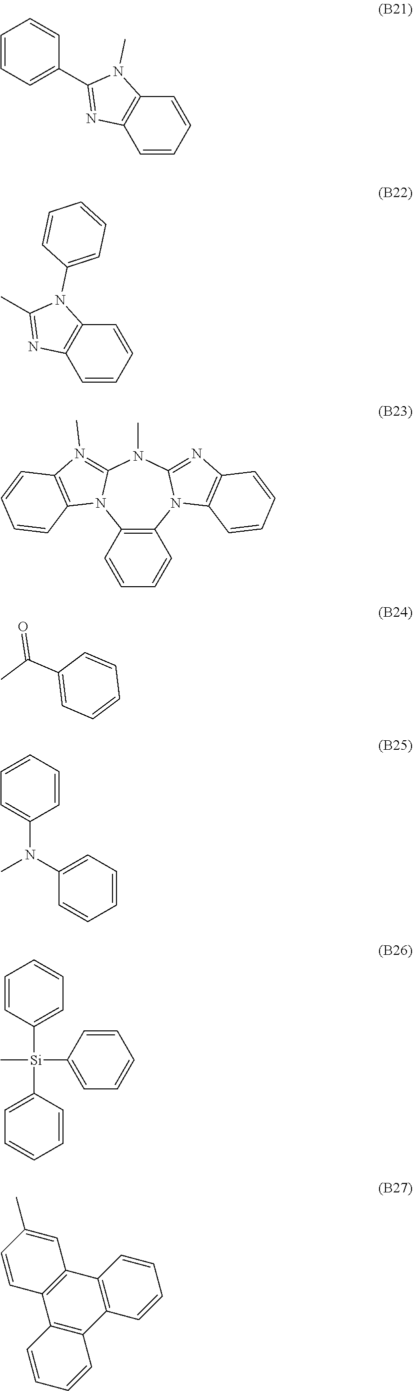

X²⁰⁰ in the formula (B20) is a nitrogen atom or CH. However, when R¹⁶ is —CN or any one of the formulae (B12), (B13), (B21), (B23) and (B25), “o” in -(A¹)o-(A²)p-(A³)q-(A⁴)r-R¹⁶ is not zero.

In the third compound, R¹⁷ is preferably —CN, or any one of groups represented by the formulae (B11) to (B27). It should be noted that, when R¹⁷ is a group represented by the formula (B20), X²⁰⁰ in the formula (B20) is a nitrogen atom or CH.

In the exemplary embodiment, the third compound is preferably a compound represented by a formula (31) below.

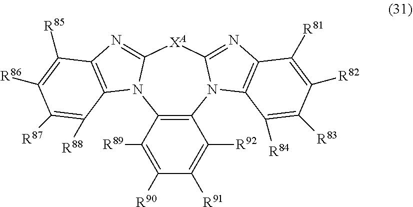

In the formula (31), X^{A} represents the same as X^{A} in the formula (3); and

R⁸¹ to R⁹² each independently represent the same as R⁸⁰ in the formula (3).

In the exemplary embodiment, the third compound is more preferably a compound represented by a formula (32) below.

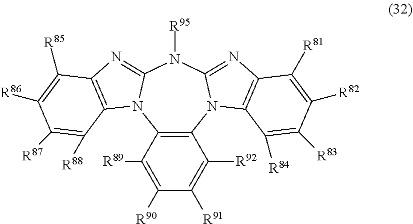

In the formula (32), R⁹⁵ represents the same as R⁹⁵ in the formula (3);

R⁸¹ to R⁹² each independently represent the same as R⁸⁰ in the formula (3).

In the formula (32), R⁹⁵ is preferably a group represented by -(A¹)o-(A²)p-(A³)q-(A⁴)r-R¹⁶. R¹⁶ is preferably a group selected from —CN and the group consisting of groups represented by the formulae (B11) to (B25).

In the formula (32), it is preferable that R⁹⁰ and R⁹¹ are hydrogen atoms, R⁹⁰ and R⁹¹ are cyano groups, one of R⁹⁰ and R⁹¹ is a hydrogen atom and the other is a cyano group, or one of R⁹⁰ and R⁹¹ is a hydrogen atom and the other is a group represented by -(A⁵)s-(A⁶)t-(A⁷)u-(A⁸)v-R¹⁷.

In the formula (32), A¹ to A⁸ are preferably each independently a group represented by any one of formulae (A11) to (A23).

In the formula (32), R¹⁷ is preferably a group selected from the group consisting of a cyano group, and groups represented by the formulae (B11) to (B25). It should be noted that, when R¹⁷ is a group represented by the formula (B20), X²⁰⁰ in the formula (B20) is a nitrogen atom or CH.

In the exemplary embodiment, the third compound is more preferably a compound represented by a formula (33) below.

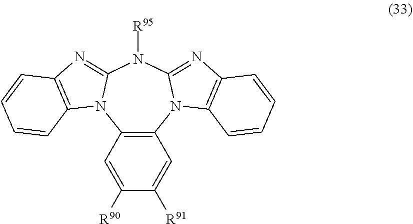

In the formula (33), R⁹⁵ represents the same as R⁹⁵ in the formula (3);

R⁹⁰ and R⁹¹ are hydrogen atoms, R⁹⁰ and R⁹¹ are cyano groups, one of R⁹⁰ and R⁹¹ is a hydrogen atom and the other is a cyano group, or one of R⁹⁰ and R⁹¹ is a hydrogen atom and the other is a group represented by -(A⁵)s-(A⁶)t-(A⁷)u-(A⁸)v-R¹⁷;

s, t, u and v are each independently 0 or 1;

A⁵ to A⁸ are each independently a group selected from the group consisting of groups represented by formulae (A11) to (A23); and

R¹⁷ is a group selected from the group consisting of a cyano group, and the groups represented by the formulae (B11) to (B25). It should be noted that, when R¹⁷ is a group represented by the formula (B20), X²⁰⁰ in the formula (B20) is a nitrogen atom or CH.

In the third compound, it is preferable that R⁹⁵ is a group represented by —(A¹)o-(A²)p-(A³)q-(A⁴)r-R¹⁶ and R¹⁶ is a group selected from groups represented by formulae (A1) and (A2) below.

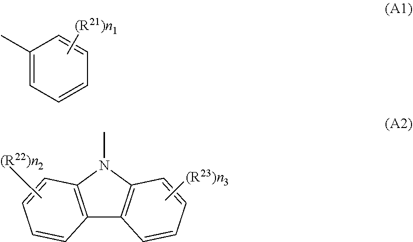

In the formula (A1), R²¹ is a hydrogen atom or a substituent, R²¹ as the substituent is each independently an unsubstituted alkyl group having 1 to 18 carbon atoms, an unsubstituted aryl group having 6 to 24 ring carbon atoms, an unsubstituted heteroaryl group having 2 to 30 ring carbon atoms, an aryl group having 6 to 24 ring carbon atoms substituted by a substituted or unsubstituted alkyl group having 1 to 18 carbon atoms, a heteroaryl group having 2 to 30 ring carbon atoms substituted by a substituted or unsubstituted alkyl group having 1 to 18 carbon atoms, a heteroaryl group having 2 to 30 ring carbon atoms substituted by a substituted or unsubstituted aryl group having 6 to 24 ring carbon atoms, or an aryl group having 6 to 24 ring carbon atoms substituted by a substituted or unsubstituted heteroaryl group having 2 to 30 ring carbon atoms; n₁ is 5; and a plurality of R²¹ are mutually the same or different.

In the formula (A2), R²² and R²³ each independently represent a hydrogen atom or a substituent; R²² and R²³ as the substituent each independently represent the same as R²¹ in the formula (A1); n₂ and n₃ are each 4; a plurality of R²² are mutually the same or different; and a plurality of R²³ are mutually the same or different.

In the formula (33), R⁹⁵ is a group represented by a formula (33a) below, or a group represented by a formula (33b) below;

R⁹⁰ and R⁹¹ are hydrogen atoms, R⁹⁰ and R⁹¹ are cyano groups, one of R⁹⁰ and R⁹¹ is a hydrogen atom and the other is a cyano group, or one of R⁹⁰ and R⁹¹ is a hydrogen atom and the other is a group represented by -(A⁵)s-(A⁶)t-(A⁷)u-(A⁸)v-R¹⁷.

The group represented by the formula -(A⁵)s-(A⁶)t-(A⁷)u-(A⁸)v-R¹⁷ is more preferably a group represented by a formula (33b) below.

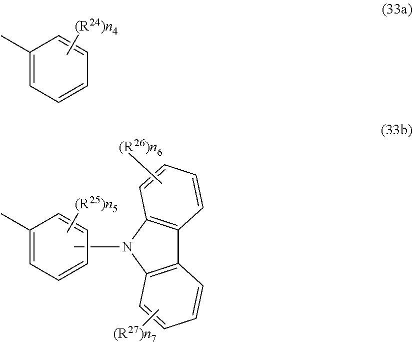

In the formulae (33a) and (33b), R²⁴ to R²⁷ each independently represent a hydrogen atom or a substituent; R²⁴ to R²⁷ as the substituents are each independently an unsubstituted alkyl group having 1 to 18 carbon atoms, an unsubstituted aryl group having 6 to 24 ring carbon atoms, an unsubstituted heteroaryl group having 2 to 30 ring carbon atoms, an aryl group having 6 to 24 ring carbon atoms substituted by a substituted or unsubstituted alkyl group having 1 to 18 carbon atoms, a heteroaryl group having 2 to 30 ring carbon atoms substituted by a substituted or unsubstituted alkyl group having 1 to 18 carbon atoms, a heteroaryl group having 2 to 30 ring carbon atoms substituted by a substituted or unsubstituted aryl group having 6 to 24 ring carbon atoms, or an aryl group having 6 to 24 ring carbon atoms substituted by a substituted or unsubstituted heteroaryl group having 2 to 30 ring carbon atoms;

n₄ is 5; n₅, n₆ and n₇ are each 4;

a plurality of R²⁴ are mutually the same or different;

a plurality of R²⁵ are mutually the same or different;

a plurality of R²⁶ are mutually the same or different; and

a plurality of R²⁷ are mutually the same or different.

In the organic EL device of the exemplary embodiment, the third compound contained in the emitting layer is also preferably a compound represented by a formula (34) below.

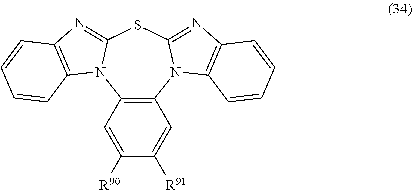

In the formula (34), R⁹⁰ to R⁹¹ each independently represent the same as R⁸⁰ in the formula (3).

Examples of the “substituted or unsubstituted alkyl group having 1 to 25 carbon atoms” in the third component of the exemplary embodiment are alkyl groups having 1 to 25 carbon atoms mentioned in a later-described “Description of Substituents in the Formula of First Compound and Second Compound (sometimes referred to as description of the substituents).” Preferable alkyl groups in the third compound are also the same as preferable alkyl groups mentioned in the later-described “description of the substituents.”

Similarly, examples of the “substituted or unsubstituted alkyl group having 1 to 18 carbon atoms” are alkyl groups having 1 to 18 carbon atoms mentioned in the later-described “description of the substituents.” Preferable alkyl groups for the third compound are also the same as preferable alkyl groups mentioned in the later-described “description of the substituents.”

Similarly, examples of the “substituted or unsubstituted aryl group having 6 to 24 ring carbon atoms” are aryl groups having 6 to 24 ring carbon atoms mentioned in the later-described “description of the substituents.” Preferable aryl groups for the third compound are also the same as preferable aryl groups mentioned in the later-described “description of the substituents.”

Similarly, examples of the “substituted or unsubstituted aryl group having 6 to 18 ring carbon atoms” are aryl groups having 6 to 18 ring carbon atoms mentioned in the later-described “description of the substituents.” Preferable aryl groups for the third compound are also the same as preferable aryl groups mentioned in the later-described “description of the substituents.”

Examples of the “substituted or unsubstituted arylene group having 6 to 24 ring carbon atoms” are divalent groups obtained by removing an atom from the aryl groups having 6 to 24 ring carbon atoms (i.e. the aryl groups having 6 to 24 ring carbon atoms among the aryl groups mentioned in the later-described “description of the substituents”). Preferable arylene groups for the third compound are also the same as divalent groups obtained by removing an atom from the preferable aryl groups (i.e. the preferable aryl groups mentioned in the later-described “description of the substituents”).

Examples of the “substituted or unsubstituted heteroaryl group having 2 to 30 ring carbon atoms” are heteroaryl groups having 2 to 30 ring carbon atoms among the heteroaryl groups mentioned in the later-described “description of the substituents.” Preferable heteroaryl groups for the third compound are also the same as preferable heteroaryl groups mentioned in the later-described “description of the substituents.”

Examples of the “substituted or unsubstituted heteroarylene group having 2 to 30 ring carbon atoms” for the third compound in the exemplary embodiment are divalent groups obtained by removing an atom from the heteroaryl groups having 2 to 30 ring carbon atoms (i.e. the heteroaryl groups having 2 to 30 ring carbon atoms among the heteroaryl groups mentioned in the later-described “description of the substituents”). Preferable heteroarylene groups for the third compound are also the same as divalent groups obtained by removing an atom from the preferable heteroaryl groups (i.e. the preferable heteroaryl groups mentioned in the later-described “description of the substituents”).

Examples of the “substituted or unsubstituted alkoxy group having 1 to 18 carbon atoms” are alkoxy groups having 1 to 18 ring carbon atoms among the alkoxy groups mentioned in the later-described “description of the substituents.” Preferable alkoxy groups for the third compound are also the same as preferable alkoxy groups mentioned in the later-described “description of the substituents.”

Specific examples of the third compound (the compound represented by the formula (3)) of the exemplary embodiment are shown below. It should be noted that the third compound in the invention is by no means limited to the specific examples below.

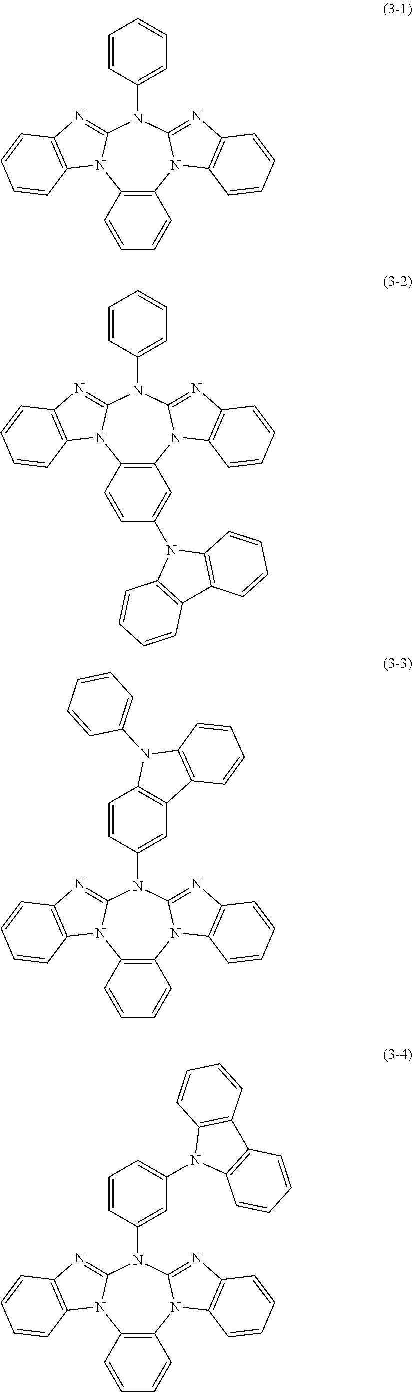

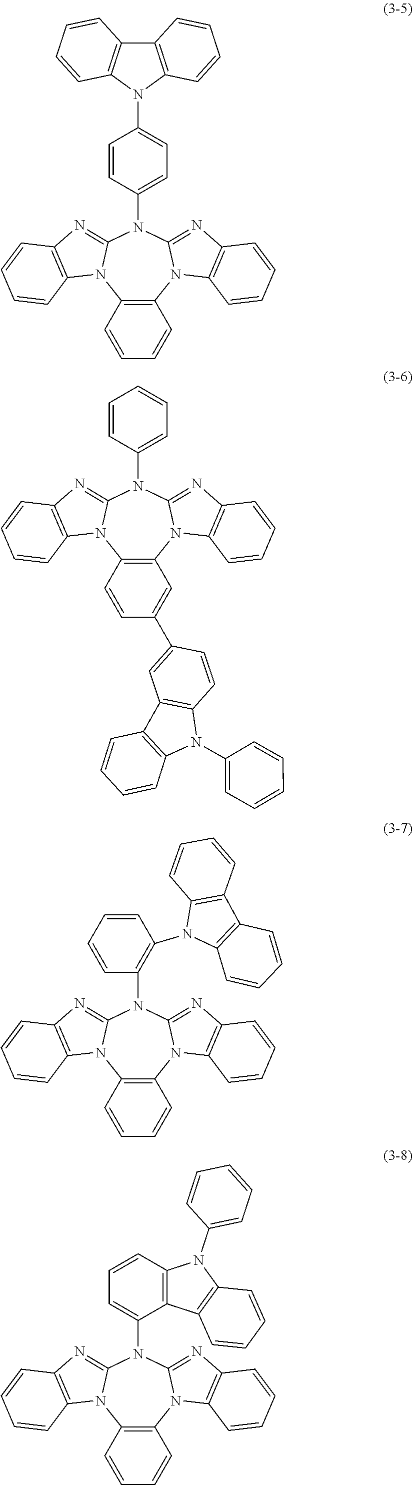

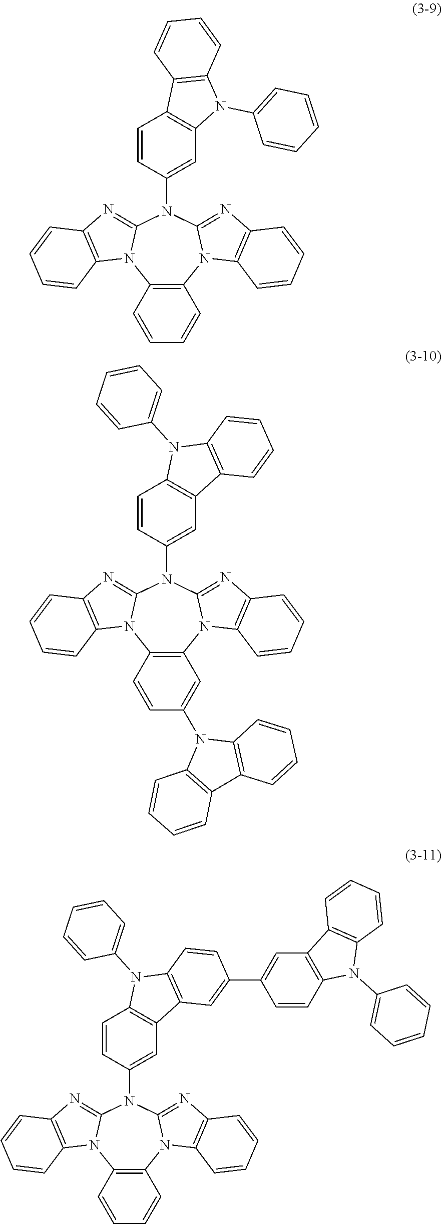

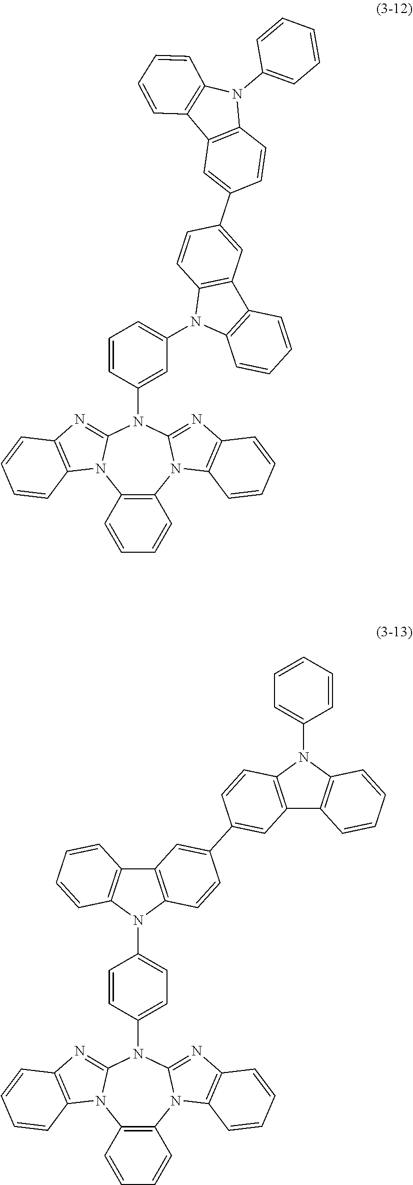 [SMILES: c1ccc(-n2c3ccccc3c3cc(-c4ccc5c(c4)c4ccccc4n5-c4cccc(-n5c6nc7ccccc7n6c6ccccc6n6c7ccccc7nc56)c4)ccc32)cc1 ; c1ccc(-n2c3ccccc3c3cc(-c4ccc5c(c4)c4ccccc4n5-c4ccc(-n5c6nc7ccccc7n6c6ccccc6n6c7ccccc7nc56)cc4)ccc32)cc1]

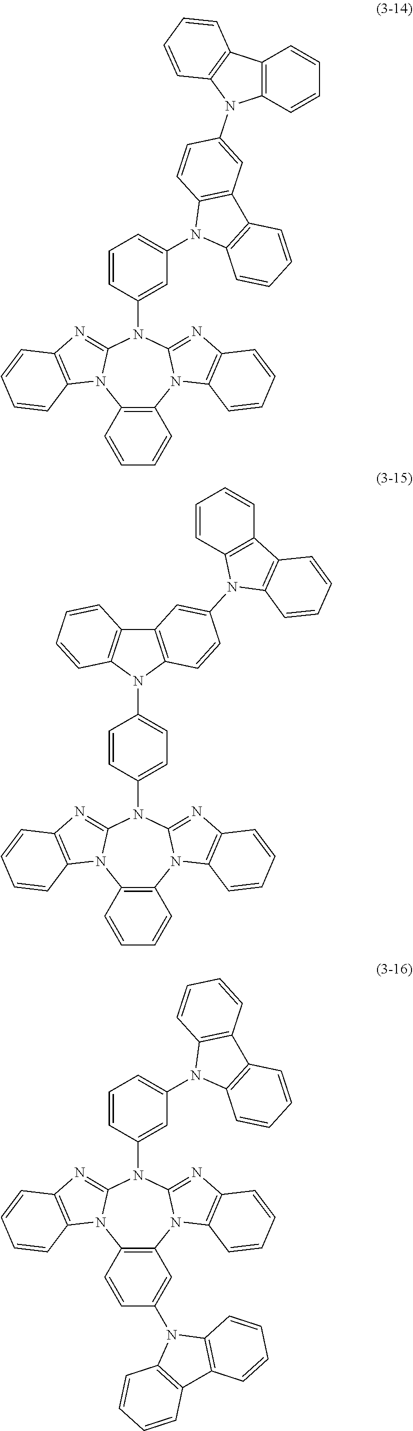 [SMILES: c1cc(-n2c3ccccc3c3cc(-n4c5ccccc5c5ccccc54)ccc32)cc(-n2c3nc4ccccc4n3c3ccccc3n3c4ccccc4nc23)c1 ; c1ccc2c(c1)nc1n(-c3ccc(-n4c5ccccc5c5cc(-n6c7ccccc7c7ccccc76)ccc54)cc3)c3nc4ccccc4n3c3ccccc3n21 ; c1cc(-n2c3ccccc3c3ccccc32)cc(-n2c3nc4ccccc4n3c3ccc(-n4c5ccccc5c5ccccc54)cc3n3c4ccccc4nc23)c1]

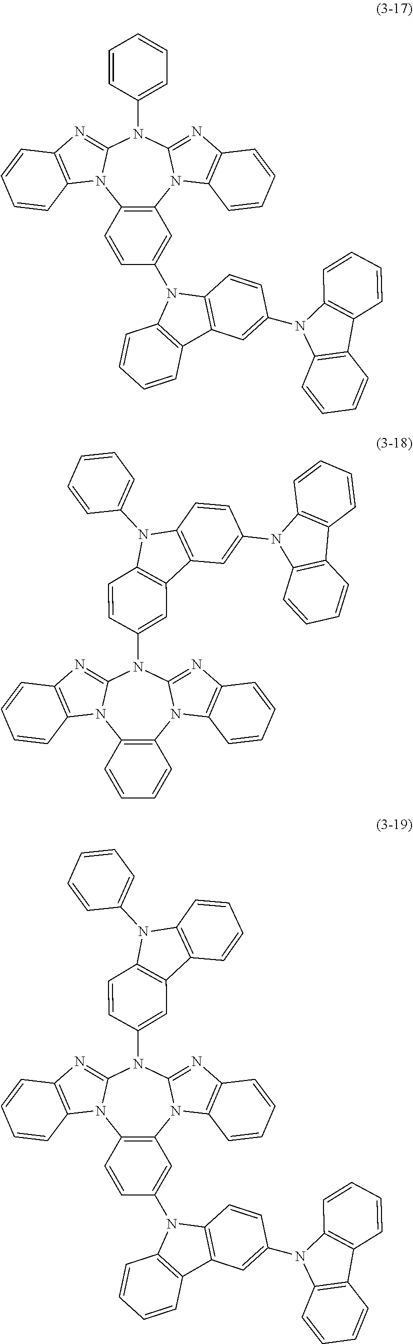 [SMILES: c1ccc(-n2c3nc4ccccc4n3c3ccc(-n4c5ccccc5c5cc(-n6c7ccccc7c7ccccc76)ccc54)cc3n3c4ccccc4nc23)cc1 ; c1ccc(-n2c3ccc(-n4c5ccccc5c5ccccc54)cc3c3cc(-n4c5nc6ccccc6n5c5ccccc5n5c6ccccc6nc45)ccc32)cc1 ; c1ccc(-n2c3ccccc3c3cc(-n4c5nc6ccccc6n5c5ccc(-n6c7ccccc7c7cc(-n8c9ccccc9c9ccccc98)ccc76)cc5n5c6ccccc6nc45)ccc32)cc1]

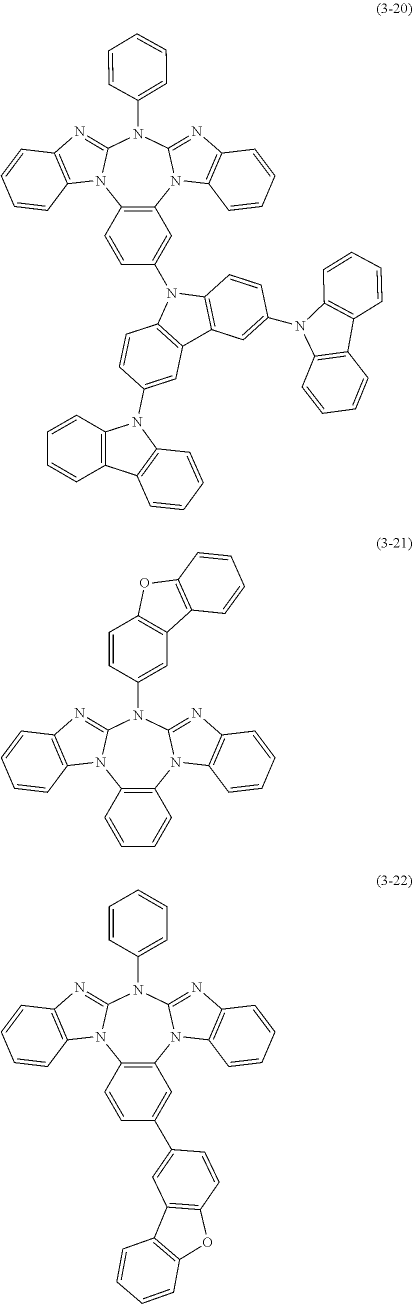

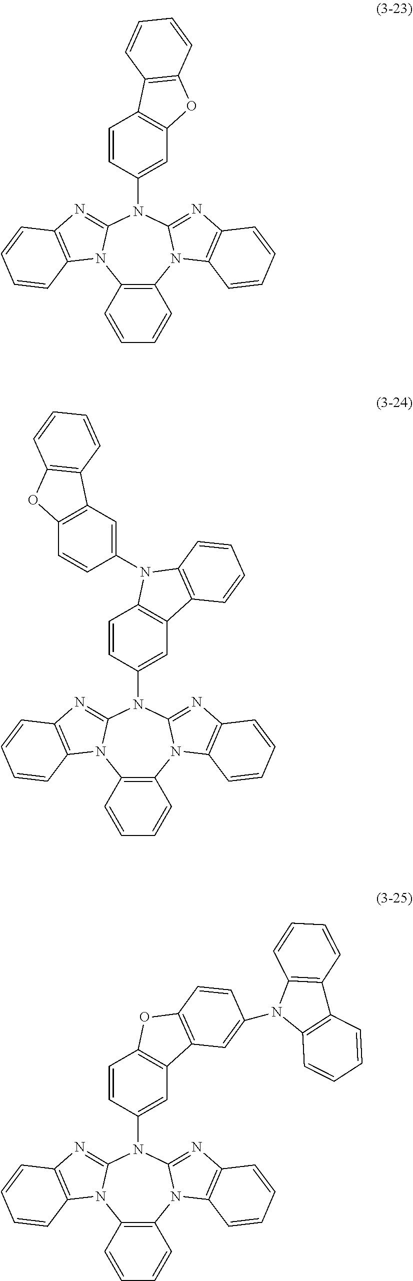 [SMILES: c1ccc2c(c1)nc1n(-c3ccc4c(c3)oc3ccccc34)c3nc4ccccc4n3c3ccccc3n21 ; c1ccc2c(c1)nc1n(-c3ccc4c(c3)c3ccccc3n4-c3ccc4oc5ccccc5c4c3)c3nc4ccccc4n3c3ccccc3n21 ; c1ccc2c(c1)nc1n(-c3ccc4oc5ccc(-n6c7ccccc7c7ccccc76)cc5c4c3)c3nc4ccccc4n3c3ccccc3n21]

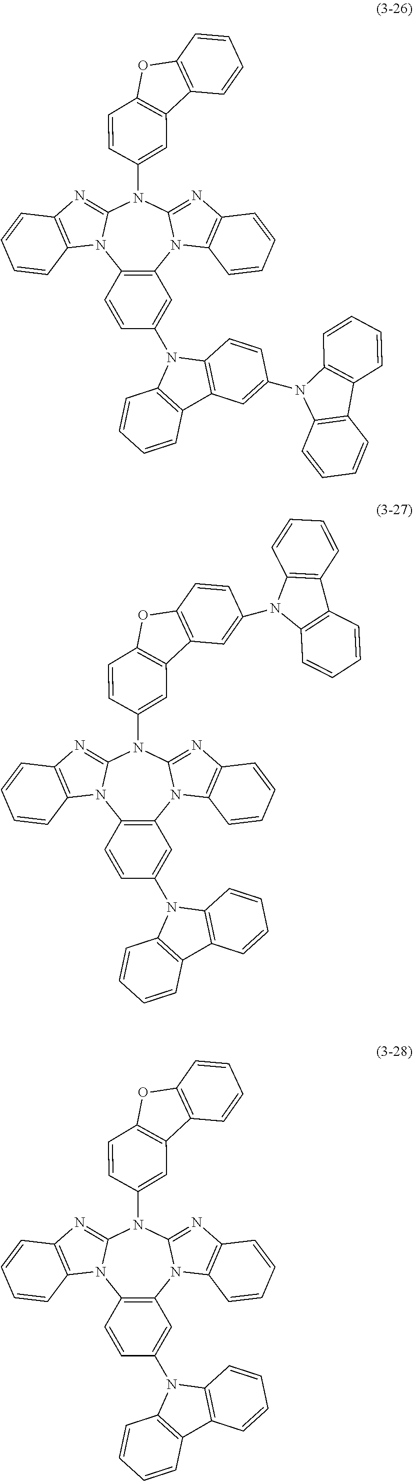

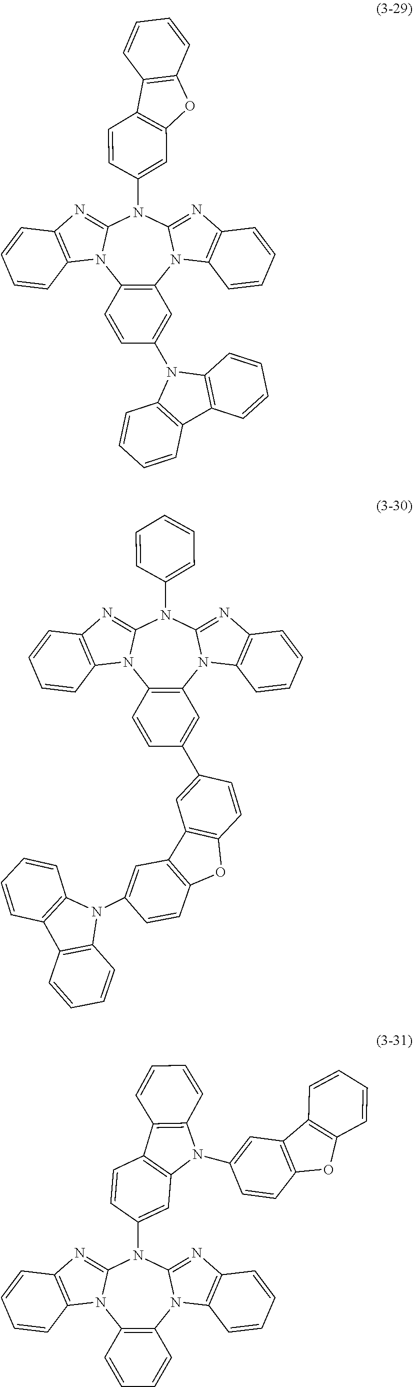 [SMILES: c1ccc2c(c1)nc1n(-c3ccc4c(c3)oc3ccccc34)c3nc4ccccc4n3c3cc(-n4c5ccccc5c5ccccc54)ccc3n21 ; c1ccc(-n2c3nc4ccccc4n3c3ccc(-c4ccc5oc6ccc(-n7c8ccccc8c8ccccc87)cc6c5c4)cc3n3c4ccccc4nc23)cc1 ; c1ccc2c(c1)nc1n(-c3ccc4c5ccccc5n(-c5ccc6oc7ccccc7c6c5)c4c3)c3nc4ccccc4n3c3ccccc3n21]

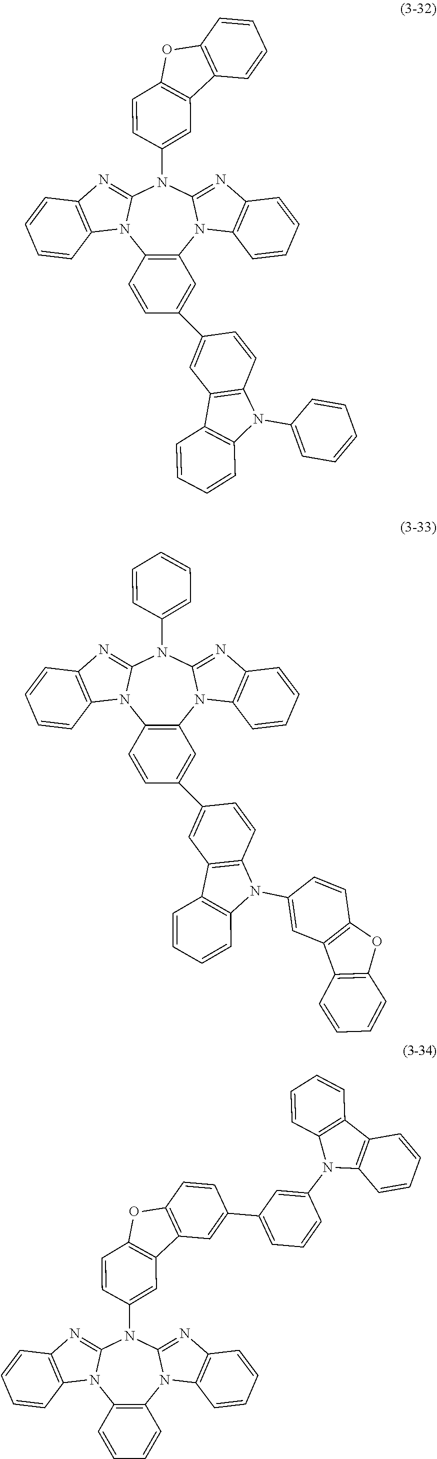 [SMILES: c1ccc(-n2c3ccccc3c3cc(-c4ccc5c(c4)n4c6ccccc6nc4n(-c4ccc6oc7ccccc7c6c4)c4nc6ccccc6n54)ccc32)cc1 ; c1ccc(-n2c3nc4ccccc4n3c3ccc(-c4ccc5c(c4)c4ccccc4n5-c4ccc5oc6ccccc6c5c4)cc3n3c4ccccc4nc23)cc1 ; c1cc(-c2ccc3oc4ccc(-n5c6nc7ccccc7n6c6ccccc6n6c7ccccc7nc56)cc4c3c2)cc(-n2c3ccccc3c3ccccc32)c1]

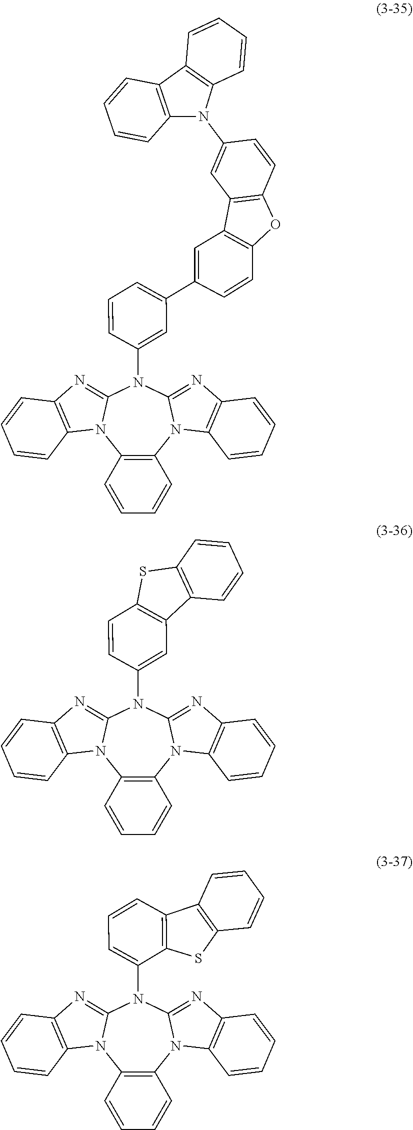 [SMILES: c1cc(-c2ccc3oc4ccc(-n5c6ccccc6c6ccccc65)cc4c3c2)cc(-n2c3nc4ccccc4n3c3ccccc3n3c4ccccc4nc23)c1 ; c1ccc2c(c1)nc1n(-c3ccc4sc5ccccc5c4c3)c3nc4ccccc4n3c3ccccc3n21 ; c1ccc2c(c1)nc1n(-c3cccc4c3sc3ccccc34)c3nc4ccccc4n3c3ccccc3n21]

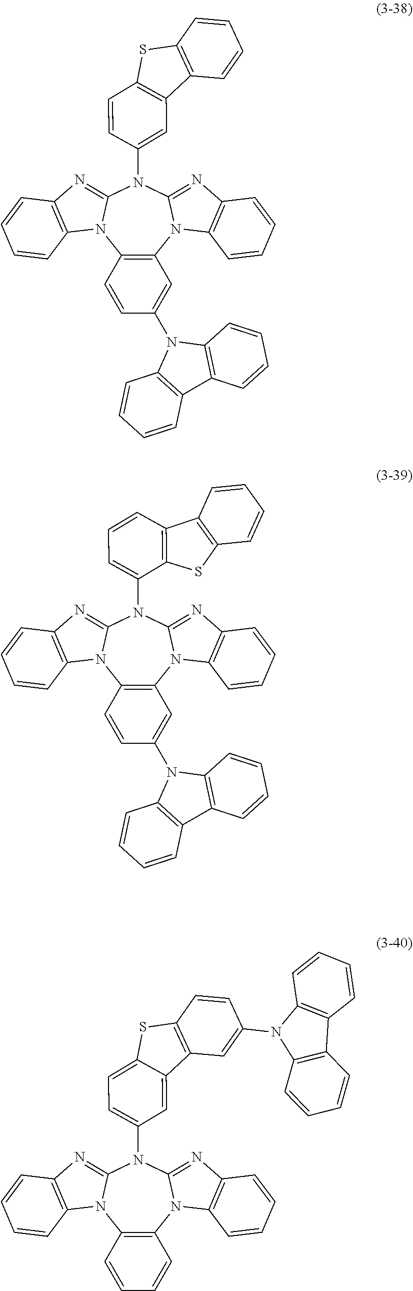 [SMILES: c1ccc2c(c1)nc1n(-c3ccc4sc5ccccc5c4c3)c3nc4ccccc4n3c3cc(-n4c5ccccc5c5ccccc54)ccc3n21 ; c1ccc2c(c1)nc1n(-c3cccc4c3sc3ccccc34)c3nc4ccccc4n3c3cc(-n4c5ccccc5c5ccccc54)ccc3n21 ; c1ccc2c(c1)nc1n(-c3ccc4sc5ccc(-n6c7ccccc7c7ccccc76)cc5c4c3)c3nc4ccccc4n3c3ccccc3n21]

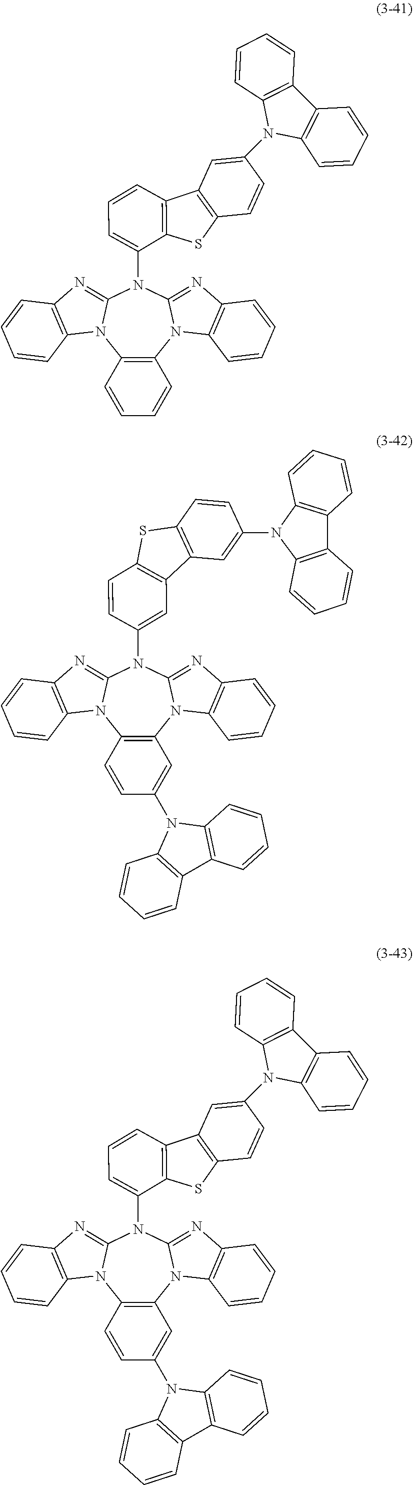 [SMILES: c1ccc2c(c1)nc1n(-c3cccc4c3sc3ccc(-n5c6ccccc6c6ccccc65)cc34)c3nc4ccccc4n3c3ccccc3n21 ; c1ccc2c(c1)nc1n(-c3ccc4sc5ccc(-n6c7ccccc7c7ccccc76)cc5c4c3)c3nc4ccccc4n3c3cc(-n4c5ccccc5c5ccccc54)ccc3n21 ; c1ccc2c(c1)nc1n(-c3cccc4c3sc3ccc(-n5c6ccccc6c6ccccc65)cc34)c3nc4ccccc4n3c3cc(-n4c5ccccc5c5ccccc54)ccc3n21]

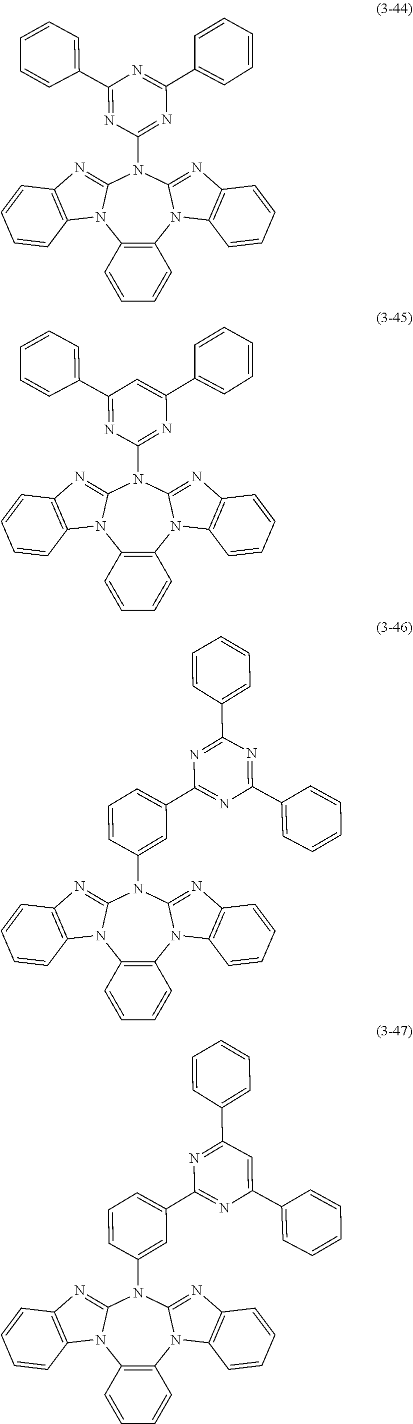 [SMILES: c1ccc(-c2nc(-c3ccccc3)nc(-n3c4nc5ccccc5n4c4ccccc4n4c5ccccc5nc34)n2)cc1 ; c1ccc(-c2cc(-c3ccccc3)nc(-n3c4nc5ccccc5n4c4ccccc4n4c5ccccc5nc34)n2)cc1 ; c1ccc(-c2nc(-c3ccccc3)nc(-c3cccc(-n4c5nc6ccccc6n5c5ccccc5n5c6ccccc6nc45)c3)n2)cc1 ; c1ccc(-c2cc(-c3ccccc3)nc(-c3cccc(-n4c5nc6ccccc6n5c5ccccc5n5c6ccccc6nc45)c3)n2)cc1]

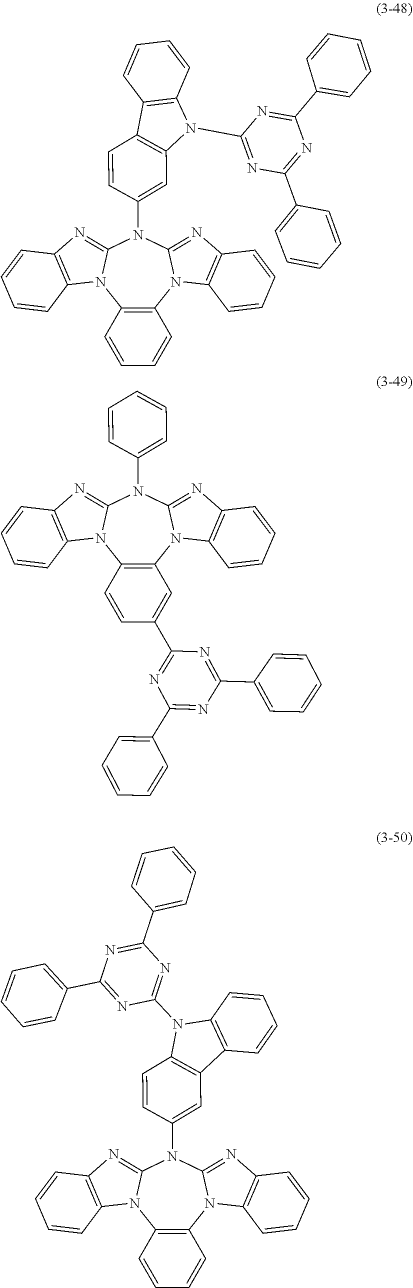

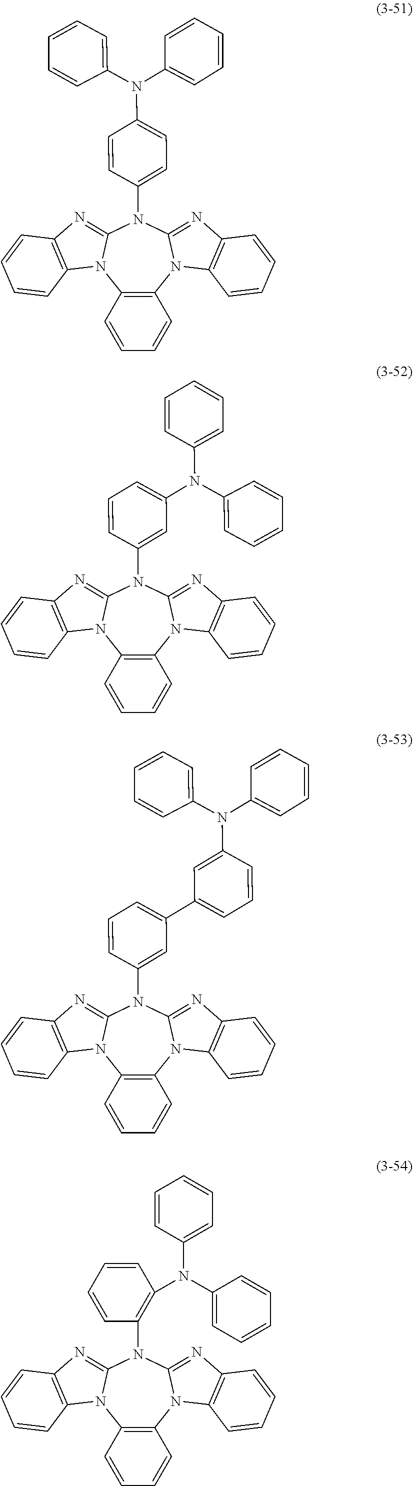

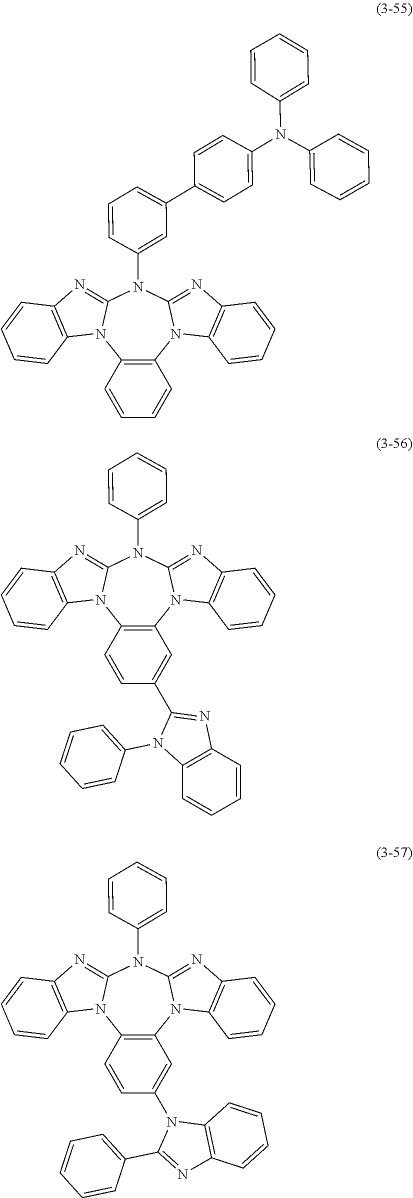

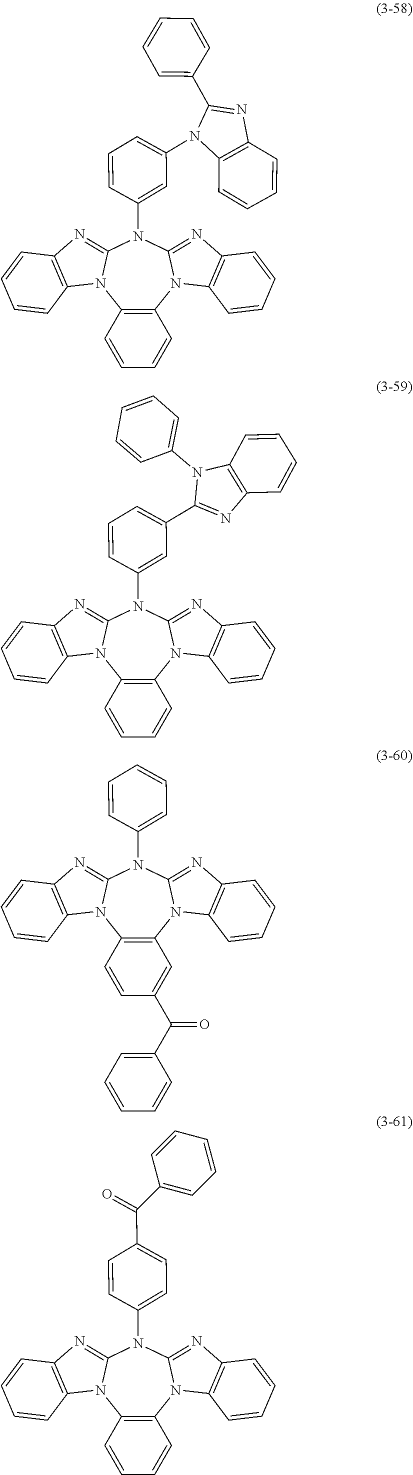

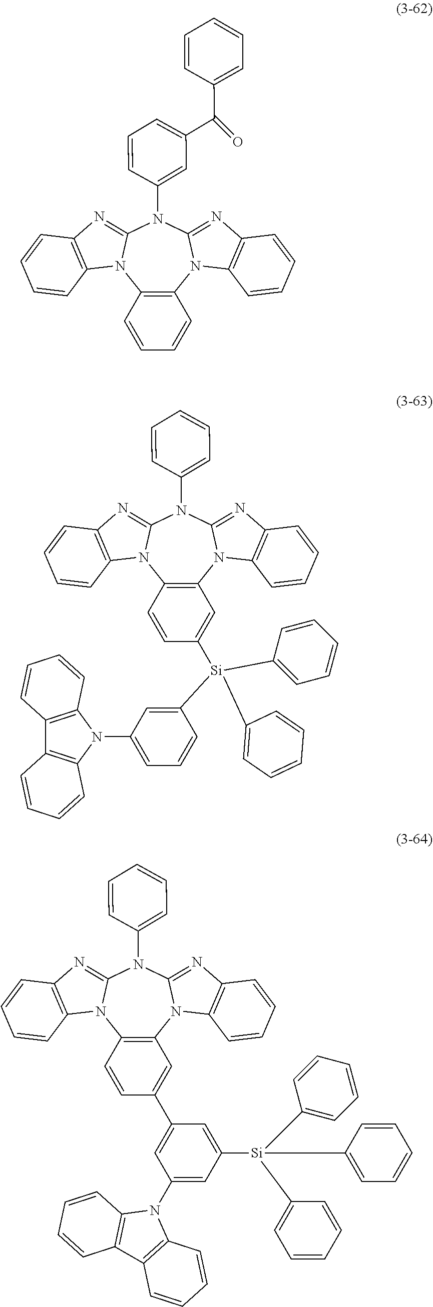 [SMILES: O=C(c1ccccc1)c1cccc(-n2c3nc4ccccc4n3c3ccccc3n3c4ccccc4nc23)c1 ; c1ccc(-n2c3nc4ccccc4n3c3ccc([Si](c4ccccc4)(c4ccccc4)c4cccc(-n5c6ccccc6c6ccccc65)c4)cc3n3c4ccccc4nc23)cc1 ; c1ccc(-n2c3nc4ccccc4n3c3ccc(-c4cc(-n5c6ccccc6c6ccccc65)cc([Si](c5ccccc5)(c5ccccc5)c5ccccc5)c4)cc3n3c4ccccc4nc23)cc1]

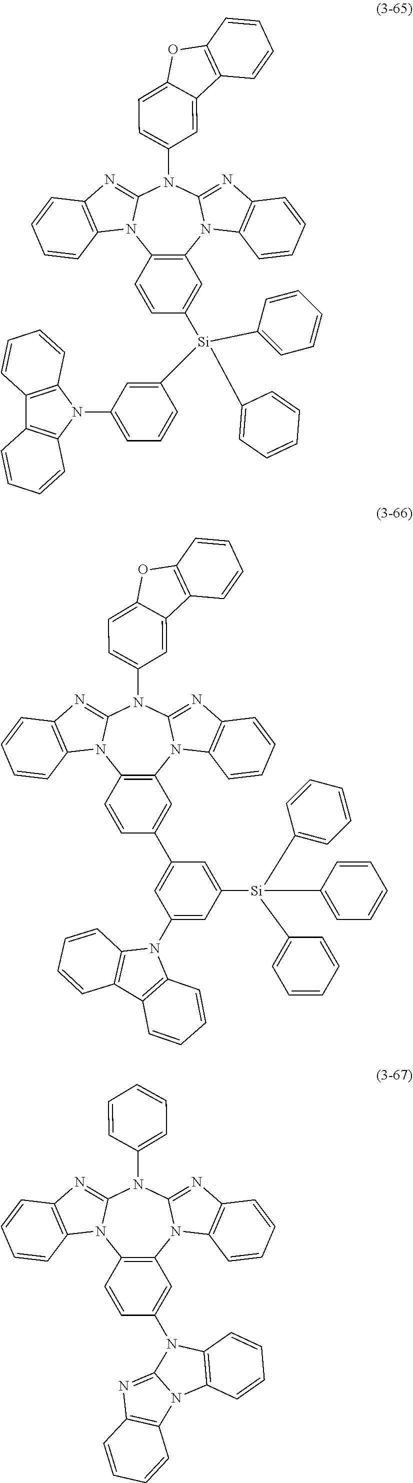 [SMILES: c1ccc([Si](c2ccccc2)(c2cccc(-n3c4ccccc4c4ccccc43)c2)c2ccc3c(c2)n2c4ccccc4nc2n(-c2ccc4oc5ccccc5c4c2)c2nc4ccccc4n32)cc1 ; c1ccc([Si](c2ccccc2)(c2ccccc2)c2cc(-c3ccc4c(c3)n3c5ccccc5nc3n(-c3ccc5oc6ccccc6c5c3)c3nc5ccccc5n43)cc(-n3c4ccccc4c4ccccc43)c2)cc1 ; c1ccc(-n2c3nc4ccccc4n3c3ccc(-n4c5ccccc5n5c6ccccc6nc45)cc3n3c4ccccc4nc23)cc1]

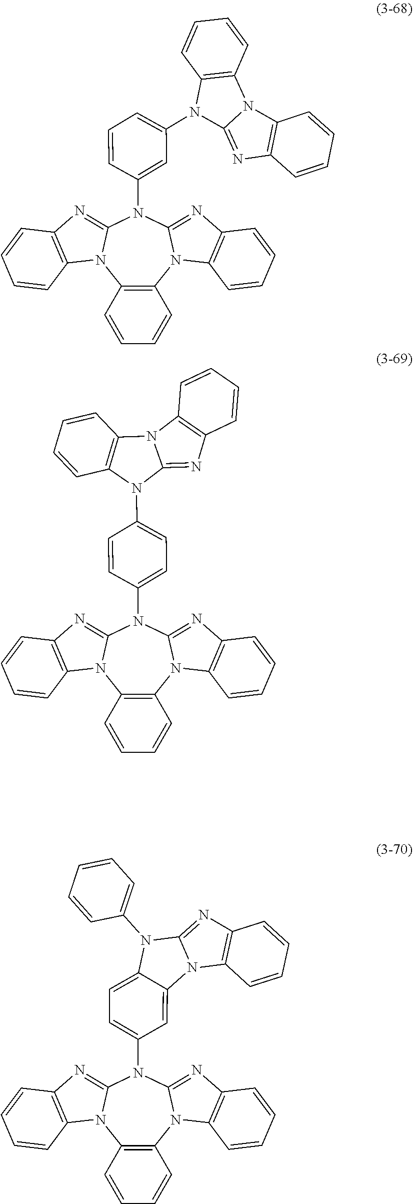 [SMILES: c1cc(-n2c3ccccc3n3c4ccccc4nc23)cc(-n2c3nc4ccccc4n3c3ccccc3n3c4ccccc4nc23)c1 ; c1ccc2c(c1)nc1n(-c3ccc(-n4c5nc6ccccc6n5c5ccccc5n5c6ccccc6nc45)cc3)c3ccccc3n21 ; c1ccc(-n2c3ccc(-n4c5nc6ccccc6n5c5ccccc5n5c6ccccc6nc45)cc3n3c4ccccc4nc23)cc1]

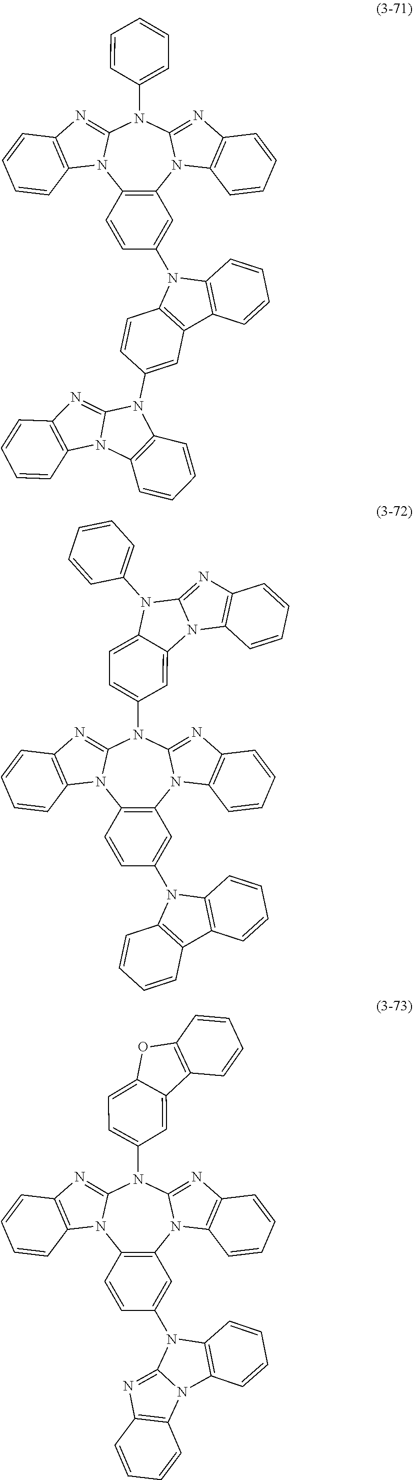

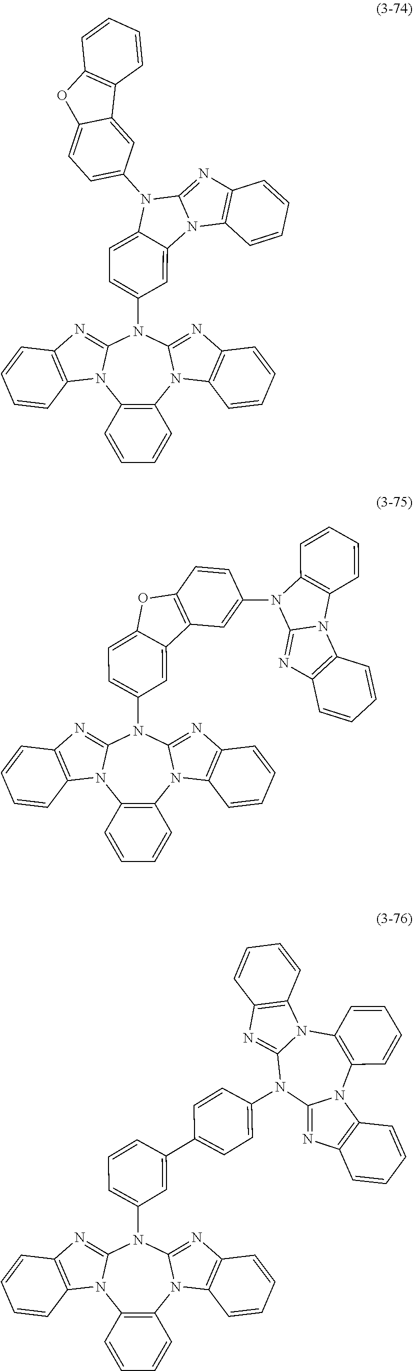 [SMILES: c1ccc2c(c1)nc1n(-c3ccc4oc5ccccc5c4c3)c3ccc(-n4c5nc6ccccc6n5c5ccccc5n5c6ccccc6nc45)cc3n21 ; c1ccc2c(c1)nc1n(-c3ccc4oc5ccc(-n6c7nc8ccccc8n7c7ccccc7n7c8ccccc8nc67)cc5c4c3)c3ccccc3n21 ; c1cc(-c2ccc(-n3c4nc5ccccc5n4c4ccccc4n4c5ccccc5nc34)cc2)cc(-n2c3nc4ccccc4n3c3ccccc3n3c4ccccc4nc23)c1]

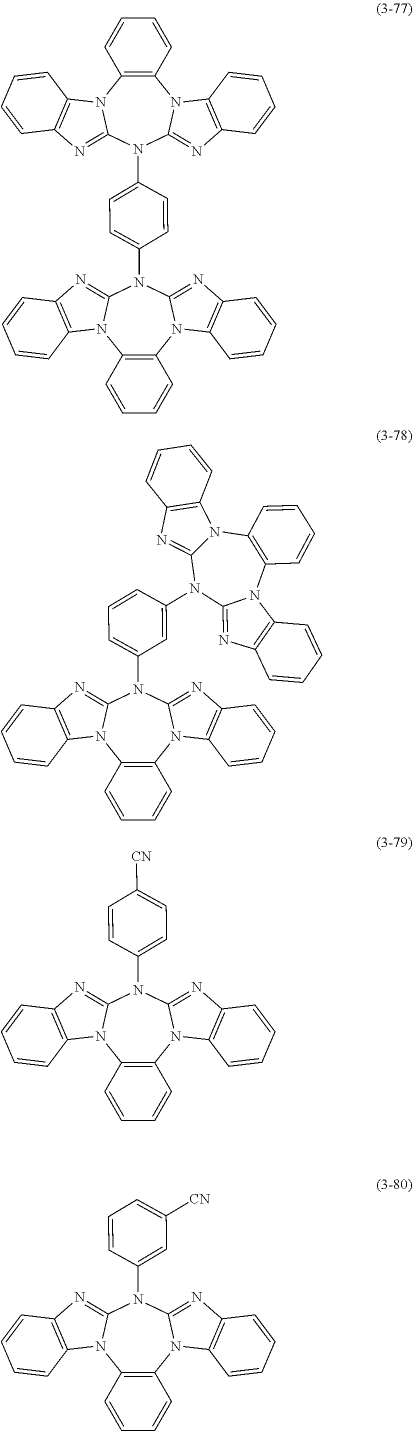

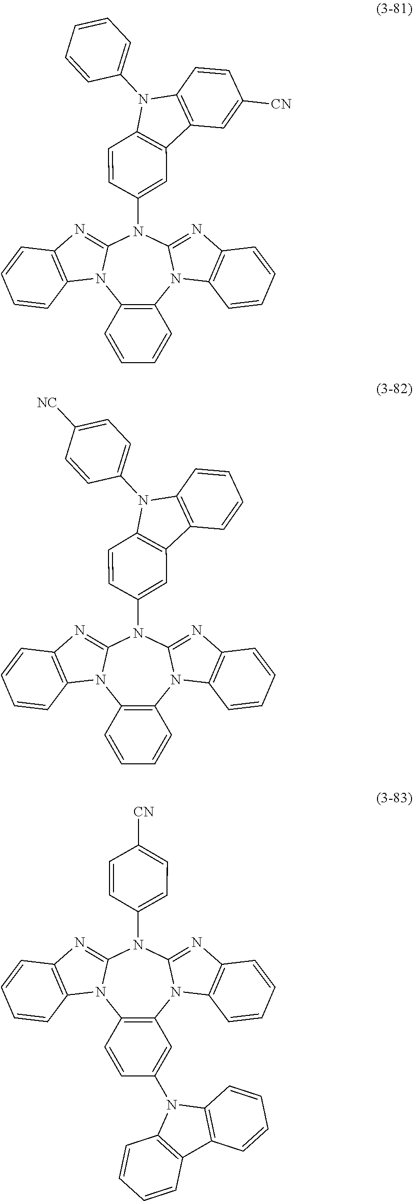 [SMILES: N#Cc1ccc2c(c1)c1cc(-n3c4nc5ccccc5n4c4ccccc4n4c5ccccc5nc34)ccc1n2-c1ccccc1 ; N#Cc1ccc(-n2c3ccccc3c3cc(-n4c5nc6ccccc6n5c5ccccc5n5c6ccccc6nc45)ccc32)cc1 ; N#Cc1ccc(-n2c3nc4ccccc4n3c3ccc(-n4c5ccccc5c5ccccc54)cc3n3c4ccccc4nc23)cc1]

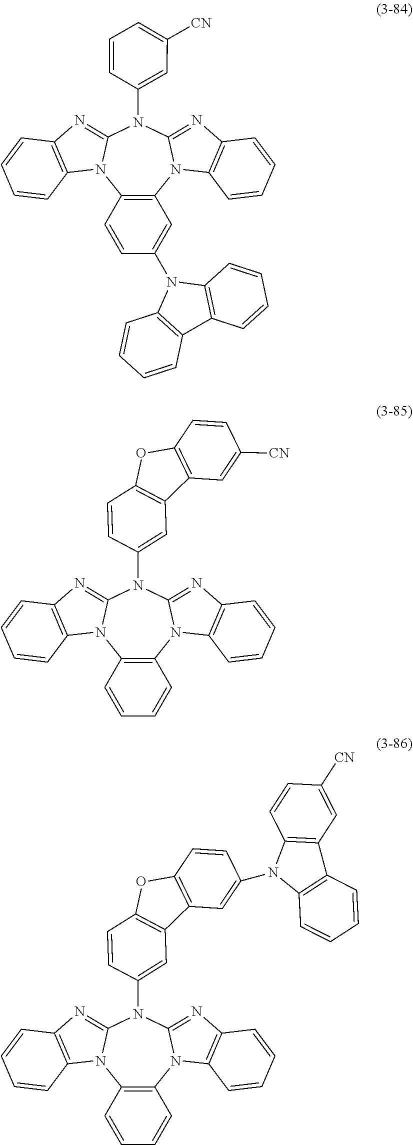 [SMILES: N#Cc1cccc(-n2c3nc4ccccc4n3c3ccc(-n4c5ccccc5c5ccccc54)cc3n3c4ccccc4nc23)c1 ; N#Cc1ccc2oc3ccc(-n4c5nc6ccccc6n5c5ccccc5n5c6ccccc6nc45)cc3c2c1 ; N#Cc1ccc2c(c1)c1ccccc1n2-c1ccc2oc3ccc(-n4c5nc6ccccc6n5c5ccccc5n5c6ccccc6nc45)cc3c2c1]

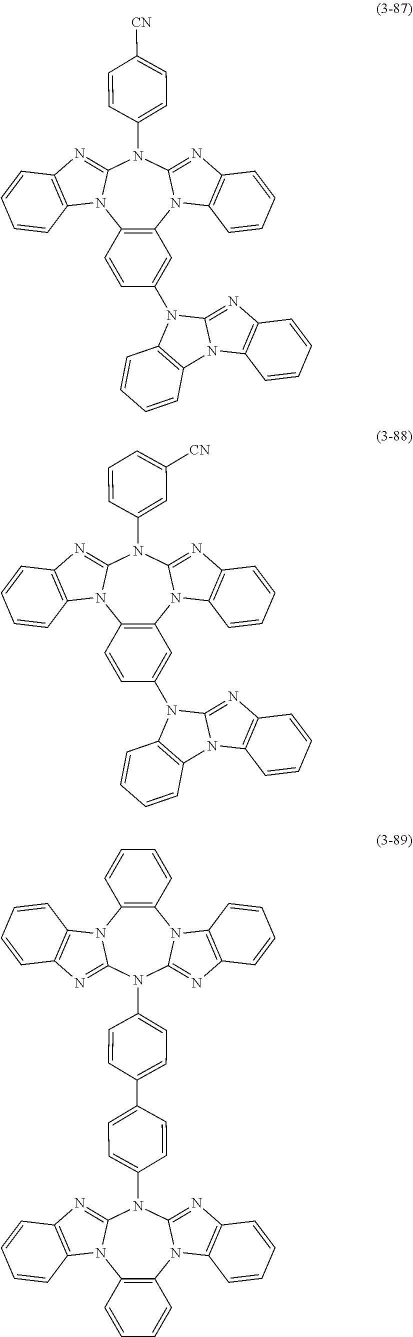

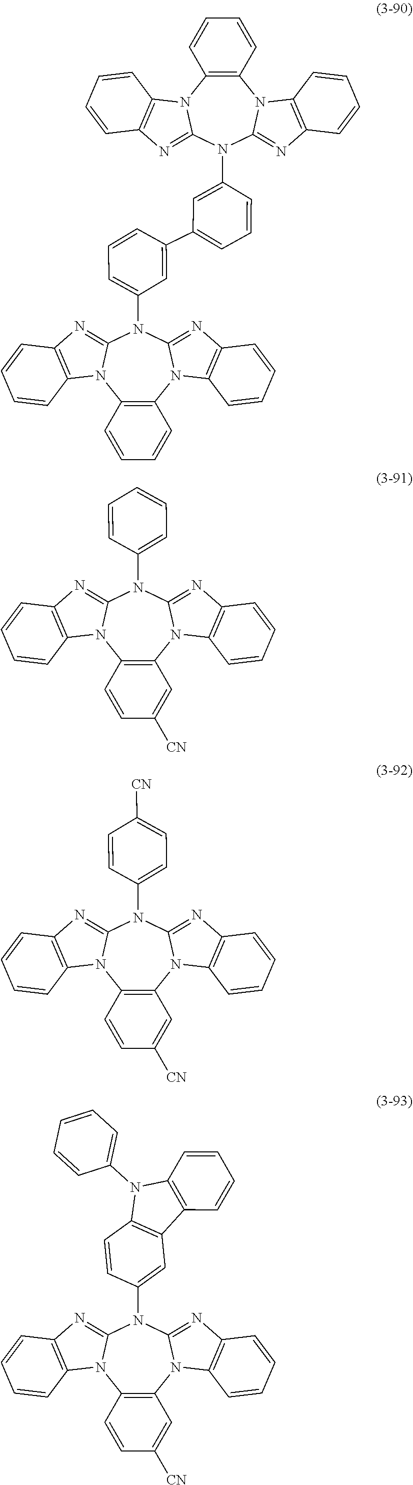

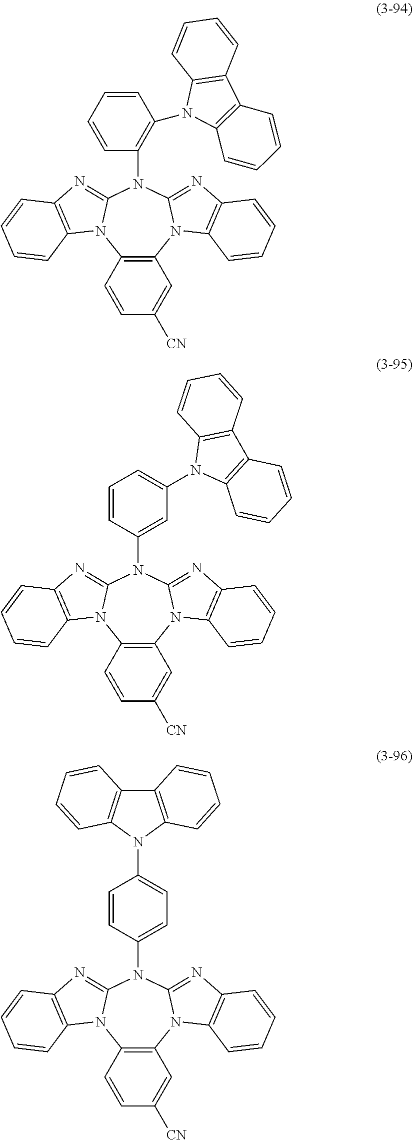

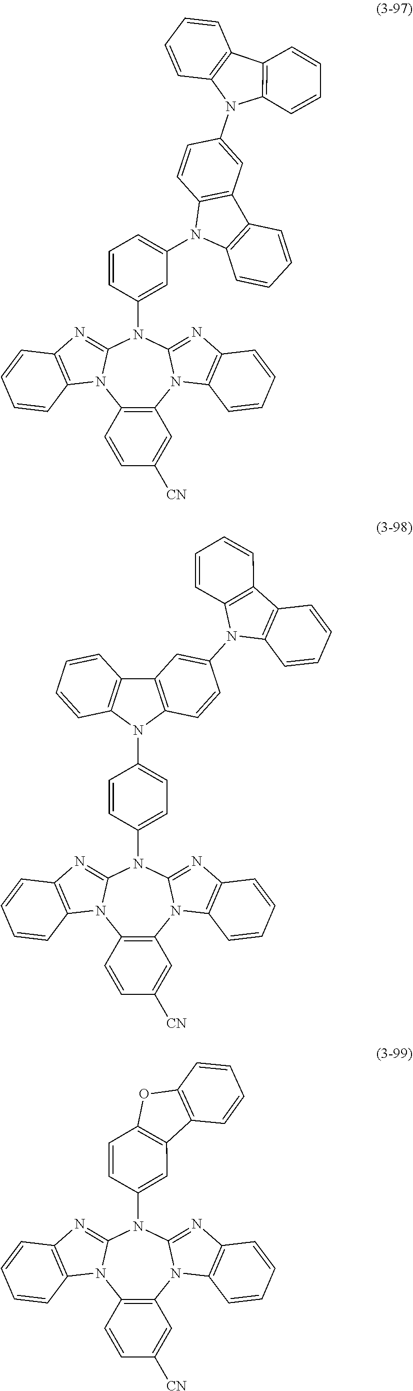 [SMILES: N#Cc1ccc2c(c1)n1c3ccccc3nc1n(-c1cccc(-n3c4ccccc4c4cc(-n5c6ccccc6c6ccccc65)ccc43)c1)c1nc3ccccc3n21 ; N#Cc1ccc2c(c1)n1c3ccccc3nc1n(-c1ccc(-n3c4ccccc4c4cc(-n5c6ccccc6c6ccccc65)ccc43)cc1)c1nc3ccccc3n21 ; N#Cc1ccc2c(c1)n1c3ccccc3nc1n(-c1ccc3oc4ccccc4c3c1)c1nc3ccccc3n21]

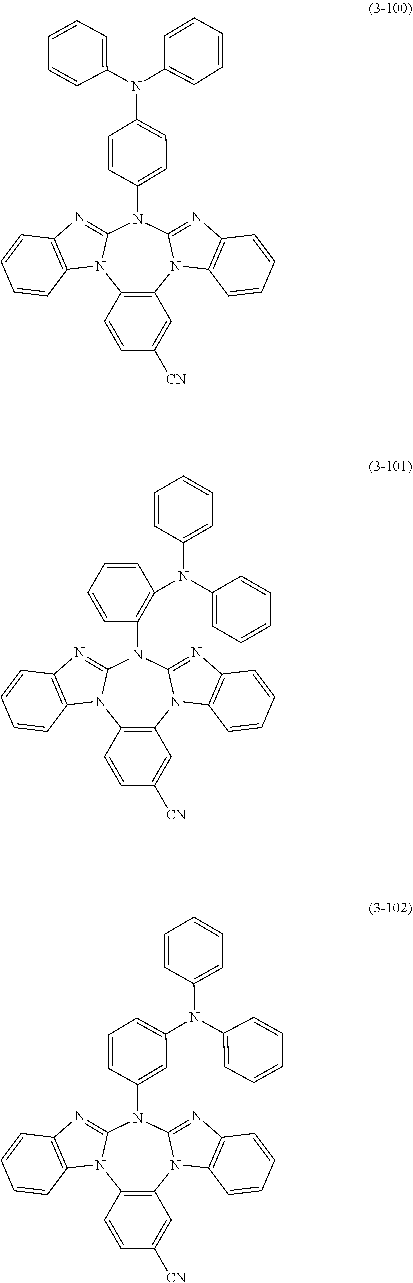 [SMILES: N#Cc1ccc2c(c1)n1c3ccccc3nc1n(-c1ccc(N(c3ccccc3)c3ccccc3)cc1)c1nc3ccccc3n21 ; N#Cc1ccc2c(c1)n1c3ccccc3nc1n(-c1ccccc1N(c1ccccc1)c1ccccc1)c1nc3ccccc3n21 ; N#Cc1ccc2c(c1)n1c3ccccc3nc1n(-c1cccc(N(c3ccccc3)c3ccccc3)c1)c1nc3ccccc3n21]

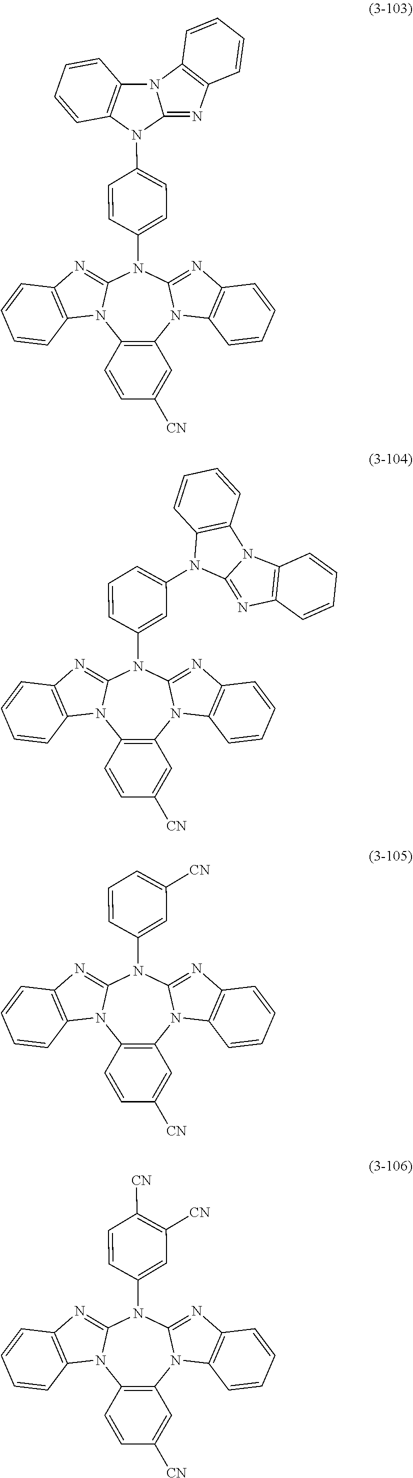 [SMILES: N#Cc1ccc2c(c1)n1c3ccccc3nc1n(-c1ccc(-n3c4ccccc4n4c5ccccc5nc34)cc1)c1nc3ccccc3n21 ; N#Cc1ccc2c(c1)n1c3ccccc3nc1n(-c1cccc(-n3c4ccccc4n4c5ccccc5nc34)c1)c1nc3ccccc3n21 ; N#Cc1cccc(-n2c3nc4ccccc4n3c3ccc(C#N)cc3n3c4ccccc4nc23)c1 ; N#Cc1ccc2c(c1)n1c3ccccc3nc1n(-c1ccc(C#N)c(C#N)c1)c1nc3ccccc3n21]

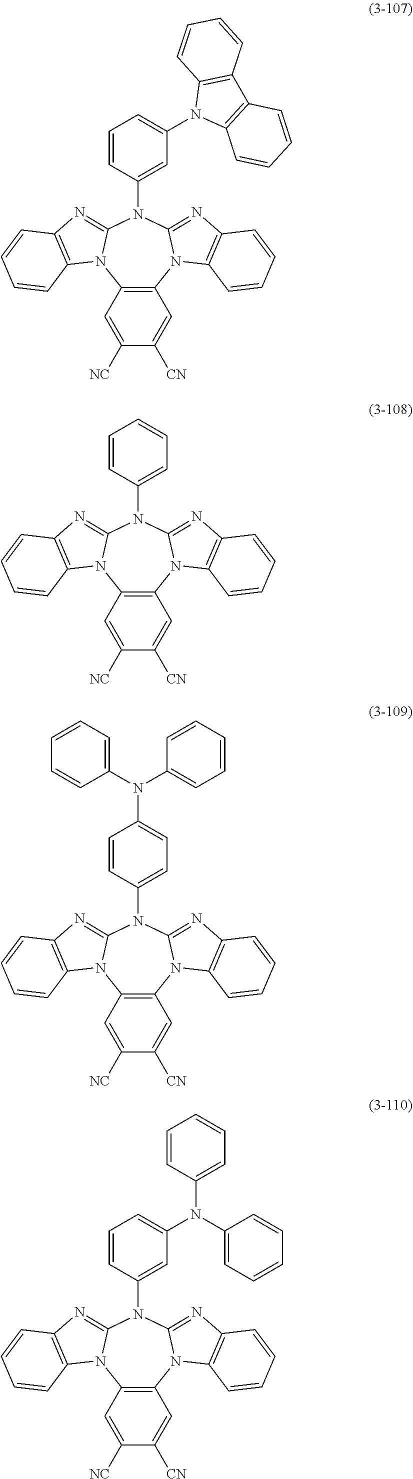

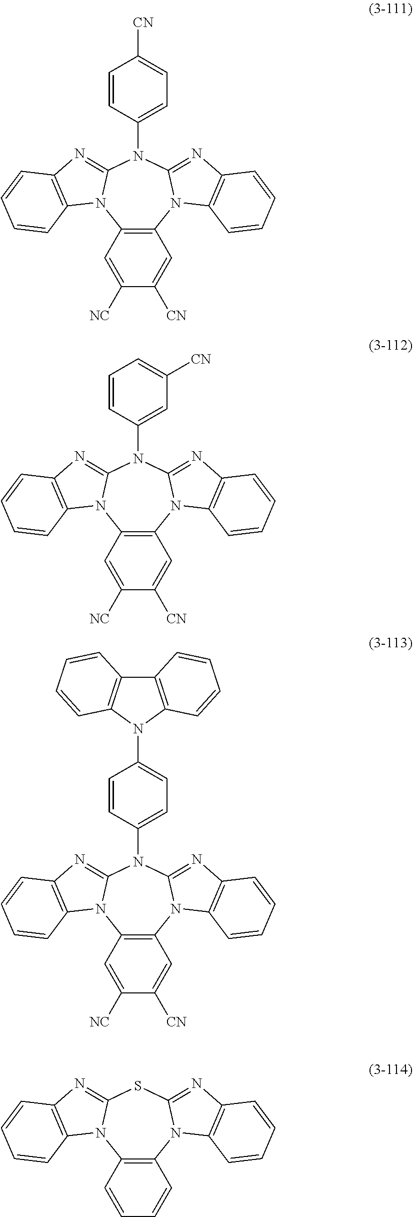

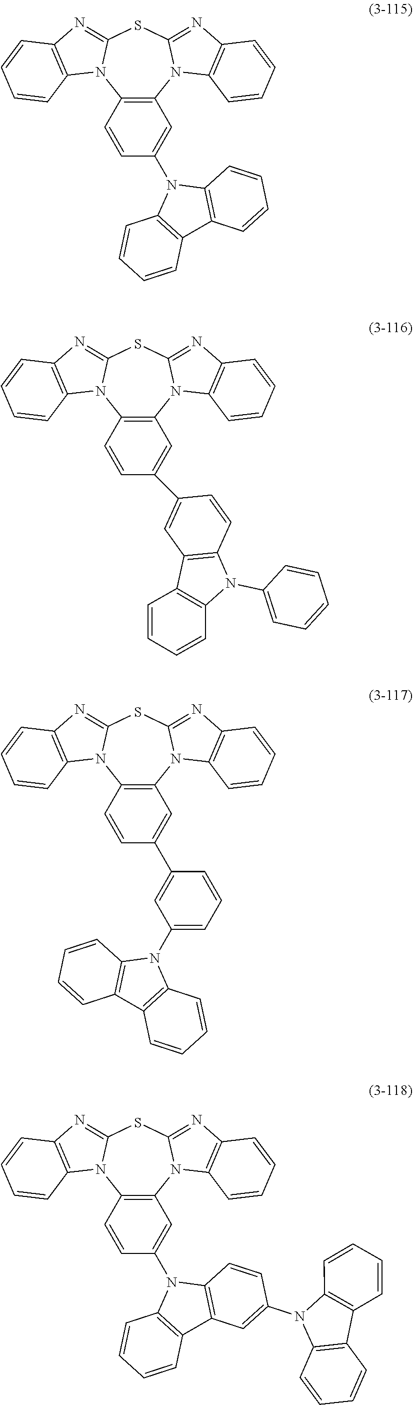 [SMILES: c1ccc2c(c1)nc1sc3nc4ccccc4n3c3cc(-n4c5ccccc5c5ccccc54)ccc3n12 ; c1ccc(-n2c3ccccc3c3cc(-c4ccc5c(c4)n4c(nc6ccccc64)sc4nc6ccccc6n45)ccc32)cc1 ; c1cc(-c2ccc3c(c2)n2c(nc4ccccc42)sc2nc4ccccc4n23)cc(-n2c3ccccc3c3ccccc32)c1 ; c1ccc2c(c1)nc1sc3nc4ccccc4n3c3cc(-n4c5ccccc5c5cc(-n6c7ccccc7c7ccccc76)ccc54)ccc3n12]

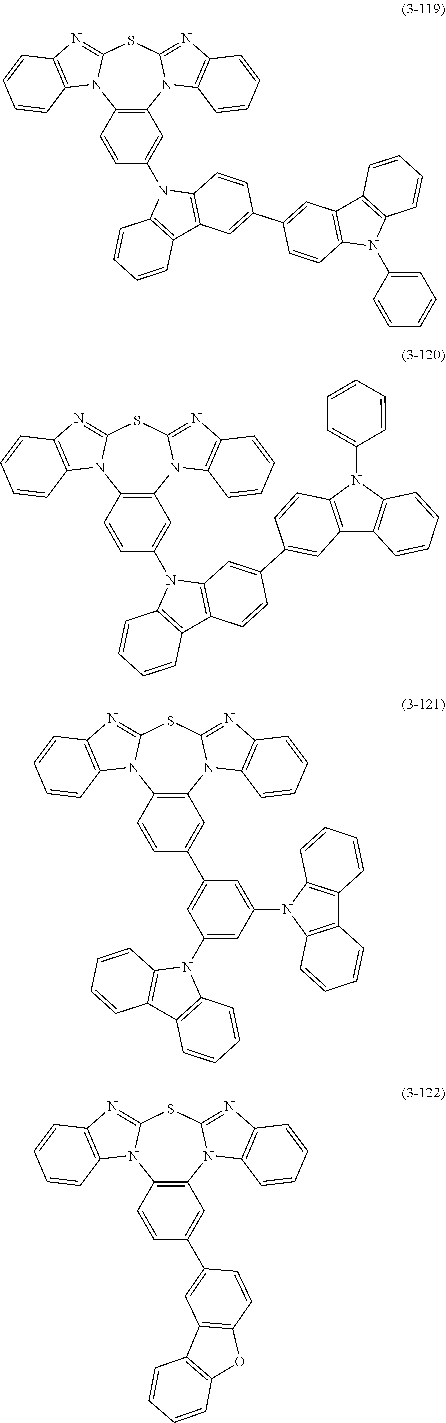

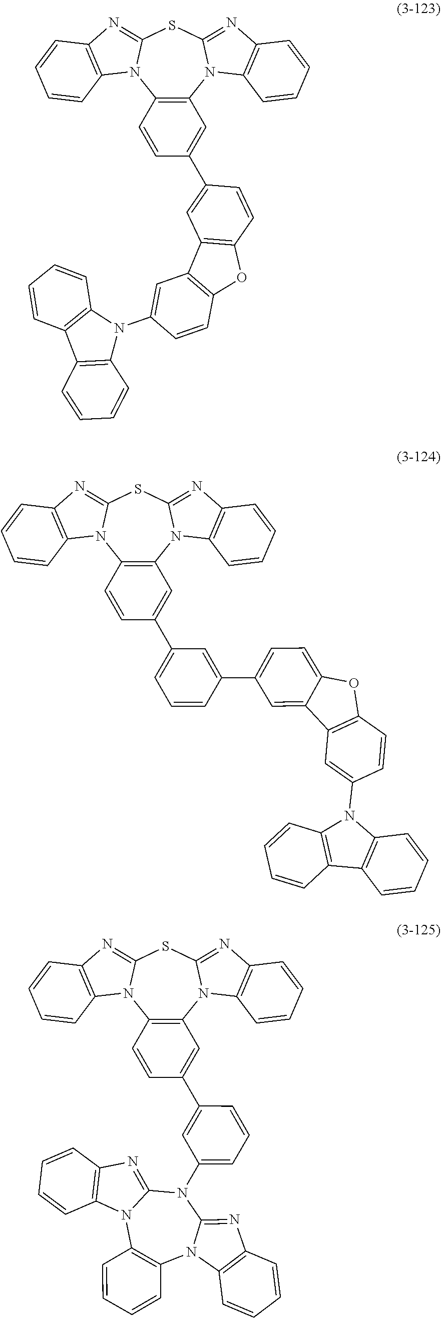 [SMILES: c1ccc2c(c1)nc1sc3nc4ccccc4n3c3cc(-c4ccc5oc6ccc(-n7c8ccccc8c8ccccc87)cc6c5c4)ccc3n12 ; c1cc(-c2ccc3oc4ccc(-n5c6ccccc6c6ccccc65)cc4c3c2)cc(-c2ccc3c(c2)n2c(nc4ccccc42)sc2nc4ccccc4n23)c1 ; c1cc(-c2ccc3c(c2)n2c(nc4ccccc42)sc2nc4ccccc4n23)cc(-n2c3nc4ccccc4n3c3ccccc3n3c4ccccc4nc23)c1]

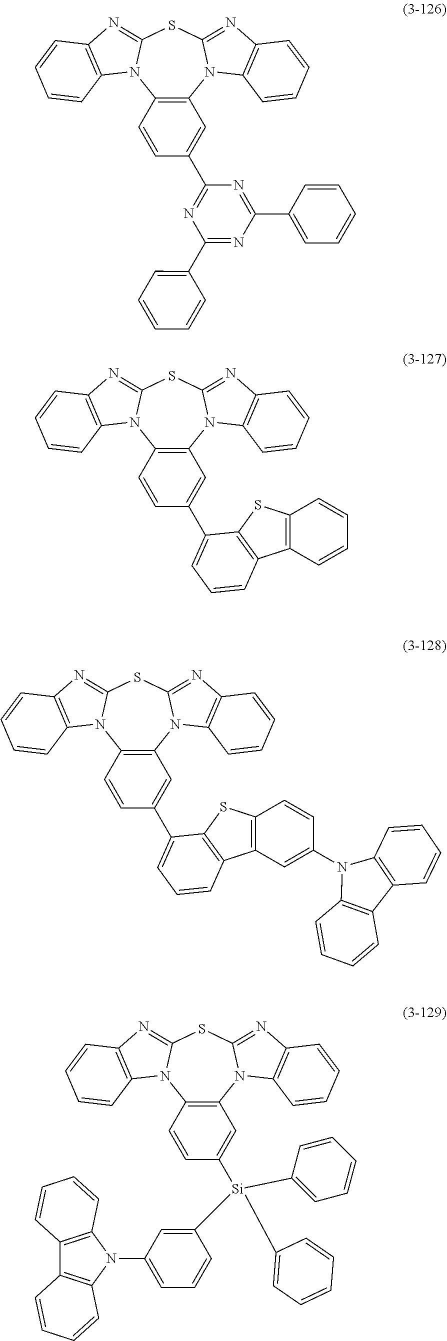 [SMILES: c1ccc(-c2nc(-c3ccccc3)nc(-c3ccc4c(c3)n3c(nc5ccccc53)sc3nc5ccccc5n34)n2)cc1 ; c1ccc2c(c1)nc1sc3nc4ccccc4n3c3cc(-c4cccc5c4sc4ccccc45)ccc3n12 ; c1ccc2c(c1)nc1sc3nc4ccccc4n3c3cc(-c4cccc5c4sc4ccc(-n6c7ccccc7c7ccccc76)cc45)ccc3n12 ; c1ccc([Si](c2ccccc2)(c2cccc(-n3c4ccccc4c4ccccc43)c2)c2ccc3c(c2)n2c(nc4ccccc42)sc2nc4ccccc4n23)cc1]

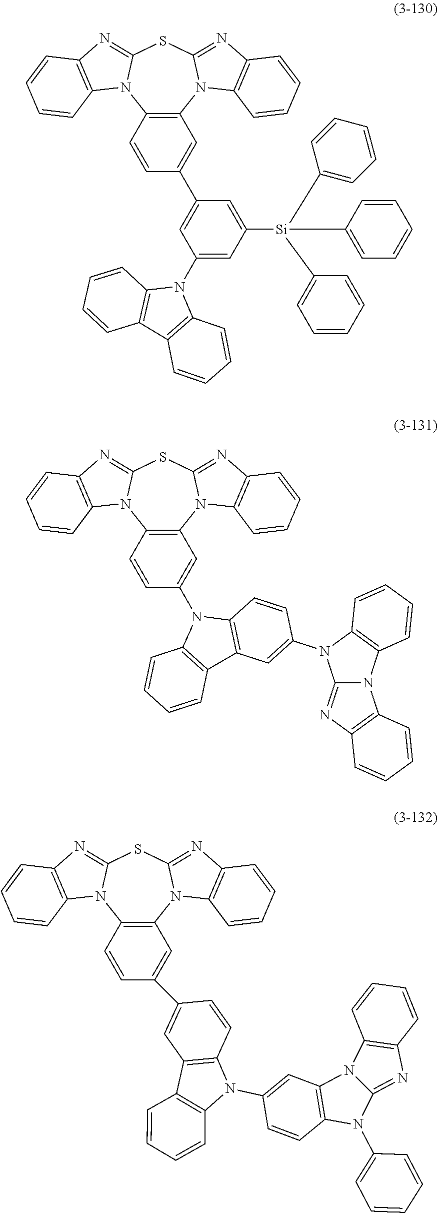 [SMILES: c1ccc([Si](c2ccccc2)(c2ccccc2)c2cc(-c3ccc4c(c3)n3c(nc5ccccc53)sc3nc5ccccc5n34)cc(-n3c4ccccc4c4ccccc43)c2)cc1 ; c1ccc2c(c1)nc1sc3nc4ccccc4n3c3cc(-n4c5ccccc5c5cc(-n6c7ccccc7n7c8ccccc8nc67)ccc54)ccc3n12 ; c1ccc(-n2c3ccc(-n4c5ccccc5c5cc(-c6ccc7c(c6)n6c(nc8ccccc86)sc6nc8ccccc8n67)ccc54)cc3n3c4ccccc4nc23)cc1]

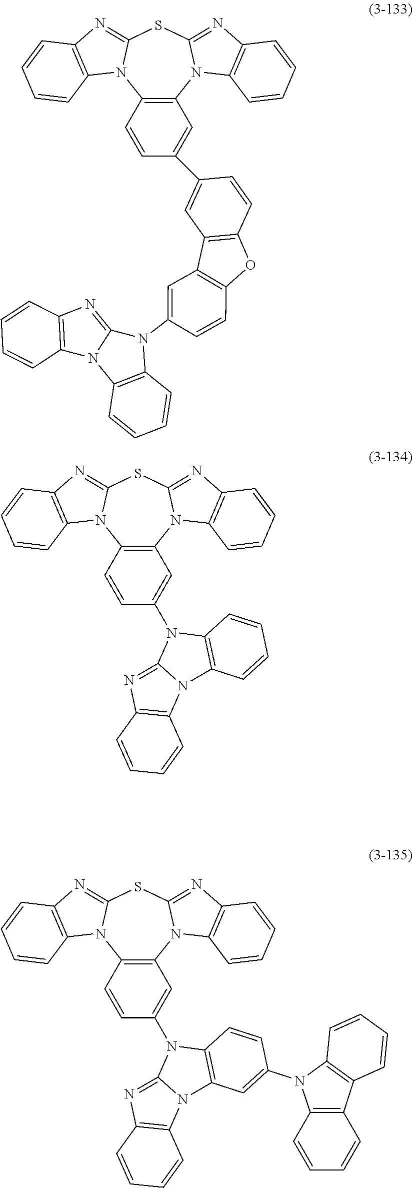

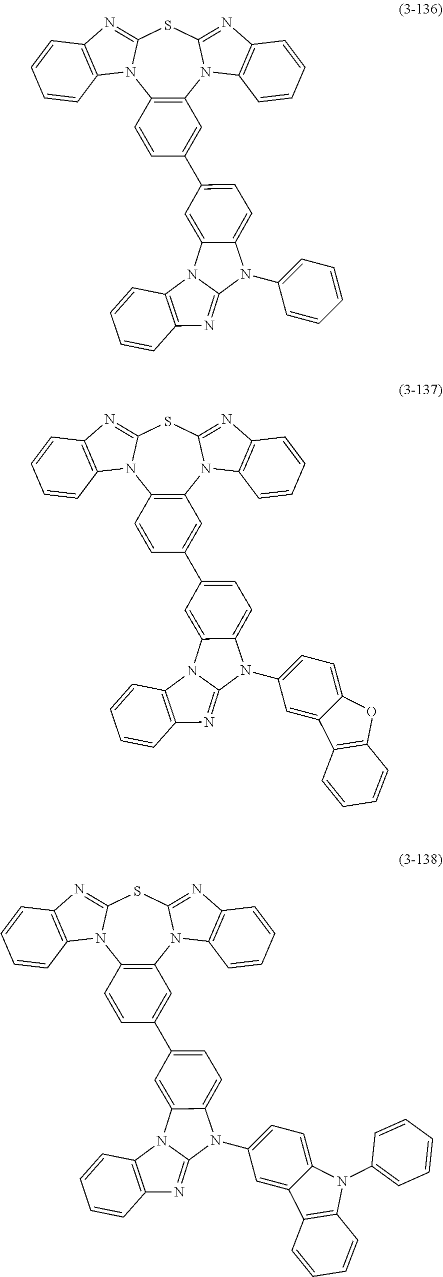 [SMILES: c1ccc(-n2c3ccc(-c4ccc5c(c4)n4c(nc6ccccc64)sc4nc6ccccc6n45)cc3n3c4ccccc4nc23)cc1 ; c1ccc2c(c1)nc1sc3nc4ccccc4n3c3cc(-c4ccc5c(c4)n4c6ccccc6nc4n5-c4ccc5oc6ccccc6c5c4)ccc3n12 ; c1ccc(-n2c3ccccc3c3cc(-n4c5ccc(-c6ccc7c(c6)n6c(nc8ccccc86)sc6nc8ccccc8n67)cc5n5c6ccccc6nc45)ccc32)cc1]

### Method of Preparing Third Compound

The third compound can be prepared b a method disclosed in, for instance, EP 3070144 A1. Alternatively, the third compound can be prepared, for instance, by application of known substitution reactions and/or materials depending on a target compound according to reactions described later in Examples.

### First Compound

The first compound in the exemplary embodiment is a fluorescent compound.

The emission color of the first compound is not limited.

The first compound preferably exhibits fluorescence having a main peak wavelength of 550 nm or less, more preferably of 480 nm or less. Typically, improvement in the luminous efficiency in the blue-emission wavelength region has been a problem in organic EL devices. It is believed that an organic EL device according to the exemplary embodiment is capable of improving the luminous efficiency in the blue-emission wavelength region.

The main peak wavelength means a peak wavelength of luminescence spectrum exhibiting a maximum fluorescence intensity among fluorescence spectra measured in a toluene solution in which the first compound is dissolved at a concentration from 10⁻⁶ mol/L to 10⁻⁶ mol/L.

The first compound preferably exhibits a blue fluorescence. Moreover, the first compound is preferably a material having a high fluorescence quantum efficiency.

As the first compound in the exemplary embodiment, a fluorescent material is usable. Examples of the fluorescent material include a bisarylamino naphthalene derivative, an aryl-substituted naphthalene derivative, a bisarylamino anthracene derivative, an aryl-substituted anthracene derivative, a bisarylamino pyrene derivative, an aryl-substituted pyrene derivative, a bisarylamino chrysene derivative, an aryl-substituted chrysene derivative, a bisarylamino fluoranthene derivative, an aryl-substituted fluoranthene derivative, an indenoperylene derivative, acenaphthofluoranthene derivative, a pyrromethene boron complex compound, a compound having a pyrromethene skeleton or a metal complex thereof, a diketopyrrolopyrrole derivative, a perylene derivative, and a naphthacene derivative.

In the organic EL device according to the exemplary embodiment, the first compound is preferably a compound represented by a formula (1) below.

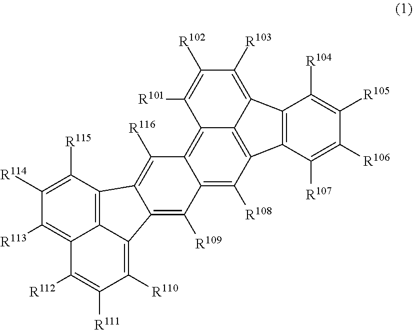

In the formula (1), R¹⁰¹ to R¹¹⁶ are each dependently a hydrogen atom or a substituent, or at least one of a pair of R¹⁰¹ and R¹⁰², a pair of R¹⁰² and R¹⁰³, a pair of R¹⁰³ and R¹⁰⁴, a pair of R¹⁰⁴ and R¹⁰⁵, a pair of R¹⁰⁵ and R¹⁰⁶, a pair of R¹⁰⁶ and R¹⁰⁷, a pair of R¹⁰⁷ and R¹⁰⁸, a pair of R¹⁰⁸ and R¹⁰⁹, a pair of R¹⁰⁹ and R¹¹⁰, a pair of R¹¹⁰ and R¹¹¹, a pair of R¹¹¹ and R¹¹², a pair of R¹¹² and R¹¹³, a pair of R¹¹³ and R¹¹⁴, a pair of R¹¹⁴ and R¹¹⁵, a pair of R¹¹⁵ and R¹¹⁶, and a pair of R¹¹⁶ and R¹⁰¹ are mutually bonded to form a ring,

R¹⁰¹ to R¹¹⁶ as the substituents are each independently selected from the group consisting of a substituted or unsubstituted alkyl group having 1 to 30 carbon atoms, a substituted or unsubstituted alkoxy group having 1 to 30 carbon atoms, a substituted or unsubstituted alkylthio group having 1 to 30 carbon atoms, a substituted or unsubstituted amino group, a substituted or unsubstituted aryl group having 6 to 30 ring carbon atoms, a substituted or unsubstituted heteroaryl group having 5 to 30 ring atoms, a substituted or unsubstituted alkenyl group having 2 to 30 carbon atoms; a substituted or unsubstituted aryloxy group having 6 to 30 ring carbon atoms, a substituted or unsubstituted arylthio group having 6 to 30 ring carbon atoms, a substituted or unsubstituted phosphino group, a substituted or unsubstituted phosphoryl group; a substituted or unsubstituted silyl group; a substituted or unsubstituted arylcarbonyl group having 6 to 30 ring carbon atoms, a cyano group, a nitro group, a carboxy group, a halogen atom, and a substituted or unsubstituted acyl group having 2 to 31 carbon atoms.

In a preferable example of the first compound, at least one of R¹⁰¹ to R¹⁰⁸, and R¹¹⁰ to R¹¹⁵ in the formula (1) is each independently a group selected from the group consisting of a substituted or unsubstituted alkyl group having 1 to 30 carbon atoms, a substituted or unsubstituted alkoxy group having 1 to 30 carbon atoms, a substituted or unsubstituted amino group, a substituted or unsubstituted aryl group having 6 to 30ring carbon atoms, a substituted or unsubstituted heteroaryl group having 5 to 30 ring atoms, a substituted or unsubstituted alkenyl group having 2 to 30 carbon atoms, a substituted or unsubstituted aryloxy group having 6 to 30 ring carbon atoms, a substituted or unsubstituted phosphino group, a substituted or unsubstituted silyl group, a substituted or unsubstituted acyl group having 2 to 31 carbon atoms, and a halogen atom.

In a preferable example of the first compound, R¹⁰⁹ and R¹¹⁶ in the formula (1) are each independently a substituent. In a more preferable example among the preferable example of the first compound, R¹⁰⁹ and R¹¹⁶ in the formula (1) are each independently a substituent, and R¹⁰¹ to R¹⁰⁸ and R¹¹⁶ to R¹¹⁵ are hydrogen atoms.

In a preferable example of the first compound: at least one of R¹⁰¹ to R¹⁰⁸, and R¹¹⁰ to R¹¹⁵ in the formula (1) is each independently a group selected from the group consisting of a substituted or unsubstituted alkyl group having 1 to 30 carbon atoms, a substituted or unsubstituted alkoxy group having 1 to 30 carbon atoms, a substituted or unsubstituted amino group, a substituted or unsubstituted aryl group having 6 to 30ring carbon atoms, a substituted or unsubstituted heteroaryl group having 5 to 30 ring atoms, a substituted or unsubstituted alkenyl group having 2 to 30 carbon atoms, a substituted or unsubstituted aryloxy group having 6 to 30 ring carbon atoms, a substituted or unsubstituted phosphino group, a substituted or unsubstituted silyl group, a substituted or unsubstituted acyl group having 2 to 31 carbon atoms, and a halogen atom; and R¹⁰⁹ and R¹¹⁶ in the formula (1) are each independently a substituent.

R¹⁰¹ to R¹¹⁶ as the substituents are preferably each independently a group selected from the group consisting of a substituted or unsubstituted alkyl group having 1 to 30 carbon atoms, a substituted or unsubstituted alkoxy group having 1 to 30 carbon atoms, a substituted or unsubstituted amino group, a substituted or unsubstituted aryl group having 6 to 30 ring carbon atoms, and a substituted or unsubstituted heteroaryl group having 5 to 30 ring atoms.

R¹⁰⁹ and R¹¹⁶ in the formula (1) are more preferably each independently a group selected from the group consisting of a substituted or unsubstituted alkyl group having 1 to 30 carbon atoms, a substituted or unsubstituted amino group, a substituted or unsubstituted aryl group having 6 to 30 ring carbon atoms, and a substituted or unsubstituted heteroaryl group having 5 to 30 ring atoms.

In the formula (1), R¹⁰⁹ and R¹¹⁶ are further preferably each independently a substituted or unsubstituted aryl group having 6 to 30 ring carbon atoms, and especially preferably a substituted or unsubstituted phenyl group. When R¹⁰⁹ and R¹¹⁶ in the formula (1) are phenyl groups, these phenyl groups are also preferably unsubstituted.

R¹⁰⁹ and R¹¹⁶ in the formula (1) are preferably substituted or unsubstituted phenyl groups, and R¹⁰¹ to R¹⁰⁸, R¹¹⁰, R¹¹¹, R¹¹⁴, and R¹¹⁵ are preferably hydrogen atoms. In this case, the first compound is represented by a formula (1A) below.

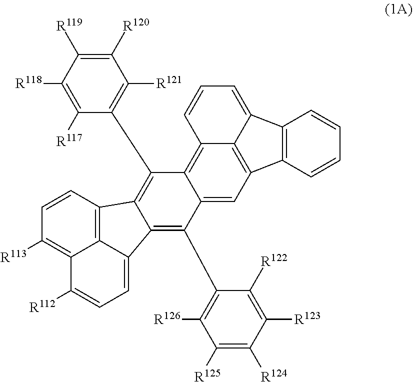

In the formula (1A), R¹¹², R¹¹³ and R¹¹⁷ to R¹²⁶ are each independently a hydrogen atom or a substituent, R¹¹², R¹¹³ and R¹¹⁷ to R¹²⁶ as the substituent being each independently a group selected from the group consisting of a substituted or unsubstituted alkyl group having 1 to 30 carbon atoms, a substituted or unsubstituted alkoxy group having 1 to 30 carbon atoms, a substituted or unsubstituted amino group, a substituted or unsubstituted aryl group having 6 to 30 ring carbon atoms, a substituted or unsubstituted heteroaryl group having 5 to 30 ring atoms, a substituted or unsubstituted alkenyl group having 2 to 30 carbon atoms, a substituted or unsubstituted aryloxy group having 6 to 30 ring carbon atoms, a substituted or unsubstituted phosphino group, a substituted or unsubstituted silyl group, a substituted or unsubstituted acyl group having 2 to 31 carbon atoms, and a halogen atom, at least one of R¹¹² and R¹¹³ being a group selected from the group consisting of a substituted or unsubstituted alkyl group having 1 to 30 carbon atoms, a substituted or unsubstituted alkoxy group having 1 to 30 carbon atoms, a substituted or unsubstituted amino group, a substituted or unsubstituted aryl group having 6 to 30 ring carbon atoms, a substituted or unsubstituted heteroaryl group having 5 to 30 ring atoms, a substituted or unsubstituted alkenyl group having 2 to 30 carbon atoms, a substituted or unsubstituted aryloxy group having 6 to 30 ring carbon atoms, a substituted or unsubstituted phosphino group, a substituted or unsubstituted silyl group, a substituted or unsubstituted acyl group having 2 to 31 carbon atoms, and a halogen atom.

In the formula (1A), one of R¹¹² and R¹¹³ is preferably a group selected from the group consisting of a substituted or unsubstituted alkyl group having 1 to 30 carbon atoms, a substituted or unsubstituted alkoxy group having 1 to 30 carbon atoms, a substituted or unsubstituted amino group, a substituted or unsubstituted aryl group having 6 to 30 ring carbon atoms, and a substituted or unsubstituted heteroaryl group having 5 to 30 ring atoms, and the other of R¹¹² and R¹¹³ is preferably a hydrogen atom.

In the formula (1A), at least one of R¹¹² and R¹¹³ is also preferably a substituted or unsubstituted aryl group having 6 to 30 ring carbon atoms.

In the formula (1A), it is also preferable that one of R¹¹² and R¹¹³ is a substituted or unsubstituted aryl group having 6 to 30 ring carbon atoms and the other of R¹¹² and R¹¹³ is a hydrogen atom.

In the formula (1A), R¹¹⁷ to R¹²⁶ are also preferably hydrogen atoms.

R¹¹⁷ to R¹²⁶ as the substituents are preferably each independently a group selected from the group consisting of a substituted or unsubstituted alkyl group having 1 to 30 carbon atoms, a substituted or unsubstituted alkoxy group having 1 to 30 carbon atoms, a substituted or unsubstituted amino group, a substituted or unsubstituted aryl group having 6 to 30 ring carbon atoms, and a substituted or unsubstituted heteroaryl group having 5 to 30 ring atoms.

In the first compound, one of R¹¹¹ to R¹¹⁴ is preferably a group represented by a formula (1a) below.

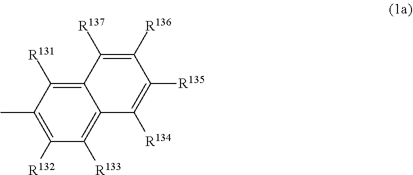

In the formula (1a), R¹³¹ to R¹³⁴ and R¹³⁶ each independently represent a hydrogen atom or a substituent, R¹³¹ to R¹³⁴ and R¹³⁶ as the substituent are each independently selected from the group consisting of a substituted or unsubstituted alkyl group having 1 to 30 carbon atoms, a substituted or unsubstituted alkoxy group having 1 to 30 carbon atoms, a substituted or unsubstituted alkylthio group having 1 to 30 carbon atoms, a substituted or unsubstituted amino group, a substituted or unsubstituted aryl group having 6 to 30 ring carbon atoms, a substituted or unsubstituted heteroaryl group having 5 to 30 ring atoms, a substituted or unsubstituted alkenyl group having 2 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted phosphino group, a substituted or unsubstituted phosphoryl group; a substituted or unsubstituted silyl group; a substituted or unsubstituted arylcarbonyl group having 6 to 30 ring carbon atoms, a cyano group, a nitro group, a carboxy group, and a halogen atom; and

R¹³⁵ and R¹³⁷ are each independently a substituent selected from the group consisting of a substituted or unsubstituted aryl group having 6 to 30 ring carbon atoms, a substituted or unsubstituted heteroaryl group having 5 to 30 ring atoms, and a cyano group, or are selected from the group consisting of a hydrogen atom, a substituted or unsubstituted alkyl group having 1 to 30 carbon atoms, a substituted or unsubstituted alkoxy group having 1 to 30 carbon atoms, a substituted or unsubstituted alkylthio group having 1 to 30 carbon atoms, a substituted or unsubstituted amino group, a substituted or unsubstituted aryl group having 6 to 30 ring carbon atoms, a substituted or unsubstituted heteroaryl group having 5 to 30 ring atoms, a substituted or unsubstituted alkenyl group having 2 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted phosphanyl group, a substituted or unsubstituted phosphoryl group, a substituted or unsubstituted silyl group, substituted or unsubstituted arylcarbonyl group having 6 to 30 ring carbon atoms, a cyano group, a nitro group, a carboxy group, and a halogen atom, R¹³⁵ and R¹³⁷ being mutually the same or different.

The first compound is also preferably a compound represented by a formula (1 B) below or a compound represented by a formula (1C) below.

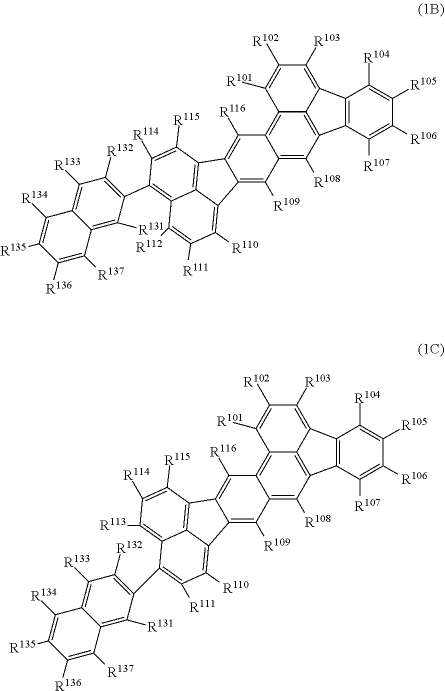

In the formula (1B), R¹⁰¹ to R¹¹² and R¹¹⁴ to R¹¹⁶ respectively represent the same as R¹⁰¹ to R¹¹² and R¹¹⁴ to R¹¹⁶ in the formula (1) and R¹³¹ to R¹³⁷ respectively represent the same as R¹³¹ to R¹³⁷ in the formula (1 a).

In the formulae (1C), R¹⁰¹ to R¹¹¹ and R¹¹³ to R¹¹⁶ respectively represent the same as R¹⁰¹ to R¹¹¹ and R¹¹³ to R¹¹⁶ in the formula (1) and R¹³¹ to R¹³⁷ respectively represent the same as R¹³¹ to R¹³⁷ in the formula (1a).

In the formula (1), R¹³¹ to R¹³⁷ as the substituents are preferably each independently a group selected from the group consisting of a substituted or unsubstituted alkyl group having 1 to 30 carbon atoms, a substituted or unsubstituted aryl group having 6 to 30 ring carbon atoms, a substituted or unsubstituted heteroaryl group having 5 to 30 ring atoms, a substituted or unsubstituted amino group, a substituted or unsubstituted alkoxy group having 1 to 30 carbon atoms, a cyano group, and a halogen atom.

Specific examples of the substituents in the formulae (1), (1A) to (1C), and (1a) (e.g. a substituted or unsubstituted alkyl group having 1 to 30 carbon atoms) are substituents exemplified in the below-described “Description of Substituents in the Formula of First Compound and Second Compound.”

### Method of Preparing First Compound

The first compound can be prepared by any known method. For instance, the first compound can be prepared, for instance, by application of known substitution reactions and/or materials depending on a target compound.

The first compound is sometimes prepared in a form of a mixture of isomers depending on the method of preparation. The mixture of the isomers may be used as the first compound.

Specific examples of the first compound of the exemplary embodiment are shown below. It should be noted that the first compound in the invention is by no means limited to the examples below.

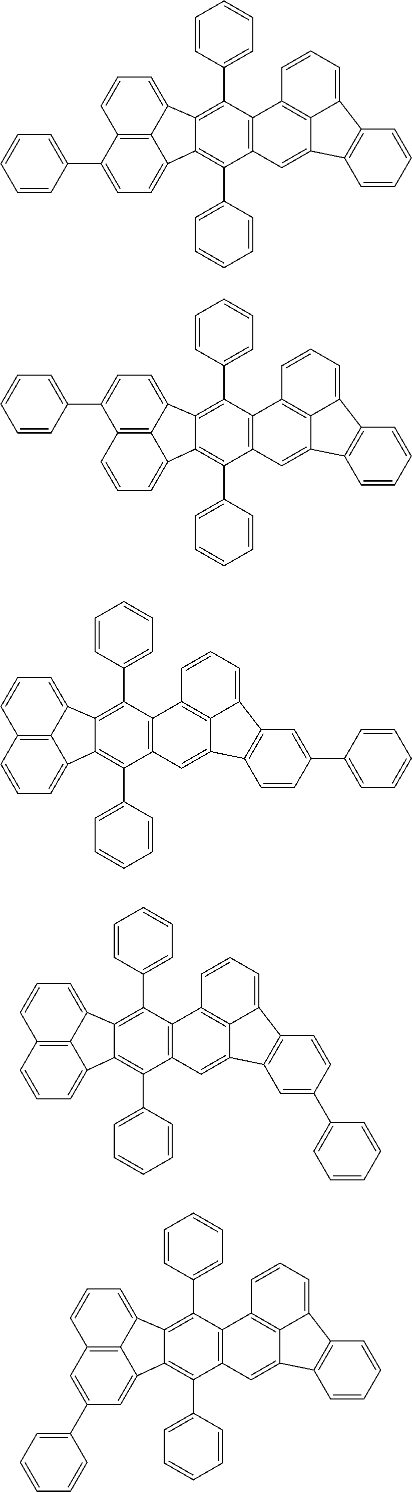

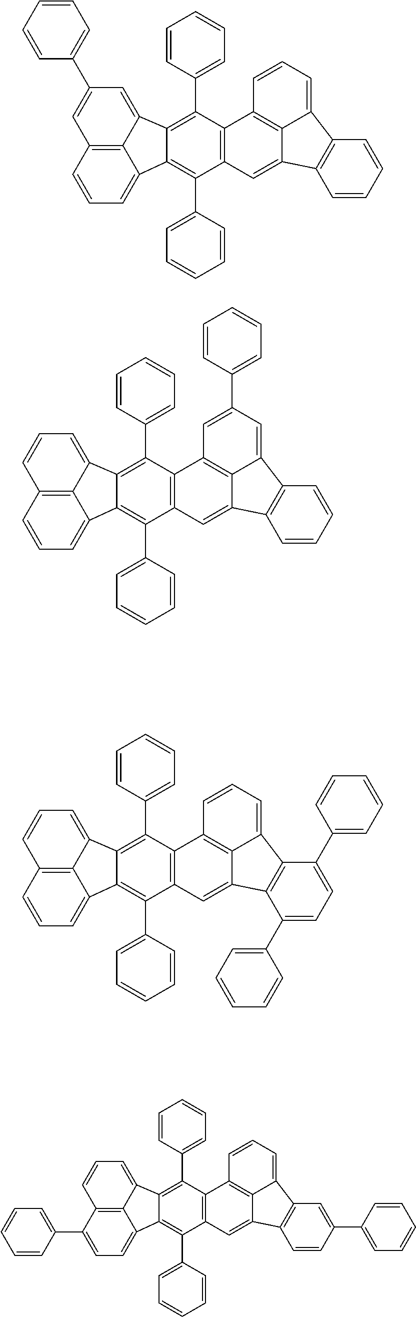

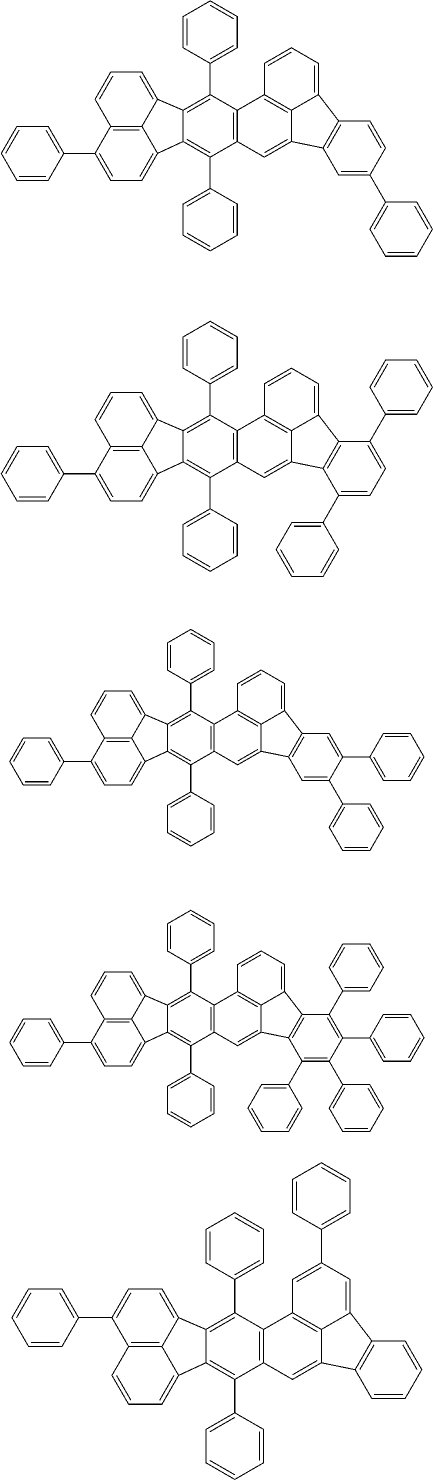

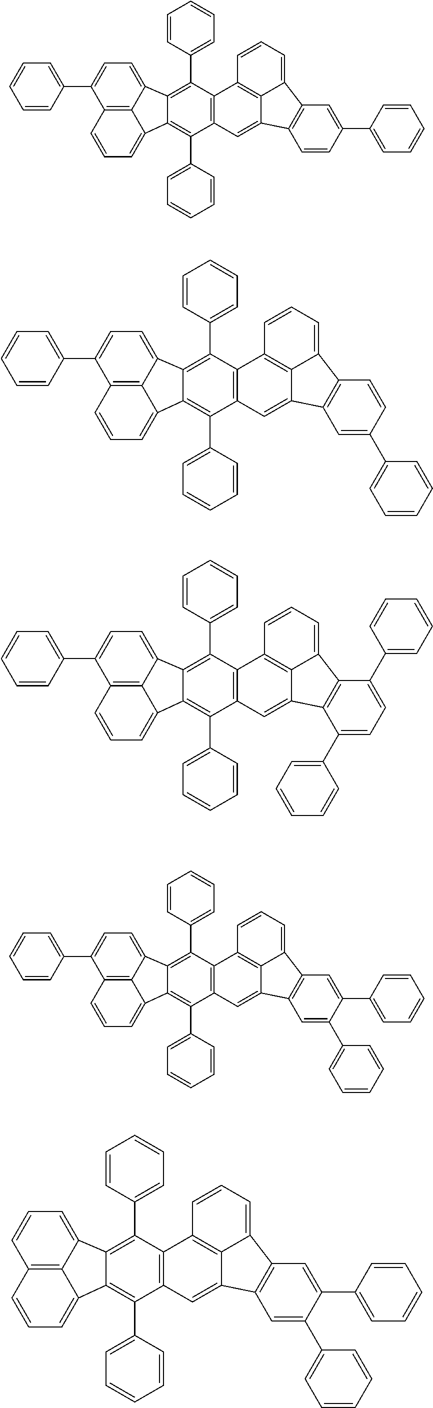

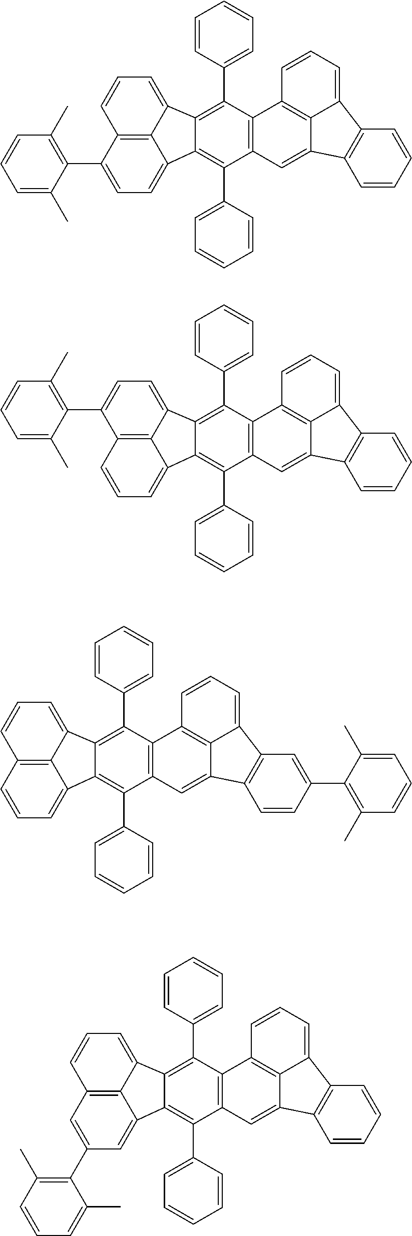

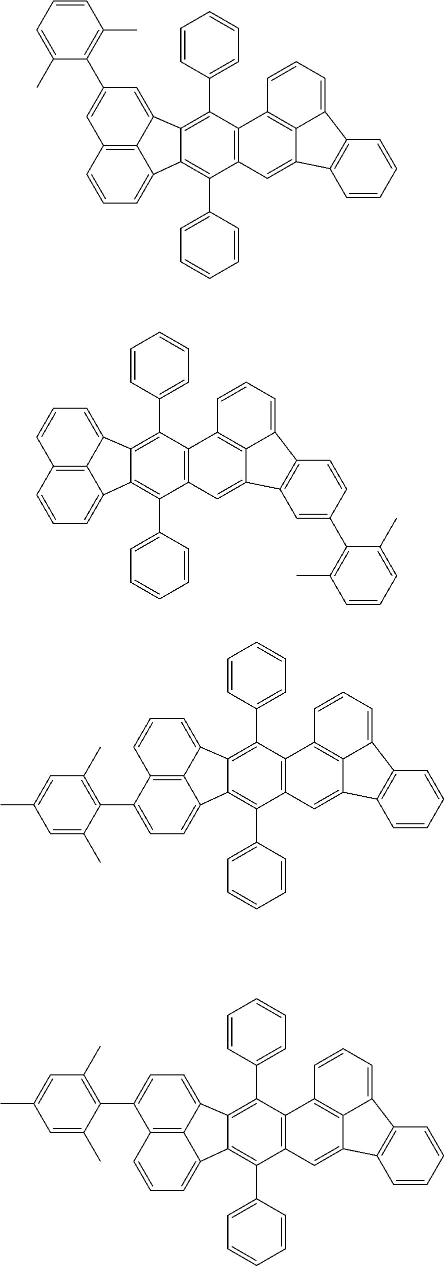

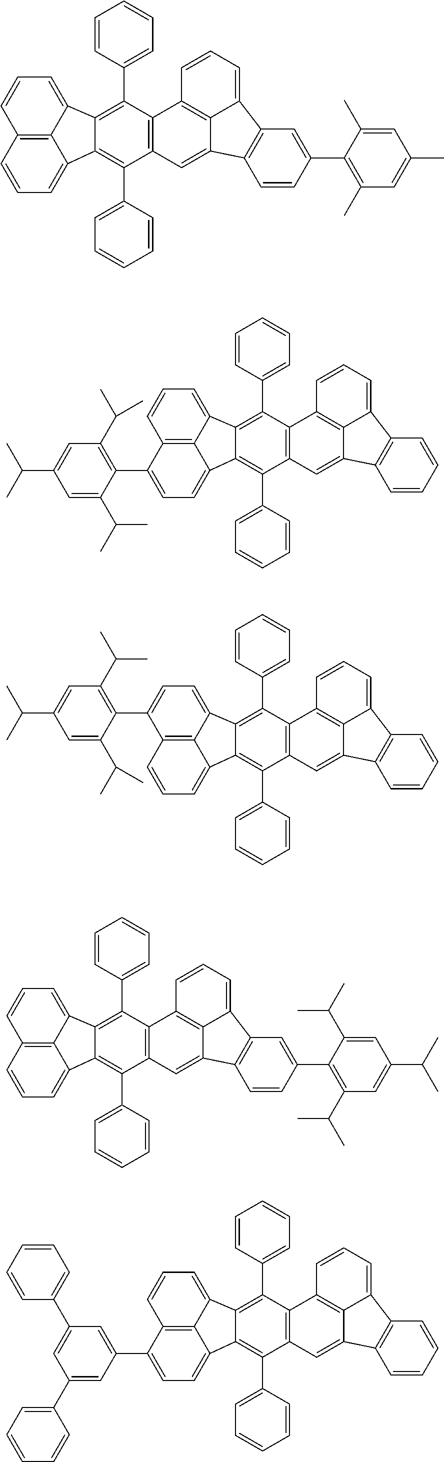

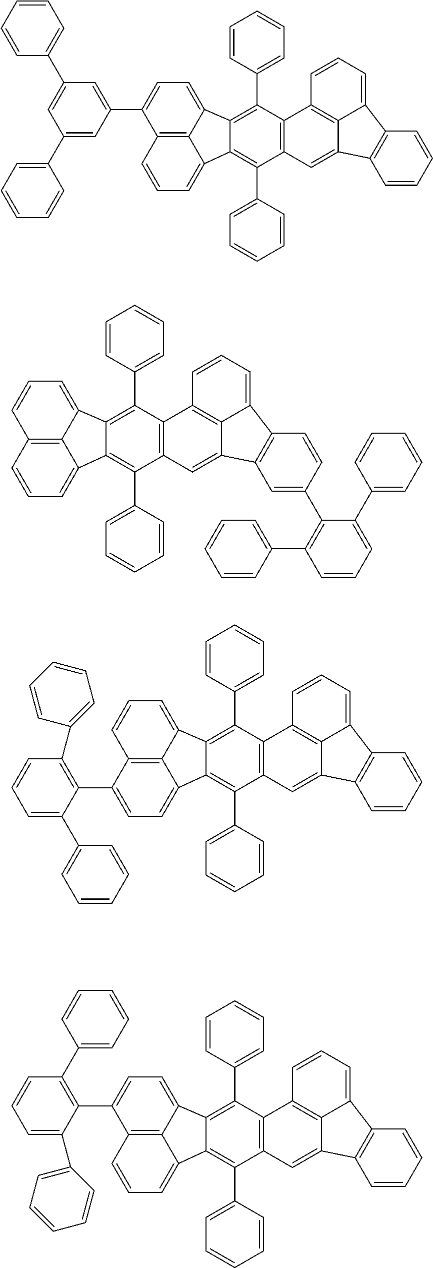

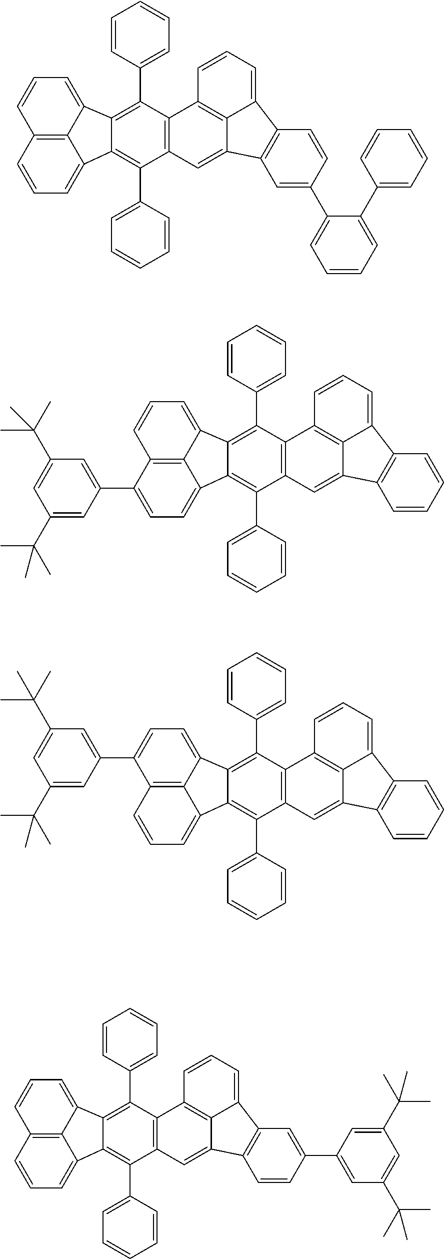

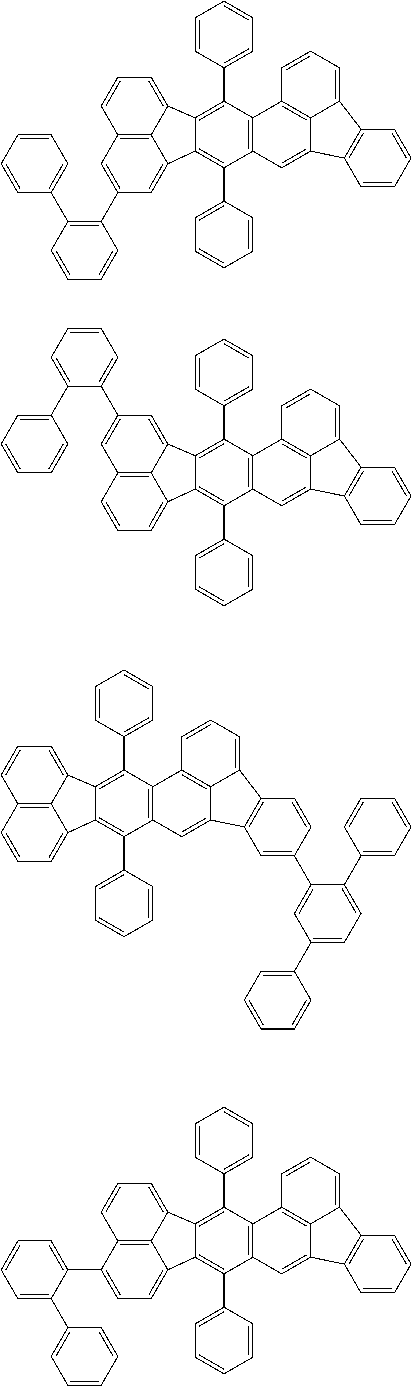

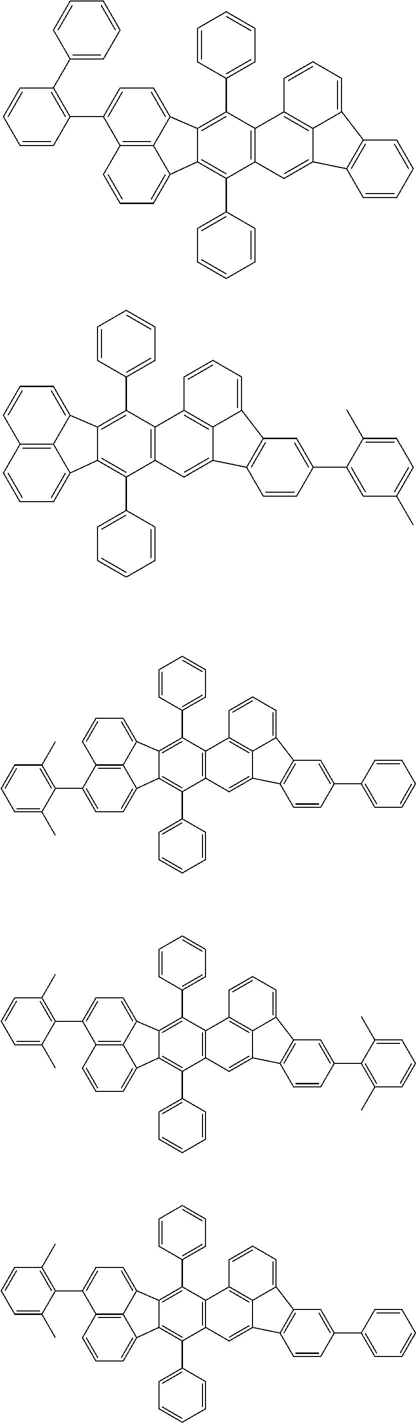

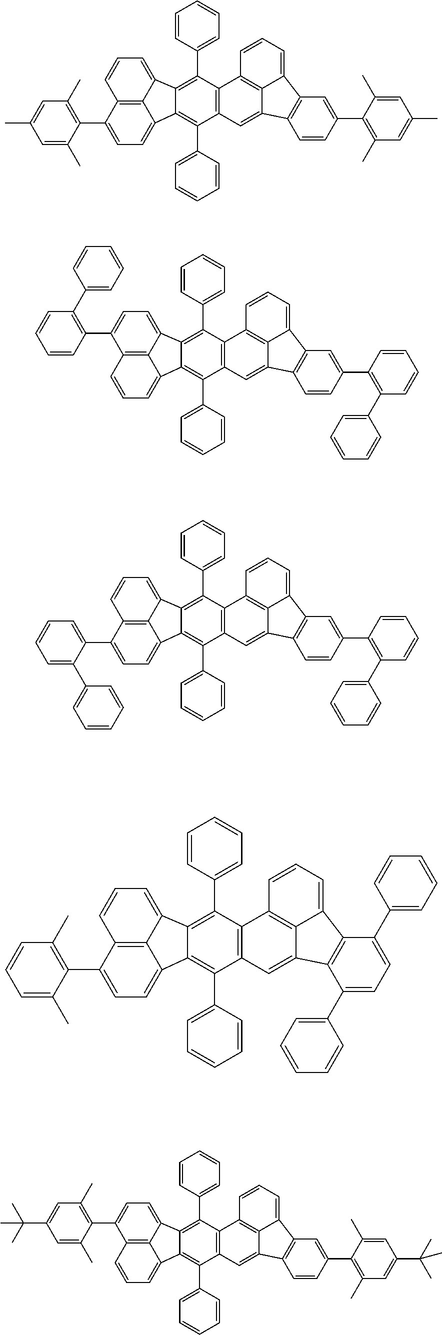

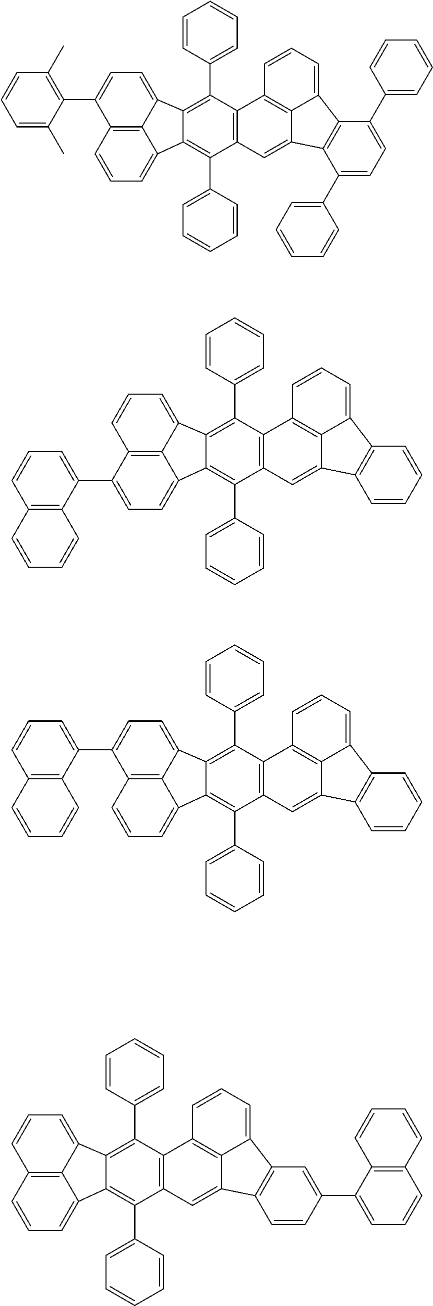

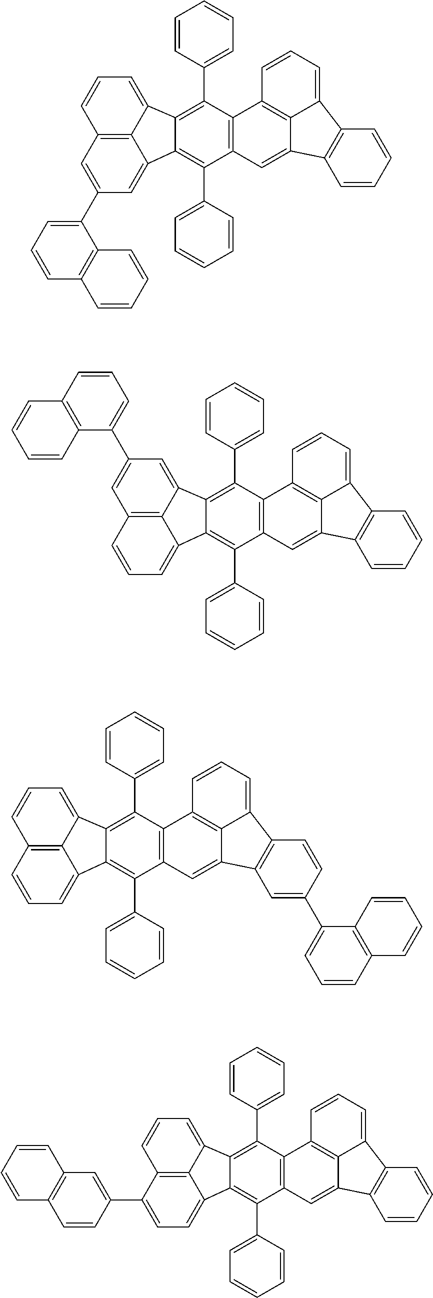

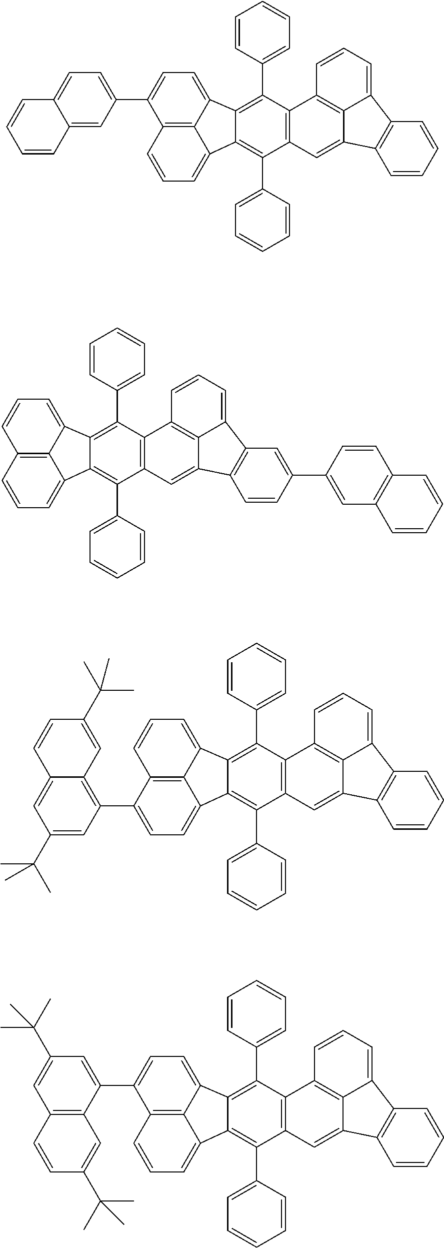

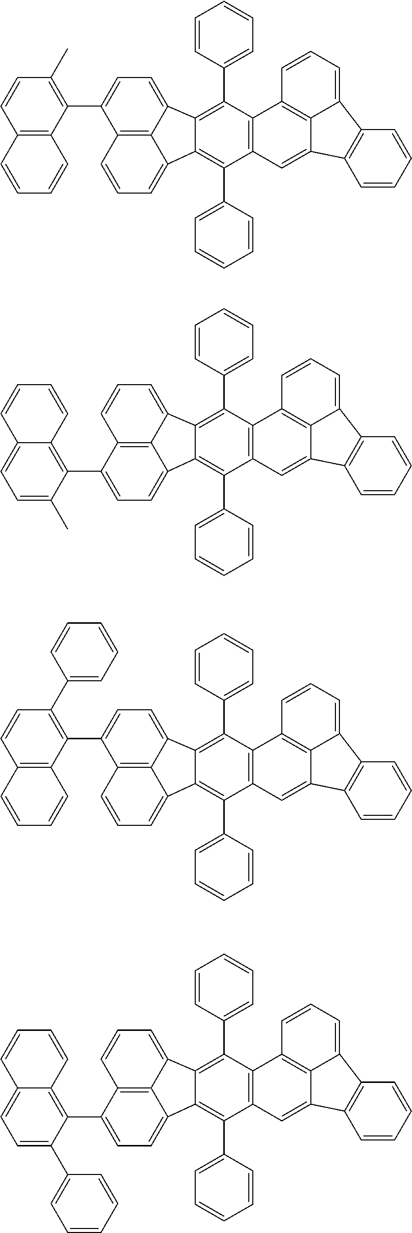

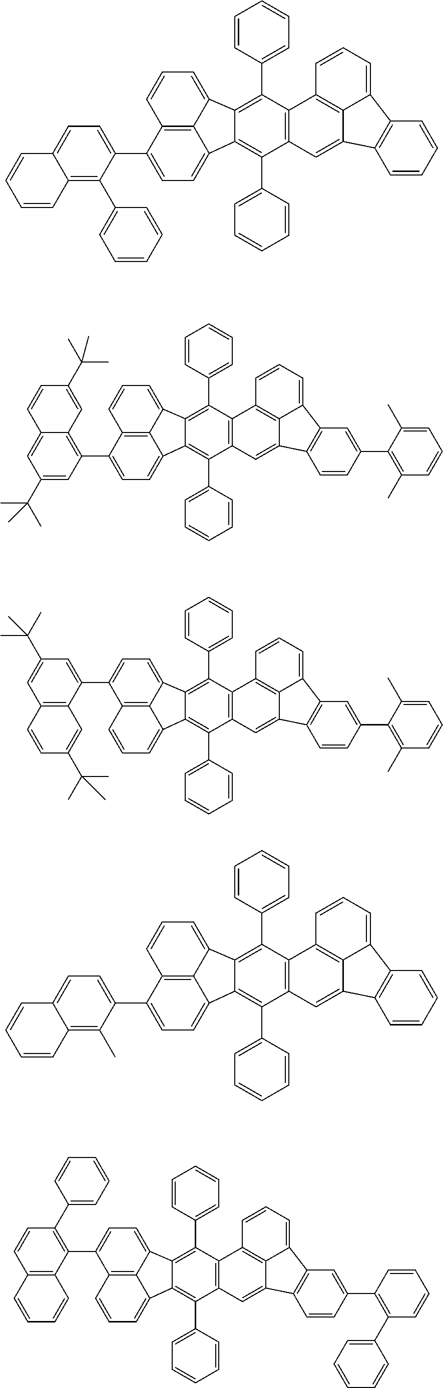

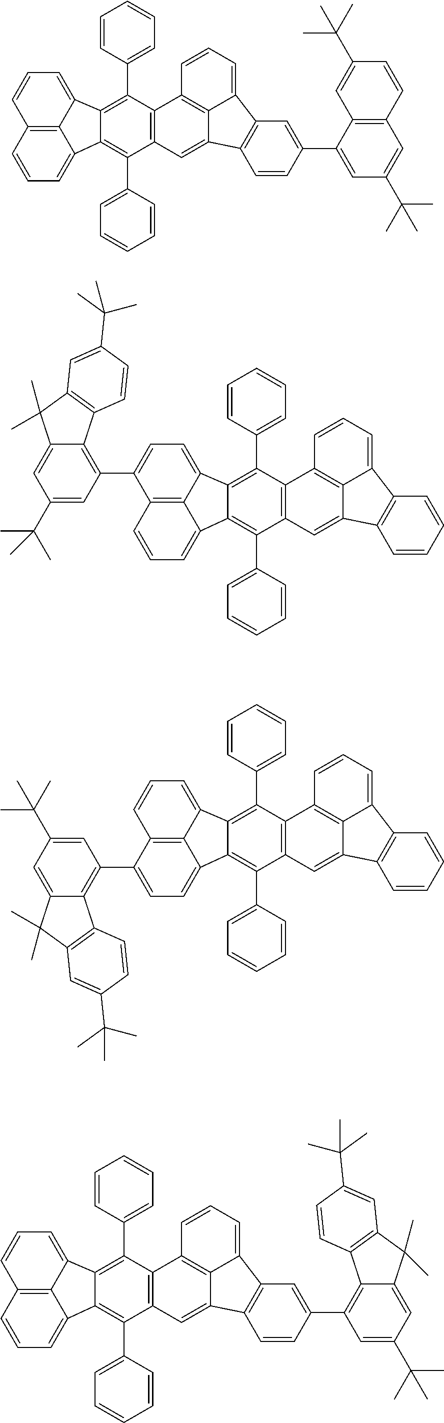

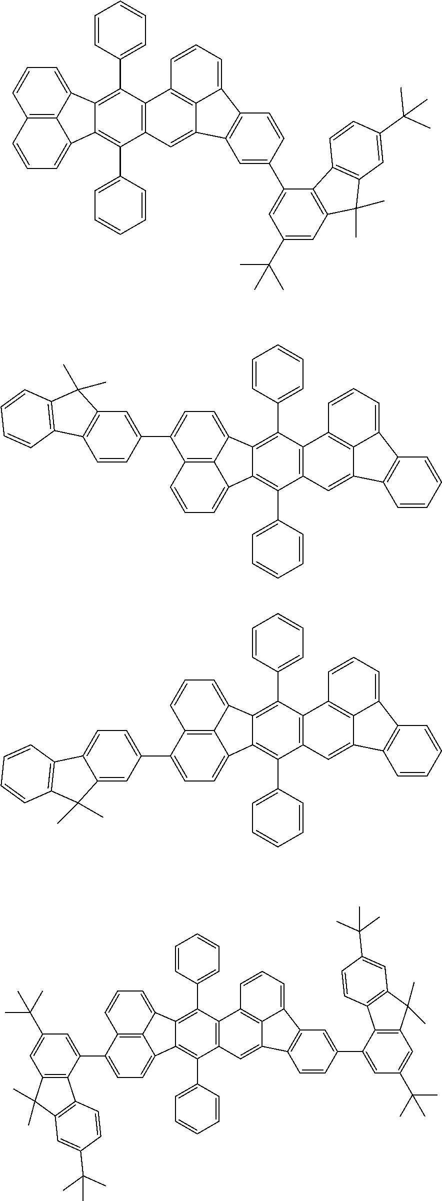

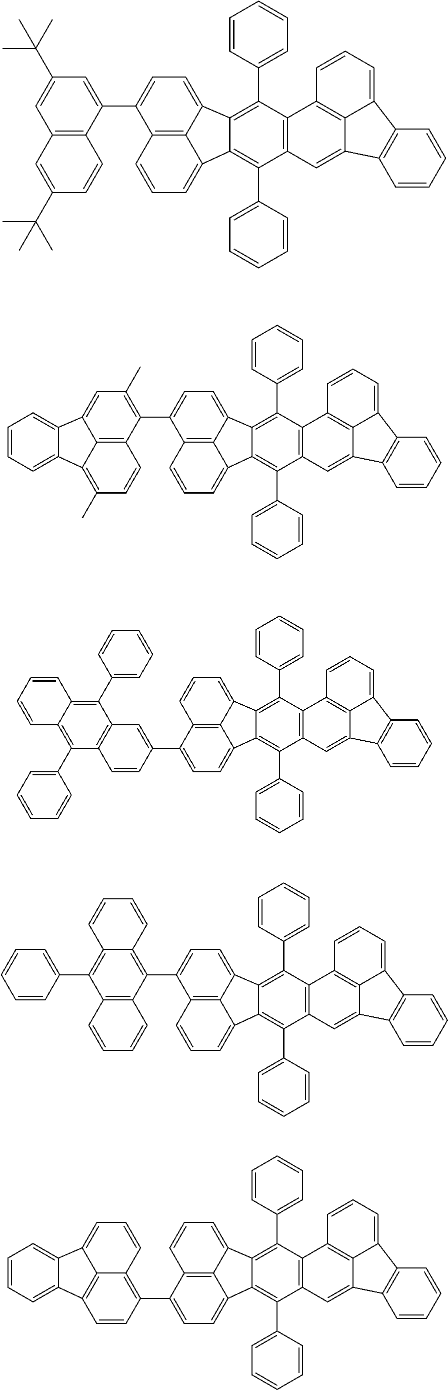

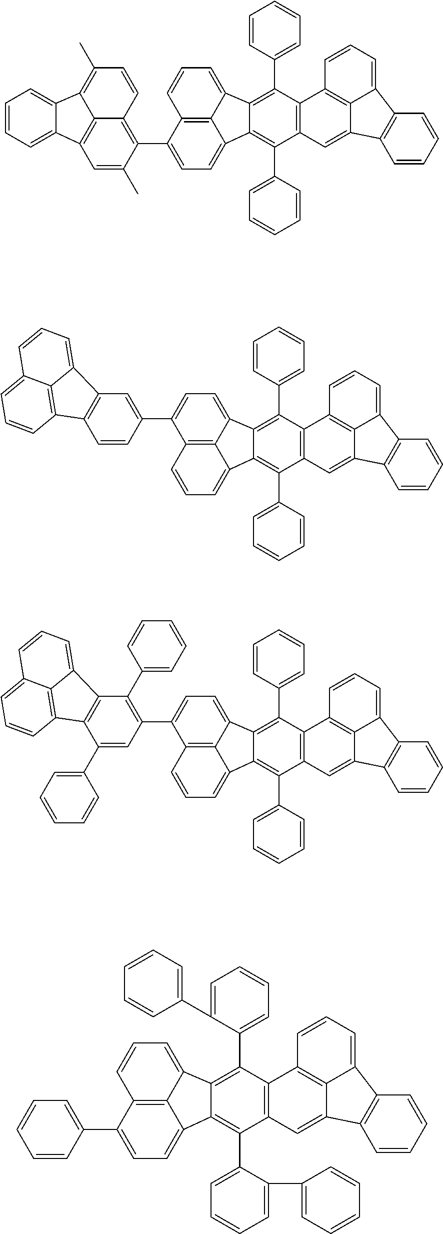

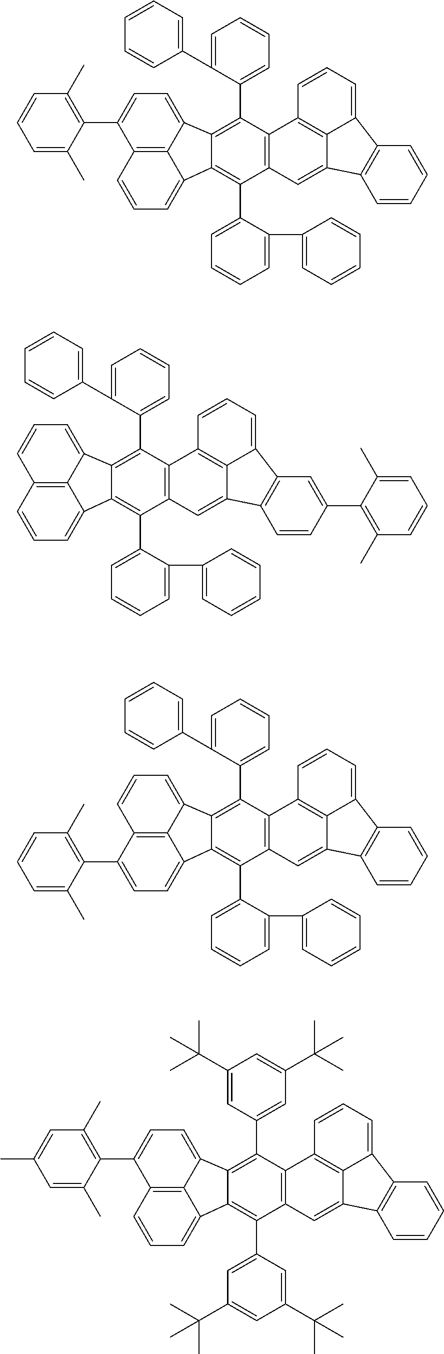

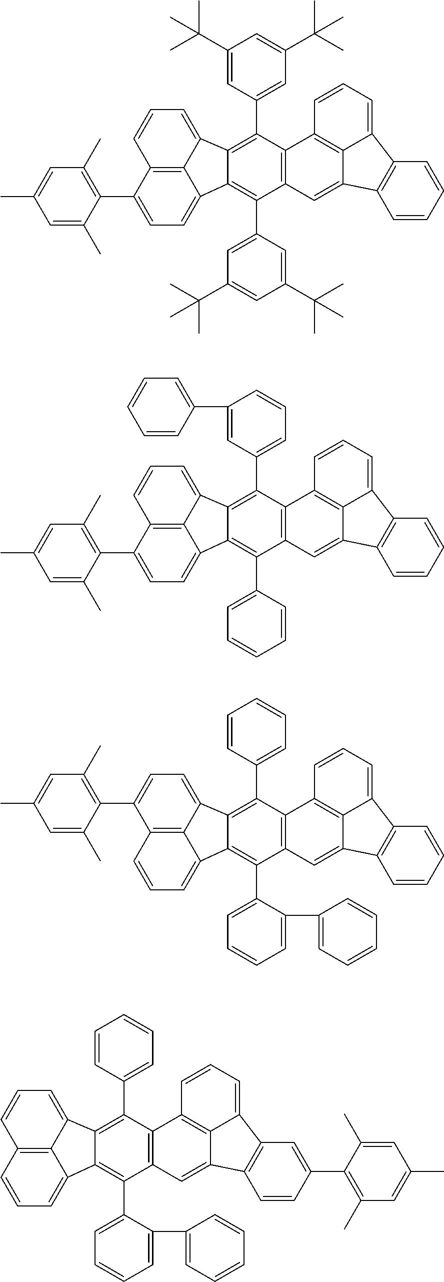

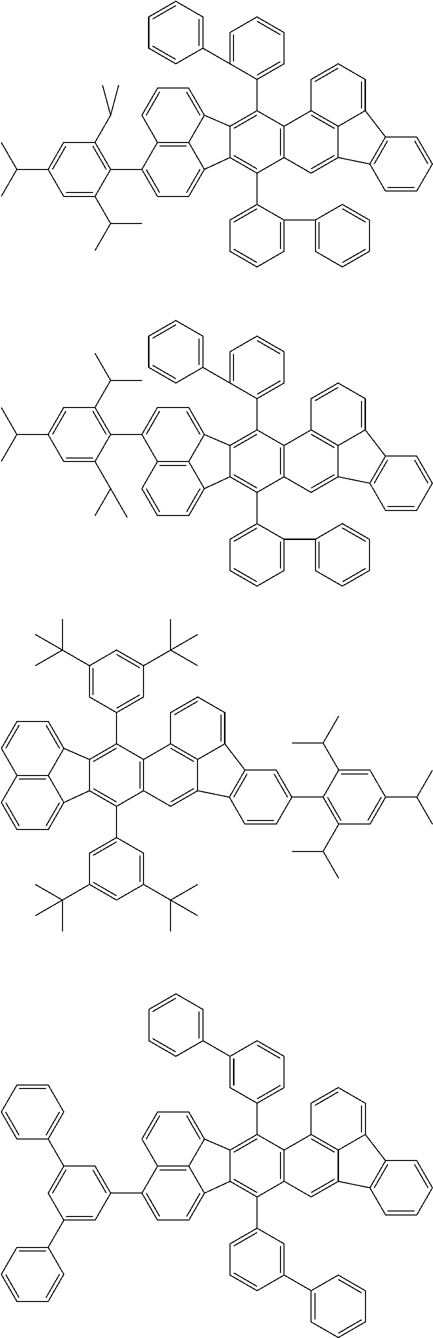

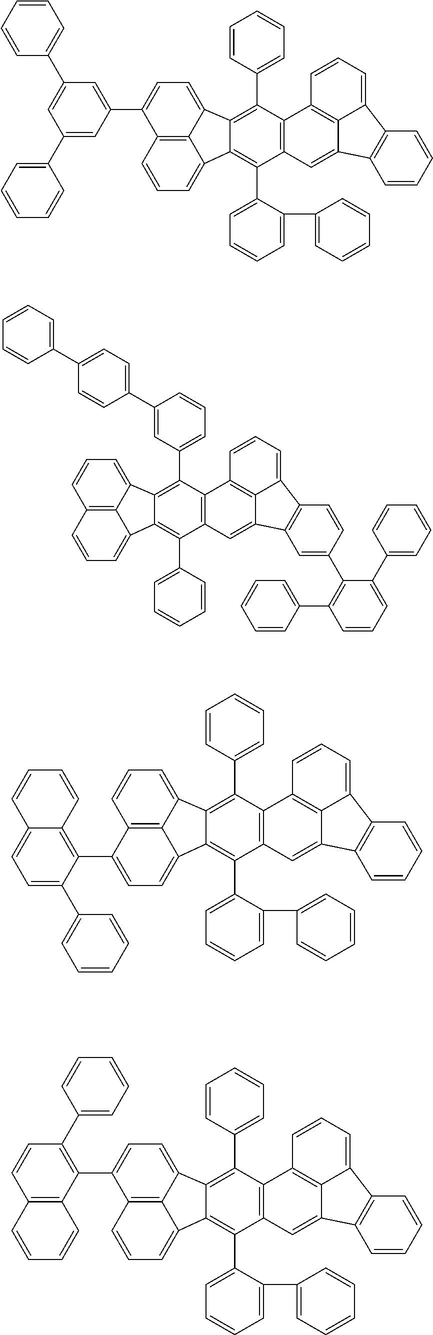

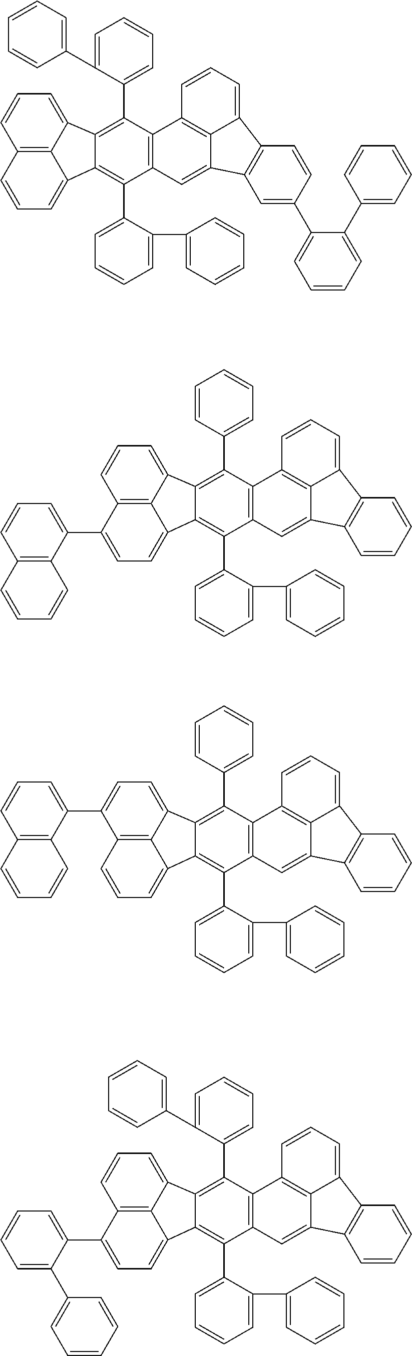

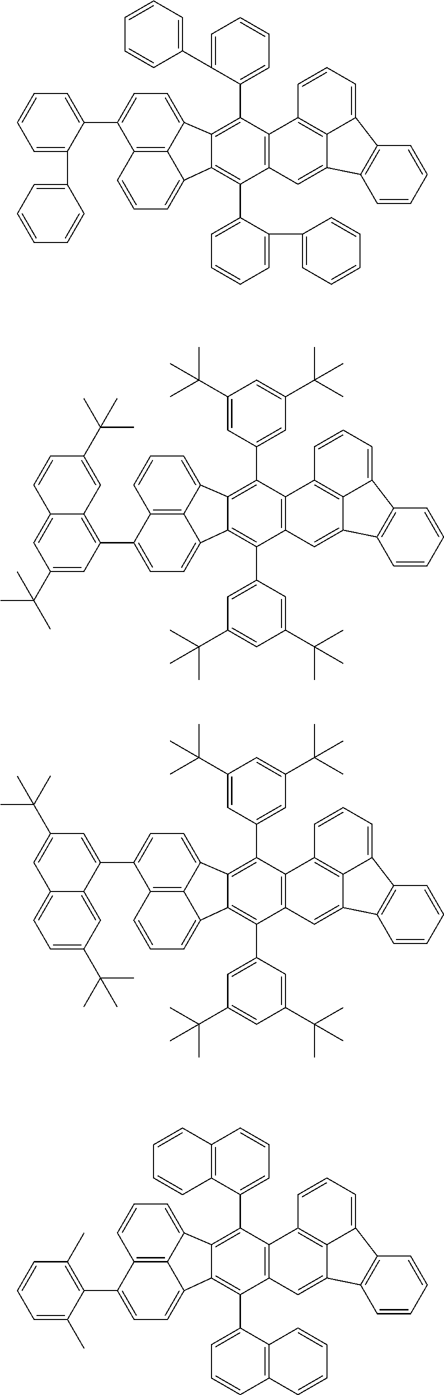

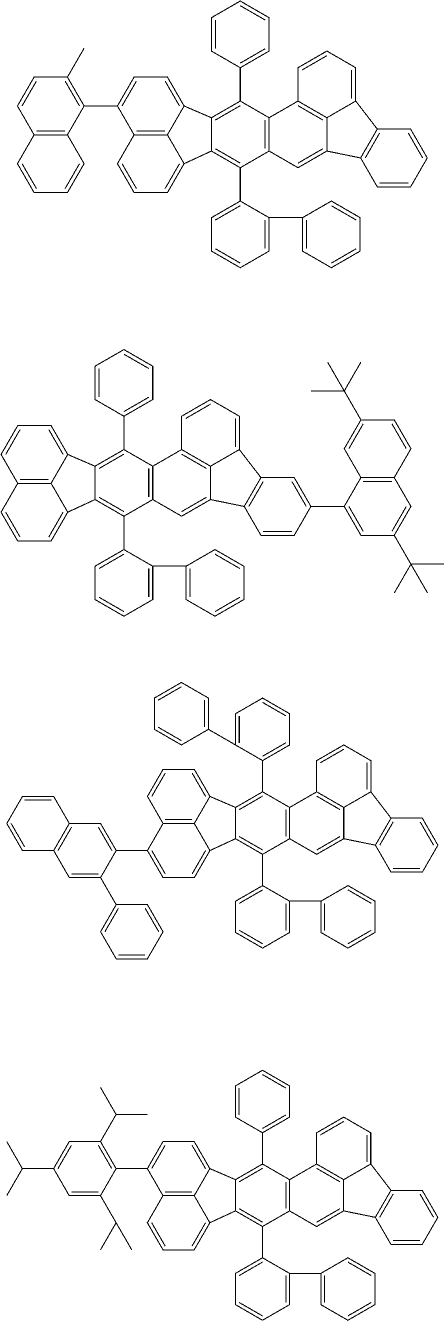

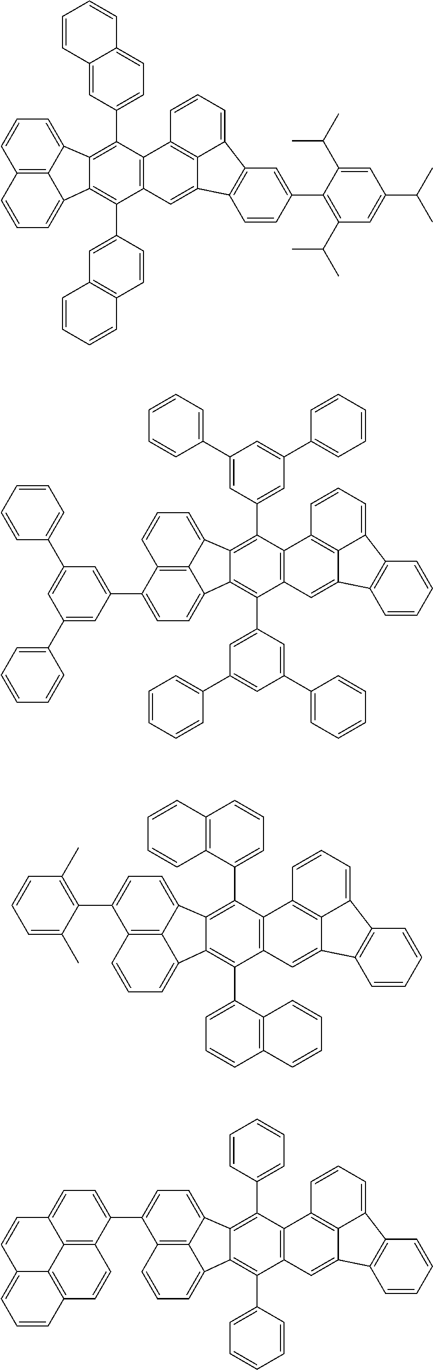

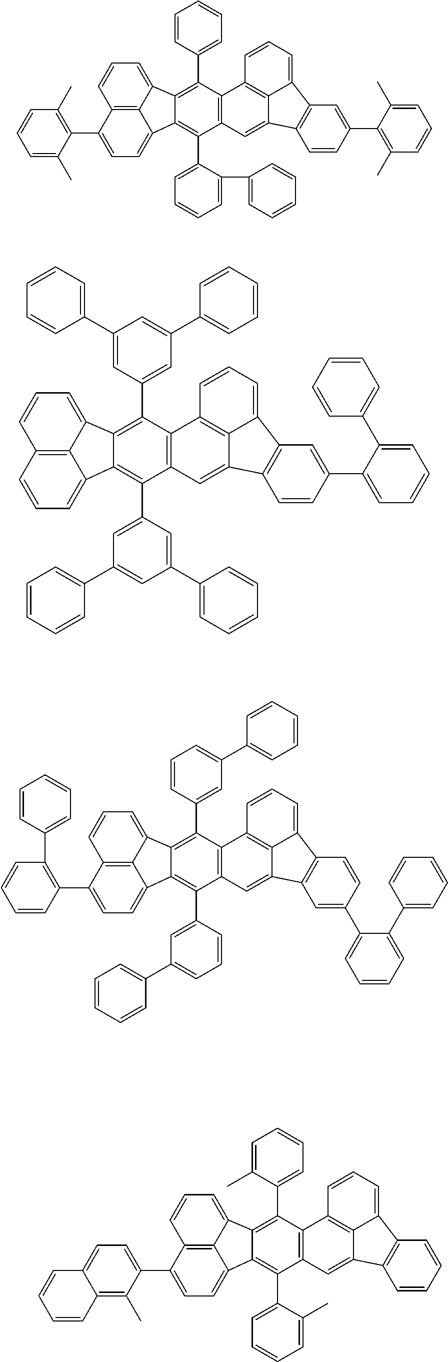

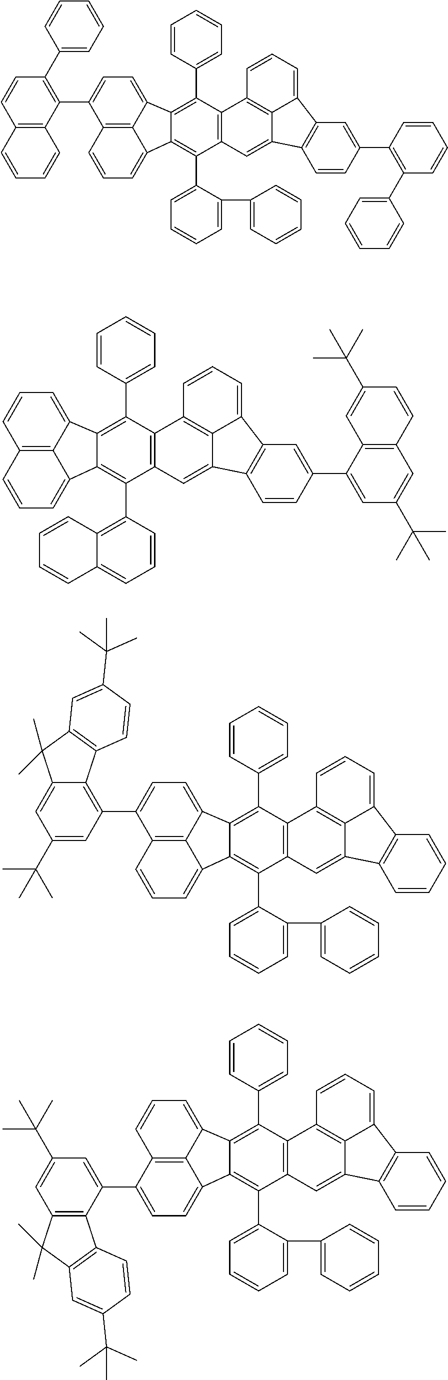

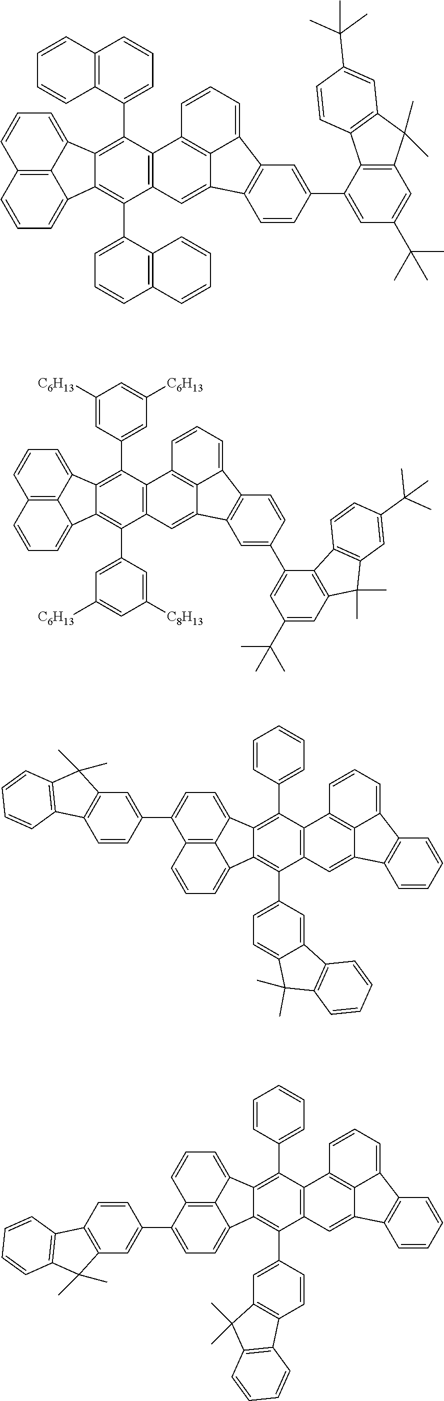

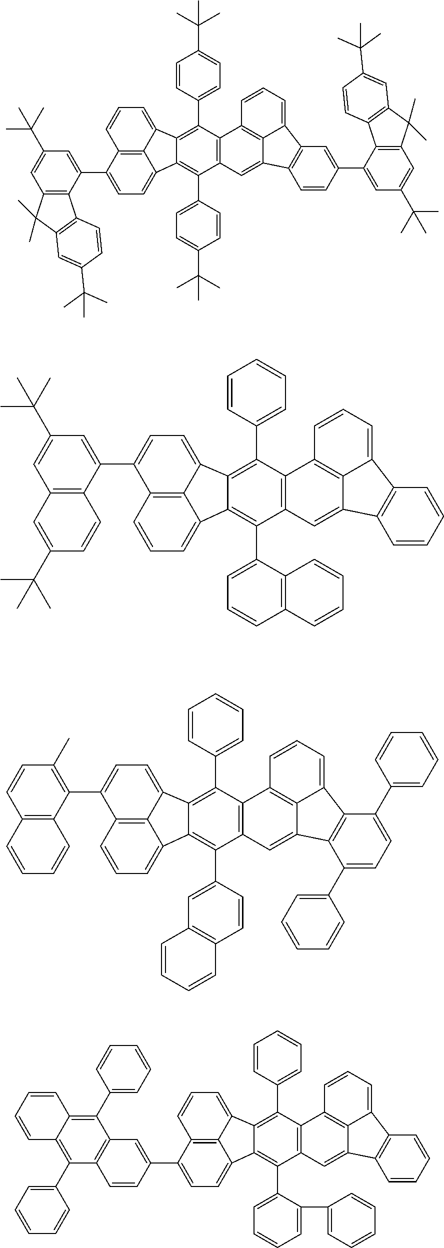

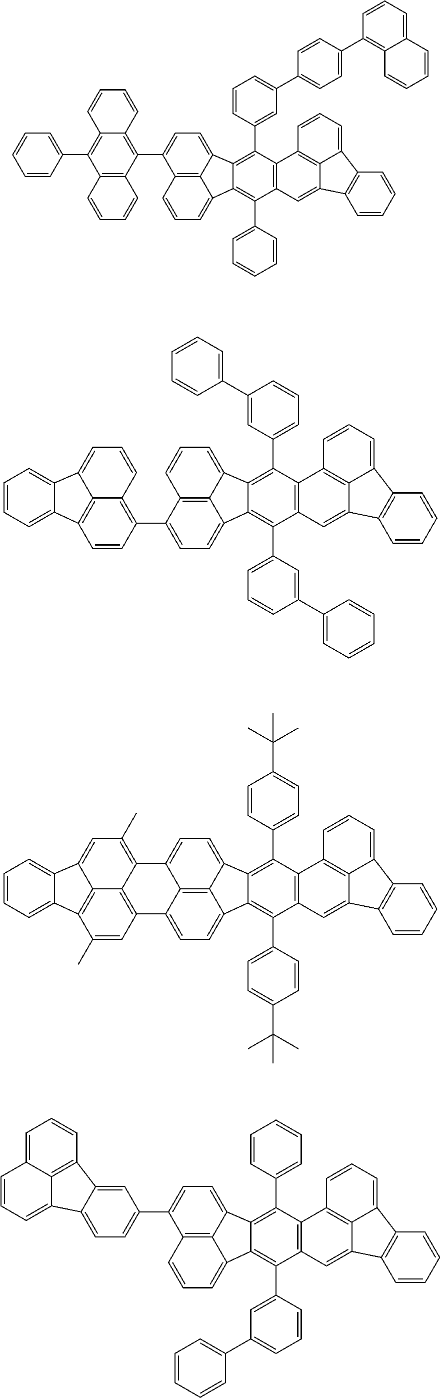

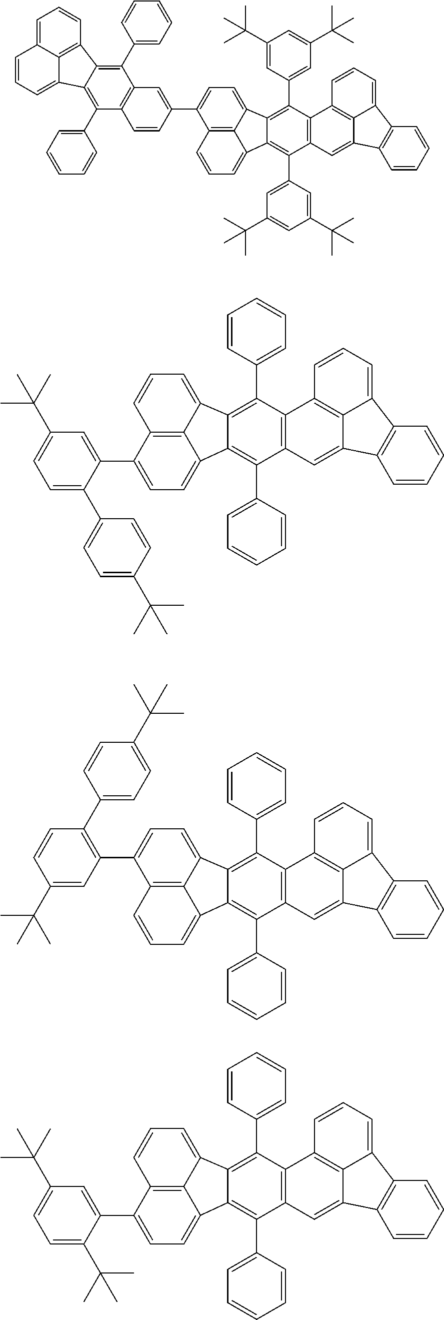

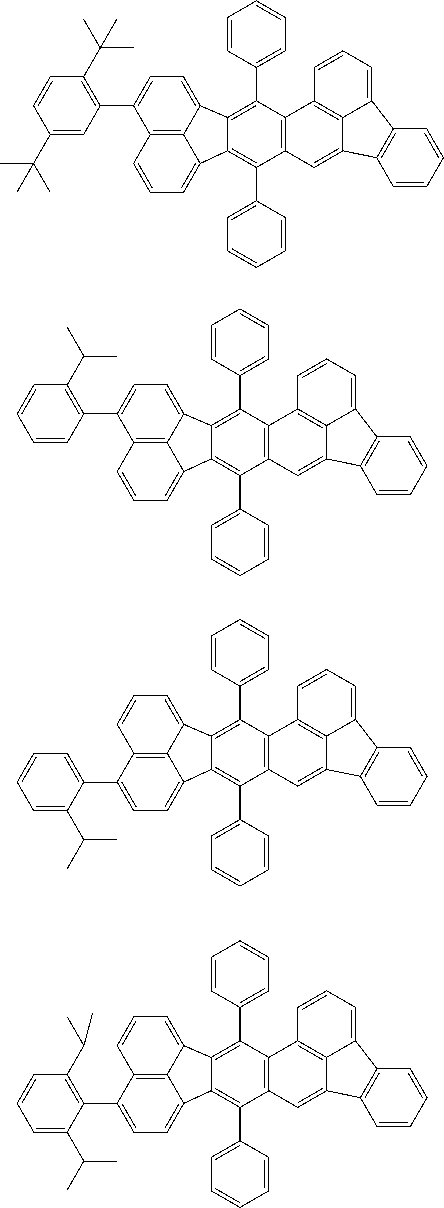

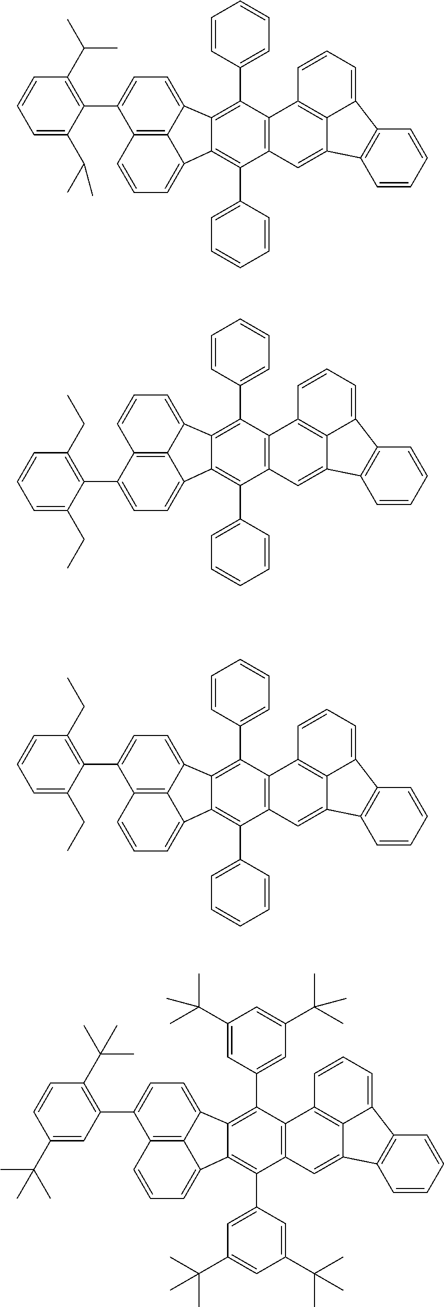

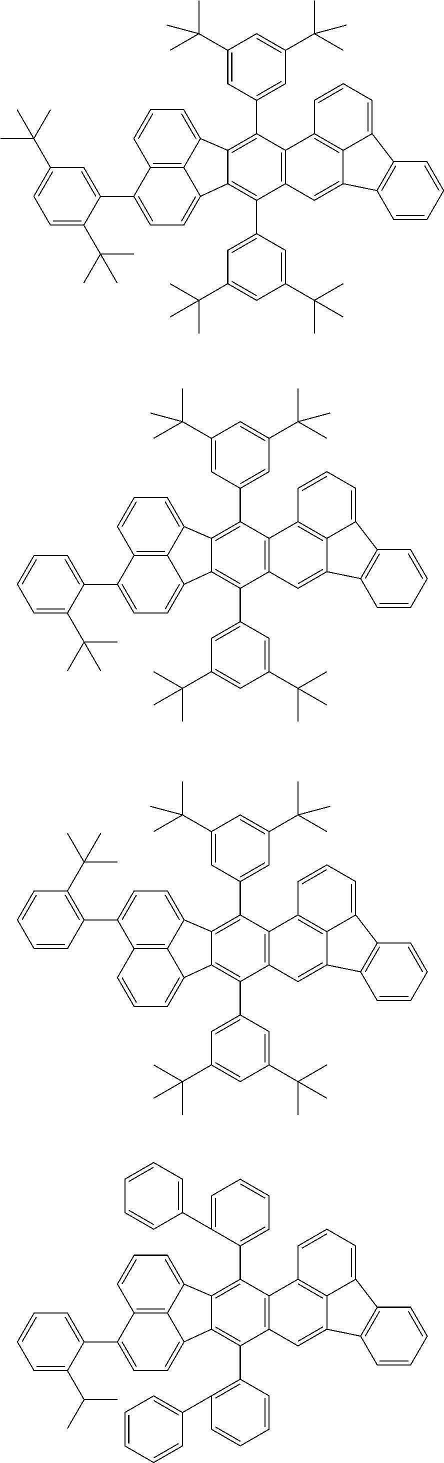

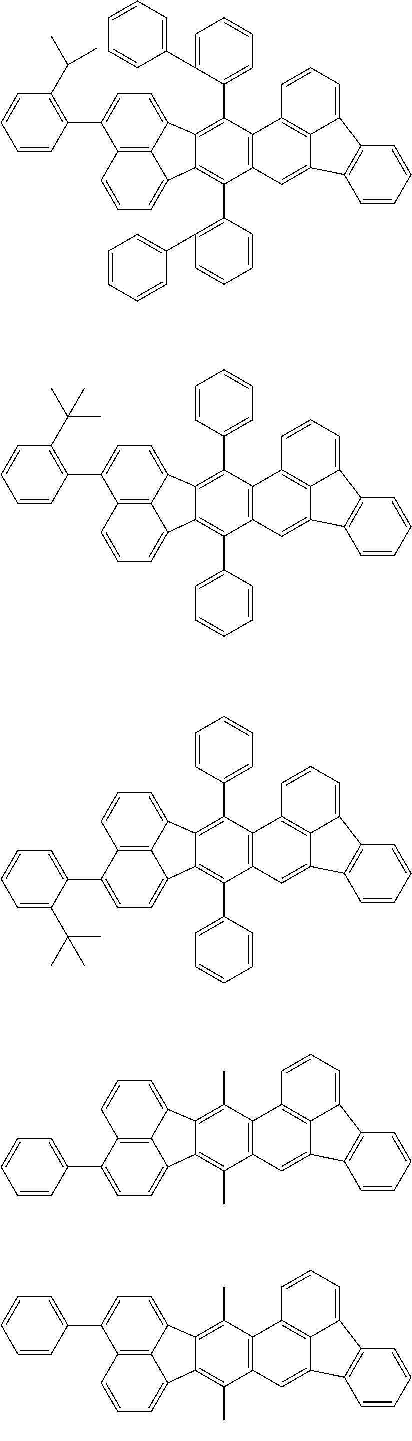

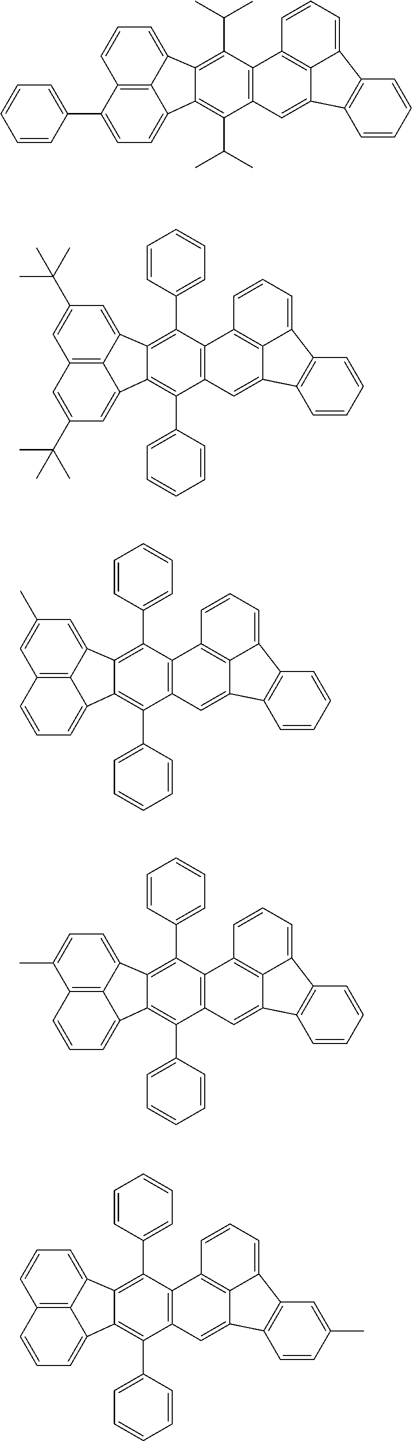

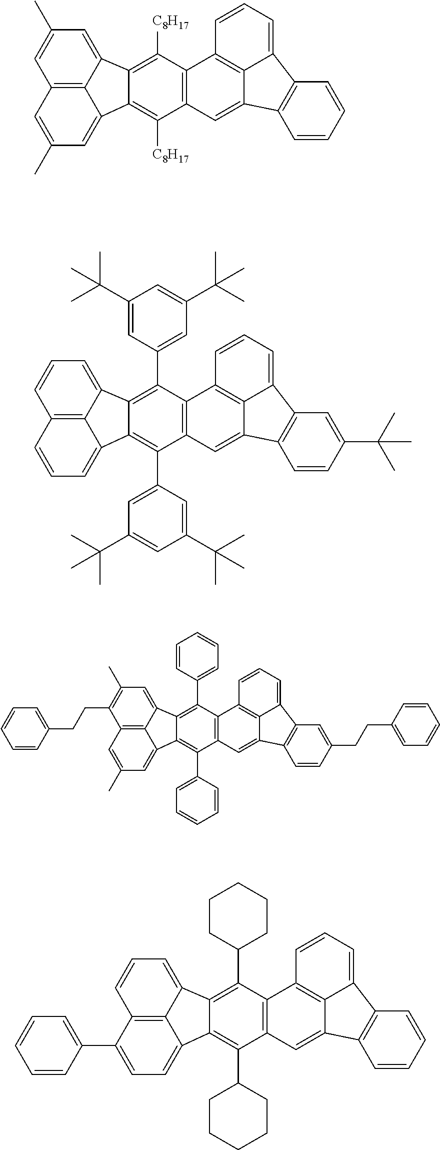

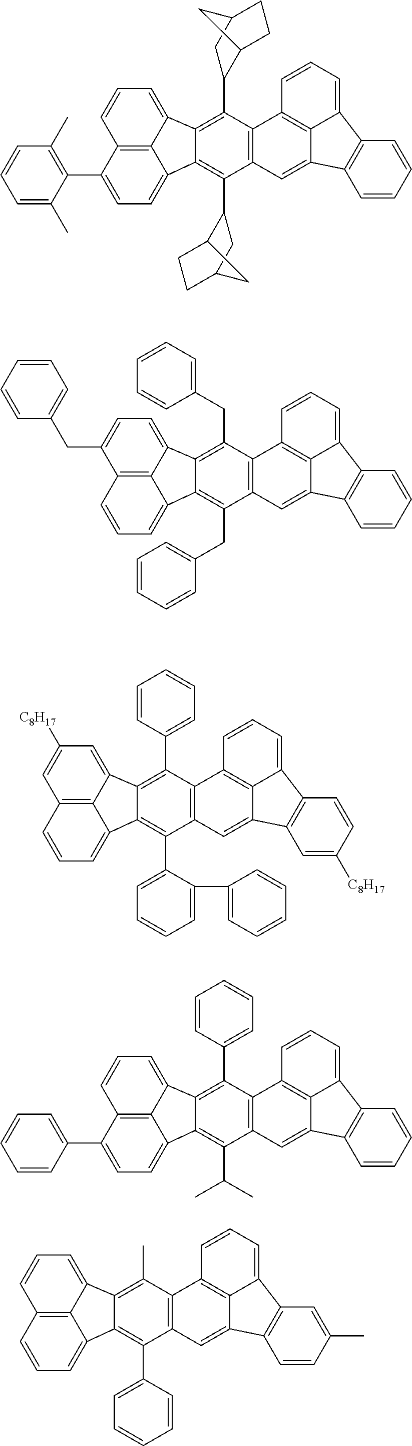

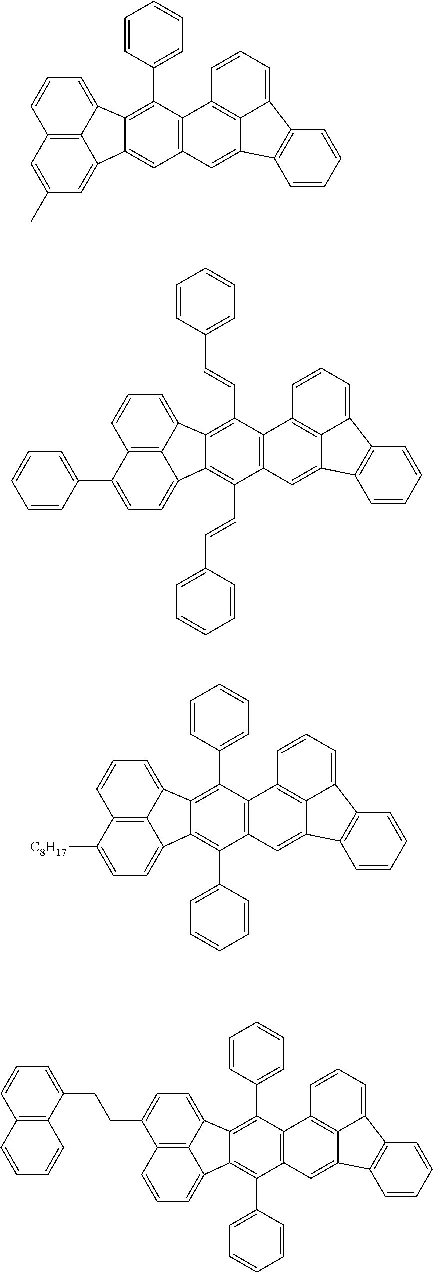

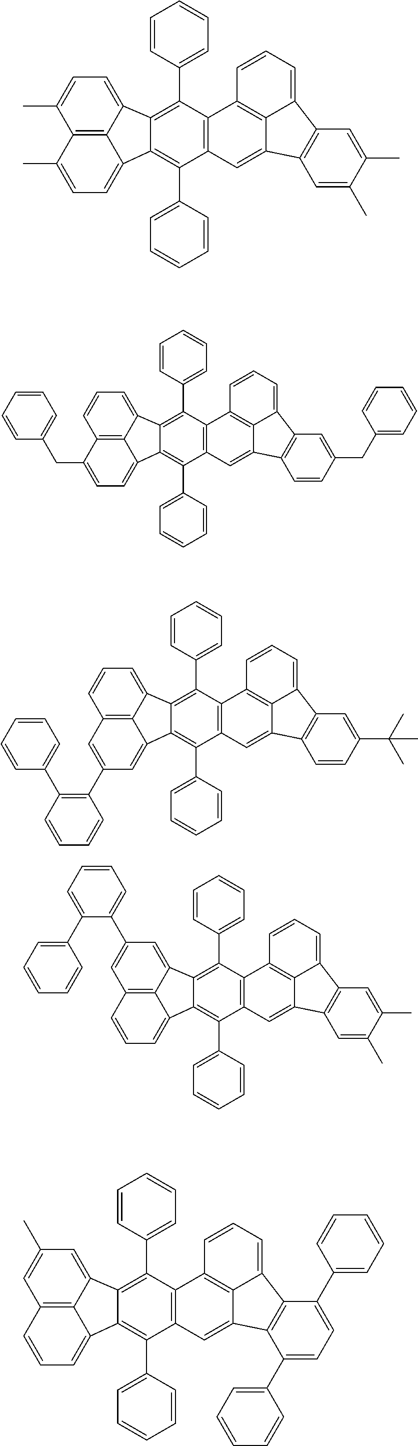

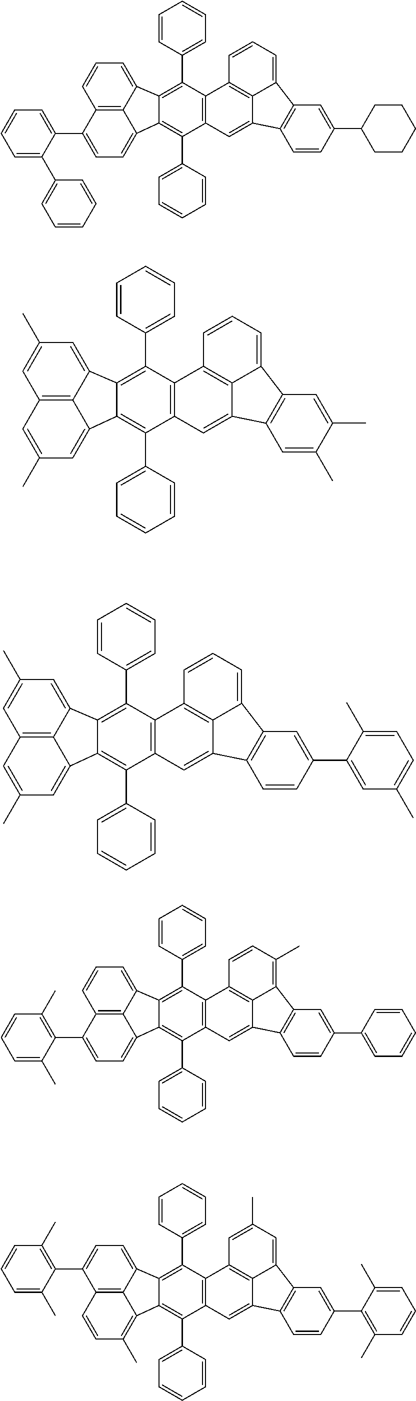

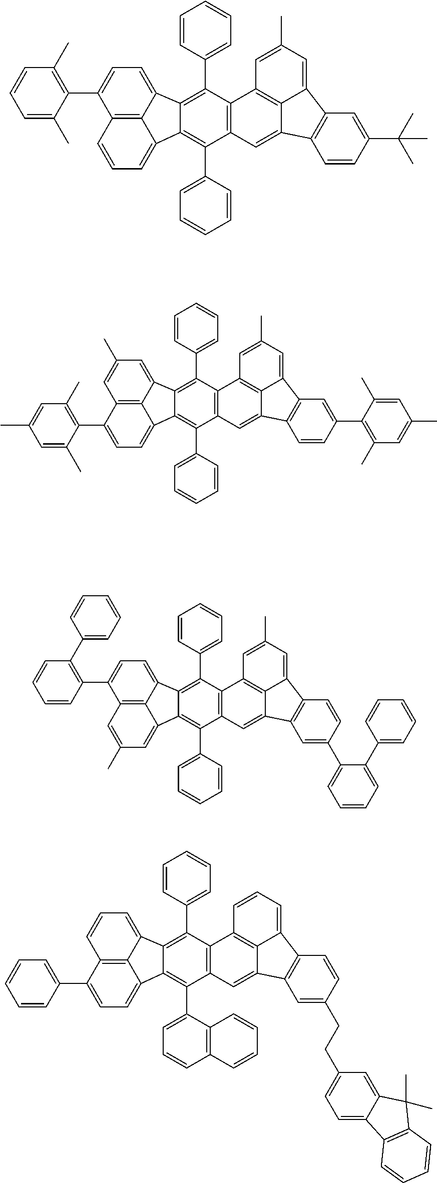

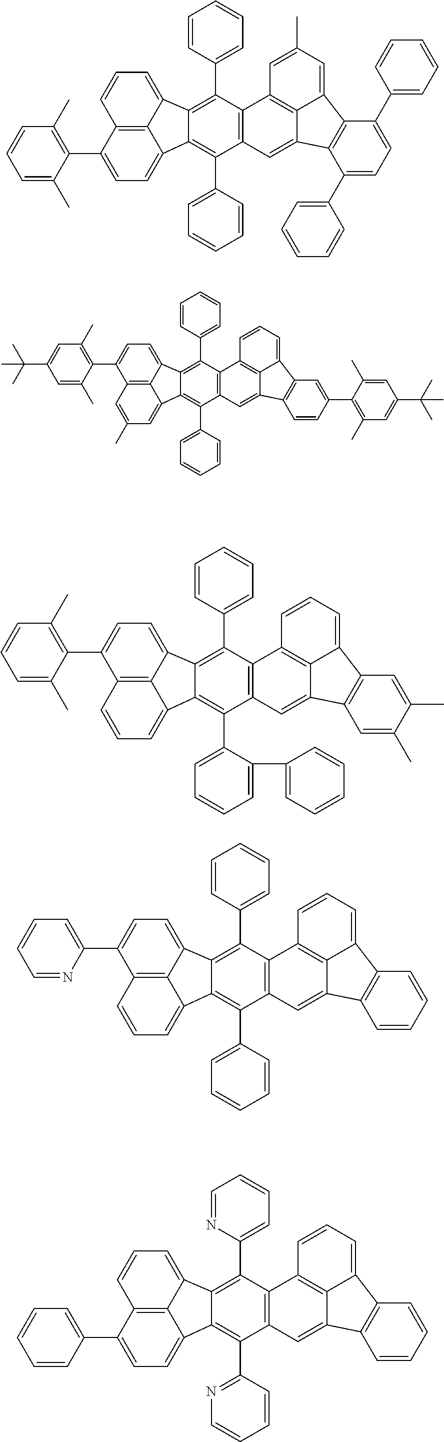

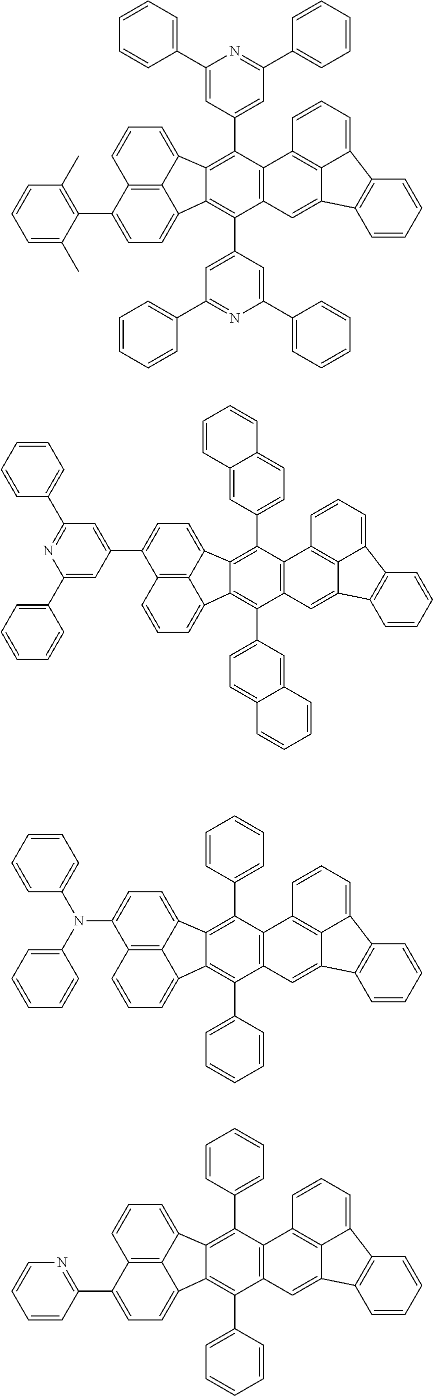

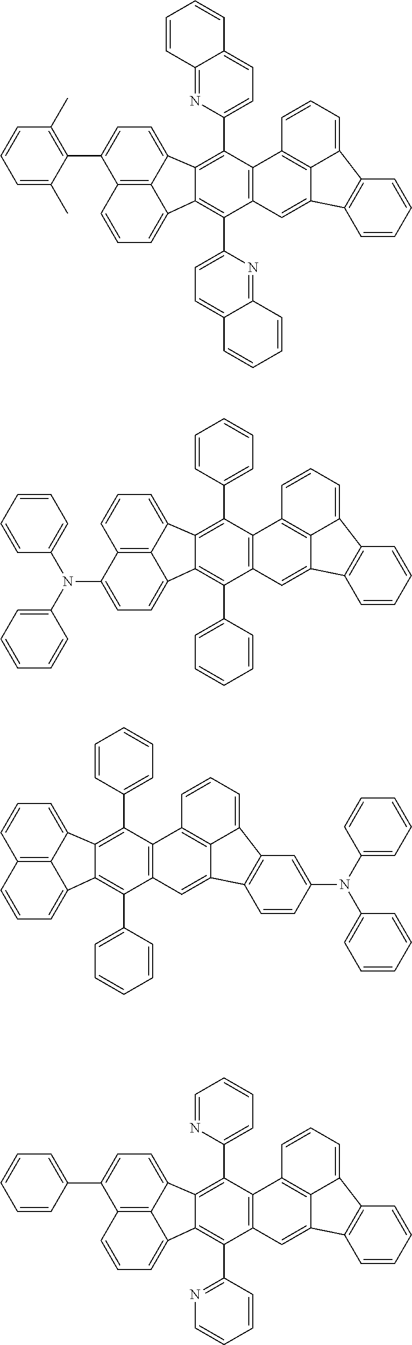 [SMILES: Cc1cccc(C)c1-c1ccc2c3c(-c4ccc5ccccc5n4)c4c(cc5c6ccccc6c6cccc4c65)c(-c4ccc5ccccc5n4)c3c3cccc1c32 ; c1ccc(-c2c3cc4c5ccccc5c5cccc(c3c(-c3ccccc3)c3c6cccc7c(N(c8ccccc8)c8ccccc8)ccc(c23)c76)c54)cc1 ; c1ccc(-c2c3cc4c5ccc(N(c6ccccc6)c6ccccc6)cc5c5cccc(c3c(-c3ccccc3)c3c6cccc7cccc(c23)c76)c54)cc1 ; c1ccc(-c2ccc3c4c(-c5ccccn5)c5c(cc6c7ccccc7c7cccc5c76)c(-c5ccccn5)c4c4cccc2c43)cc1]

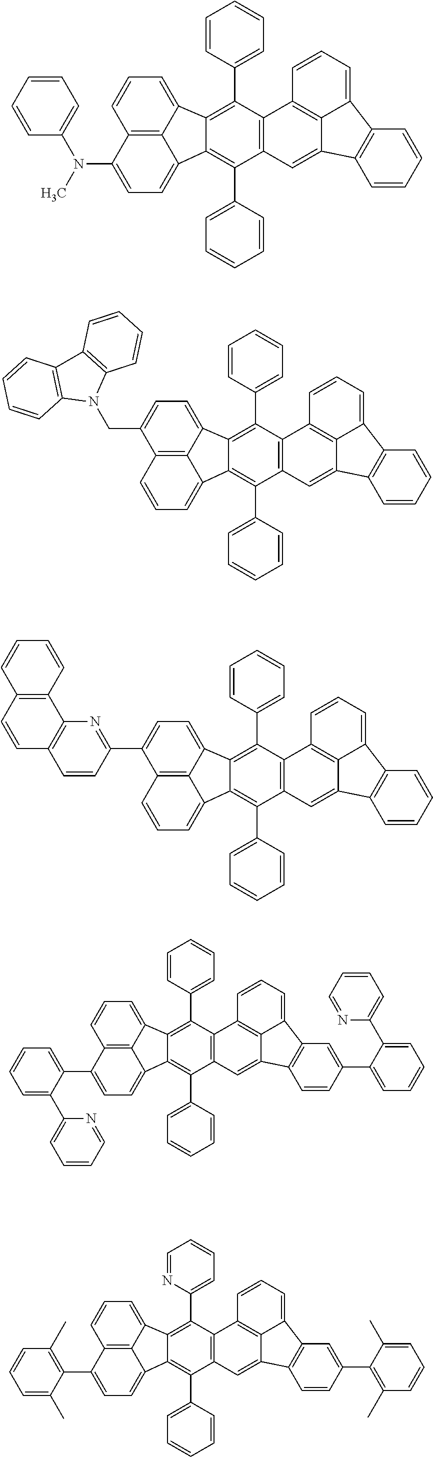 [SMILES: CN(c1ccccc1)c1ccc2c3c(-c4ccccc4)c4cc5c6ccccc6c6cccc(c4c(-c4ccccc4)c3c3cccc1c23)c65 ; c1ccc(-c2c3cc4c5ccccc5c5cccc(c3c(-c3ccccc3)c3c6ccc(Cn7c8ccccc8c8ccccc87)c7cccc(c23)c76)c54)cc1 ; c1ccc(-c2c3cc4c5ccccc5c5cccc(c3c(-c3ccccc3)c3c6ccc(-c7ccc8ccc9ccccc9c8n7)c7cccc(c23)c76)c54)cc1 ; c1ccc(-c2c3cc4c5ccc(-c6ccccc6-c6ccccn6)cc5c5cccc(c3c(-c3ccccc3)c3c6cccc7c(-c8ccccc8-c8ccccn8)ccc(c23)c76)c54)cc1 ; Cc1cccc(C)c1-c1ccc2c(c1)c1cccc3c4c(-c5ccccn5)c5c6cccc7c(-c8c(C)cccc8C)ccc(c5c(-c5ccccc5)c4cc2c13)c76]

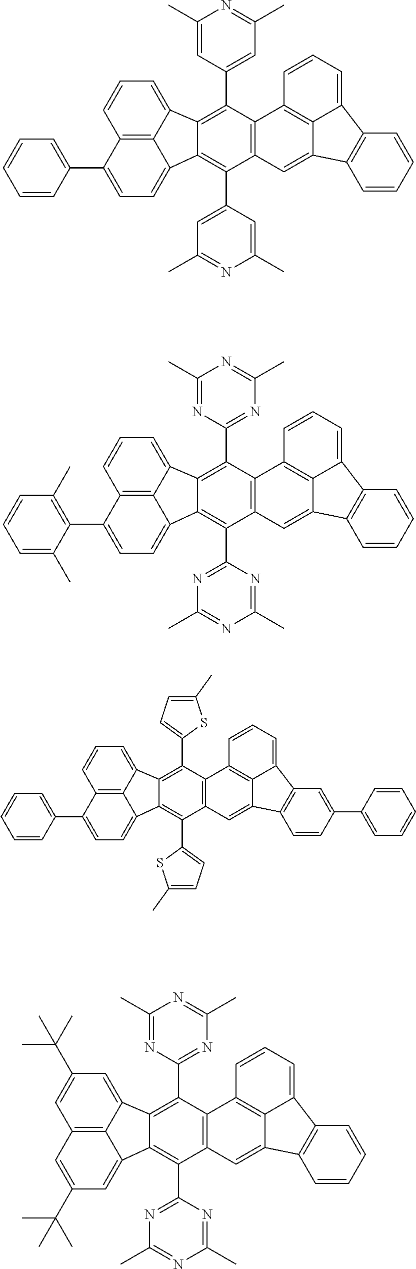 [SMILES: Cc1cc(-c2c3cc4c5ccccc5c5cccc(c3c(-c3cc(C)nc(C)c3)c3c6cccc7c(-c8ccccc8)ccc(c23)c76)c54)cc(C)n1 ; Cc1nc(C)nc(-c2c3cc4c5ccccc5c5cccc(c3c(-c3nc(C)nc(C)n3)c3c6cccc7c(-c8c(C)cccc8C)ccc(c23)c76)c54)n1 ; Cc1ccc(-c2c3cc4c5ccc(-c6ccccc6)cc5c5cccc(c3c(-c3ccc(C)s3)c3c6cccc7c(-c8ccccc8)ccc(c23)c76)c54)s1 ; Cc1nc(C)nc(-c2c3cc4c5ccccc5c5cccc(c3c(-c3nc(C)nc(C)n3)c3c6cc(C(C)(C)C)cc7cc(C(C)(C)C)cc(c23)c76)c54)n1]

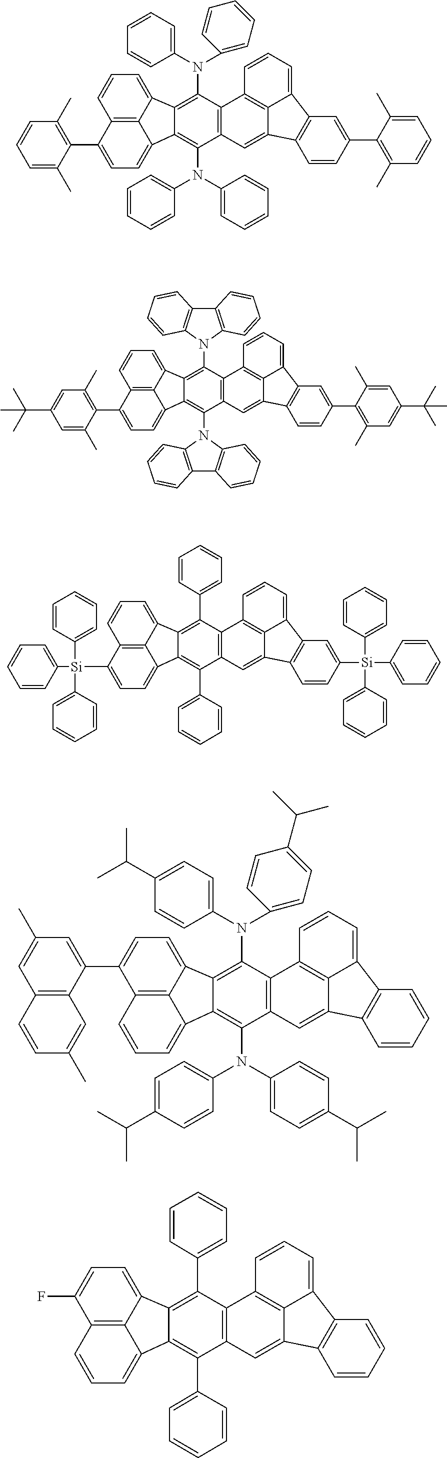

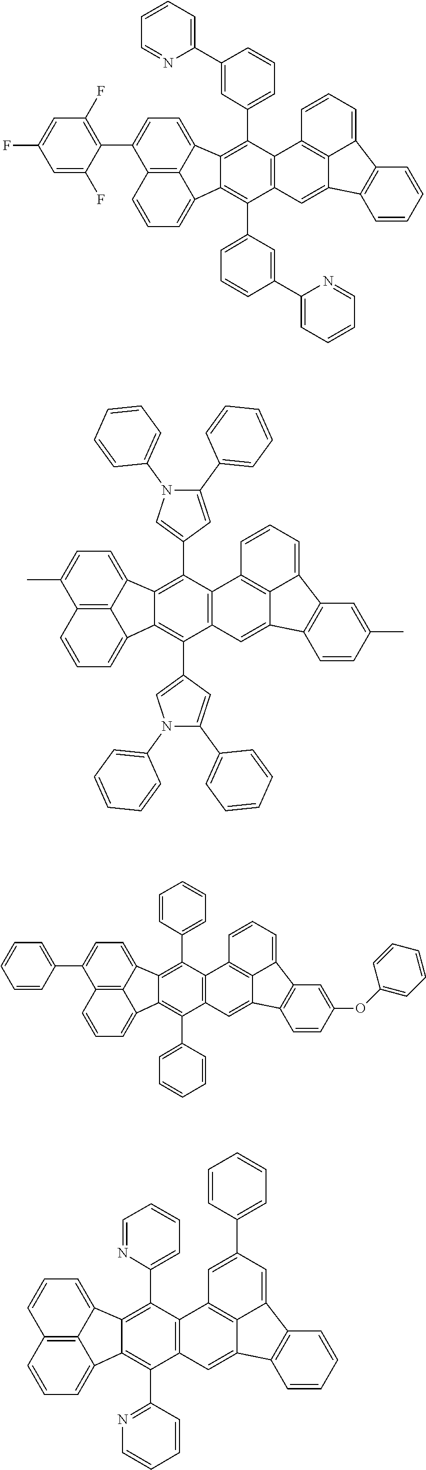

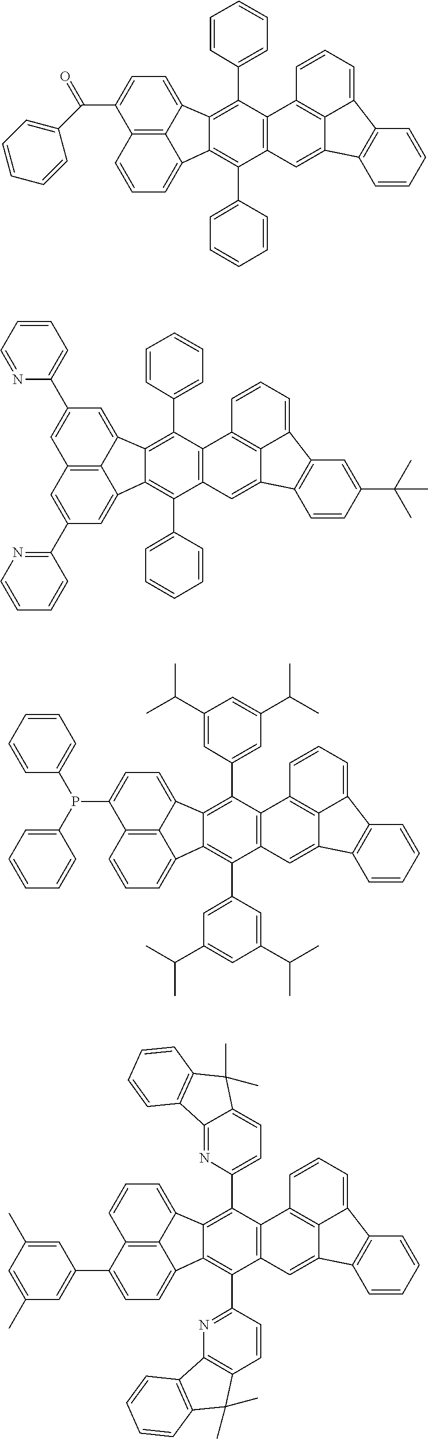 [SMILES: O=C(c1ccccc1)c1ccc2c3c(-c4ccccc4)c4c(cc5c6ccccc6c6cccc4c65)c(-c4ccccc4)c3c3cccc1c32 ; CC(C)(C)c1ccc2c(c1)c1cccc3c4c(-c5ccccc5)c5c6cc(-c7ccccn7)cc7cc(-c8ccccn8)cc(c5c(-c5ccccc5)c4cc2c13)c76 ; CC(C)c1cc(-c2c3cc4c5ccccc5c5cccc(c3c(-c3cc(C(C)C)cc(C(C)C)c3)c3c6ccc(P(c7ccccc7)c7ccccc7)c7cccc(c23)c76)c54)cc(C(C)C)c1 ; Cc1cc(C)cc(-c2ccc3c4c(-c5ccc6c(n5)-c5ccccc5C6(C)C)c5cc6c7ccccc7c7cccc(c5c(-c5ccc8c(n5)-c5ccccc5C8(C)C)c4c4cccc2c34)c76)c1]

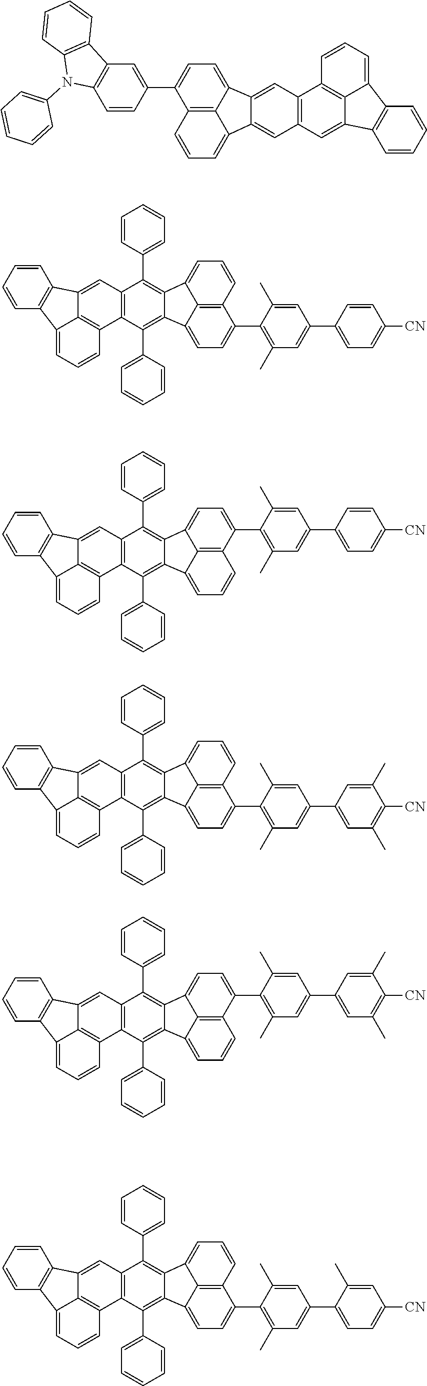

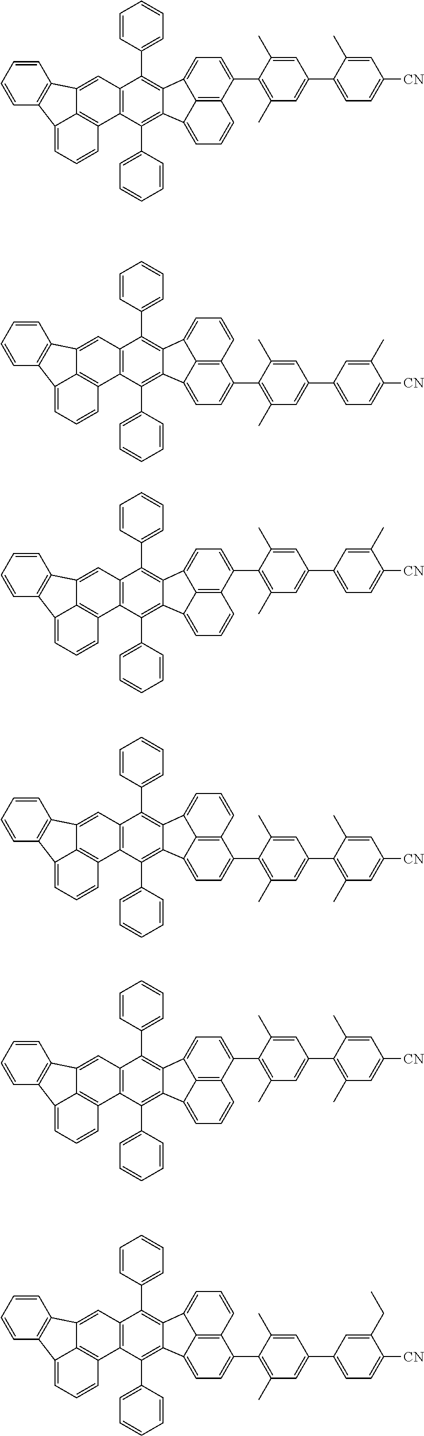

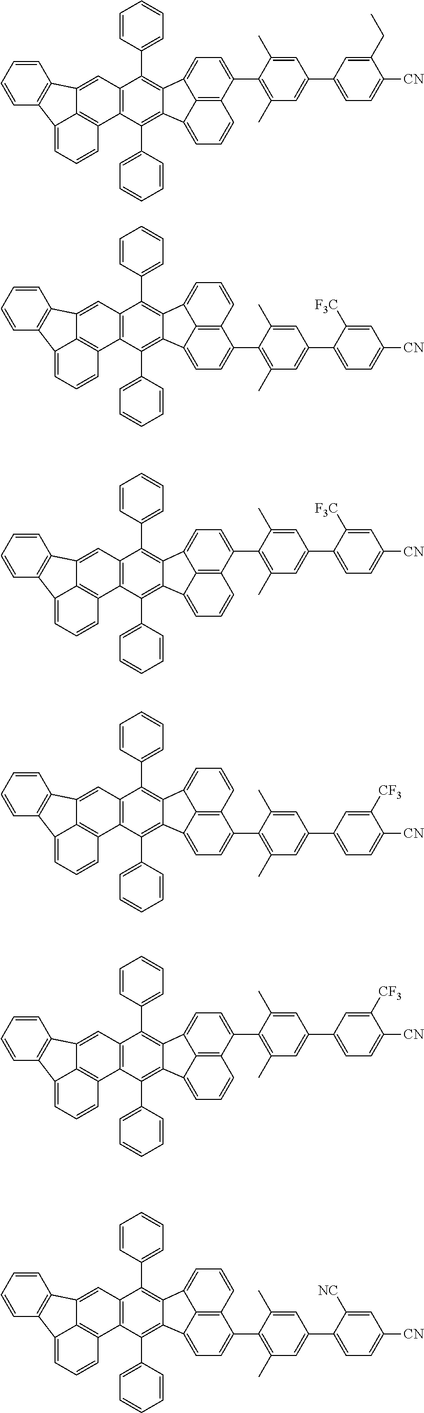

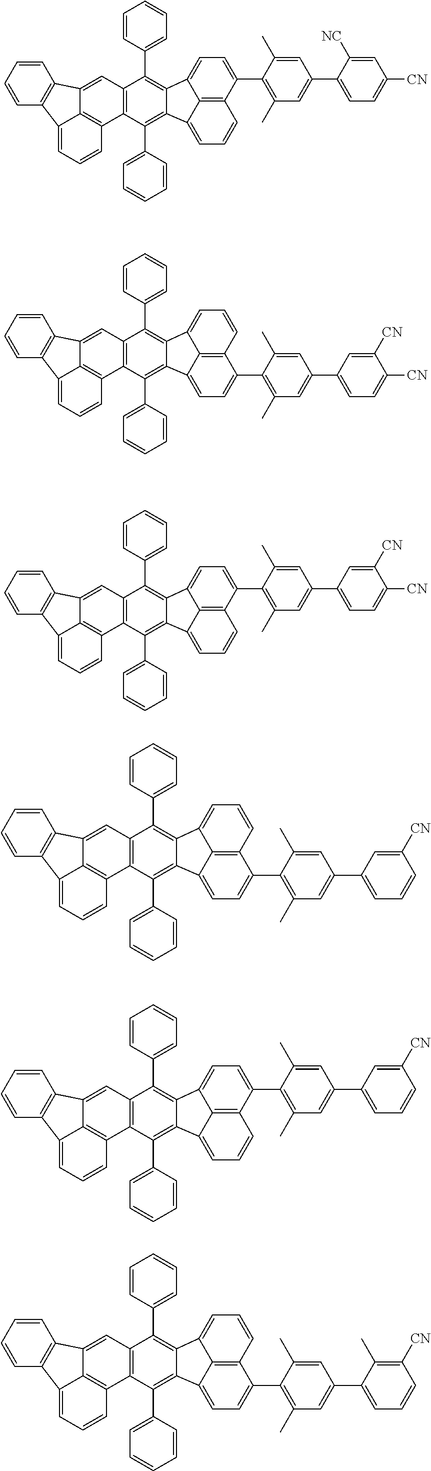

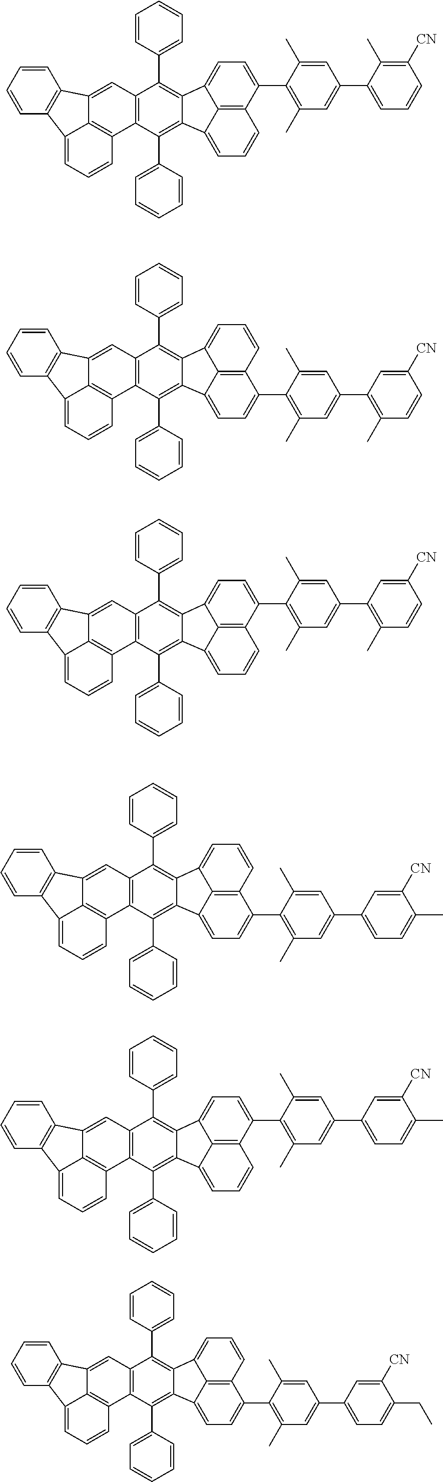

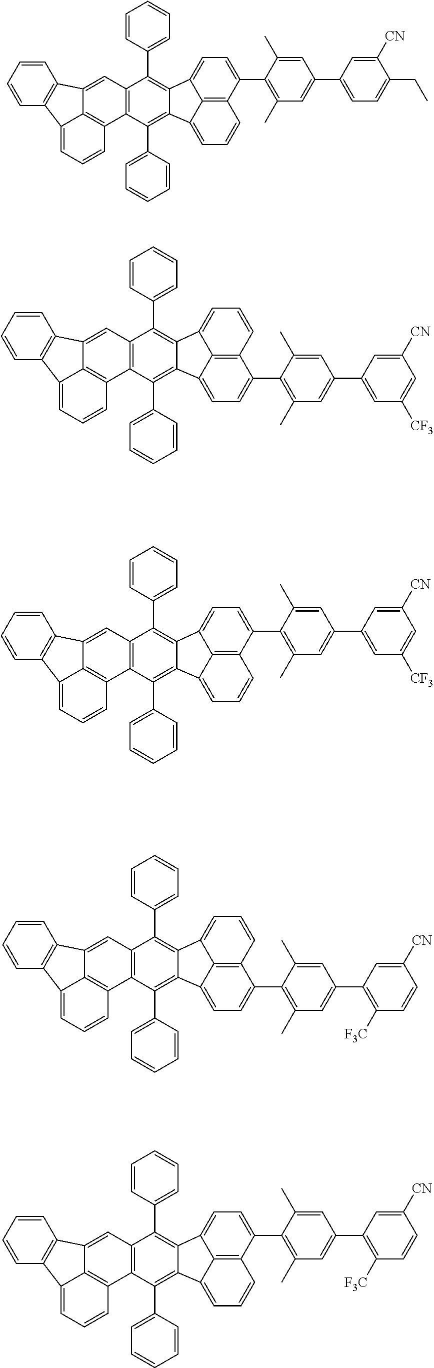

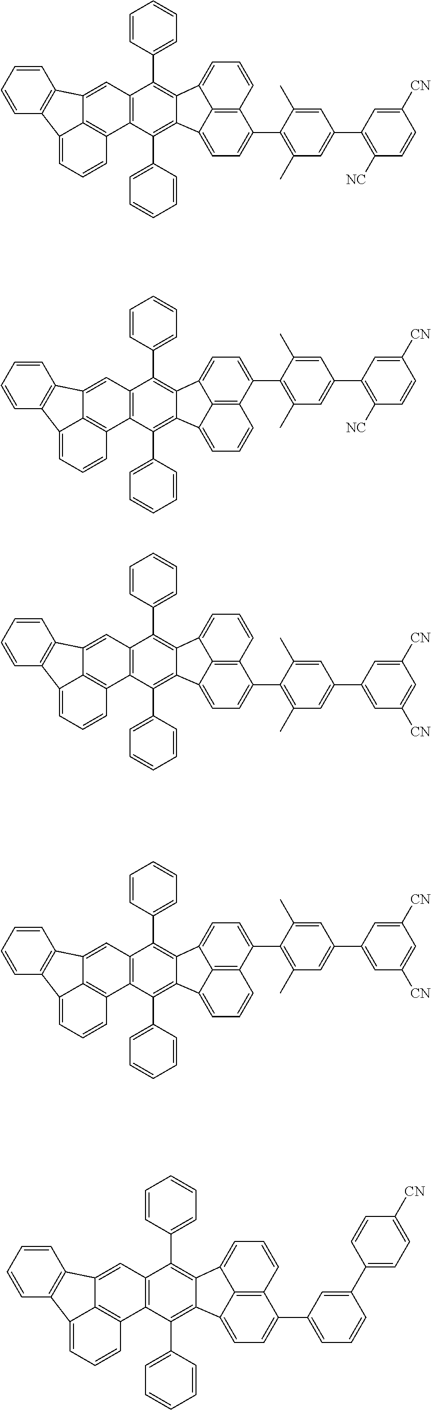

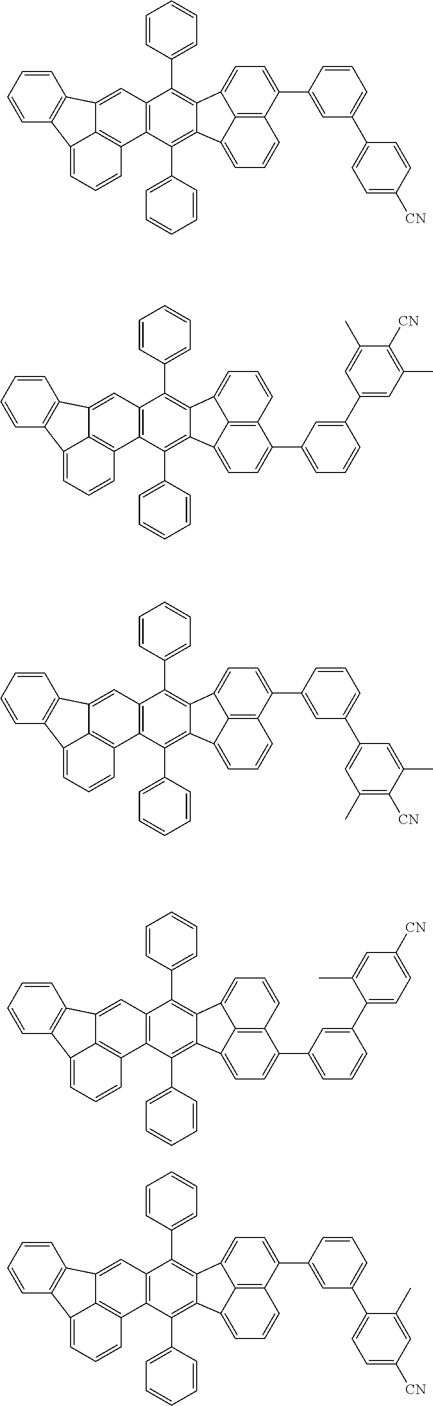

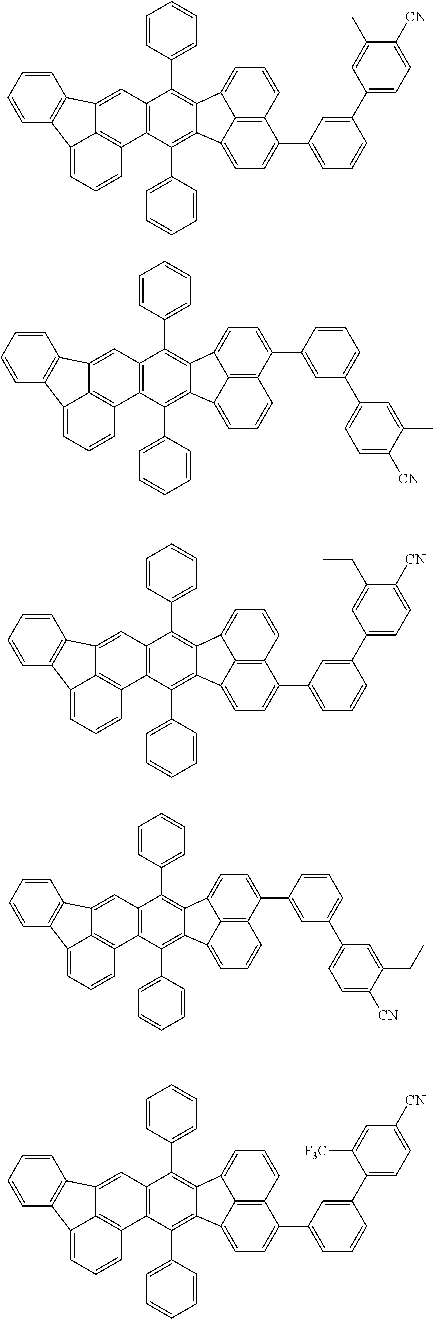

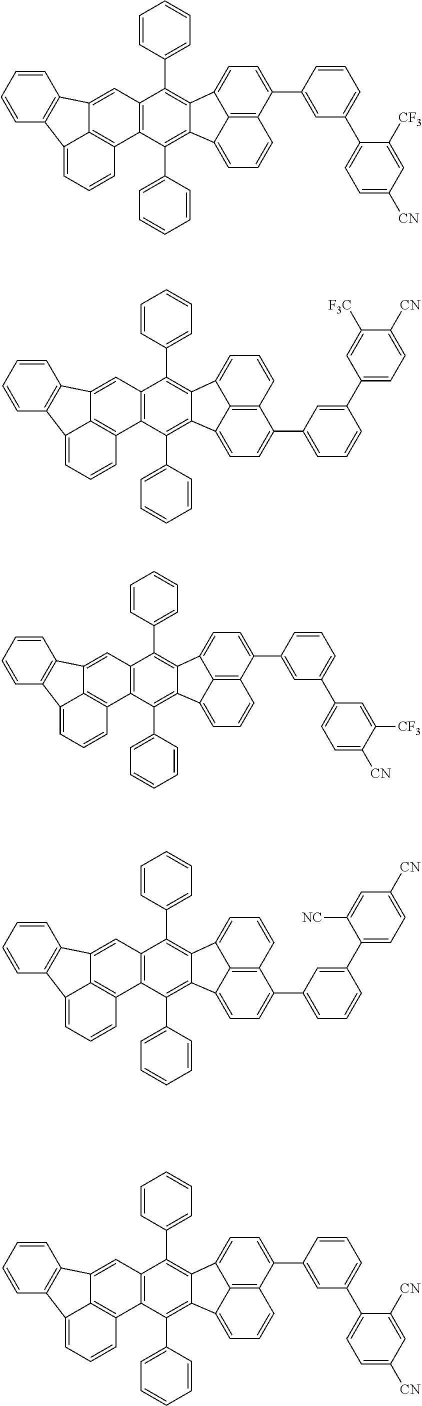

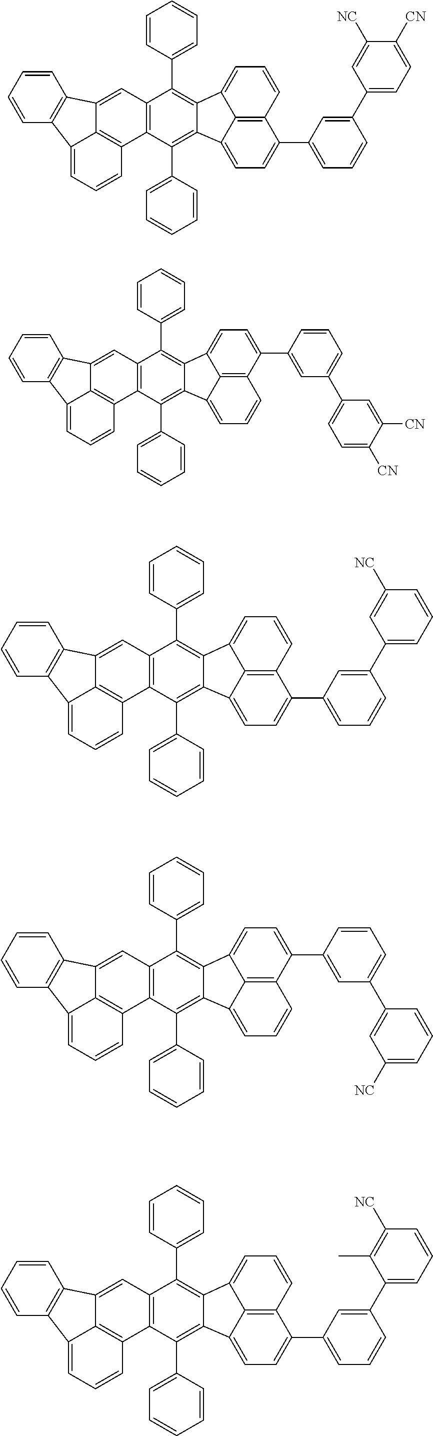

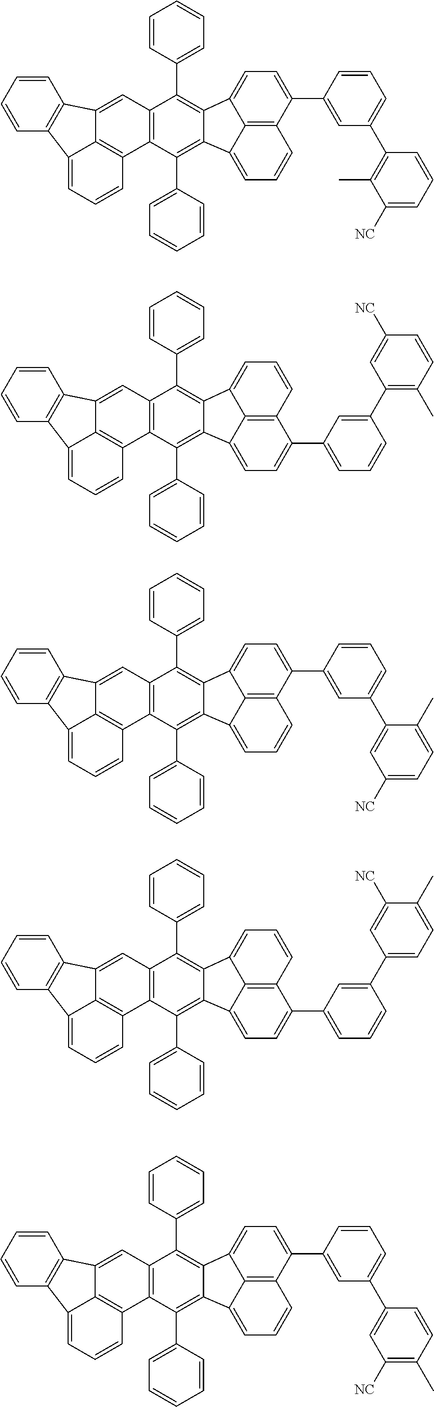

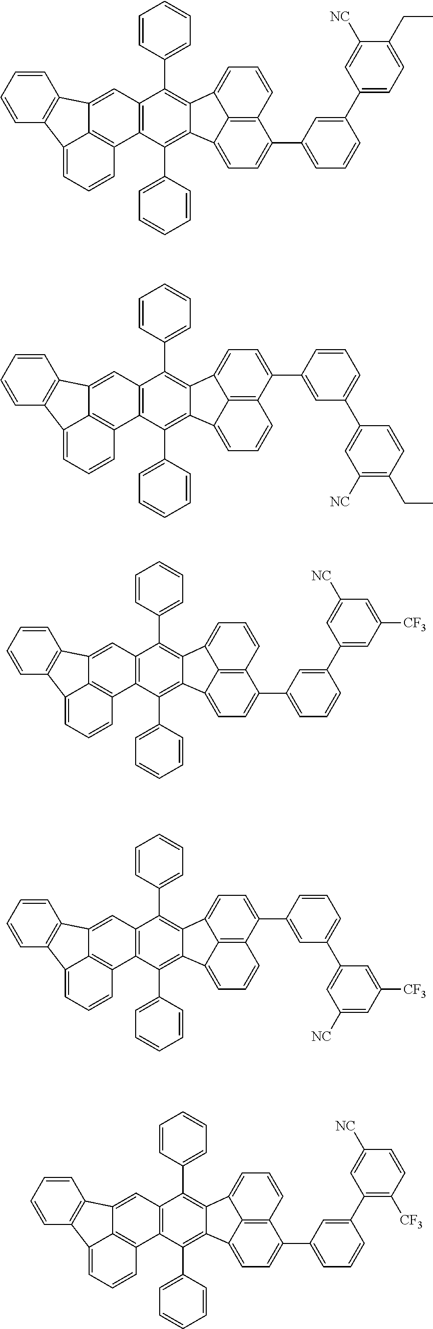

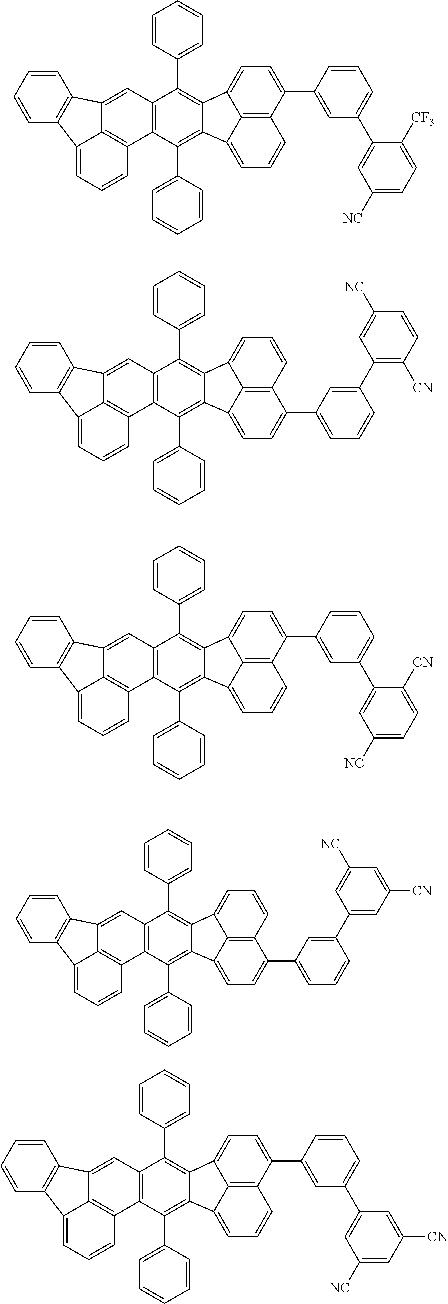

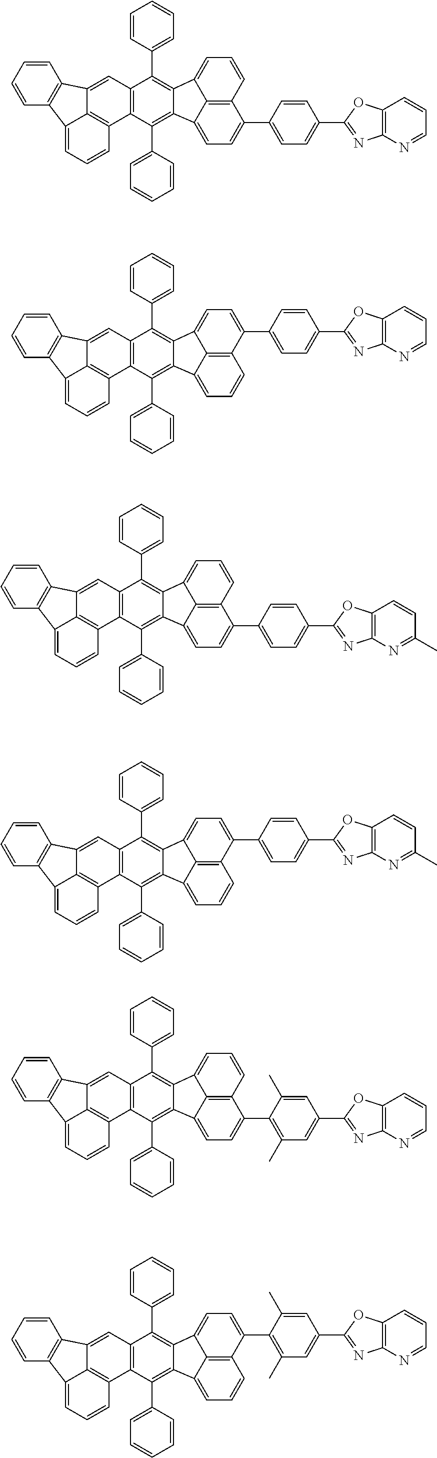

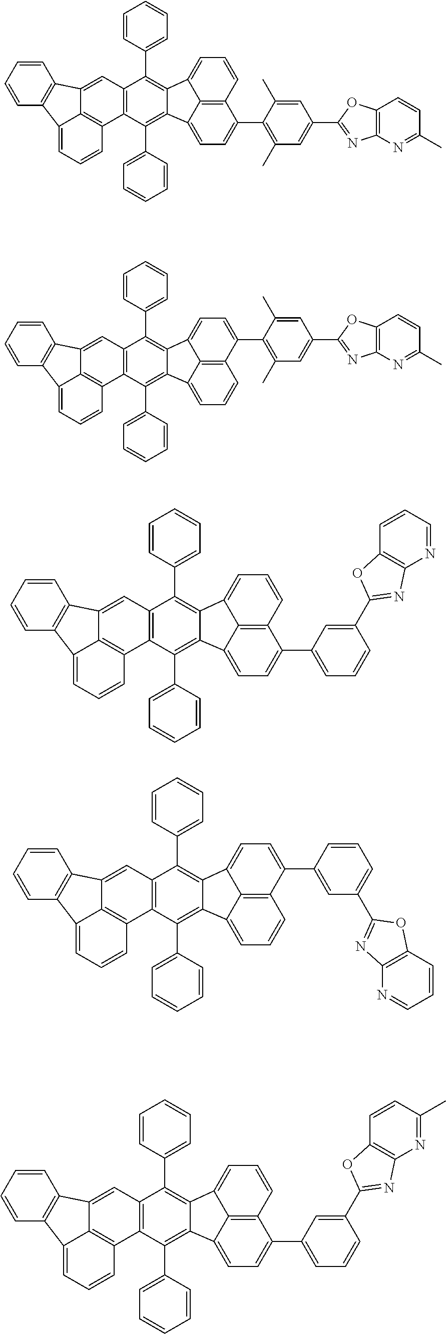

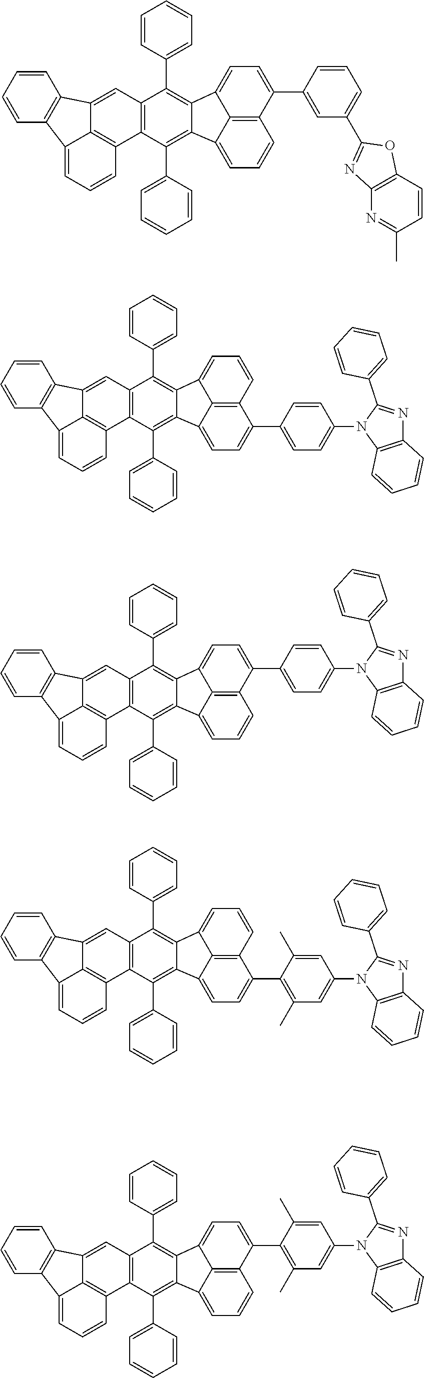

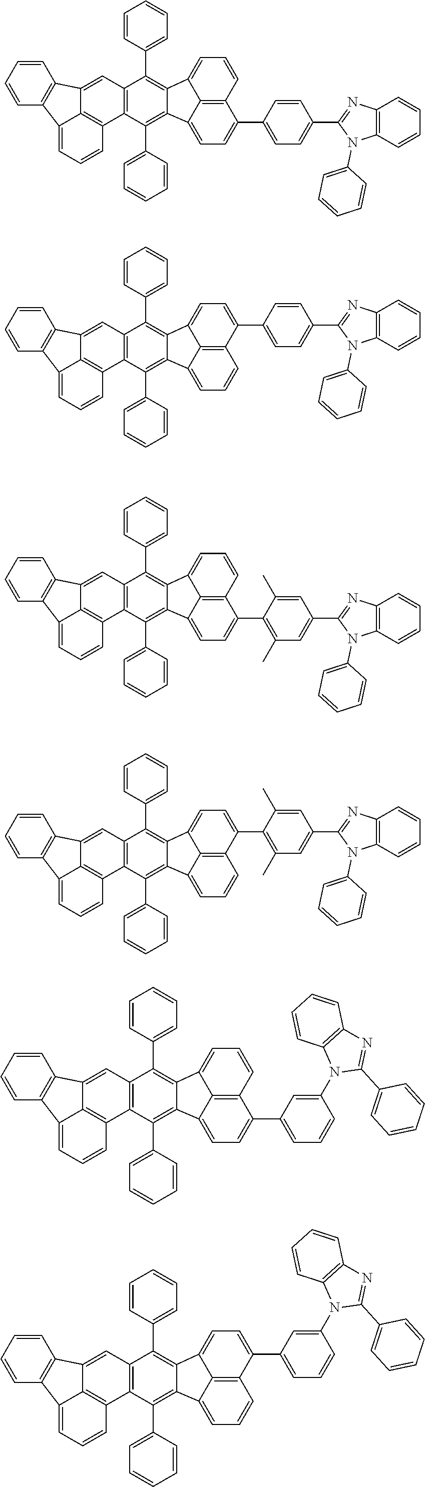

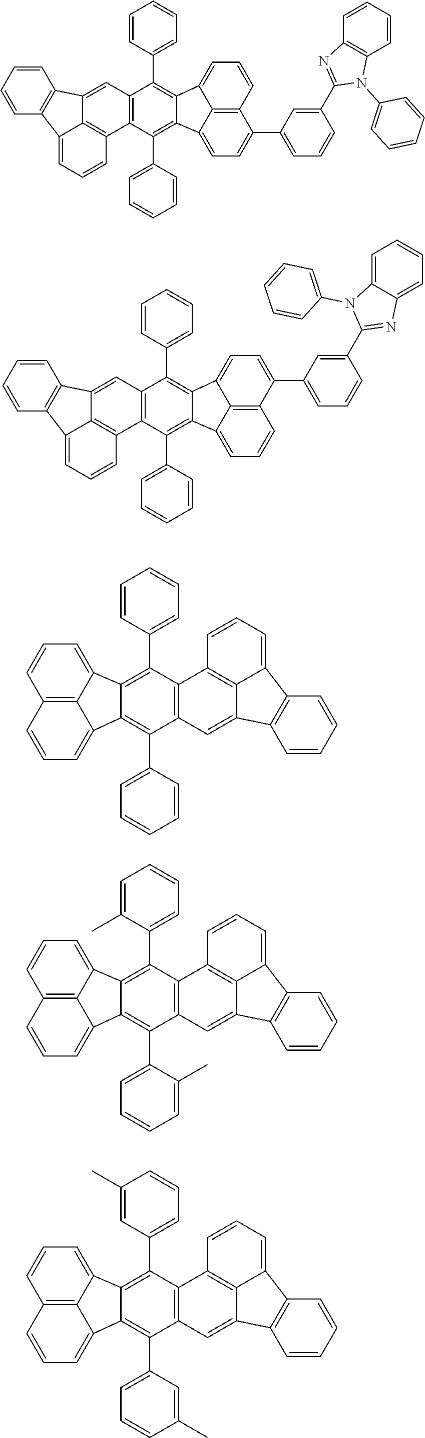

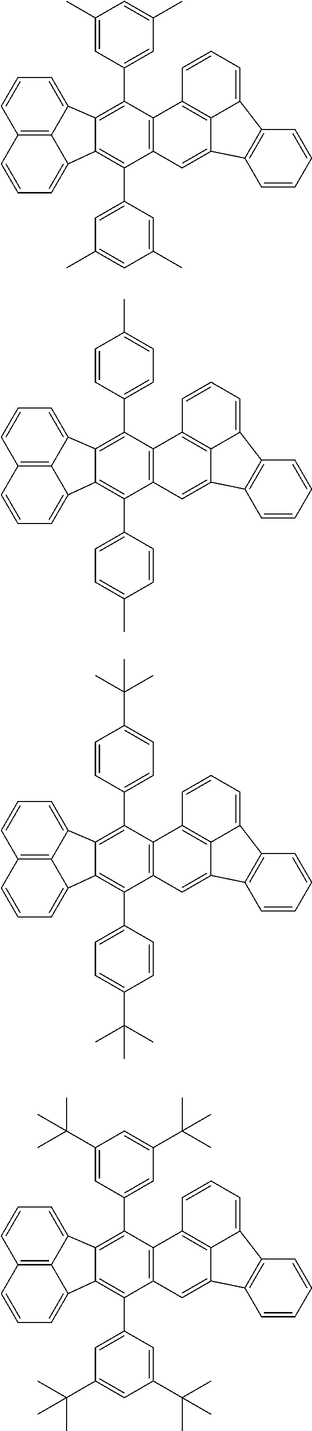

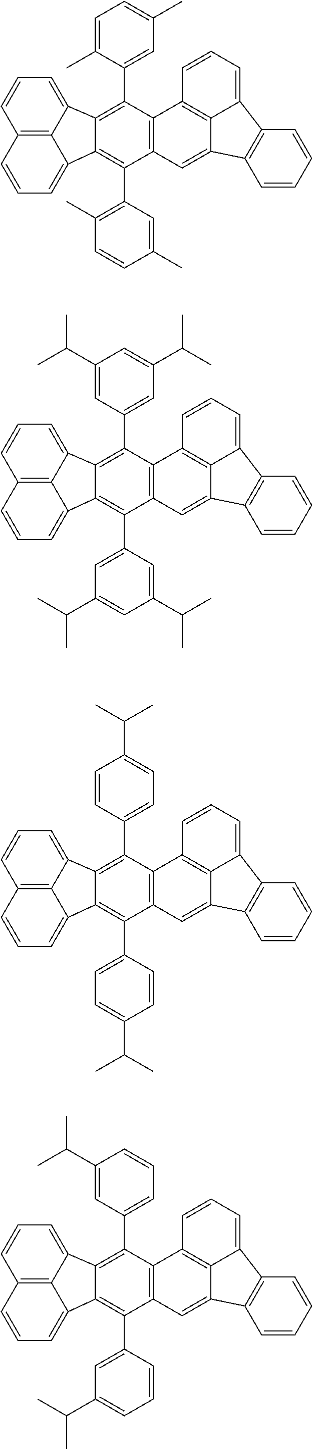

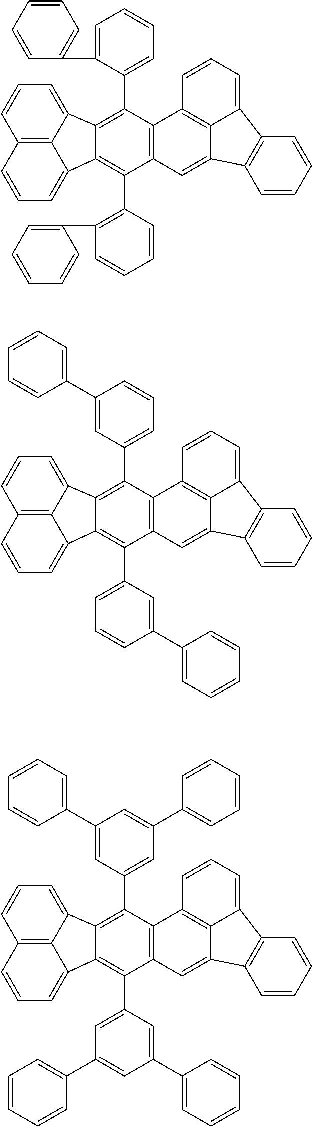

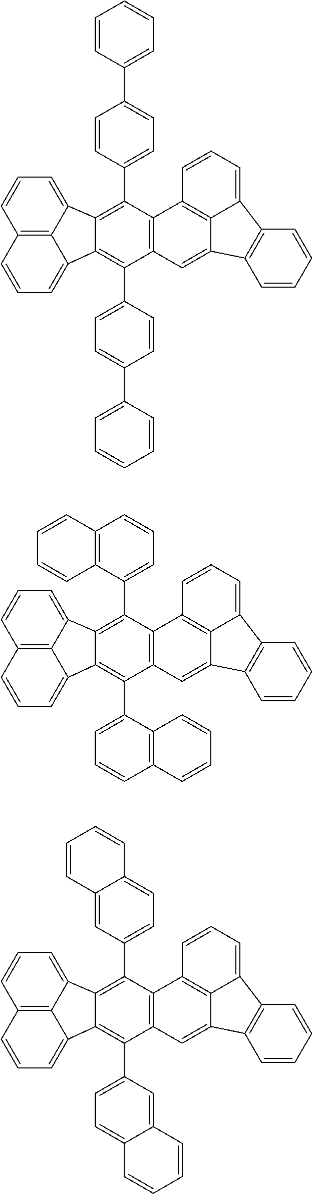

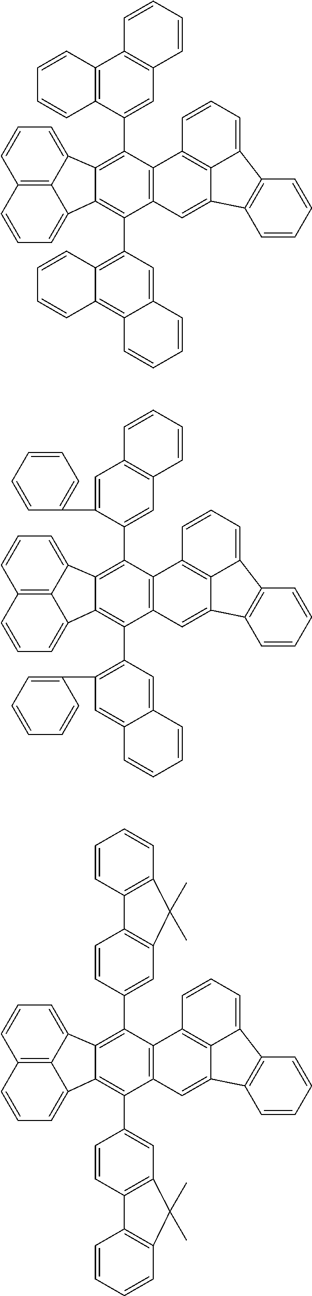

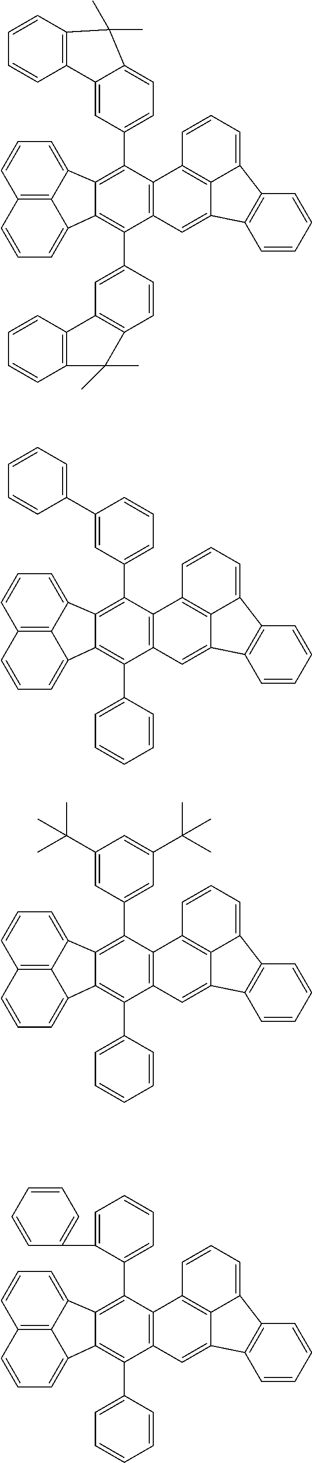

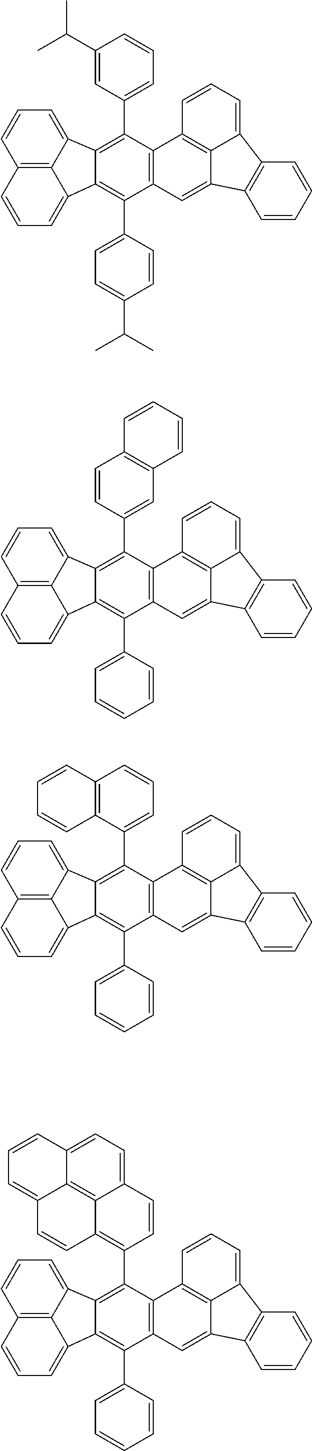

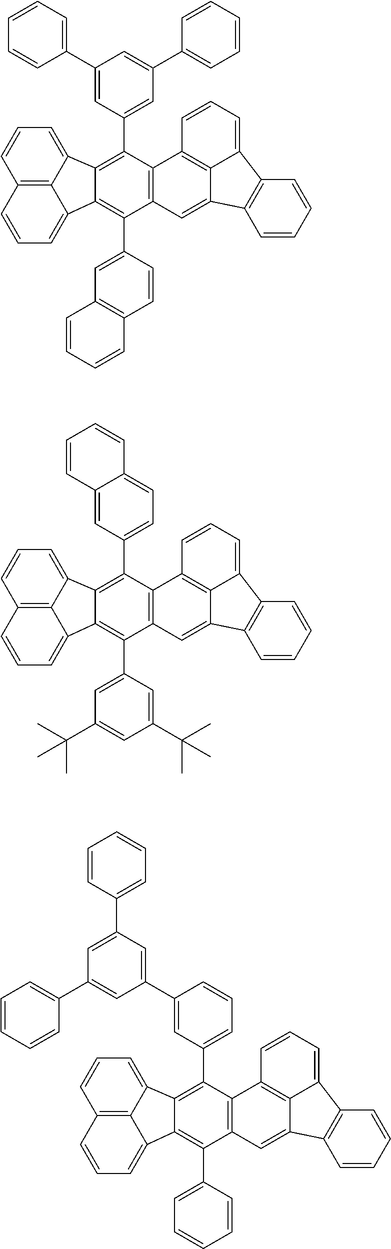

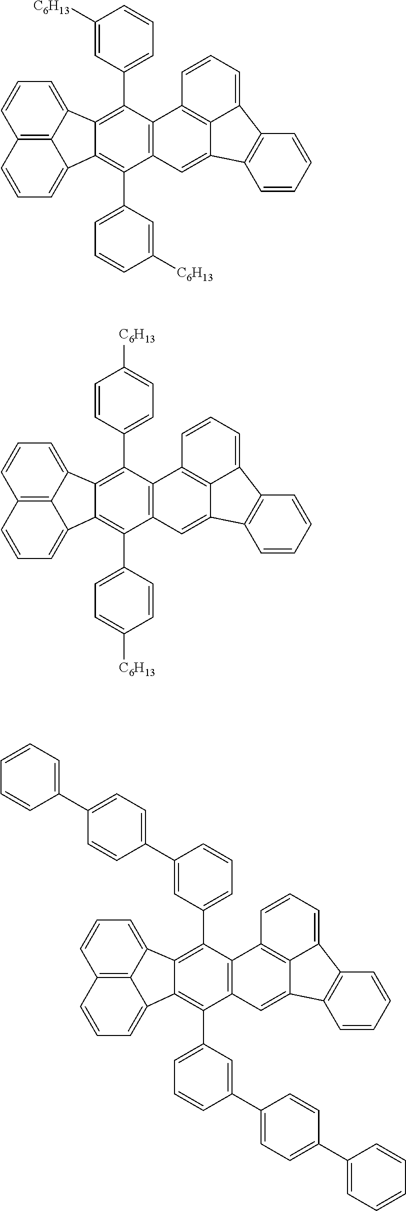

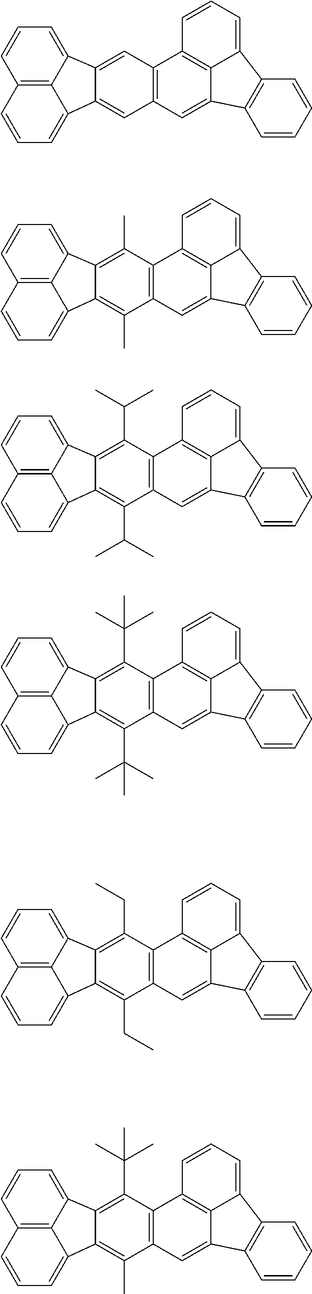

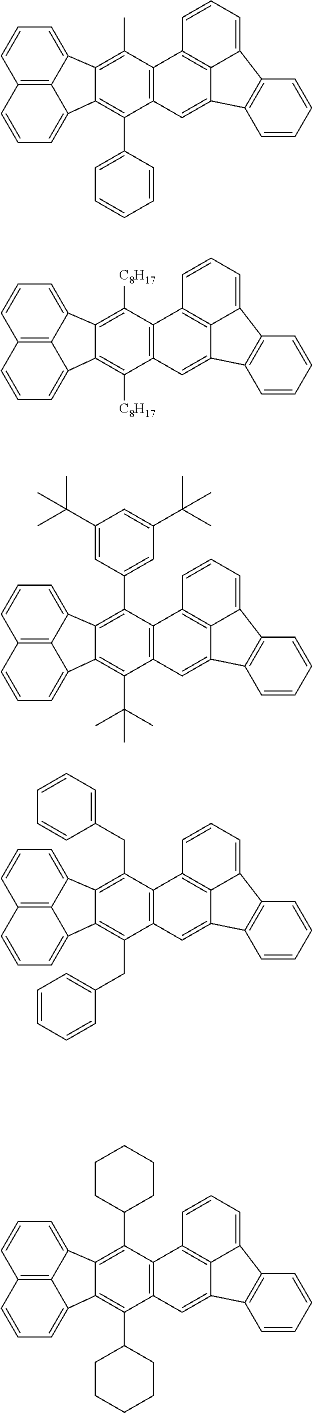

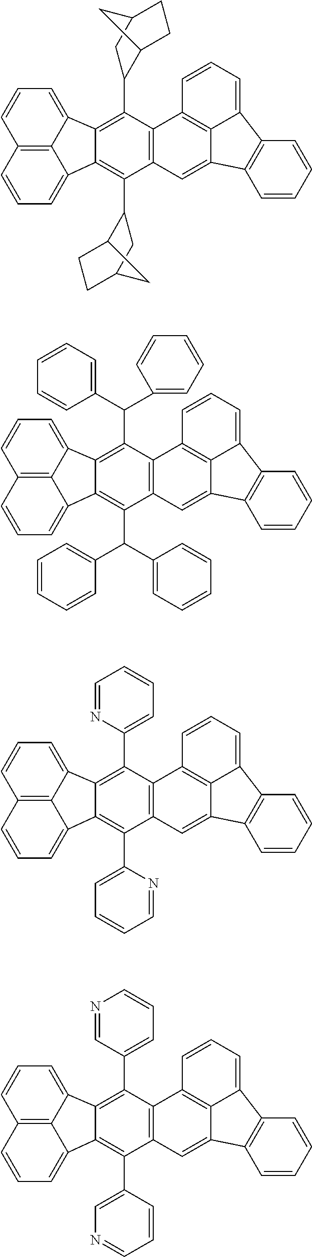

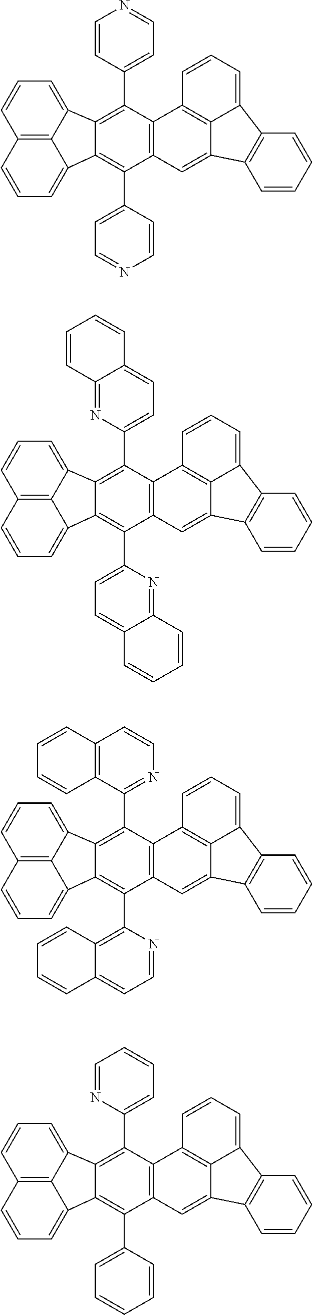 [SMILES: c1ccc2c(c1)c1cccc3c4c(-c5ccncc5)c5c6cccc7cccc(c5c(-c5ccncc5)c4cc2c13)c76 ; c1ccc2nc(-c3c4cc5c6ccccc6c6cccc(c4c(-c4ccc7ccccc7n4)c4c7cccc8cccc(c34)c87)c65)ccc2c1 ; c1ccc2c(-c3c4cc5c6ccccc6c6cccc(c4c(-c4nccc7ccccc47)c4c7cccc8cccc(c34)c87)c65)nccc2c1 ; c1ccc(-c2c3cc4c5ccccc5c5cccc(c3c(-c3ccccn3)c3c6cccc7cccc(c23)c76)c54)cc1]

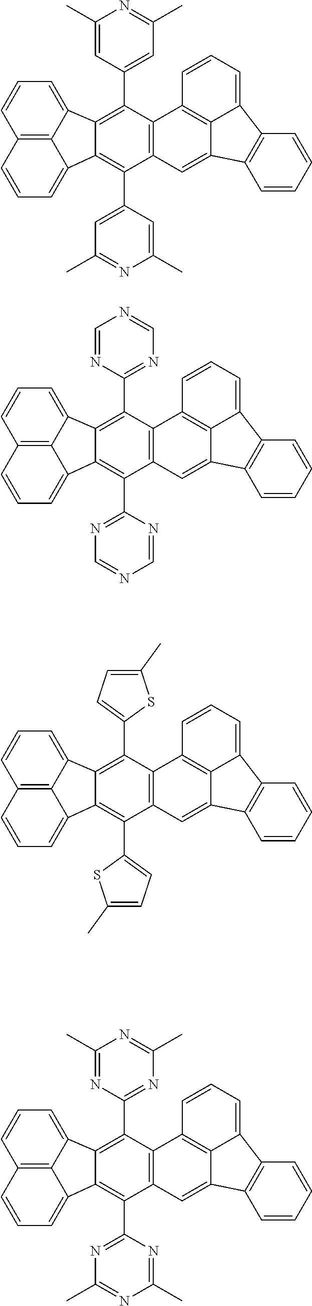

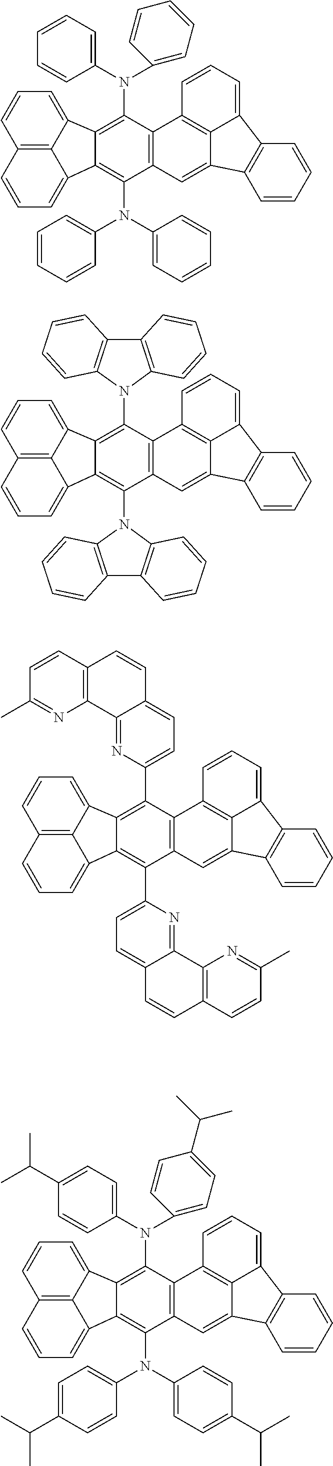

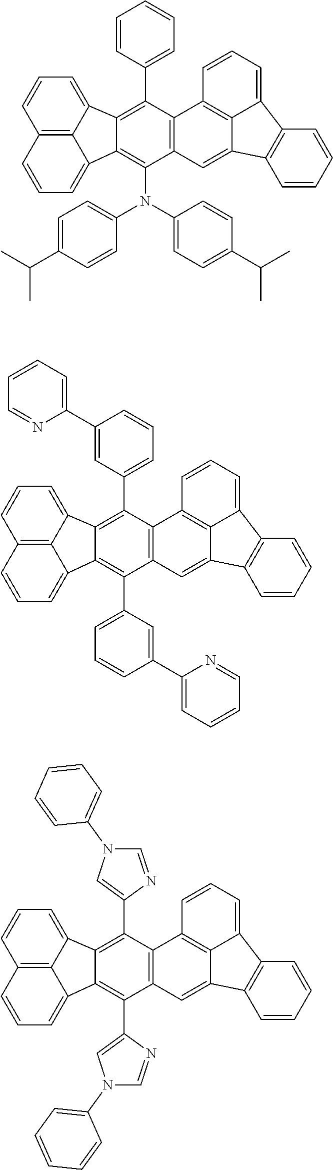 [SMILES: CC(C)c1ccc(N(c2ccc(C(C)C)cc2)c2c3cc4c5ccccc5c5cccc(c3c(-c3ccccc3)c3c6cccc7cccc(c23)c76)c54)cc1 ; c1ccc(-c2cccc(-c3c4cc5c6ccccc6c6cccc(c4c(-c4cccc(-c7ccccn7)c4)c4c7cccc8cccc(c34)c87)c65)c2)nc1 ; c1ccc(-n2cnc(-c3c4cc5c6ccccc6c6cccc(c4c(-c4cn(-c7ccccc7)cn4)c4c7cccc8cccc(c34)c87)c65)c2)cc1]

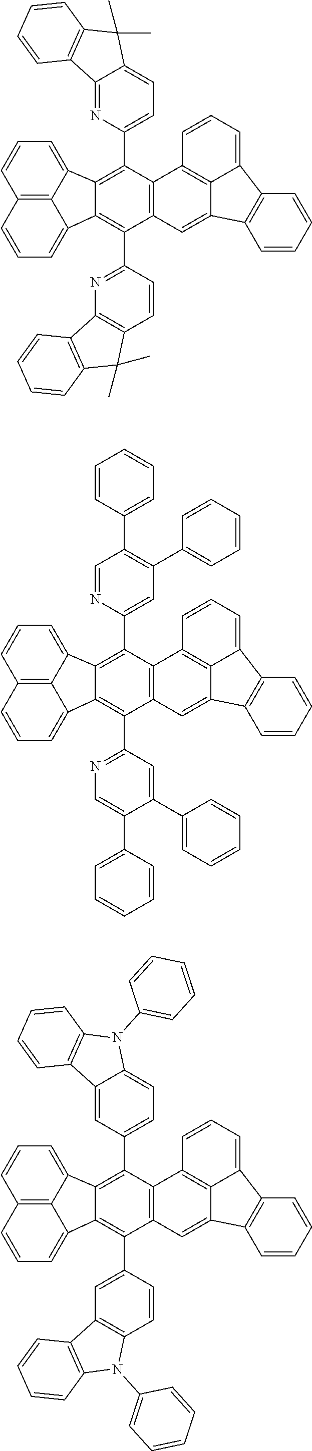 [SMILES: CC1(C)c2ccccc2-c2nc(-c3c4cc5c6ccccc6c6cccc(c4c(-c4ccc7c(n4)-c4ccccc4C7(C)C)c4c7cccc8cccc(c34)c87)c65)ccc21 ; c1ccc(-c2cnc(-c3c4cc5c6ccccc6c6cccc(c4c(-c4cc(-c7ccccc7)c(-c7ccccc7)cn4)c4c7cccc8cccc(c34)c87)c65)cc2-c2ccccc2)cc1 ; c1ccc(-n2c3ccccc3c3cc(-c4c5cc6c7ccccc7c7cccc(c5c(-c5ccc8c(c5)c5ccccc5n8-c5ccccc5)c5c8cccc9cccc(c45)c98)c76)ccc32)cc1]

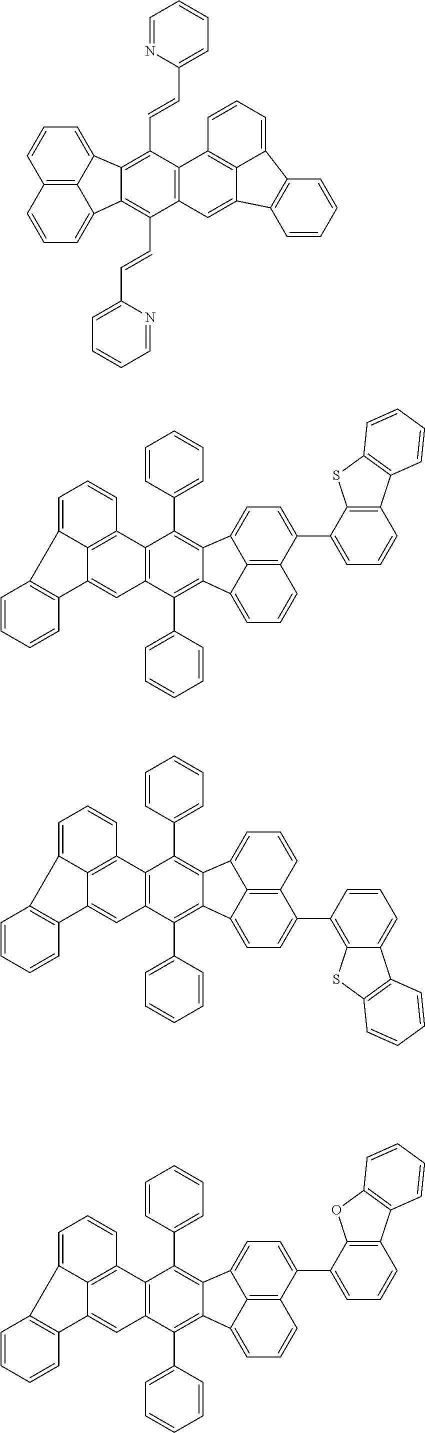 [SMILES: C(=C\c1c2cc3c4ccccc4c4cccc(c2c(/C=C/c2ccccn2)c2c5cccc6cccc(c12)c65)c43)/c1ccccn1 ; c1ccc(-c2c3cc4c5ccccc5c5cccc(c3c(-c3ccccc3)c3c6ccc(-c7cccc8c7sc7ccccc78)c7cccc(c23)c76)c54)cc1 ; c1ccc(-c2c3cc4c5ccccc5c5cccc(c3c(-c3ccccc3)c3c6cccc7c(-c8cccc9c8sc8ccccc89)ccc(c23)c76)c54)cc1 ; c1ccc(-c2c3cc4c5ccccc5c5cccc(c3c(-c3ccccc3)c3c6ccc(-c7cccc8c7oc7ccccc78)c7cccc(c23)c76)c54)cc1]

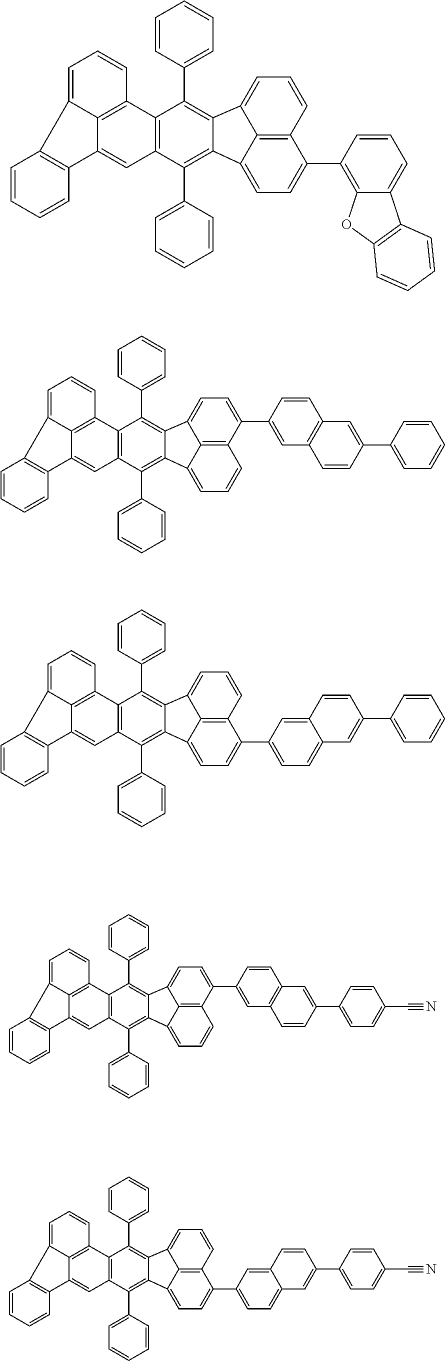

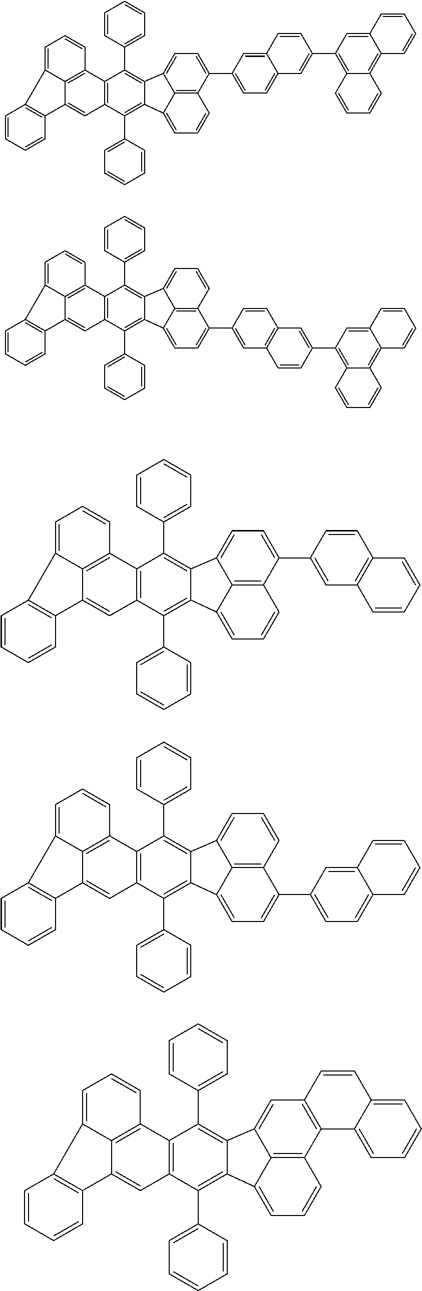

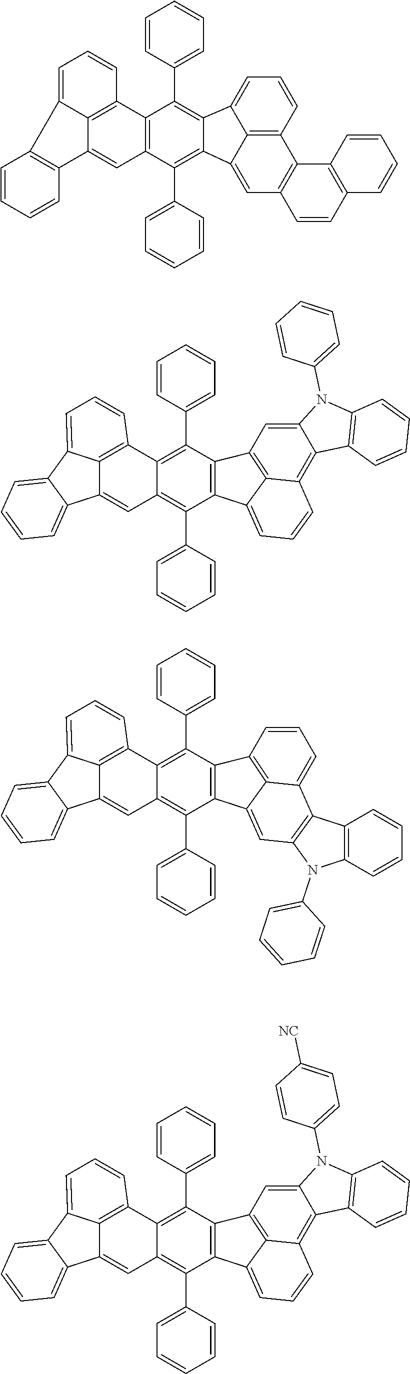

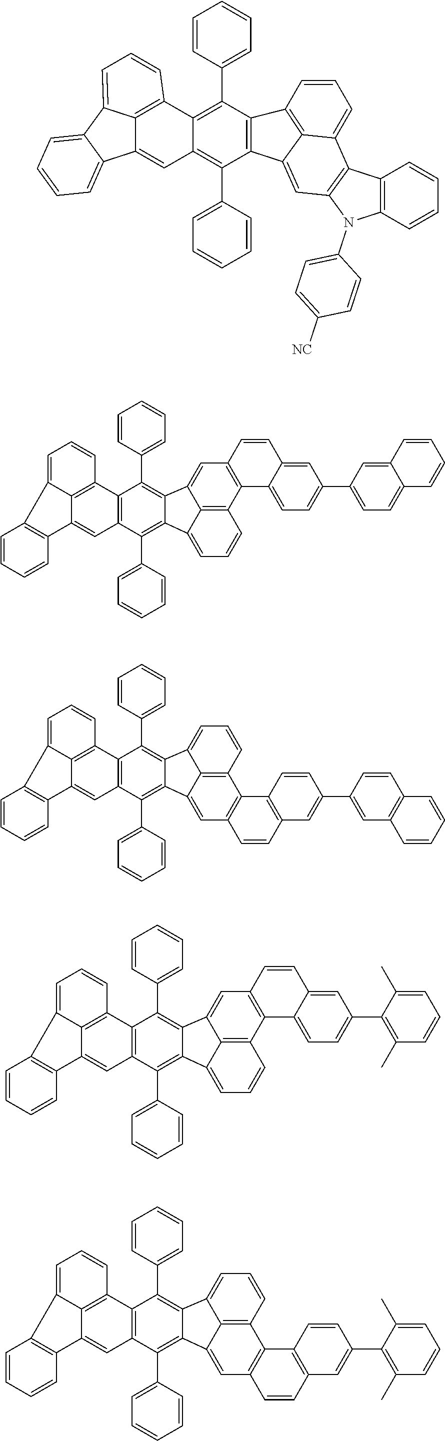

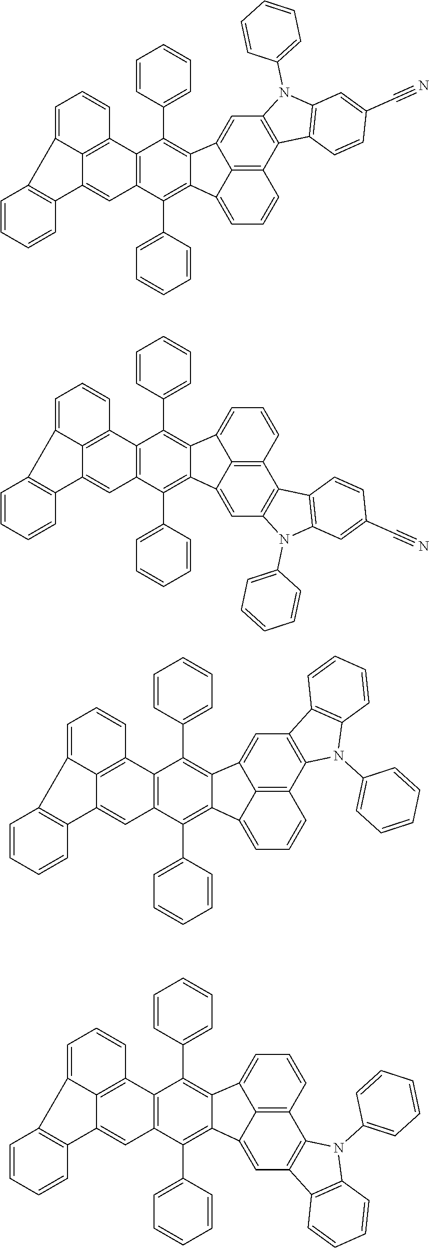

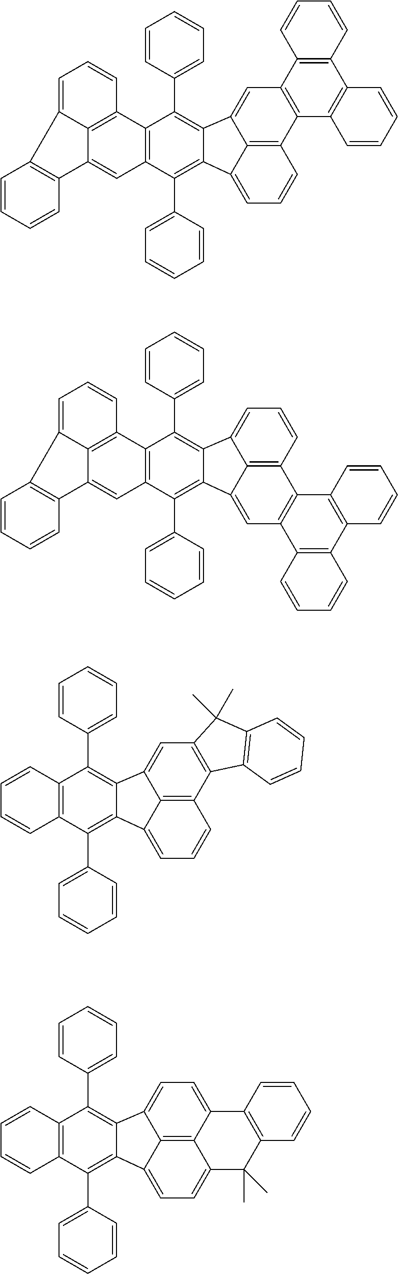

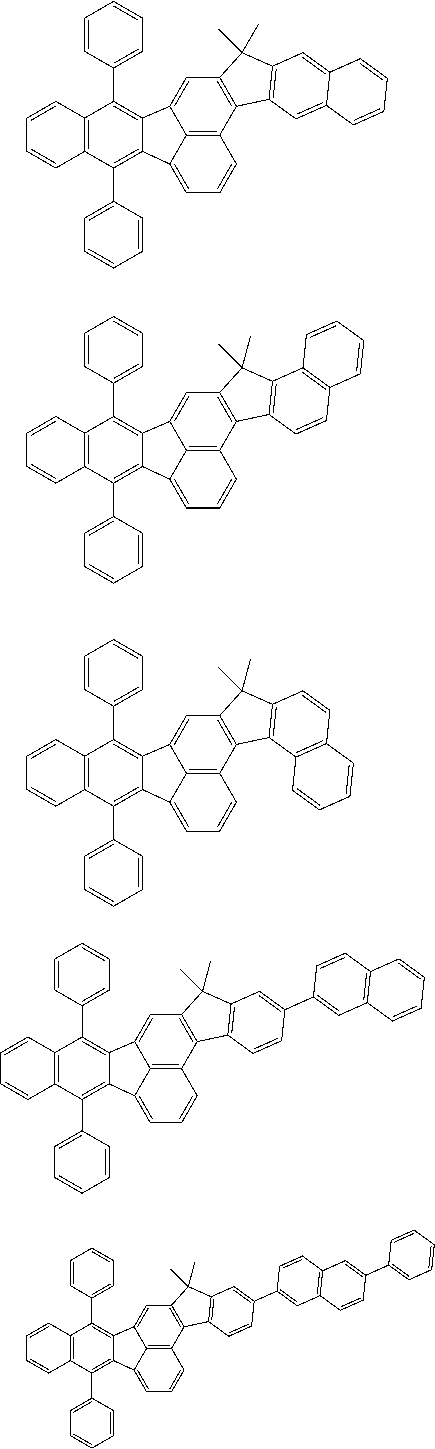

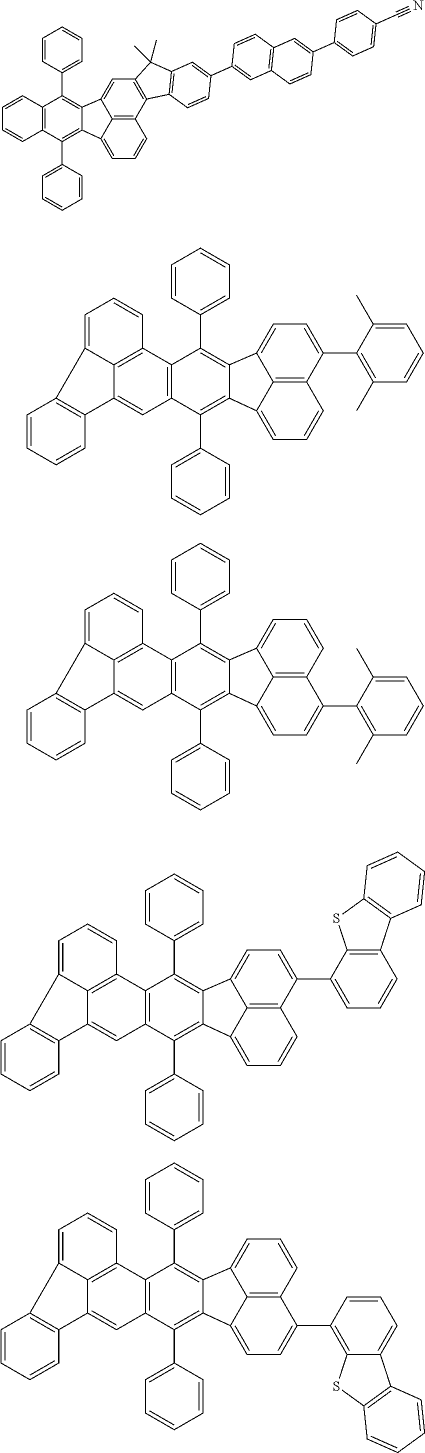

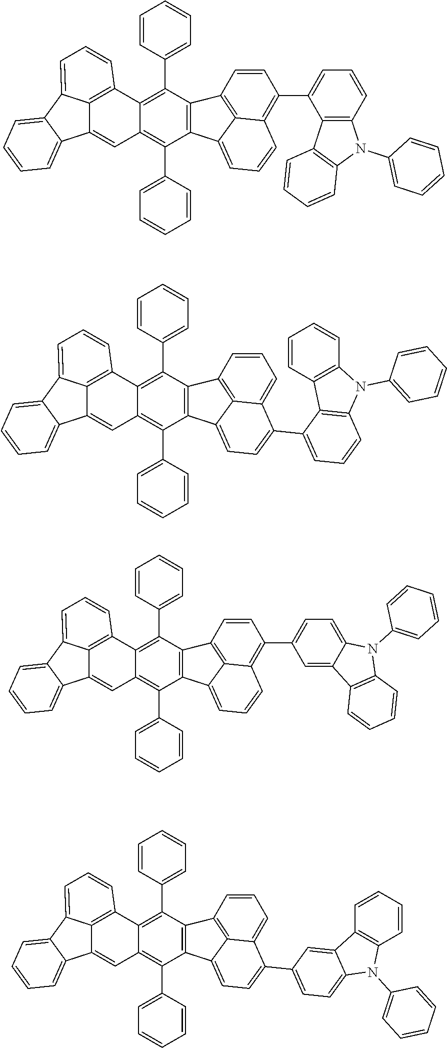

### Second Compound

The second compound in the exemplary embodiment is a delayed fluorescent compound.

The second compound in the exemplary embodiment is not a phosphorescent metal complex. Preferably, the second compound in the exemplary embodiment is not a metal complex.

### Delayed Fluorescence

Delayed fluorescence is described in “Yuki Hando-tai no Debaisu Bussei (Device Physics of Organic Semiconductor)” edited by Chihaya Adachi, published by Kodansha Company Ltd, pages 261 to 268. This document describes that, when an energy gap ΔE13 between a singlet state and a triplet state of a fluorescent material can be decreased, in spite of a typical low transition probability, inverse energy transfer from the triplet state to the singlet state occurs at a high efficiency to express thermally activated delayed fluorescence (TADF). Further, a generating mechanism of delayed fluorescence is described in FIG. 10.38 in this document. The second compound in the exemplary embodiment is a compound emitting thermally activated delayed fluorescence to be generated by such a mechanism.

Delayed fluorescence can be observed by measuring transient PL (Photo Luminescence).

Behavior of delayed fluorescence can also be analyzed based on the decay curve obtained by measuring the transient PL. The transient PL measurement is a method for measuring reduction behavior (transitional property) of PL emission obtained after irradiating pulse laser on a sample to excite the sample and stopping irradiating the pulse laser. PL emission using a TADF material is divided into an emission component from singlet excitons generated by the first PL excitation and an emission component from singlet excitons generated via triplet excitons. Lifetime of the singlet excitons initially generated in the PL excitation is very short at a nano-second order. Accordingly, the emission from the singlet excitons is rapidly reduced after pulse laser radiation.

On the other hand, since delayed fluorescence provides emission from singlet excitons generated through long-life triplet excitons, emission is gradually reduced. Thus, there is a large difference in time between the emission from the singlet excitons initially generated in the PL excitation and the emission from the singlet excitons derived from the triplet excitons. Accordingly, a luminous intensity derived from delayed fluorescence is obtainable.

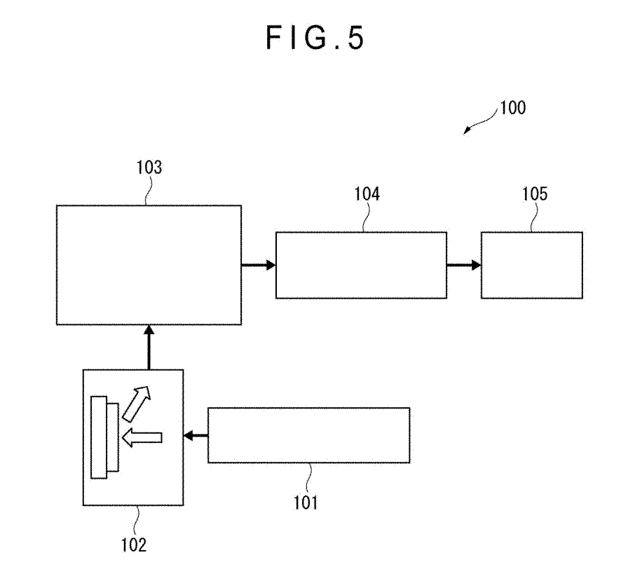

FIG. 5 is a schematic illustration of an exemplary device for measuring the transient PL.

A transient PL measuring device 100 in the exemplary embodiment includes: a pulse laser 101 capable of radiating a light having a predetermined wavelength; a sample chamber 102 configured to house a measurement sample; a spectrometer 103 configured to divide a light radiated from the measurement sample; a streak camera 104 configured to provide a two-dimensional image; and a personal computer 105 configured to import and analyze the two-dimensional image. A device usable for the measurement of the transient PL is not limited to the device described in the exemplary embodiment.

The sample housed in the sample chamber 102 is obtained by forming a thin film, in which a matrix material is doped with a doping material at a concentration of 12 mass %, on the quartz substrate.

The thin film sample housed in the sample chamber 102 is irradiated with pulse laser from the pulse laser 101 to excite the doping material. Emission is extracted at 90 degrees angle relative to an irradiation direction of the excited light. The extracted emission is dispersed with the spectrometer 103 to form a two-dimensional image in the streak camera 104. As a result, the two-dimensional image expressed in coordinates of which ordinate axis indicates time and of which abscissa axis indicates a wavelength, in which a luminous point indicates a luminous intensity, can be obtained. If the two-dimensional image is cut out along a predetermined time axis, emission spectrum expressed in coordinates of which ordinate axis indicates a luminous intensity and of which abscissa axis indicates the wavelength can be obtained. If the two-dimensional image is cut out along a wavelength axis, a decay curve (transient PL) expressed in coordinates of which ordinate axis indicates a logarithm of the luminous intensity and of which abscissa axis indicates time can be obtained.

For instance, using a reference compound H1 below as the matrix material and a reference compound D1 as the doping material, a thin film sample A was prepared as described above and the transitional PL was measured.

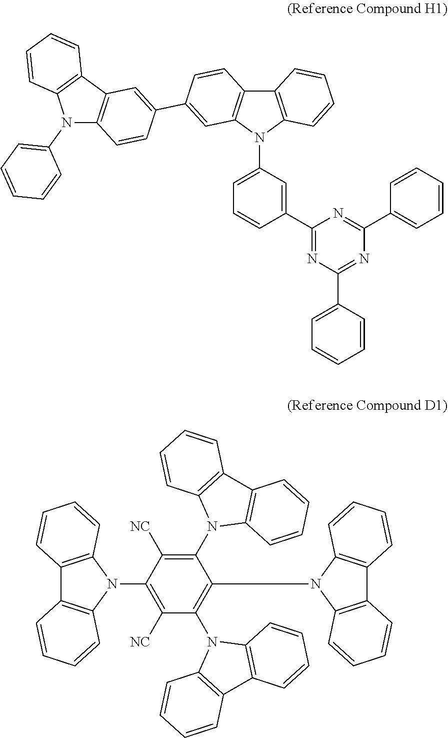 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

Herein, the decay curve was analyzed using the above-described thin film sample A and a thin film sample B. The thin film sample B was prepared as described above, using a reference compound H2 below as the matrix material and the reference compound D1 as the doping material.

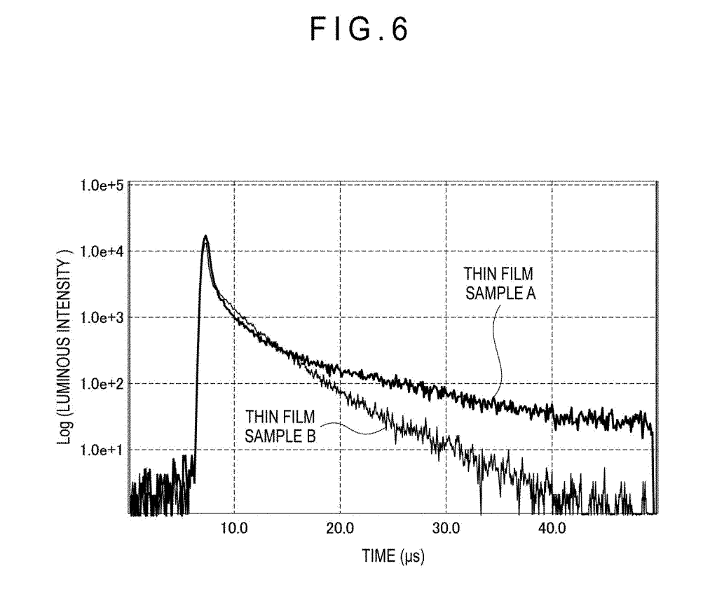

FIG. 6 shows a decay curve obtained from the measured transitional PL of the thin film sample A and the thin film sample B.

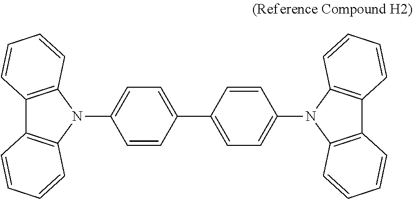 [SMILES: c1ccc2c(c1)c1ccccc1n2-c1ccc(-c2ccc(-n3c4ccccc4c4ccccc43)cc2)cc1]

An emission decay curve expressed in coordinates of which ordinate axis indicates a luminous intensity and of which abscissa axis indicates time can be obtained by measuring the transient PL as described above. Based on the emission decay curve, a fluorescence intensity ratio between fluorescence in the single state generated by light excitation and the delayed fluorescence in the singlet state generated by the inverse energy transfer through the triplet state can be estimated. In a delayed fluorescent material, a ratio of the intensity of the slowly decaying delayed fluorescence to the intensity of the promptly decaying fluorescence is relatively large.

In the exemplary embodiment, an amount of the delayed fluorescence can be calculated using the device of FIG. 5. The emission from the second compound includes Prompt emission and Delay emission. The Prompt emission refers to an emission observed in an excited state immediately after the second compound is excited with pulse light (light emitted from the pulse laser) having a wavelength to be absorbed in the second compound. Delay emission refers to an emission that is not observed immediately after the excitation by the pulse light but observed later. In the exemplary embodiment, provided that the amount of Prompt emission is denoted by X_{P} and the amount of Delay emission is denoted by X_{D}, a value of X_{D}/X_{P} is preferably 0.05 or more.

The amount of Prompt emission and the amount of Delay emission can be obtained according to the same method as described in “Nature 492, 234-238, 2012” (Reference Literature 1). The amount of Prompt emission and the amount of Delay emission may be calculated using a device different from one described in the above Reference Literature.

A sample prepared by a method below is used for the measurement of the delayed fluorescence. For instance, a sample was prepared by co-depositing the second compound and later-described compound TH-2 on a quartz substrate at a ratio of the second compound of 12 mass % to form a 100-nm-thick thin film.

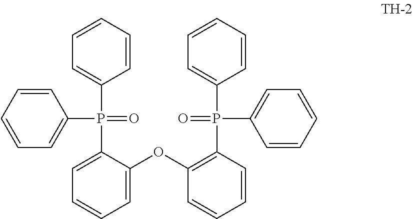 [SMILES: O=P(c1ccccc1)(c1ccccc1)c1ccccc1Oc1ccccc1P(=O)(c1ccccc1)c1ccccc1]

In the organic EL device of the exemplary embodiment, the second compound contained in the emitting layer is also preferably a compound represented by a formula (2) below.

(B_{b}LA)ₐ (2)

In the formula (2):

A is a group having a moiety selected from formulae (a-1) to (a-2) below;

B is a group having a moiety selected from formulae (b-1) to (b-4) below;

L is a single bond or a linking group and;

L as the linking group is a group derived from a substituted or unsubstituted aryl group having 6 to 30 ring carbon atoms, a group derived from a substituted or unsubstituted heteroaryl group having 5 to 30 ring atoms, or a group provided by combining two, three, four or five groups selected from the group consisting of the group derived from the substituted or unsubstituted aryl group having 6 to 30 ring carbon atoms and the group derived from the substituted or unsubstituted heteroaryl group having 5 to 30 ring atoms. The bonded groups are mutually the same or different.

a is 1, 2, 3, 4, or 5 and represents the number of A directly bonded to L.

A plurality of A are mutually the same or different when a is 2, 3, 4 or 5.

b is 1, 2, 3, 4 or 5 and represents the number of B directly bonded to L.

A plurality of B are mutually the same or different when b is 2, 3, 4 or 5.

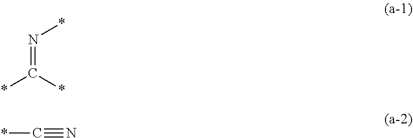

* in the formulae (a-1) and (a-2) each independently represent a bonding position with another atom in the molecule of the second compound (the compound represented by the formula (2)).

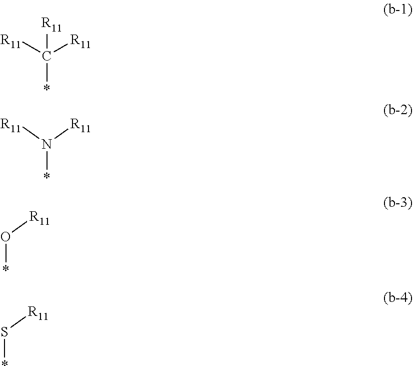

In the formulae (b-1) to (b-4): R₁₁ each independently represent a hydrogen atom or a substituent, or at least one pair of a plurality of R₁₁ is optionally mutually bonded to form a ring;

R₁₁ as the substituent is selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms;

when a plurality of R₁₁ are present, the plurality of R₁₁ are mutually the same or different; and * each independently represent a bonding position with another atom in the molecule of the second compound (the compound represented by the formula (2)).

In the formula (2), A is an acceptor (electron accepting) moiety and B is a donor (electron donating) moiety.

Examples of the group having the moiety selected from the group consisting of the moieties represented by the respective formulae (a-1) to (a-2) are shown below.

For instance, a group having the moiety in the formula (a-1) is exemplified by a group represented by a formula (a-1-1).

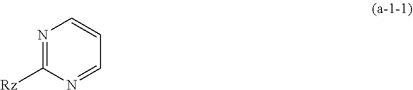

In the formula (a-1-1): Rz is a hydrogen atom, a substituent, or a bonding position to L or B in the formula (2); and

Rz as the substituent is selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms.

Examples of the group having the moiety selected from the group consisting of the moieties represented by the formulae (b-1) to (b-4) are shown below.

For instance, a group having the moiety in the formula (b-2) is exemplified by a group represented by a formula (b-2-1).

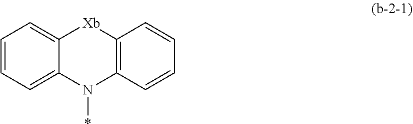

In the formula (b-2-1), X_{b} is a single bond, an oxygen atom, a sulfur atom, CR_{b1}R_{b2} or a carbon atom to be bonded to L or A in the formula (2).

The group represented by the formula (b-2-1) in which X_{b} is a single bond is a group represented by a formula (b-2-2). The group represented by the formula (b-2-1) in which X_{b} is an oxygen atom is a group represented by a formula (b-2-3). The group represented by the formula (b-2-1) in which X_{b} is a sulfur atom is a group represented by a formula (b-2-4). The group represented by the formula (b-2-1) in which X_{b} is CR_{b1}R_{b2} is a group represented by a formula (b-2-5).

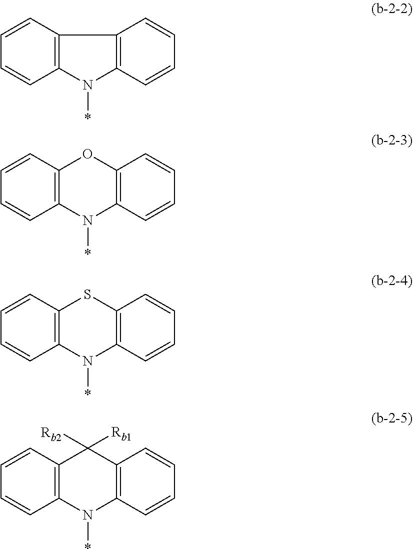

R_{b1} and R_{b2} are each independently a hydrogen atom or a substituent. R_{b1} and R_{b2} as the substituents are each independently selected from the group consisting of a substituted or unsubstituted alkyl group having 1 to 30 carbon atoms and a substituted or unsubstituted aryl group having 6 to 30 ring carbon atoms. R_{b1} and R_{b2} are each independently preferably a substituent selected from the group consisting of a substituted or unsubstituted alkyl group having 1 to 30 carbon atoms and a substituted or unsubstituted aryl group having 6 to 30 ring carbon atoms, more preferably a substituent selected from the group consisting of a substituted or unsubstituted alkyl group having 1 to 30 carbon atoms.

In the organic EL device of the exemplary embodiment, L in the formula (2) is preferably a single bond, or a group derived from a substituted or unsubstituted aryl group having 6 to 30 ring carbon atoms, more preferably a single bond or a group derived from a substituted or unsubstituted phenyl group.

In the organic EL device of the exemplary embodiment, B in the formula (2) is preferably a group having the moiety selected from the group consisting of the moieties represented by the formulae (b-2), (b-3) and (b-4), more preferably a group having the moiety represented by the formula (b-2).

B in the formula (2) is also preferably represented by a formula (100) below.

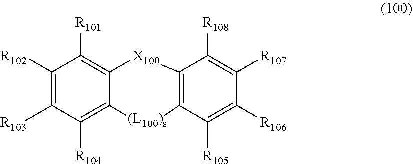

In the formula (100), R₁₀₁ to R₁₀₈ each independently represent a hydrogen atom or a substituent, or at least one of a pair of R¹⁰¹ and R¹⁰², a pair of R¹⁰² and R¹⁰³, a pair of R¹⁰³ and R¹⁰⁴, a pair of R¹⁰⁵ and R¹⁰⁶, a pair of R¹⁰⁶ and R¹⁰⁷, and a pair of R¹⁰⁷ and R¹⁰⁸ are mutually bonded to form a ring,

R₁₀₁ to R₁₀₈ as the substituents are each independently a substituent selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted silyl group, a substituted or unsubstituted alkoxy group having 1 to 30 carbon atoms, a substituted or unsubstituted aryloxy group having 6 to 30 ring carbon atoms, a substituted or unsubstituted alkylamino group having 2 to 30 carbon atoms, a substituted or unsubstituted arylamino group having 6 to 60 ring carbon atoms, a substituted or unsubstituted alkylthio group having 1 to 30 carbon atoms, and a substituted or unsubstituted arylthio group having 6 to 30 ring carbon atoms.

L₁₀₀ is a linking group selected from linking groups represented by formulae (111) to (117) below.

s is 0, 1, 2 or 3. A plurality of L₁₀₀ are mutually the same or different.

X₁₀₀ is a linking group selected from linking groups represented by formulae (121) to (125) below.

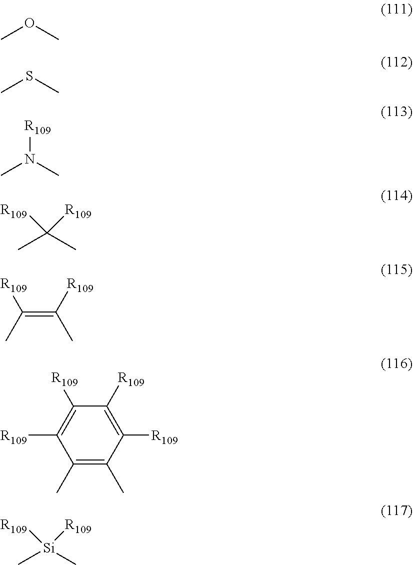

In the formulae (113) to (117), R₁₀₉ each independently represent the same as R₁₀₁ to R₁₀₈ in the formula (100).

In the formula (100), one of R₁₀₁ to R₁₀₈ or one of R₁₀₉ is a single bond to be bonded to L or A in the formula (1).

R₁₀₉ and R₁₀₄ in the formula (100) form a saturated or unsaturated ring, or are not bonded.

R₁₀₉ and R₁₀₅ in the formula (100) form a saturated or unsaturated ring, or are not bonded.

A plurality of R₁₀₉ are mutually the same or different.

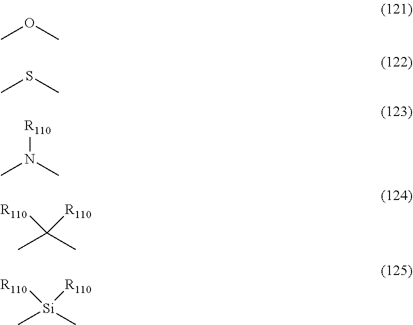

In the above formulae (123) to (125):

R₁₁₀ each independently represents a hydrogen atom or a substituent;

R₁₁₀ as the substituent is selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms;

A plurality of R₁₁₀ are mutually the same or different;

R₁₁₀ and R₁₀₁ in the formula (100) form a saturated or unsaturated ring, or are not bonded; and

R₁₁₀ and R₁₀₈ in the formula (100) form a saturated or unsaturated ring, or are not bonded.

A plurality of R₁₁₀ are mutually the same or different,

s in the formula (100) is preferably 0 or 1.

When s is 0 in the formula (100), B in the formula (2) is represented by a formula (100A) below.

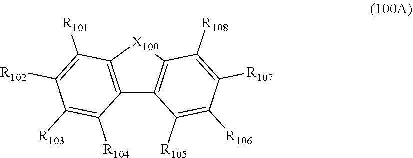

X₁₀₀ and R₁₀₁ to R₁₀₈ in the formula (100A) respectively represent the same as X₁₀₀ and R₁₀₁ to R₁₀₈ in the formula (100).

L₁₀₀ is preferably represented by one of the formulae (111) to (114), more preferably represented by the formula (113) or (114).

X₁₀₀ is preferably represented by one of the formulae (121) to (124), more preferably represented by the formula (123) or (124).

In the organic EL device of the exemplary embodiment, the second compound contained in the emitting layer is more preferably a compound represented by a formula (20) below.

(Cz_{b1}L²⁰A¹⁰)ₐ₁ (20)

In the formula (20): A¹⁰ is a group having a moiety selected from the formulae (a-1) to (a-2);

Cz is a group represented by a formula (2a) below;

L₂₀ is a single bond or a linking group, L₂₀ as the linking group being a group derived from a substituted or unsubstituted aryl group having 6 to 30 ring carbon atoms, a group derived from a substituted or unsubstituted heteroaryl group having 5 to 30 ring atoms, or a group provided by combining two, three, four or five groups selected from the group consisting of the group derived from the substituted or unsubstituted aryl group having 6 to 30 ring carbon atoms and the group derived from the substituted or unsubstituted heteroaryl group having 5 to 30 ring atoms;

a1 is 1, 2, 3, 4, or 5 and represents the number of A¹⁰ directly bonded to L²⁰;

a plurality of A¹⁰ are mutually the same or different when al is 2, 3, 4 or 5;

b1 is 1, 2, 3, 4, or 5 and represents the number of Cz directly bonded to L²⁰; and

a plurality of Cz are mutually the same or different when b1 is 2, 3, 4 or 5.

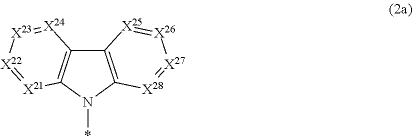

In the formula (2a): X²¹ to X²⁸ are each independently a nitrogen atom or CR^{x};

R^{x} is a hydrogen atom or a substituent;

R^{x} as the substituent is each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxyl group;

a plurality of R^{x} are mutually the same or different;

when two or more of X²¹ to X²⁸ are CR^{x} and R^{x} is a substituent, a plurality of R^{x} are bonded to each other to form a ring, or are not bonded;

* represents a bonding position with a carbon atom in the group represented by L²⁰ or A¹⁰ in the formula (20); and

X²¹ to X²⁸ in the formula (2a) is preferably CR^{x}.

In the organic EL device of the exemplary embodiment, L²⁰ in the formula (20) is preferably a single bond, or a group derived from a substituted or unsubstituted aryl group having 6 to 30 ring carbon atoms, more preferably a single bond or a group derived from a substituted or unsubstituted phenyl group.

In the organic EL device of the exemplary embodiment, the second compound is also preferably a compound represented by a formula (21) below.

Cz-Az (21)

In the formula (21): Cz represents the same as Cz in the formula (20); and

Az is a cyclic structure selected from the group consisting of a substituted or unsubstituted pyridine ring, a substituted or unsubstituted pyrimidine ring, a substituted or unsubstituted triazine ring, and a substituted or unsubstituted pyrazine ring.

In the organic EL device of the exemplary embodiment, the second compound is also preferably a compound represented by a formula (2C) below.

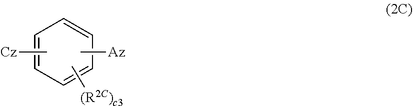

In the formula (2C): Cz represents the same as Cz in the formula (20);

Az represents the same as Az in the formula (21);

c3 is 4;

R^{2C} is a hydrogen atom or a substituent;

R^{2C} as the substituent is selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group; and

a plurality of R^{2C} is the same or different.

In the organic EL device of the exemplary embodiment, the second compound is also preferably a compound represented by a formula (2D) below.

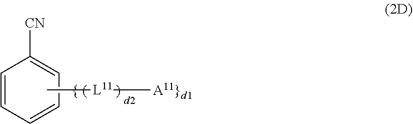

In the formula (2D): d1 is 5 and d2 is each independently 0 or 1;

L¹¹ each independently represents a single bond or a linking group, L¹¹ as the substituent being each independently a group selected from the group consisting of a group derived from a substituted or unsubstituted aryl group having 6 to 30 ring carbon atoms, and a group derived from a substituted or unsubstituted heteroaryl group having 5 to 30 ring atoms; and

A¹¹ each independently represents a hydrogen atom or a substituent, A¹¹ as the substituent being each independently a group selected from the group consisting of a cyano group, a substituted or unsubstituted aryl group having 6 to 30 ring carbon atoms, and a substituted or unsubstituted heteroaryl group having 5 to 30 ring atoms.

At least one of A¹¹ is a group represented by the formula (2a).

In the organic EL device of the exemplary embodiment, the second compound is also preferably a compound represented by a formula (22) below.

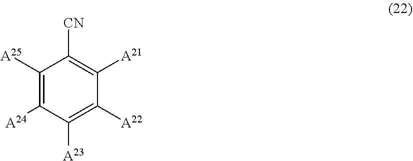

In the formula (22): A²¹ to A²⁵ are each independently a hydrogen atom or a substituent;

A²¹ to A²⁵ as the substituents are each independently a group selected from the group consisting of a cyano group, a substituted or unsubstituted aryl group having 6 to 30 ring carbon atoms, and a substituted or unsubstituted heteroaryl group having 5 to 30 ring atoms; and

At least one of A²¹ to A²⁵ is a group represented by the formula (2a).

In the organic EL device according to the exemplary embodiment, at least one of A²¹, A²², A²⁴ and A²⁵ in the formula (22) is preferably the group represented by the formula (2a). More preferably, each of A²¹, A²², A²⁴ and A²⁵ is the group represented by the formula (2a).

Cz in the formula (20) is also preferably represented by a formula (12a), (12b) or (12c) below.

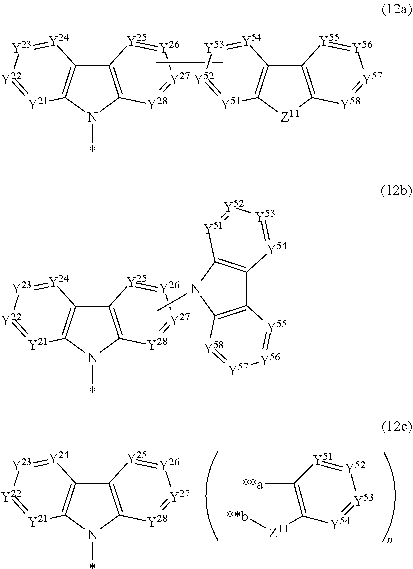

In the formulae (12a), (12b) and (12c), Y²¹ to Y²⁸ and Y⁵¹ to Y⁵⁸ each independently represent a nitrogen atom or CRy (a carbon atom having Ry).

In the formula (12a), at least one of Y²⁵ to Y²⁸ is a carbon atom bonded to one of Y⁵¹ to Y⁵⁴ while at least one of Y⁵¹ to Y⁵⁴ is a carbon atom bonded to one of Y²⁵ to Y²⁸.

In the formula (12b), at least one of Y²⁵ to Y²⁸ is a carbon atom bonded to a nitrogen atom in a five-membered ring of a nitrogen-containing fused ring including Y⁵¹ to Y⁵⁸.

In the formula (12c), **a and **b each represent a bonding position with one of Y²¹ to Y²⁸. At least one of Y²⁵ to Y²⁸ is bonded to the bonding position represented by **a. At least one of Y²⁵ to Y²⁸ is bonded to the bonding position represented by **b.

n is 1, 2, 3 or 4.

Ry each independently represents a hydrogen atom or a substituent, or at least one pair of the plurality of Ry is optionally mutually bonded to form a ring. R_{y} as the substituent are each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group.

A plurality of Ry are mutually the same or different.

Z¹¹ is one selected from the group consisting of an oxygen atom, a sulfur atom, NR⁴⁵, and CR⁴⁶R⁴⁷.

R⁴⁵ to R⁴⁷ each independently represent a hydrogen atom or a substituent, or R⁴⁵ and R⁴⁷ are optionally mutually bonded to form a ring.

R⁴⁵ to R⁴⁷ as the substituents are each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group.

A plurality of R⁴⁵ are mutually the same or different.

A plurality of R⁴⁶ are mutually the same or different.

A plurality of R⁴⁷ are mutually the same or different.

* represents a bonding position with a carbon atom in the cyclic structure represented by Az.

Z¹¹ is preferably NR⁴⁵.

When Z¹¹ is NR⁴⁵, R⁴⁵ is preferably a substituted or unsubstituted aryl group having 6 to 30 ring carbon atoms.

Y⁵¹ to Y⁵⁸ are preferably CRy. In this case, at least one of Y⁵¹ to Y⁵⁸ in the formula (12a) or (12b) is a carbon atom bonded to the cyclic structure represented by the formula (2a).

Cz in the formula (20) is preferably represented by the formula (12c) in which n is 1.

Cz in the formula (20) is also preferably represented by a formula (12c-1) below. A group represented by the formula (12c-1) is an exemplary group obtained by bonding Y₂₆ to the bonding position represented by **a and bonding Y₂₇ to the bonding position represented by **b in the formula (12c).

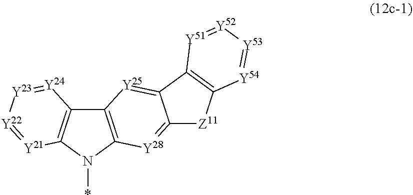

In the formula (12c-1):

Y²¹ to Y²⁵, Y²⁸, and Y⁵¹ to Y⁵⁴ are each independently a nitrogen atom or Cry;

Ry each independently represents a hydrogen atom or a substituent, or at least one pair of the plurality of Ry is optionally mutually bonded to form a ring;

Ry as the substituent is each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group;

a plurality of Ry are mutually the same or different;

Z¹¹ is one selected from the group consisting of an oxygen atom, a sulfur atom, NR⁴⁵, and CR⁴⁶R⁴⁷;

R⁴⁵ to R⁴⁷ each independently represent a hydrogen atom or a substituent, or R⁴⁵ and R⁴⁷ is optionally mutually bonded to form a ring;

R⁴⁵ to R⁴⁷ as the substituents are each independently a group selected from the group consisting of a substituted or unsubstituted aryl group having 6 to 30 ring carbon atoms, a substituted or unsubstituted heteroaryl group having 5 to 30 ring atoms, a substituted or unsubstituted alkyl group having 1 to 30 carbon atoms, a substituted or unsubstituted fluoroalkyl group having 1 to 30 carbon atoms, a substituted or unsubstituted cycloalkyl group having 3 to 30 ring carbon atoms, a substituted or unsubstituted aralkyl group having 7 to 30 carbon atoms, a substituted phosphoryl group, a substituted silyl group, a cyano group, a nitro group, and a carboxy group;

a plurality of R⁴⁵ are mutually the same or different;

a plurality of R⁴⁶ are mutually the same or different;

a plurality of R⁴⁷ are mutually the same or different; and

* represents a bonding position with a carbon atom in the cyclic structure represented by Az.

When n is 2 in the formula (12c), Cz is exemplarily represented by a formula (12c-2) below. When n is 2, two of structures each shown in brackets added with an index n are fused to the cyclic structure represented by the formula (2a). Cz represented by the formula (12c-2) is obtained by bonding Y²² to the bonding position represented by **b and bonding Y²³ to the bonding position represented by **a while bonding Y²⁶ to the bonding position represented by **a and bonding Y²⁷ to the bonding position represented by **b, in the formula (12c).

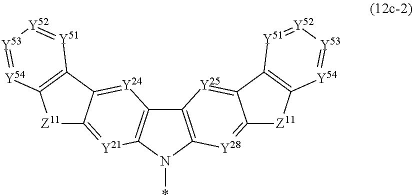

In the formula (12c-2), Y²¹, Y²⁴, Y²⁵, Y²⁸, Y⁵¹ to Y⁵⁴, Z¹¹, and * represent the same as Y²¹, Y²⁴, Y²⁵, Y²⁸, Y⁵¹ to Y⁵⁴, Z¹¹, and * in the formula (12c-1). A plurality of Y⁵¹ are mutually the same or different. A plurality of Y⁵² are mutually the same or different. A plurality of Y⁵³ are mutually the same or different. A plurality of Y⁵⁴ are mutually the same or different. A plurality of Z¹¹ are mutually the same or different.

In the formulae (21) and (2C), Az is preferably each independently a cyclic structure selected from the group consisting of a substituted or unsubstituted pyrimidine ring and a substituted or unsubstituted triazine ring.

It is more preferable that Az is a cyclic structure selected from the group consisting of a substituted pyrimidine ring and a substituted triazine ring, and a substituent for each of the pyrimidine ring and the triazine ring is selected from the group consisting of a substituted or unsubstituted aryl group having 6 to 30 ring carbon atoms and a substituted or unsubstituted heteroaryl group having 5 to 30 ring atoms, further preferably a substituted or unsubstituted aryl group having 6 to 30 ring carbon atoms.

When the pyrimidine ring and the triazine ring as Az have a substituted or unsubstituted aryl group as the substituent, the aryl group preferably has 6 to 20 ring carbon atoms, more preferably 6 to 14 ring carbon atoms, further preferably 6 to 12 ring carbon atoms.

Specific examples of the substituents in the formulae (2), (b-1) to (b-4), (a-1-1), (b-2-5), (100), (113) to (117), (123) to (125), (100A), (20), (2a), (21), (2C), (2D), (22), (12a) to (12c), (12c-1), and (12c-2) (e.g. a substituted or unsubstituted alkyl group having 1 to 30 carbon atoms) are substituents exemplified in the below-described “Description of Substituents in the Formula of First Compound and Second Compound.”

When Az has a substituted or unsubstituted aryl group as the substituent, the substituent is preferably selected from the group consisting of a substituted or unsubstituted phenyl group, a substituted or unsubstituted biphenyl group, a substituted or unsubstituted naphthyl group, a substituted or unsubstituted phenanthryl group, a substituted or unsubstituted terphenyl group, and a substituted or unsubstituted fluorenyl group, more preferably selected from the group consisting of a substituted or unsubstituted phenyl group, a substituted or unsubstituted biphenyl group, and a substituted or unsubstituted naphthyl group.

When Az has a substituted or unsubstituted heteroaryl group as the substituent, the substituent is preferably a group selected from the group consisting of a substituted or unsubstituted carbazolyl group, a substituted or unsubstituted dibenzofuranyl group, and a substituted or unsubstituted dibenzothienyl group.

Ry in the formulae (12a) to (12c) is each independently a hydrogen atom or a substituent. Ry as the substituent is preferably a group selected from the group consisting of a substituted or unsubstituted aryl group having 6 to 30 ring carbon atoms and a substituted or unsubstituted heteroaryl group having 5 to 30 ring atoms.

When Ry as the substituent is a substituted or unsubstituted aryl group having 6 to 30 ring carbon atoms, Ry as the substituent is preferably a group selected from the group consisting of a substituted or unsubstituted phenyl group, a substituted or unsubstituted biphenyl group, a substituted or unsubstituted naphthyl group, a substituted or unsubstituted phenanthryl group, a substituted or unsubstituted terphenyl group, and a substituted or unsubstituted fluorenyl group, more preferably selected from the group consisting of a substituted or unsubstituted phenyl group, a substituted or unsubstituted biphenyl group, and a substituted or unsubstituted naphthyl group.

When Ry as the substituent has a substituted or unsubstituted heteroaryl group having 5 to 30 ring atoms, Ry as the substituent is preferably a group selected from the group consisting of a substituted or unsubstituted carbazolyl group, a substituted or unsubstituted dibenzofuranyl group, and a substituted or unsubstituted dibenzothienyl group.

In the formula (12a) and (12c), R⁴⁵ to R⁴⁷ as the substituents are each independently preferably selected from the group consisting of a substituted or unsubstituted aryl group having 6 to 30 ring carbon atoms, a substituted or unsubstituted heteroaryl group having 5 to 30 ring atoms, and a substituted or unsubstituted alkyl group having 1 to 30 carbon atoms.

### Method of Preparing Second Compound

The second compound can be prepared, for instance, by methods described in Chemical Communications, p.10385-10387 (2013) and NATURE Photonics, p. 326-332 (2014). Alternatively, the second compound also can be prepared, for instance, in accordance with methods disclosed in International Publication No. WO2013/180241, International Publication No. WO2014/092083, International Publication No. WO2014/104346, and the like. Furthermore, the second compound can be prepared, for instance, by application of known substitution reactions and/or materials depending on a target compound according to reactions described later in Examples.

Specific examples of the second compound of the exemplary embodiment are shown below. It should be noted that the second compound in the invention is by no means limited to the examples below.

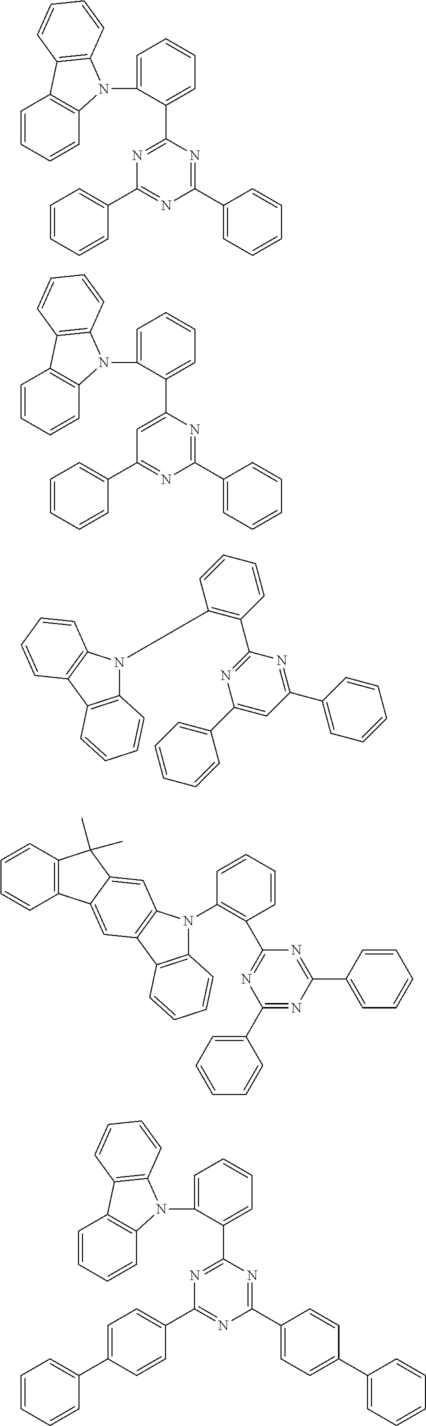

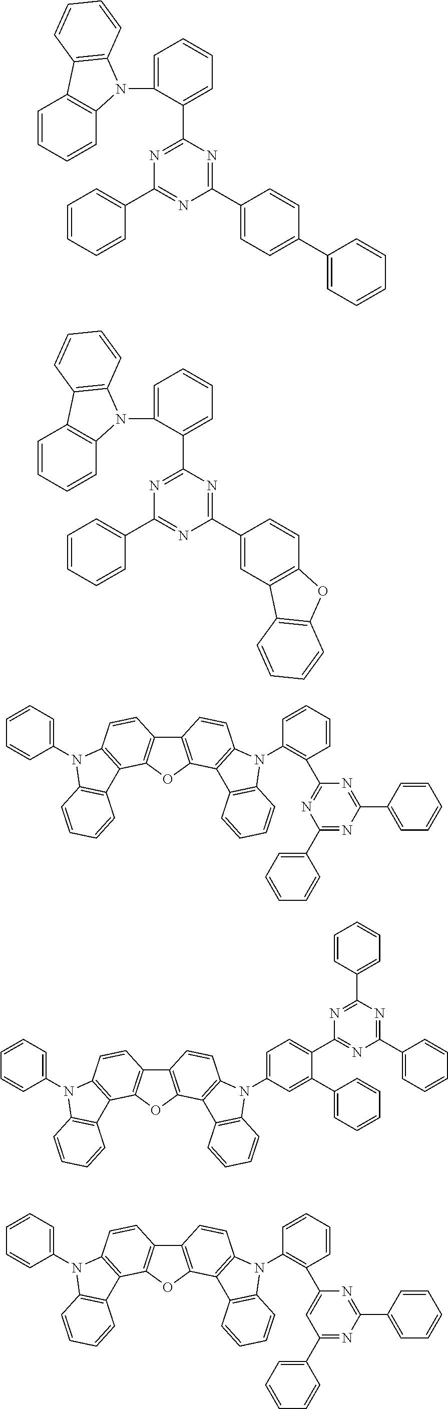

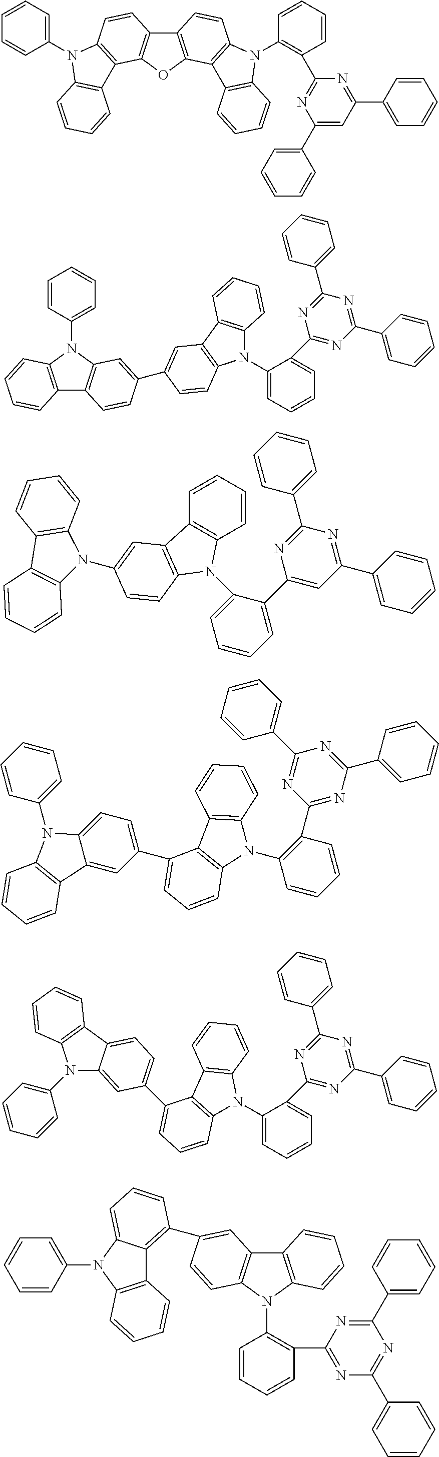

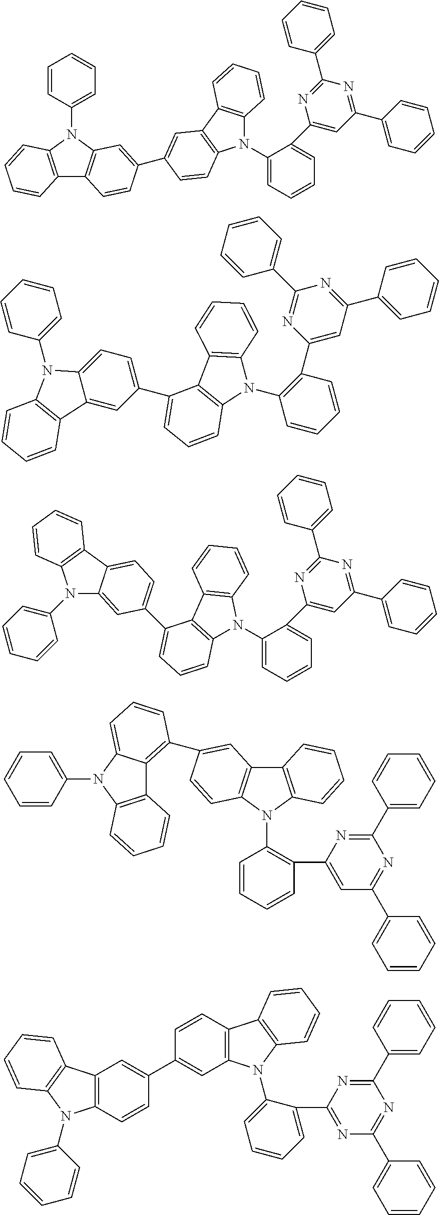

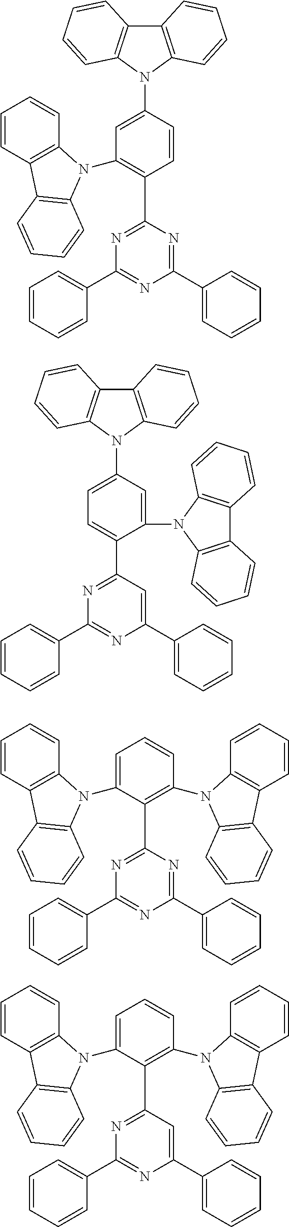

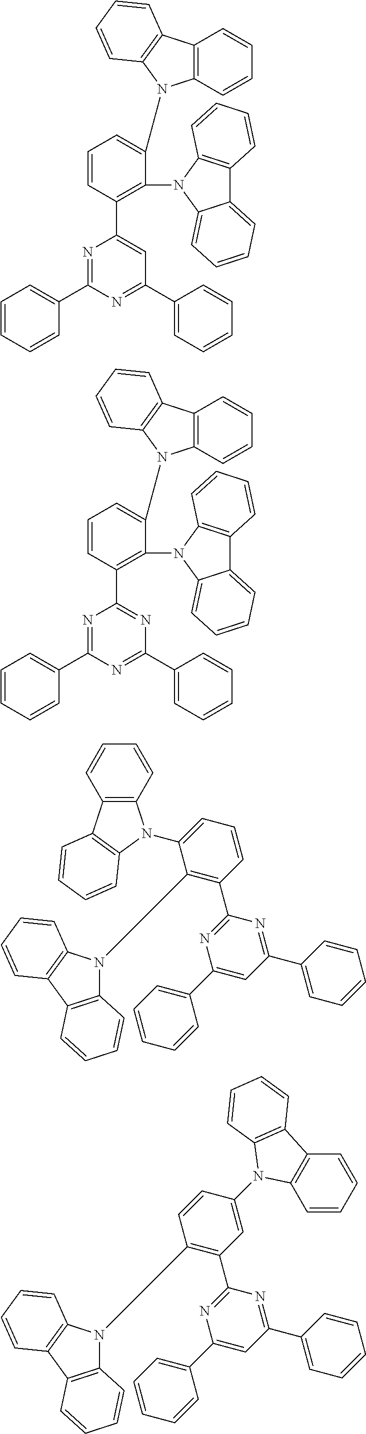

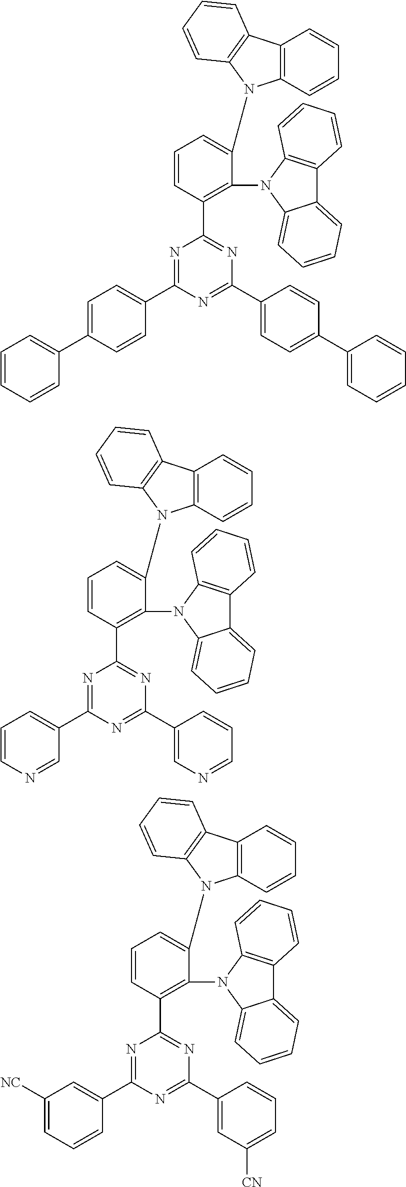

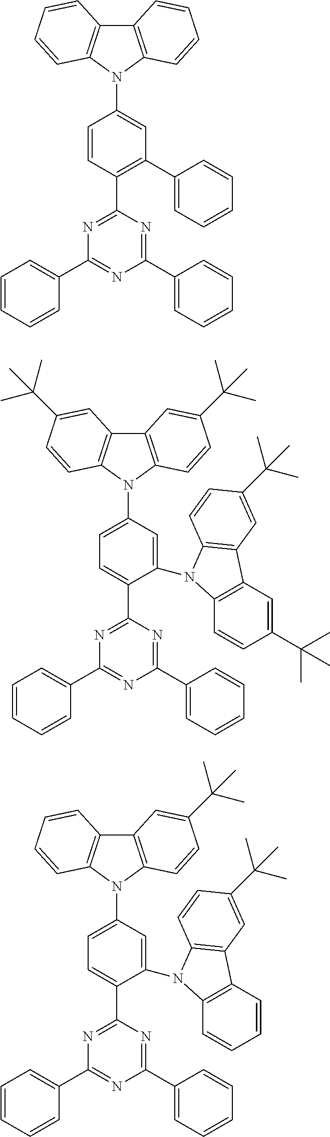

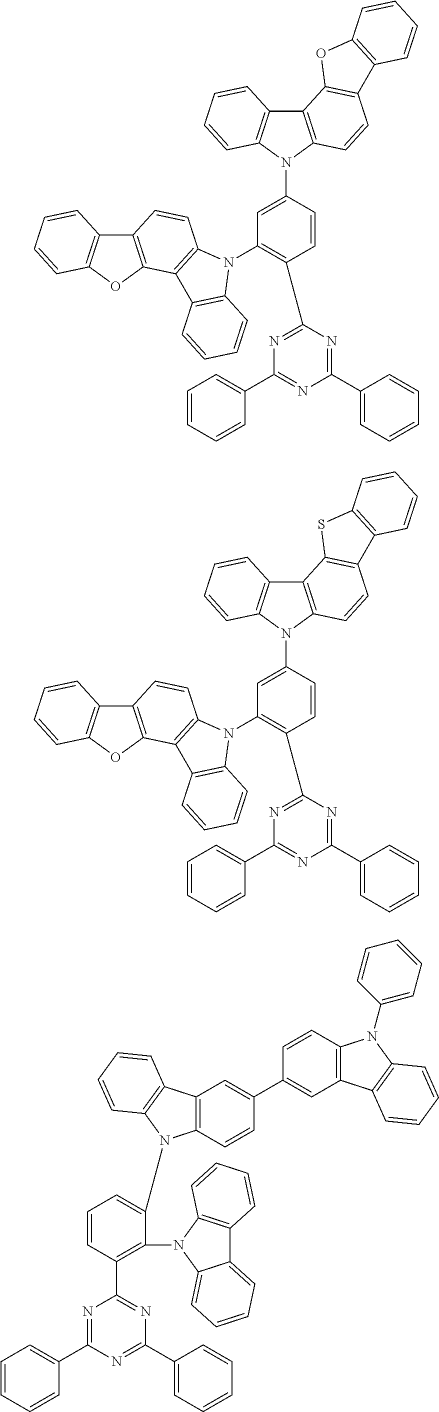

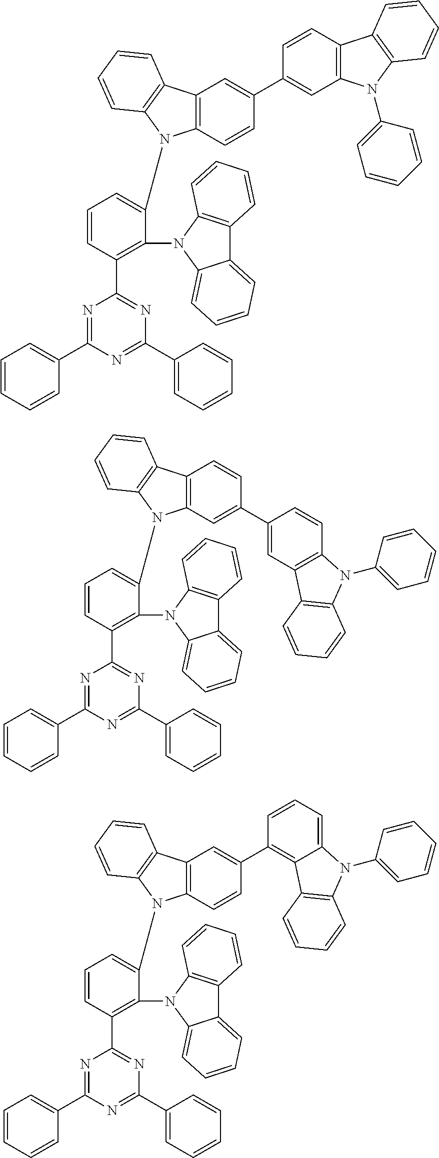 [SMILES: c1ccc(-c2nc(-c3ccccc3)nc(-c3cccc(-n4c5ccccc5c5cc(-c6ccc7c8ccccc8n(-c8ccccc8)c7c6)ccc54)c3-n3c4ccccc4c4ccccc43)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3-n3c4ccccc4c4ccccc43)n2)cc1 ; c1ccc(-c2nc(-c3ccccc3)nc(-c3cccc(-n4c5ccccc5c5cc(-c6cccc7c6c6ccccc6n7-c6ccccc6)ccc54)c3-n3c4ccccc4c4ccccc43)n2)cc1]

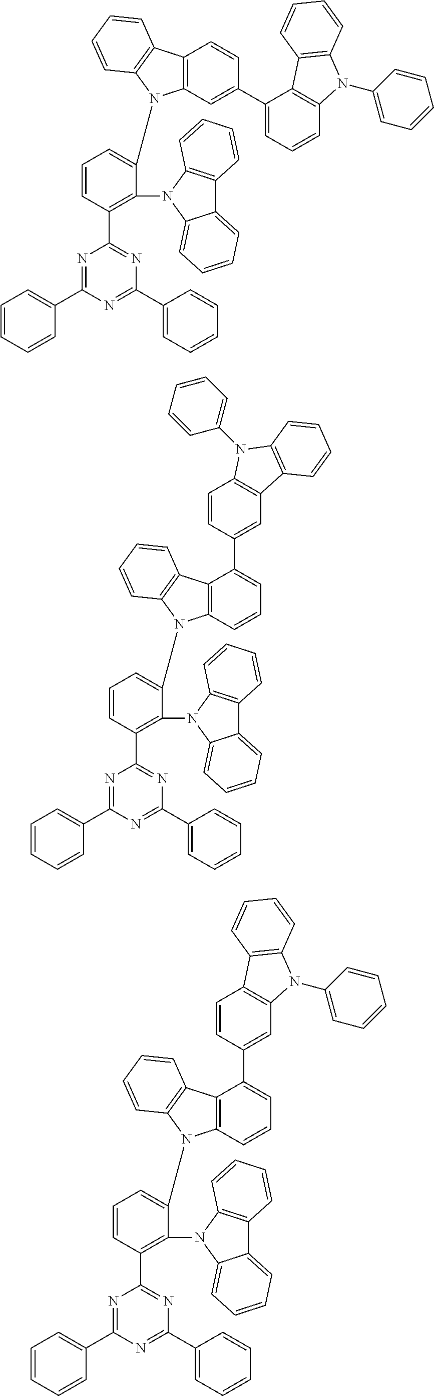

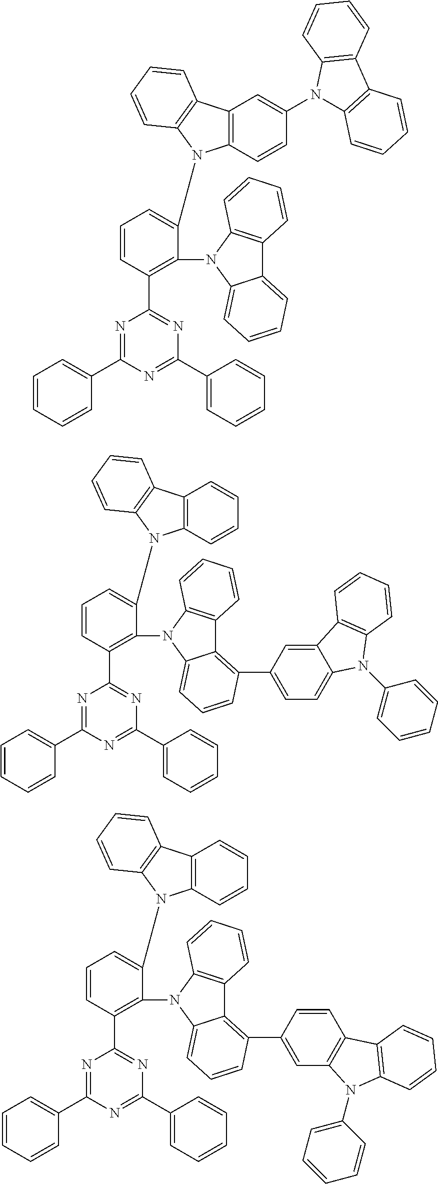

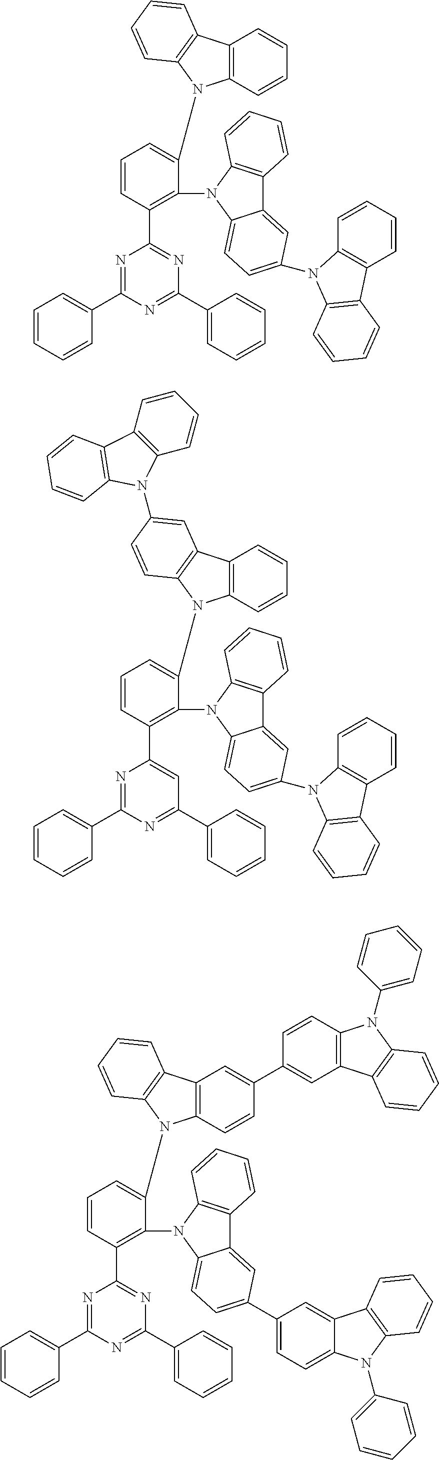 [SMILES: c1ccc(-c2nc(-c3ccccc3)nc(-c3cccc(-n4c5ccccc5c5ccccc54)c3-n3c4ccccc4c4cc(-n5c6ccccc6c6ccccc65)ccc43)n2)cc1 ; c1ccc(-c2cc(-c3cccc(-n4c5ccccc5c5cc(-n6c7ccccc7c7ccccc76)ccc54)c3-n3c4ccccc4c4cc(-n5c6ccccc6c6ccccc65)ccc43)nc(-c3ccccc3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3-n3c4ccccc4c4cc(-c5ccc6c(c5)c5ccccc5n6-c5ccccc5)ccc43)n2)cc1]

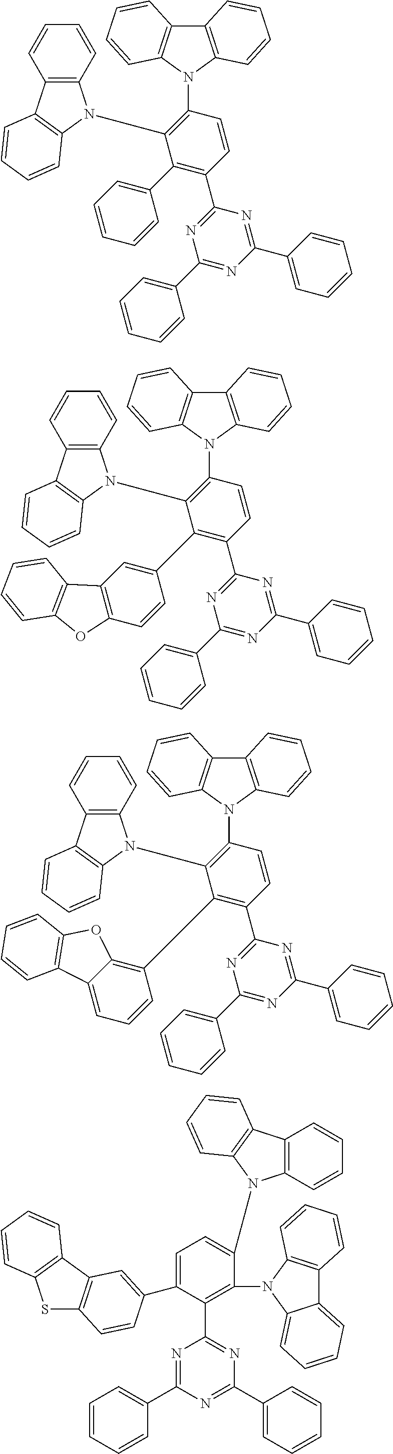

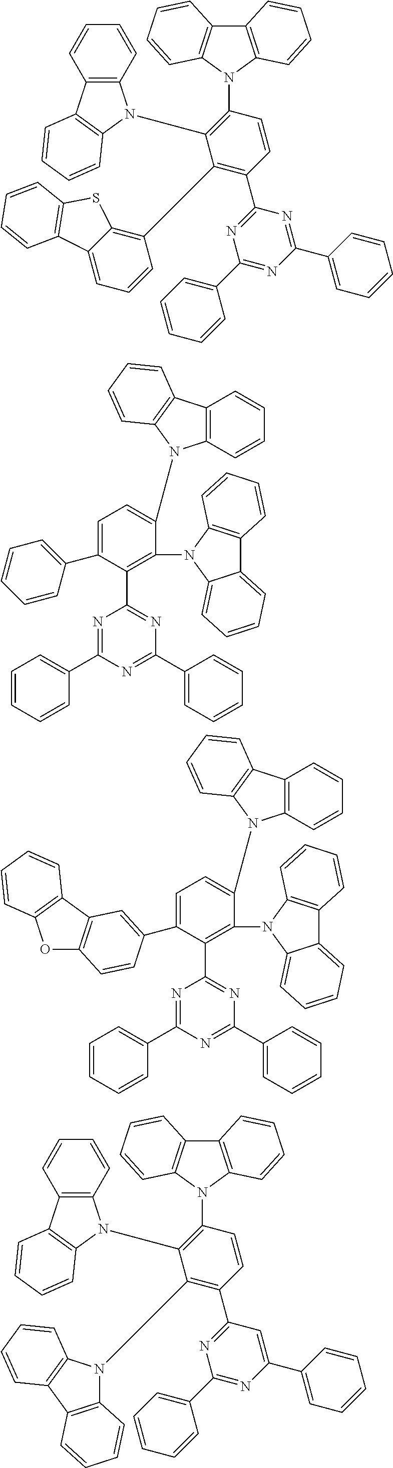

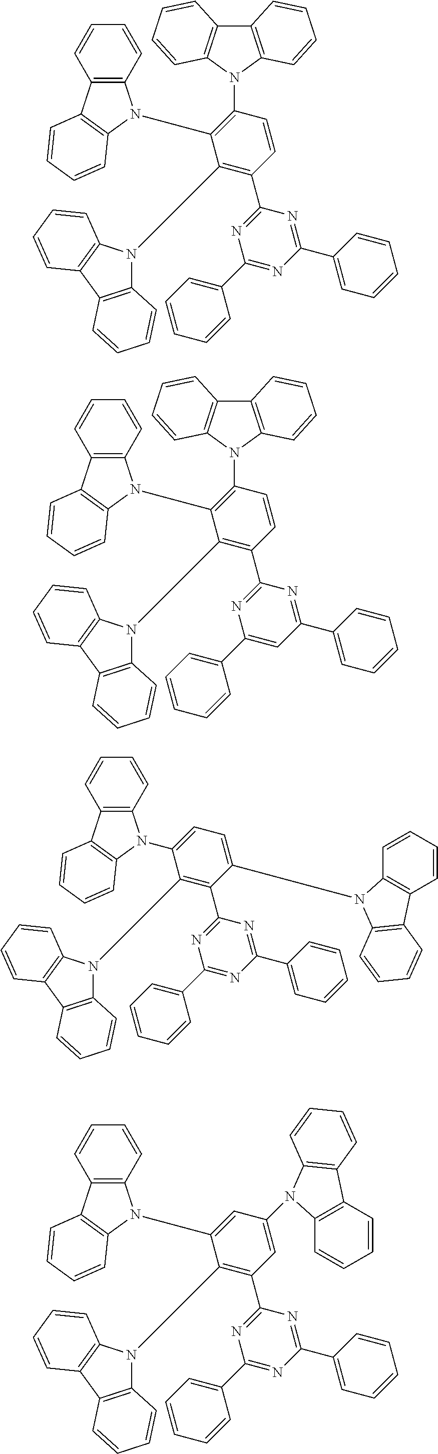

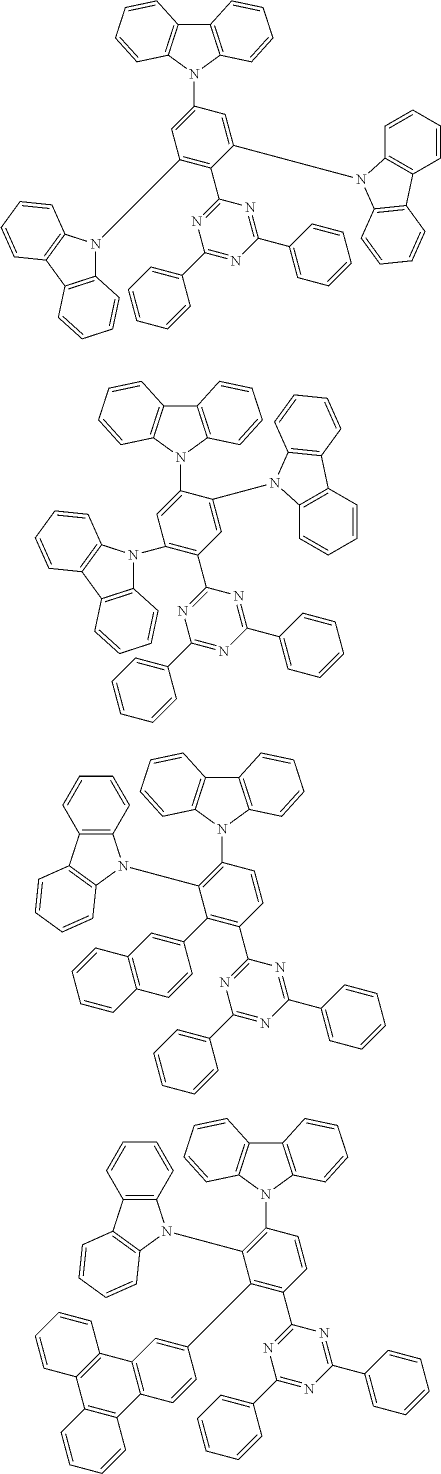

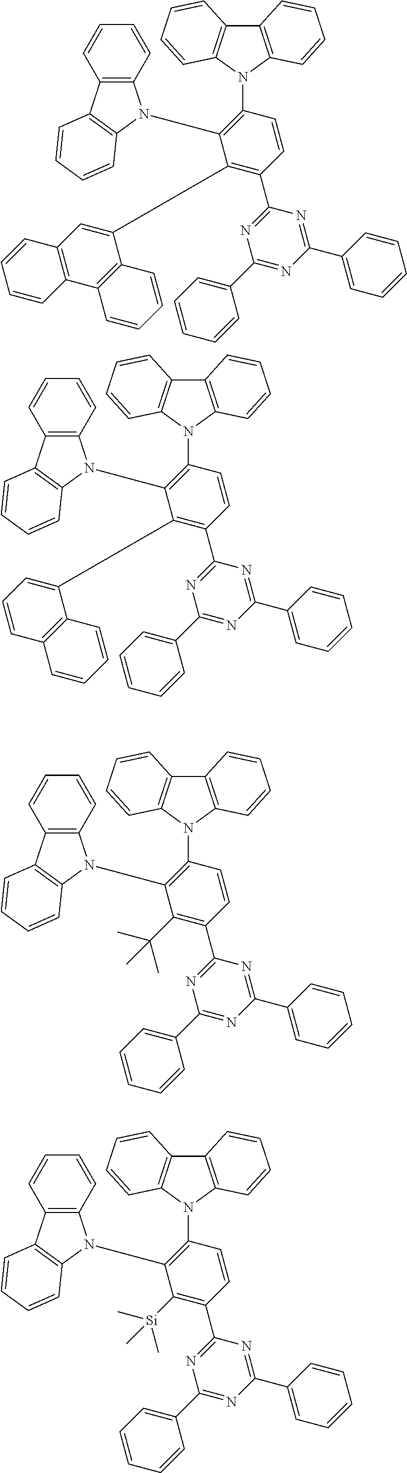

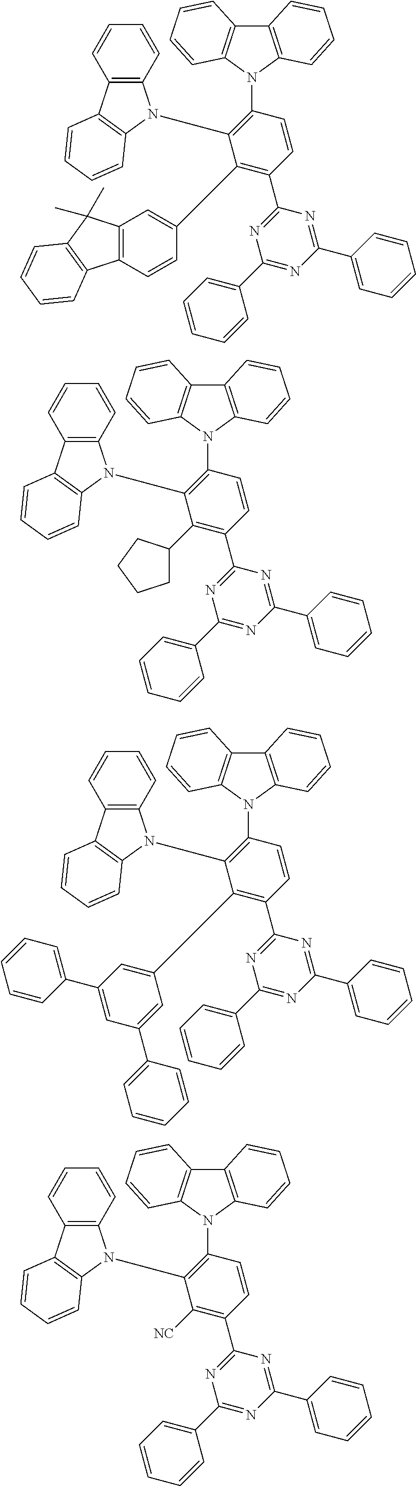

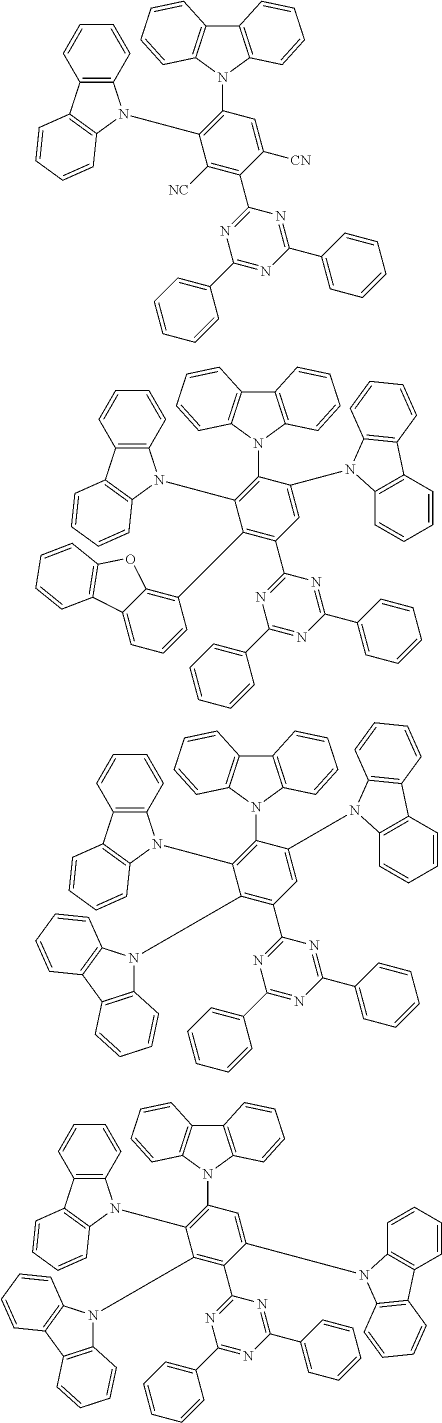

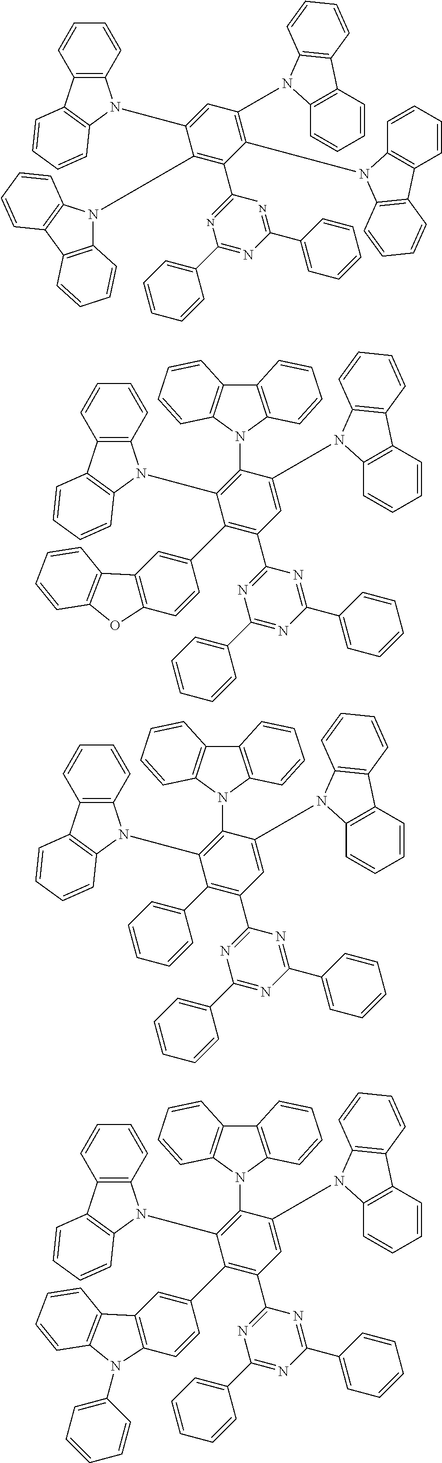

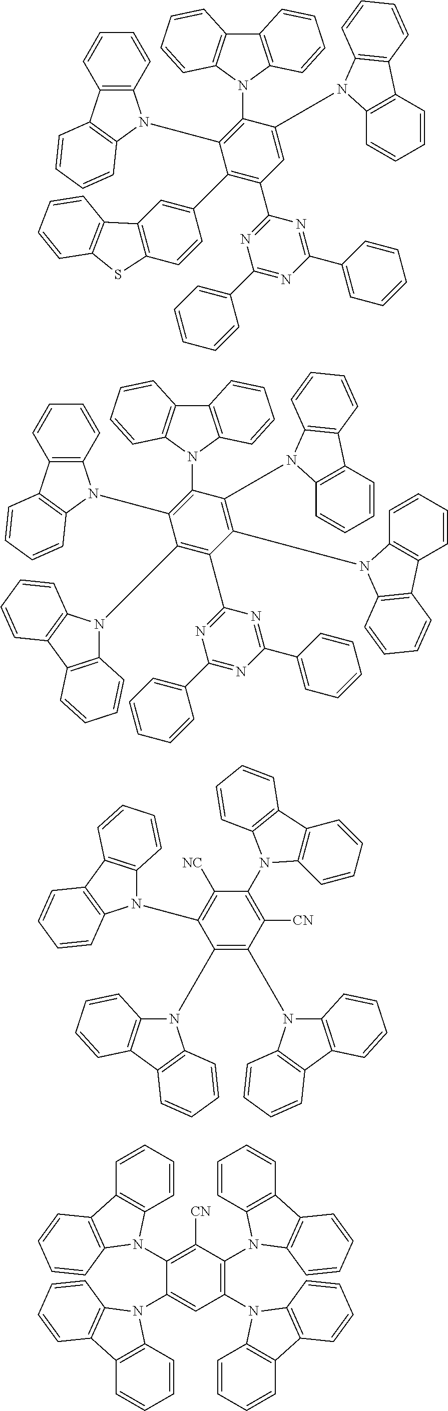

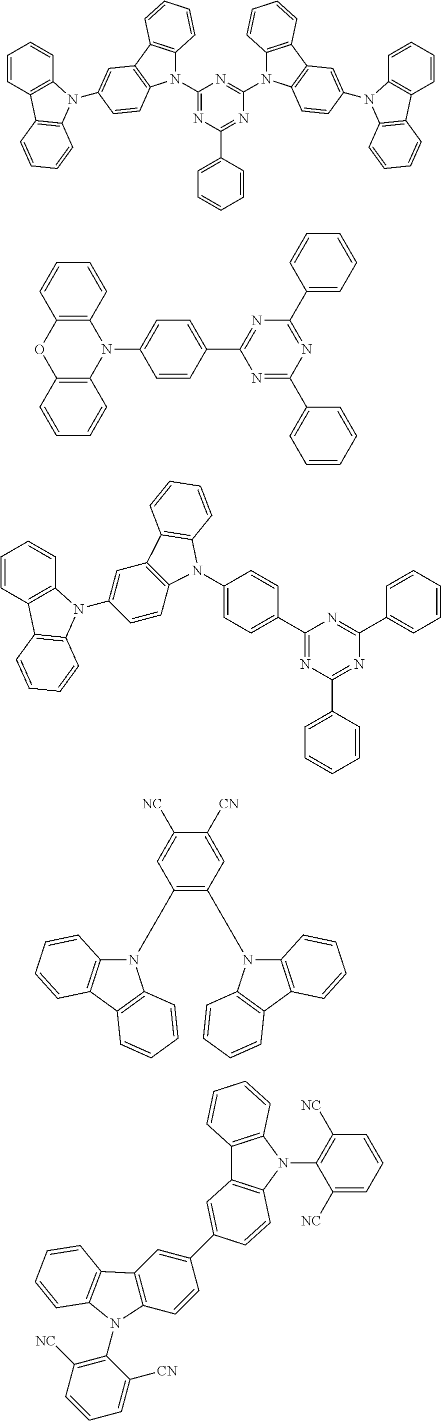

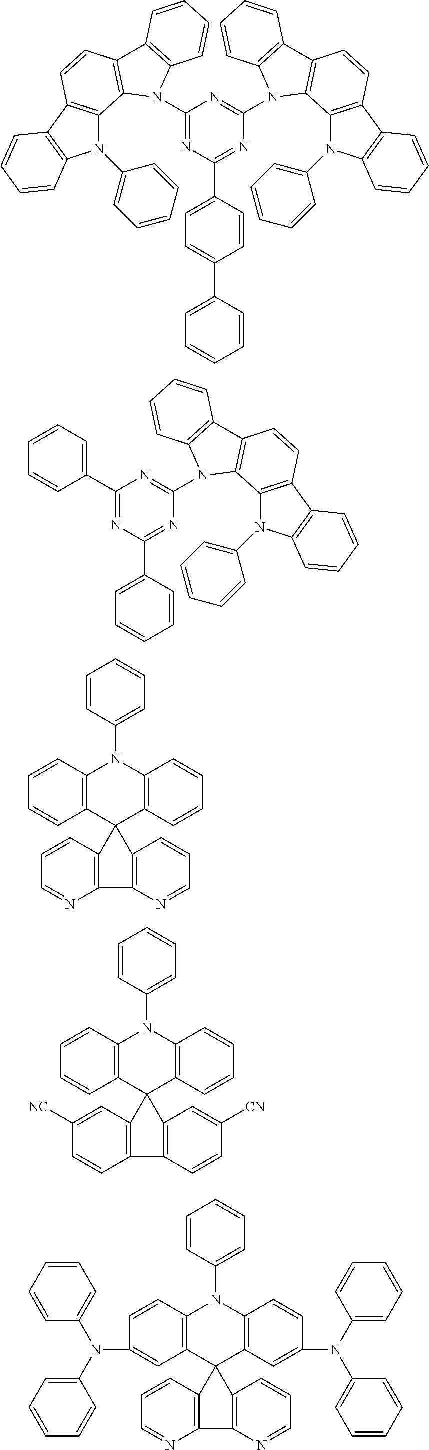

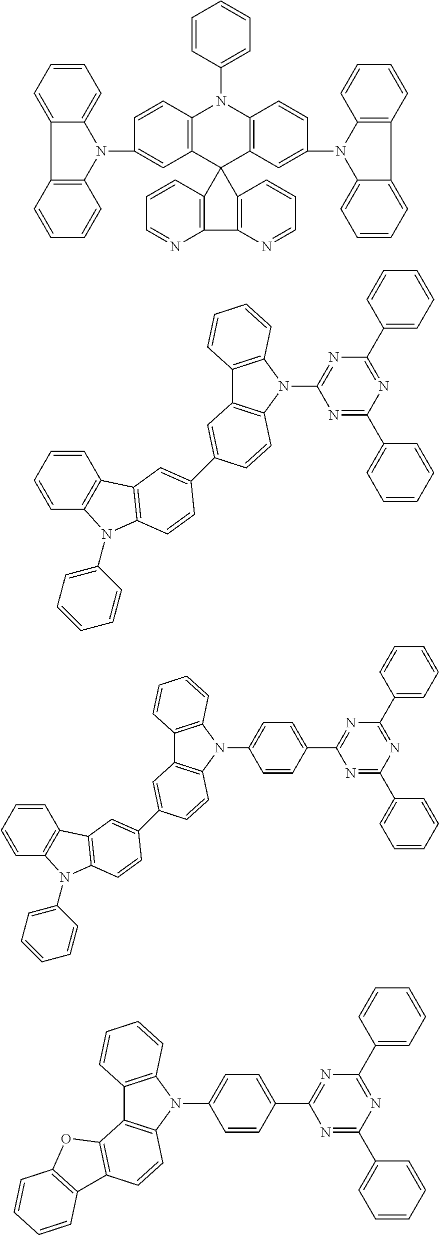

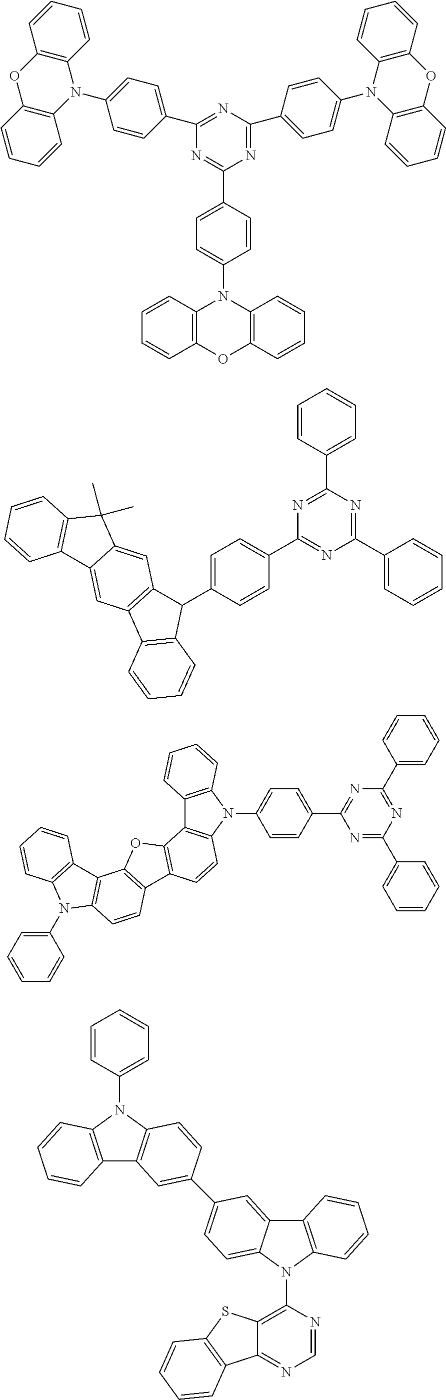 [SMILES: c1ccc2c(c1)Oc1ccccc1N2c1ccc(-c2nc(-c3ccc(N4c5ccccc5Oc5ccccc54)cc3)nc(-c3ccc(N4c5ccccc5Oc5ccccc54)cc3)n2)cc1 ; CC1(C)c2ccccc2-c2cc3c(cc21)C(c1ccc(-c2nc(-c4ccccc4)nc(-c4ccccc4)n2)cc1)c1ccccc1-3 ; c1ccc(-c2nc(-c3ccccc3)nc(-c3ccc(-n4c5ccccc5c5c6oc7c(ccc8c7c7ccccc7n8-c7ccccc7)c6ccc54)cc3)n2)cc1 ; c1ccc(-n2c3ccccc3c3cc(-c4ccc5c(c4)c4ccccc4n5-c4ncnc5c4sc4ccccc45)ccc32)cc1]

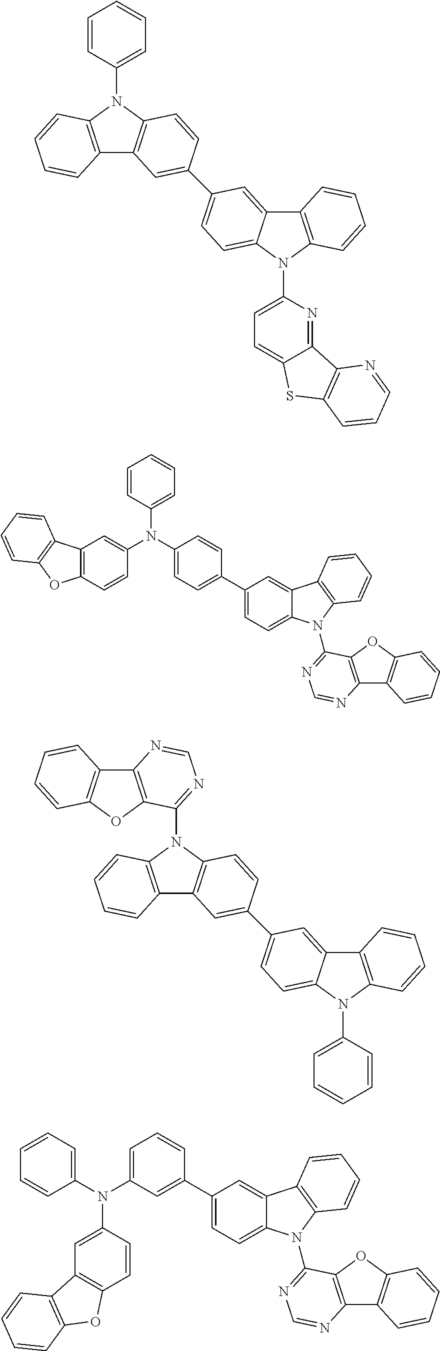 [SMILES: c1ccc(-n2c3ccccc3c3cc(-c4ccc5c(c4)c4ccccc4n5-c4ccc5sc6cccnc6c5n4)ccc32)cc1 ; c1ccc(N(c2ccc(-c3ccc4c(c3)c3ccccc3n4-c3ncnc4c3oc3ccccc34)cc2)c2ccc3oc4ccccc4c3c2)cc1 ; c1ccc(-n2c3ccccc3c3cc(-c4ccc5c(c4)c4ccccc4n5-c4ncnc5c4oc4ccccc45)ccc32)cc1 ; c1ccc(N(c2cccc(-c3ccc4c(c3)c3ccccc3n4-c3ncnc4c3oc3ccccc34)c2)c2ccc3oc4ccccc4c3c2)cc1]

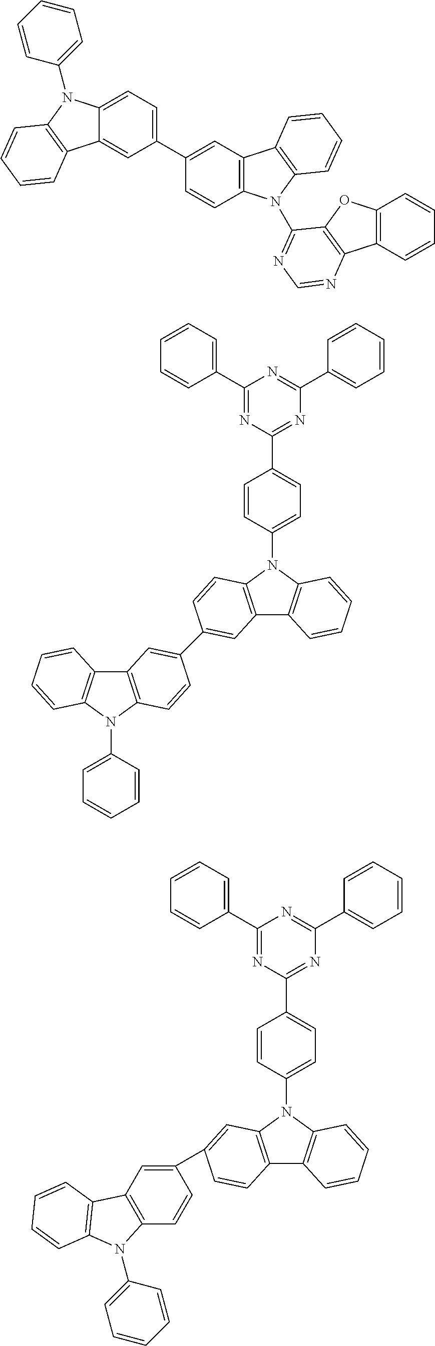

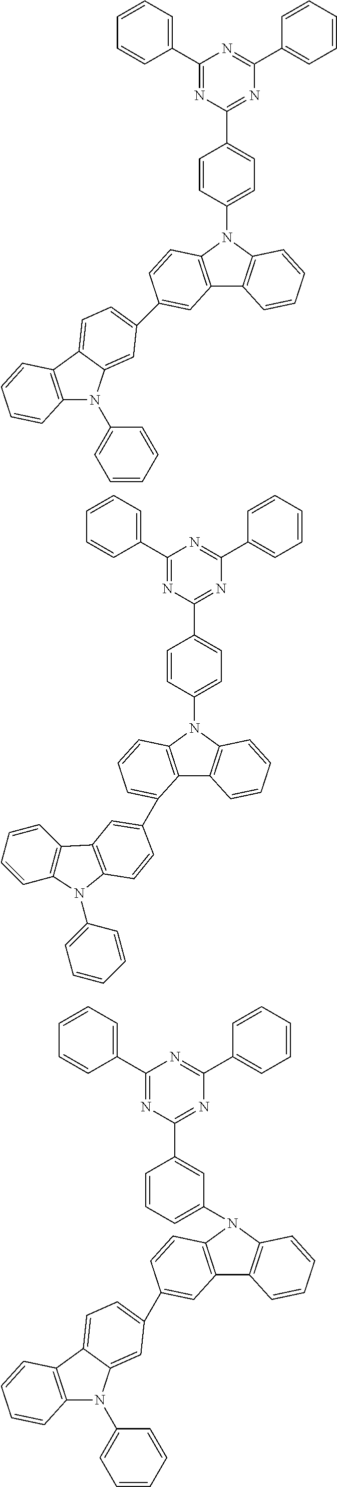

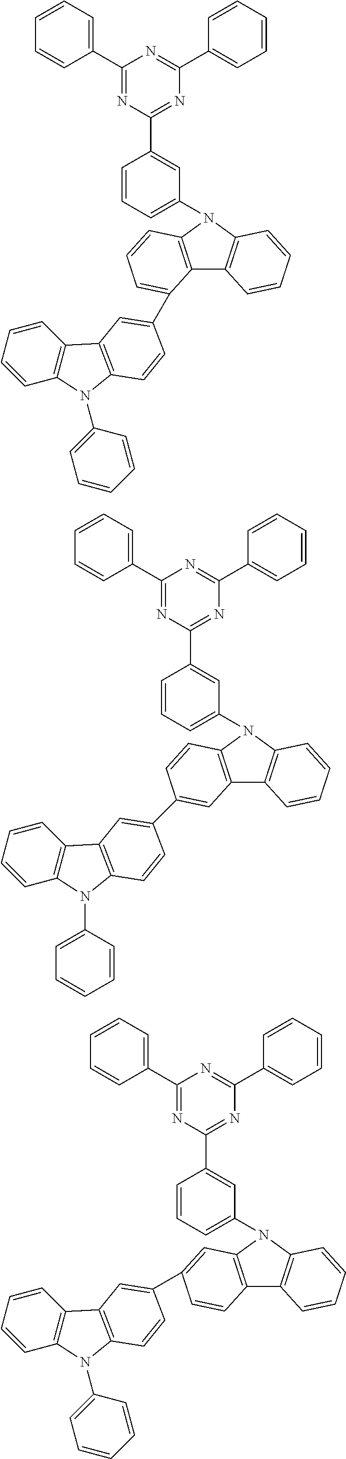

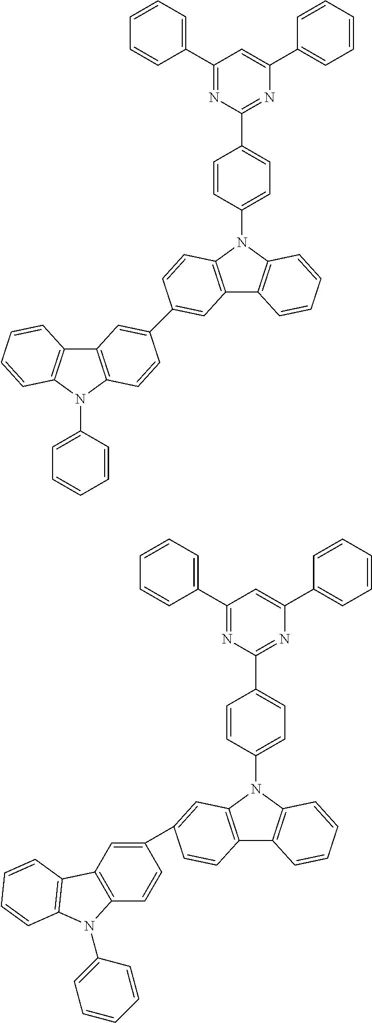 [SMILES: c1ccc(-c2cc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-c3ccc(-n4c5ccccc5c5ccc(-c6ccc7c(c6)c6ccccc6n7-c6ccccc6)cc54)cc3)n2)cc1]

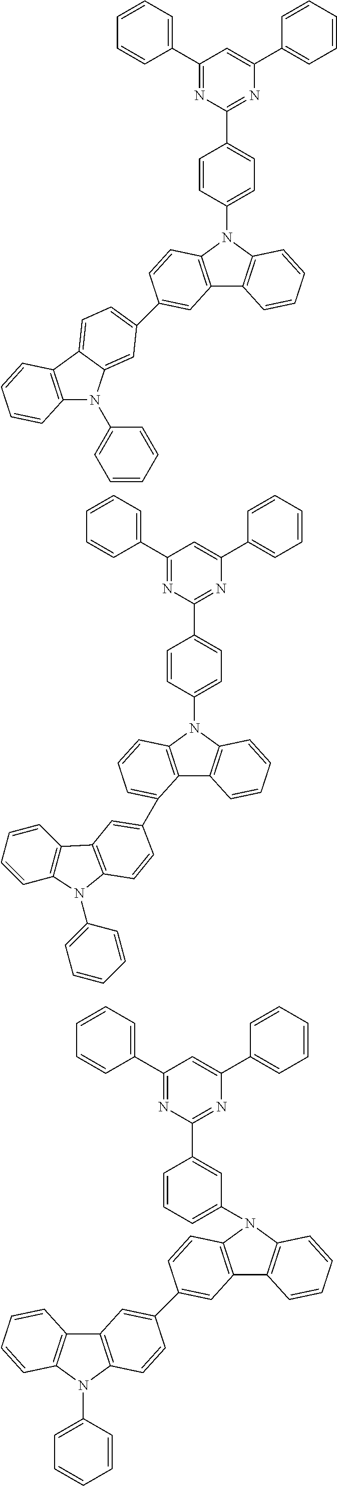

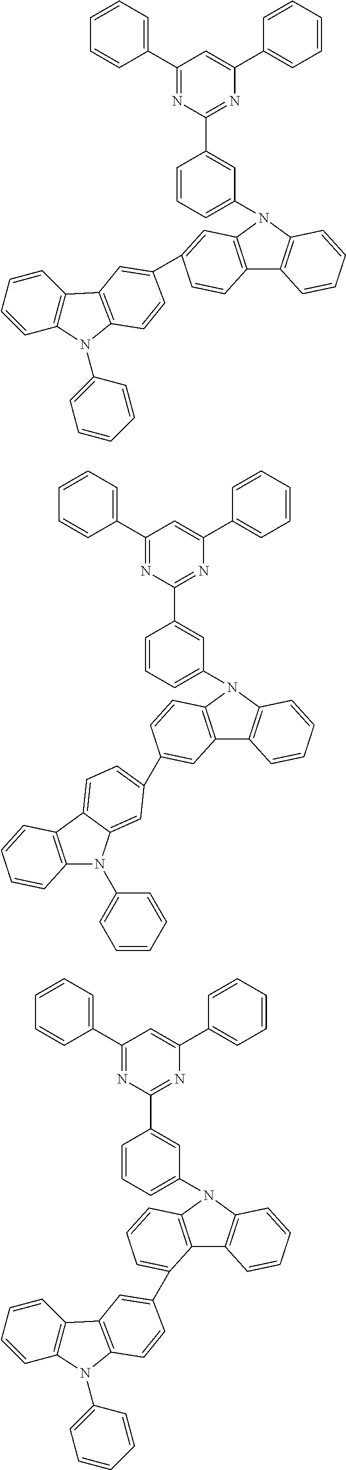

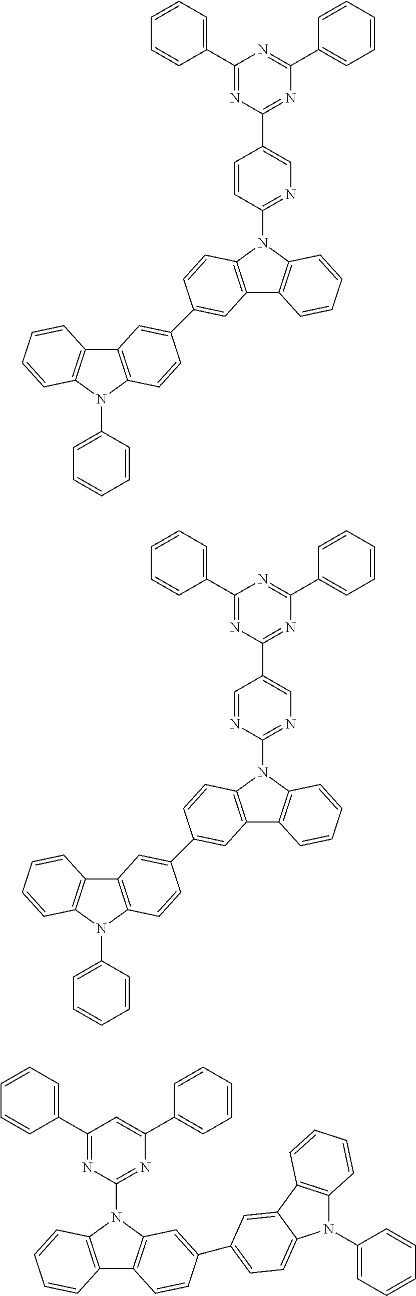 [SMILES: c1ccc(-c2nc(-c3ccccc3)nc(-c3ccc(-n4c5ccccc5c5cc(-c6ccc7c(c6)c6ccccc6n7-c6ccccc6)ccc54)nc3)n2)cc1 ; c1ccc(-c2nc(-c3ccccc3)nc(-c3cnc(-n4c5ccccc5c5cc(-c6ccc7c(c6)c6ccccc6n7-c6ccccc6)ccc54)nc3)n2)cc1 ; c1ccc(-c2cc(-c3ccccc3)nc(-n3c4ccccc4c4ccc(-c5ccc6c(c5)c5ccccc5n6-c5ccccc5)cc43)n2)cc1]

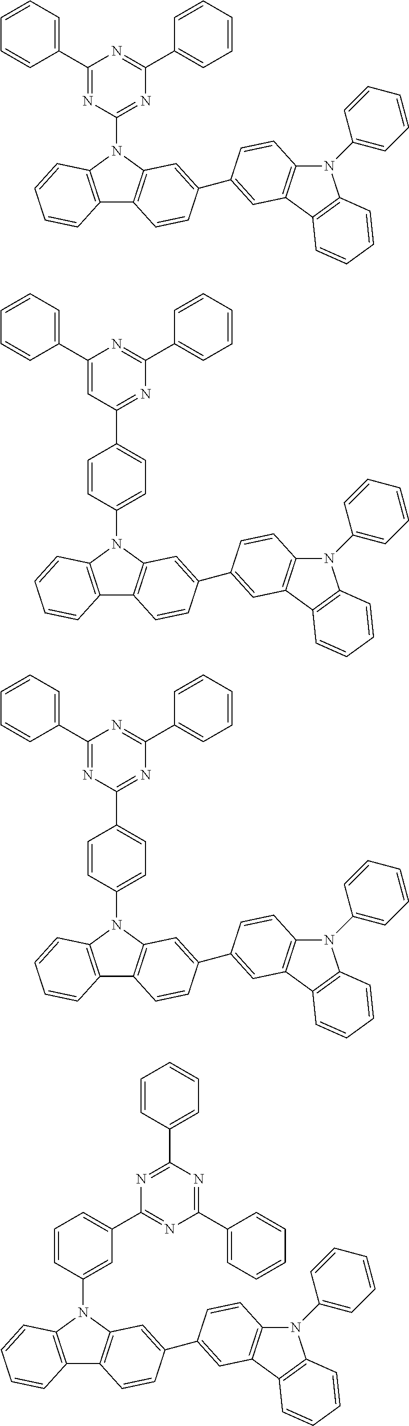 [SMILES: c1ccc(-c2nc(-c3ccccc3)nc(-n3c4ccccc4c4ccc(-c5ccc6c(c5)c5ccccc5n6-c5ccccc5)cc43)n2)cc1 ; c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1 ; c1ccc(-c2nc(-c3ccccc3)nc(-c3ccc(-n4c5ccccc5c5ccc(-c6ccc7c(c6)c6ccccc6n7-c6ccccc6)cc54)cc3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

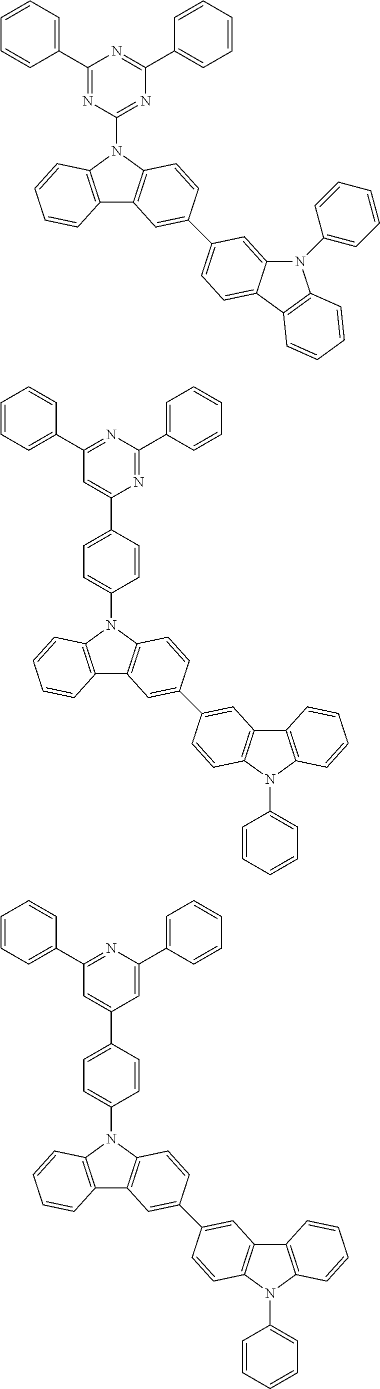 [SMILES: c1ccc(-c2nc(-c3ccccc3)nc(-n3c4ccccc4c4cc(-c5ccc6c7ccccc7n(-c7ccccc7)c6c5)ccc43)n2)cc1 ; c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; c1ccc(-c2cc(-c3ccc(-n4c5ccccc5c5cc(-c6ccc7c(c6)c6ccccc6n7-c6ccccc6)ccc54)cc3)cc(-c3ccccc3)n2)cc1]

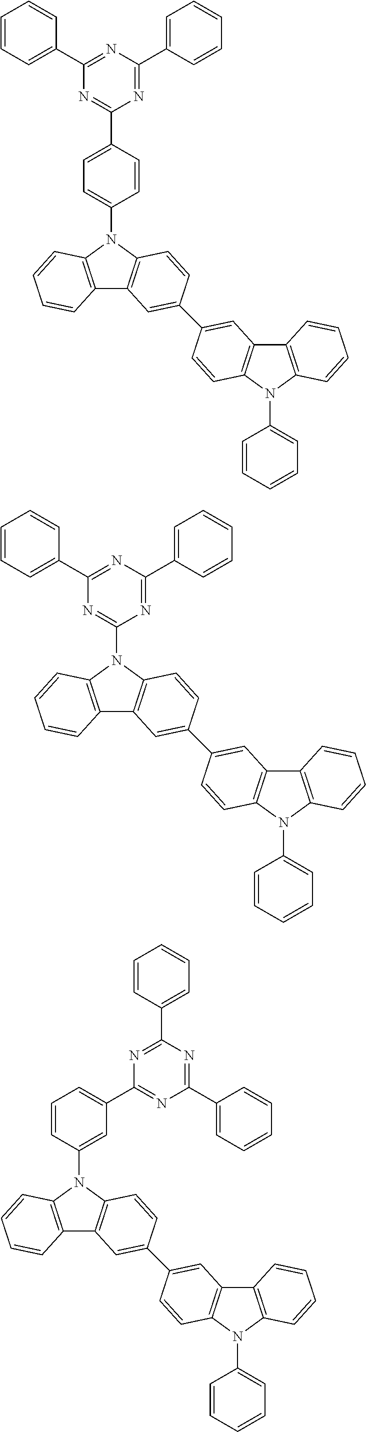 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

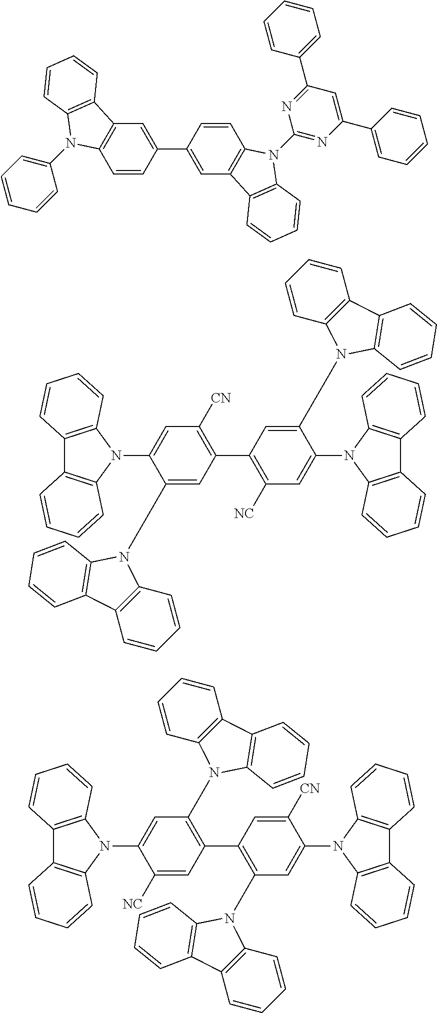

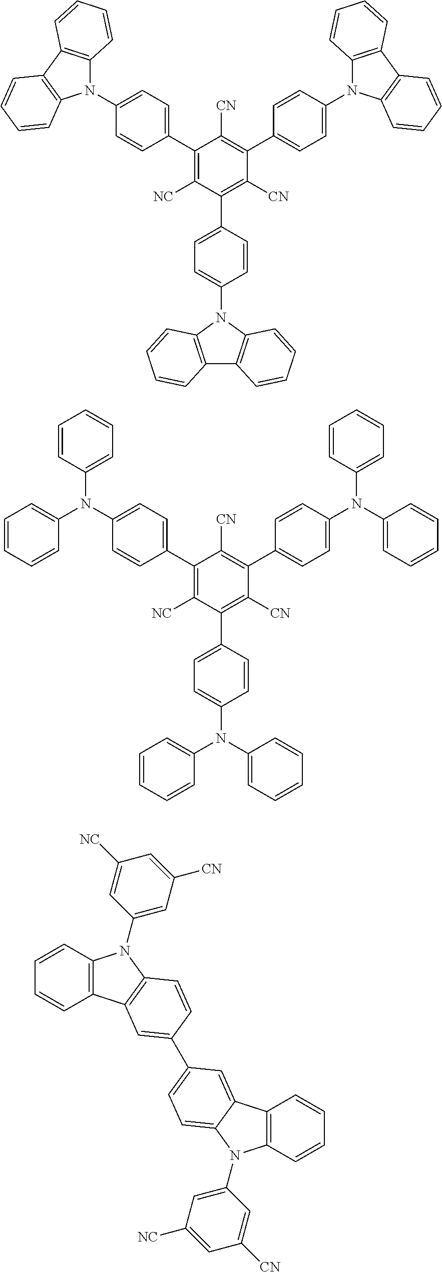 [SMILES: N#Cc1c(-c2ccc(-n3c4ccccc4c4ccccc43)cc2)c(C#N)c(-c2ccc(-n3c4ccccc4c4ccccc43)cc2)c(C#N)c1-c1ccc(-n2c3ccccc3c3ccccc32)cc1 ; N#Cc1c(-c2ccc(N(c3ccccc3)c3ccccc3)cc2)c(C#N)c(-c2ccc(N(c3ccccc3)c3ccccc3)cc2)c(C#N)c1-c1ccc(N(c2ccccc2)c2ccccc2)cc1 ; N#Cc1cc(C#N)cc(-n2c3ccccc3c3cc(-c4ccc5c(c4)c4ccccc4n5-c4cc(C#N)cc(C#N)c4)ccc32)c1]

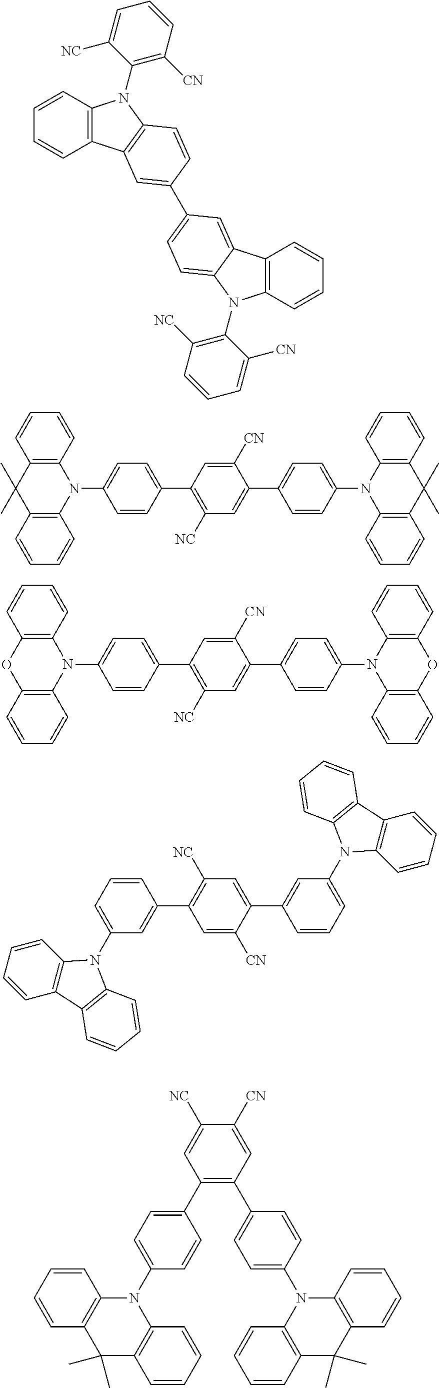

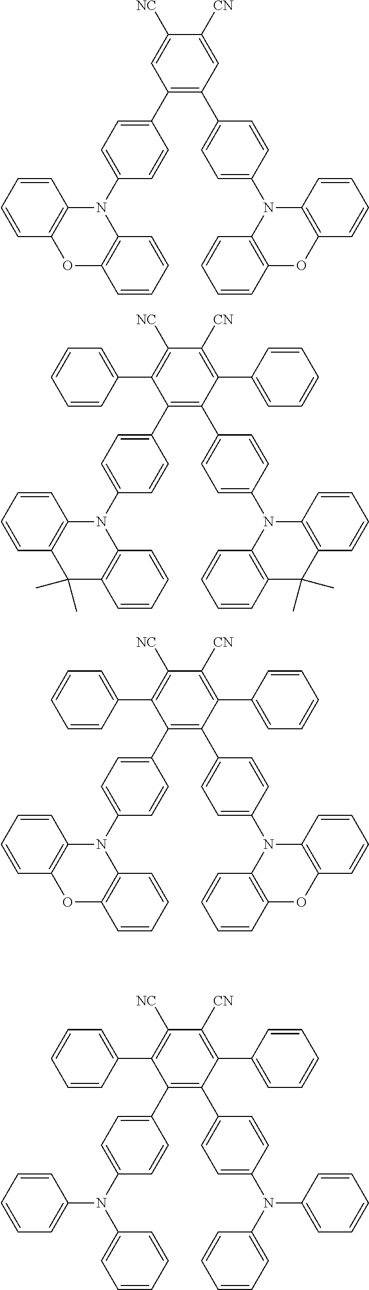

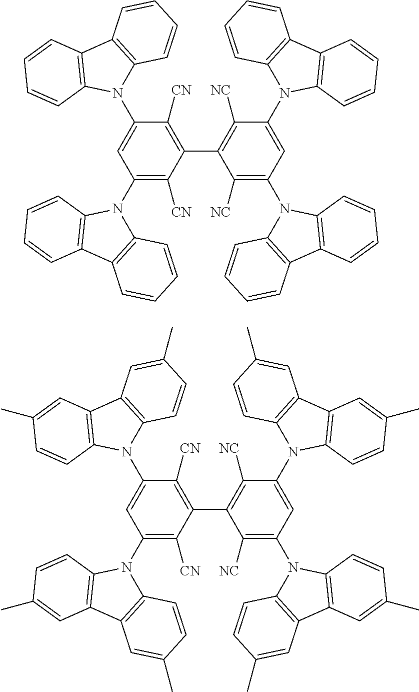

(Relationship between First Compound, Second Compound and Third Compound in Emitting Layer)

In the exemplary embodiment, the third compound is inferred to function as a dispersant that suppresses molecular association of the second compound of the exemplary embodiment in the emitting layer.

The second compound in the exemplary embodiment is a delayed fluorescent compound and thus is likely to cause molecular association. Excitation energy (singlet energy and triplet energy) of a molecule assembly is small as compared with excitation energy of a monomer. Accordingly, when a concentration of the second compound increases in a thin film, energy loss due to the molecular association is predicted.

When a blue fluorescent material with especially large excitation energy is used in the emitting layer, it is thus believed that the use of the third compound reduces the energy loss due to the above molecular association and improves the efficiency of the organic EL device. Further, when an emitting material whose emission wavelength ranges from red-emission wavelength region to yellow-emission wavelength region is used in the emitting layer, it is believed that the use of the third compound improves a carrier balance factor to enhance the efficiency of the organic EL device.

As described above, it is believed that the greatly-distorted structure of the third compound of the exemplary embodiment (see FIGS. 2A and 2B) reduces the intermolecular interaction.

The organic EL device of the exemplary embodiment contains the third compound having the above property (i.e. unlikely to cause intermolecular interaction) in the emitting layer, and thus the organic EL device is believed to be capable of efficiently trapping the triplet energy of the second compound in the emitting layer.

In the exemplary embodiment, a singlet energy S₁(M1) of the first compound, a singlet energy S₁(M2) of the second compound and a singlet energy S₁(M3) of the third compound satisfy a relationship of a numerical formula (Numerical Formula 1) below.

S₁(M3)>S₁(M2)>S₁(M1) (Numerical Formula 1).

In the exemplary embodiment, an energy gap T_{77K}(M1) at 77[K] of the first compound, an energy gap T_{77K}(M2) at 77[K] of the second compound and an energy gap T_{77K}(M3) at 77[K] of the third compound preferably satisfy a relationship of a numerical formula (Numerical Formula 4) below.

T_{77K}(M3)>T_{77K}(M2)>T_{77K}(M1) (Numerical Formula 4).

In the exemplary embodiment, a difference ΔST(M2) between the singlet energy S₁(M2) of the second compound and the energy gap T_{77K}(M2) at 77[K] of the second compound is preferably less than 0.3 eV, more preferably less than 0.2 eV, further preferably less than 0.1 eV, especially preferably 0.03 eV or less.

In the exemplary embodiment, the energy gap T_{77K}(M1) at 77[K] of the first compound, the energy gap T_{77K}(M2) at 77[K] of the second compound and the energy gap T_{77K}(M3) at 77[K] of the third compound preferably satisfy a relationship of a numerical formula (Numerical Formula 3) below.

T_{77K}(M3)>T_{77K}(M2)>T_{77K}(M1) (Numerical Formula 3).

With the energy relationship as the above, the triplet energy of the second compound (delayed fluorescent compound) can be efficiently trapped in the emitting layer.

In the exemplary embodiment, a difference ΔST(M1) between the singlet energy S₁(M1) of the first compound and the energy gap T_{77K}(M1) at 77[K] of the first compound preferably satisfies a relationship of a numerical formula (Numerical Formula 5) below.

ΔST(M1)=S₁(M1)−T_{77K}(M1)>0.3 [eV] (Numerical Formula 5)

In the exemplary embodiment, a difference ΔST(M3) between the singlet energy S₁(M3) of the third compound and the energy gap T_{77K}(M3) at 77[K] of the third compound preferably satisfies a relationship of a numerical formula (Numerical Formula 6) below.

ΔST(M3)=S₁(M3)−T_{77K}(M3)>0.3 [eV] (Numerical Formula 6)

In the exemplary embodiment, the energy gap T_{77K}(M3) at 77 [K] of the third compound is preferably 2.9 eV or more. With the energy gap T_{77K}(M3) of the third compound, it is believed that the triplet energy of the second compound (delayed fluorescent compound) can be efficiently trapped in the emitting layer.

### TADF Mechanism

In the organic EL device of the exemplary embodiment, the second compound is preferably a compound having a small ΔST(M2) so that inverse intersystem crossing from the triplet energy level of the second compound to the singlet energy level thereof is easily caused by a heat energy given from the outside. An energy state conversion mechanism to perform spin exchange from the triplet state of electrically excited excitons within the organic EL device to the singlet state by inverse intersystem crossing is referred to as TADF Mechanism.

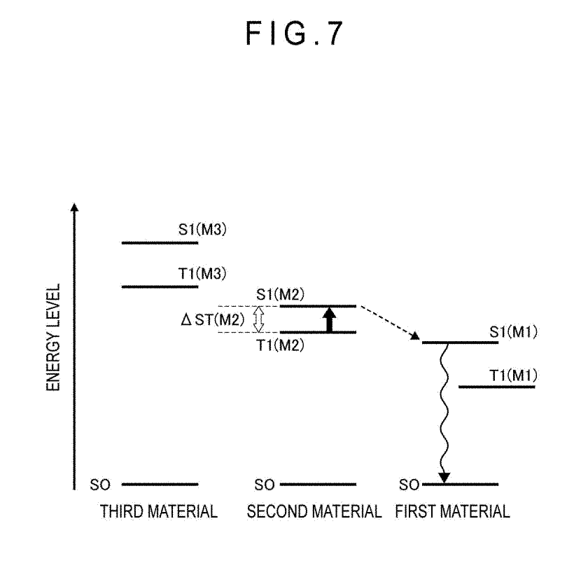

FIG. 7 shows an example of a relationship among energy levels of each of the first compound, the second compound and the third compound in the emitting layer. In FIG. 7, S0 represents a ground state, S1(M1) represents a lowest singlet state of the first compound, T1(M1) represents a lowest triplet state of the first compound, S1(M2) represents a lowest singlet state of the second compound, T1(M2) represents a lowest triplet state of the second compound, S1(M3) represents a lowest singlet state of the third compound, and T1(M3) represents a lowest triplet state of the third compound. A dashed arrow directed from S1(M2) to S1(M1) in FIG. 7 represents Förster energy transfer from the lowest singlet state of the second compound to the lowest singlet state of the first compound.

As shown in FIG. 7, when a material having a small ΔST(M2) is used as the second compound, inverse intersystem crossing from the lowest triplet state T1(M2) to the lowest singlet state S1(M2) can be caused by a heat energy. Consequently, Förster energy transfer from the lowest singlet state S1(M2) of the second compound to the lowest singlet state S1(M) of the first compound is caused. As a result, fluorescence from the lowest singlet state S1(M1) of the first compound can be observed. It is speculated that the internal quantum efficiency can be theoretically raised up to 100% also by using the delayed fluorescence by the TADF mechanism.

Relationship between Triplet Energy and Energy Gap at 77[K]

Description will be made on a relationship between a triplet energy and an energy gap at 77[K]. In the exemplary embodiment, the energy gap at 77[K] is different from a typical triplet energy in some aspects.

The triplet energy is measured as follows. Firstly, a solution in which a compound (measurement target) is dissolved in an appropriate solvent is encapsulated in a quartz glass tube to prepare a sample. A phosphorescent spectrum (ordinate axis: phosphorescent luminous intensity, abscissa axis: wavelength) of each of the samples was measured at a low temperature (77K). A tangent was drawn to the rise of the phosphorescent spectrum on the short-wavelength side. Triplet energy was calculated according to a predetermined conversion equation based on a wavelength value at an intersection of the tangent and the abscissa axis.

Herein, the delayed fluorescent compound used in the exemplary embodiment is preferably a compound having a small ΔST. When ΔST is small, intersystem crossing and inverse intersystem crossing are likely to occur even at a low temperature (77[K]), so that the singlet state and the triplet state coexist. As a result, the spectrum to be measured in the same manner as the above includes emission from both the singlet state and the triplet state. Although it is difficult to distinguish the emission from the singlet state from the emission from the triplet state, the value of the triplet energy is basically considered dominant.

Accordingly, in the exemplary embodiment, the triplet energy is measured by the same method as a typical triplet energy T, but a value measured in the following manner is referred to as an energy gap T_{77K} in order to differentiate the measured energy from the typical triplet energy in a strict meaning. The compound to be measured is dissolved in EPA (diethylether:isopentane:ethanol=5:5:2 in volume ratio) at a concentration of 10 μmol/L, and the resulting solution is set in a quartz cell to provide a measurement sample. A phosphorescent spectrum (ordinate axis: phosphorescent luminous intensity, abscissa axis: wavelength) of the sample is measured at a low temperature (77[K]). A tangent is drawn to the rise of the phosphorescent spectrum on the short-wavelength side. An energy amount is calculated as the energy gap T_{77K} at 77[K] according to a conversion equation (F1) below based on a wavelength value λ_{edge} (nm) at an intersection of the tangent and the abscissa axis.

T_{77K} [eV]=1239.8/λ_{edge} Conversion equation (F1):

The tangent to the rise of the phosphorescence spectrum on the short-wavelength side is drawn as follows. While moving on a curve of the phosphorescence spectrum from the short-wavelength side to the maximum spectral value closest to the short-wavelength side among the maximum spectral values, a tangent is checked at each point on the curve toward the long-wavelength of the phosphorescence spectrum. An inclination of the tangent is increased as the curve rises (i.e., a value of the ordinate axis was increased). A tangent drawn at a point of the maximum inclination (i.e., a tangent at an inflection point) is defined as the tangent to the rise of the phosphorescence spectrum on the short-wavelength side.

The maximum with peak intensity being 15% or less of the maximum peak intensity of the spectrum is not included in the above-mentioned maximum closest to the short-wavelength side of the spectrum. The tangent drawn at a point of the maximum spectral value being closest to the short-wavelength side and having the maximum inclination is defined as a tangent to the rise of the phosphorescence spectrum on the short-wavelength side.

For phosphorescence measurement, a spectrophotofluorometer body F-4500 (manufactured by Hitachi High-Technologies Corporation) is usable. The measurement instrument is not limited to this arrangement. A combination of a cooling unit, a low temperature container, an excitation light source and a light-receiving unit may be used for measurement.

### Singlet Energy S₁

A method of measuring a singlet energy S₁ with use of a solution (occasionally referred to as a solution method) is exemplified by a method below.

A 10 μmol/L toluene solution of a measurement target compound is prepared and put in a quartz cell. An absorption spectrum (ordinate axis: luminous intensity, abscissa axis: wavelength) of the thus-obtained sample is measured at a normal temperature (300K). A tangent is drawn to the fall of the absorption spectrum on the long-wavelength side, and a wavelength value λ_{edge} (nm) at an intersection of the tangent and the abscissa axis is assigned to a conversion equation (F2) below to calculate singlet energy.

S₁ [eV]=1239.85/λ_{edge} Conversion Equation (F2):

Any device for measuring absorption spectrum is usable. For instance, a spectrophotometer (U3310 manufactured by Hitachi, Ltd.) is usable.

The tangent to the fall of the absorption spectrum on the long-wavelength side is drawn as follows. While moving on a curve of the absorption spectrum from the maximum spectral value closest to the long-wavelength side in a long-wavelength direction, a tangent at each point on the curve is checked. An inclination of the tangent is decreased and increased in a repeated manner as the curve fell (i.e., a value of the ordinate axis is decreased). A tangent drawn at a point of the minimum inclination closest to the long-wavelength side (except when absorbance was 0.1 or less) is defined as the tangent to the fall of the absorption spectrum on the long-wavelength side.

The maximum absorbance of 0.2 or less is not included in the above-mentioned maximum absorbance on the long-wavelength side.

In the exemplary embodiment, a difference between the singlet energy S₁ and the energy gap T_{77K} at 77[K] is defined as ΔST.

### Film Thickness of Emitting Layer

A film thickness of the emitting layer of the organic EL device in the exemplary embodiment is preferably in a range of 5 nm to 50 nm, more preferably in a range of 7 nm to 50 nm, further preferably in a range of 10 nm to 50 nm. At a film thickness of 5 nm or more, formation and chromaticity adjustment of the emitting layer can be facilitated. At a film thickness of 50 nm or less, the rise in the drive voltage is likely to be restrained.

### Content Ratio of Materials in Emitting Layer

In the emitting layer of the organic EL device of the exemplary embodiment, a content ratio of the first compound is preferably in a range from 0.01 mass % to 10 mass %, a content ratio of the second compound is preferably in a range from 1 mass % to 75 mass %, a content ratio of the third compound is preferably in a range from 1 mass % to 75 mass %. An upper limit of the total of the respective content ratios of the first, second and third compounds in the emitting layer is 100 mass %. It should be noted that the exemplary embodiment does not exclude an arrangement in which a material other than the first compound, second compound and third compound is contained in the emitting layer.

The emitting layer may include a single type of the first compound or may include two or more types of the first compound. The emitting layer may include a single type of the second compound or may include two or more types of the second compound. The emitting layer may include a single type of the third compound or may include two or more types of the third compound.

### Substrate

The substrate is used as a support for the organic EL device. For instance, glass, quartz, plastics and the like are usable as the substrate. Moreover, a flexible substrate may be used. The flexible substrate means a bendable substrate. Examples of the flexible substrate include plastic substrates formed of polycarbonate, polyarylate, polyethersulfone, polypropylene, polyester, polyvinyl fluoride, polyvinyl chloride, polyimide, and polyethylene naphthalate. Moreover, an inorganic deposited film is also usable as the substrate.

### Anode

Metal having a large work function (specifically, 4.0 eV or more), an alloy, an electrically conductive compound and a mixture thereof are preferably usable as the anode formed on the substrate. Specific examples of the material include indium oxide-tin oxide (ITO: Indium Tin Oxide), indium oxide-tin oxide containing silicon or silicon oxide, indium oxide-zinc oxide, and indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metal material (e.g., titanium nitride) are usable.

The material is typically formed into a film by a sputtering method. For instance, the indium oxide-zinc oxide can be formed by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the organic layers formed on the anode, since the hole injecting layer abutting on the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

The elements belonging to the group 1 or 2 of the periodic table, which are a material having a small work function, specifically, an alkali metal such as lithium (Li) and cesium (Cs), an alkaline earth metal such as magnesium (Mg), calcium (Ca) and strontium (Sr), an alloy containing the alkali metal and the alkaline earth metal (e.g., MgAg, AlLi), a rare earth metal such as europium (Eu) and ytterbium (Yb), and an alloy containing the rare earth metal are usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

### Cathode

It is preferable to use metal, an alloy, an electroconductive compound, and a mixture thereof, which have a small work function (specifically, 3.8 eV or less) for the cathode. Examples of materials for the cathode include elements belonging to the group 1 or 2 of the periodic table, specifically, an alkali metal such as lithium (Li) and cesium (Cs), an alkaline earth metal such as magnesium (Mg), calcium (Ca) and strontium (Sr), an alloy containing the alkali metal and the alkaline earth metal (e.g., MgAg, AlLi), a rare earth metal such as europium (Eu) and ytterbium (Yb), and an alloy containing the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

### Hole Injecting Layer

The hole injecting layer is a layer containing a substance exhibiting a high hole injectability. Examples of the substance exhibiting a high hole injectability include molybdenum oxide, titanium oxide, vanadium oxide, rhenium oxide, ruthenium oxide, chrome oxide, zirconium oxide, hafnium oxide, tantalum oxide, silver oxide, tungsten oxide, and manganese oxide.

In addition, the examples of the highly hole-injectable substance further include: an aromatic amine compound, which is a low-molecule compound, such that 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl(abbreviation: DPAB), 4,4′-bis(N-{4-[N′-(3-methylphenyl)-N′-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazole-3-yl)-N-phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1); and dipyrazino[2,3-f:20,30-h]quinoxaline-2,3,6,7,10,11-hexacarbonitrile (HAT-CN).

In addition, a high polymer compound (e.g., oligomer, dendrimer and polymer) is usable as the substance exhibiting a high hole injectability. Examples of the high-molecule compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamido] (abbreviation: PTPDMA), and poly[N,N′-bis(4-butylphenyl)-N,N′-bis(phenyl)benzidine] (abbreviation: Poly-TPD). Moreover, an acid-added high polymer compound such as poly(3,4-ethylenedioxythiophene)/poly(styrene sulfonic acid) (PEDOT/PSS) and polyaniline/poly (styrene sulfonic acid)(PAni/PSS) are also usable.

### Hole Transporting Layer

The hole transporting layer is a layer containing a highly hole-transporting substance. An aromatic amine compound, carbazole derivative, anthracene derivative and the like are usable for the hole transporting layer. Specific examples of a material for the hole transporting layer include 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenylfluorene-9-yl)triphenylamine (abbreviation: BAFLP), 4,4′-bis[N-(9,9-dimethylfluorene-2-yl)-N-phenylamino]biphenyl (abbreviation: DFLDPBi), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB). The above-described substances mostly have a hole mobility of 10⁻⁶ cm²/(V·s) or more.

For the hole transporting layer, a carbazole derivative such as CBP, 9-[4-(N-carbazolyl)]phenyl-10-phenylanthracene (CzPA), and 9-phenyl-3-[4-(10-phenyl-9-anthryl)phenyl]-9H-carbazole (PCzPA) and an anthracene derivative such as t-BuDNA, DNA, and DPAnth may be used. A high polymer compound such as poly(N-vinylcarbazole) (abbreviation: PVK) and poly(4-vinyltriphenylamine) (abbreviation: PVTPA) is also usable.

However, in addition to the above substances, any substance exhibiting a higher hole transportability than an electron transportability may be used. It should be noted that the layer containing the substance exhibiting a high hole transportability may be not only a single layer but also a laminate of two or more layers formed of the above substance.

When the hole transporting layer includes two or more layers, one of the layers containing a material with a larger energy gap is preferably provided closer to the emitting layer. An example of the material with a larger energy gap is HT-2 used in later-described Examples.

### Electron Transporting Layer

The electron transporting layer is a layer containing a highly electron-transporting substance. For the electron transporting layer, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low-molecule organic compound, a metal complex such as Alq, tris(4-methyl-8-quinolinato)aluminum (abbreviation: Almq3), bis(10-hydroxybenzo[h]quinolinato)beryllium (abbreviation: BeBq2), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl)stilbene (abbreviation: BzOs) is usable. In the exemplary embodiment, a benzimidazole compound is preferably usable. The above-described substances mostly have an electron mobility of 10⁻⁶ cm²/(V·s) or more. It should be noted that any substance other than the above substance may be used for the electron transporting layer as long as the substance exhibits a higher electron transportability than the hole transportability. The electron transporting layer may be provided in the form of a single layer or a laminate of two or more layers of the above substance(s).

Moreover, a high polymer compound is usable for the electron transporting layer. For instance, poly[(9,9-dihexylfluorene-2,7-diyl)-co-(pyridine-3,5-diyl)] (abbreviation: PF-Py), poly[(9,9-dioctylfluorene-2,7-diyl)-co-(2,2′-bipyridine-6,6′-diyl)] (abbreviation: PF-BPy) and the like are usable.

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF2), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected form the anode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is usable. Further, the organic compound such as tetrathiafulvalene (abbreviation: TTF) is usable.

### Layer Formation Method(s)

A method for forming each layer of the organic EL device in the exemplary embodiment is subject to no limitation except for the above particular description. However, known methods of dry film-forming such as vacuum deposition, sputtering, plasma or ion plating and wet film-forming such as spin coating, dipping, flow coating or ink-jet are applicable.

### Film Thickness

The film thickness of each organic layer of the organic EL device in the exemplary embodiment is subject to no limitation except for the thickness particularly described above. However, the thickness is typically preferably in a range of several nanometers to 1 μm because an excessively thin film is likely to entail defects such as a pin hole while an excessively thick film requires high applied voltage and deteriorates efficiency.

### Electronic Device

An electronic device of the exemplary embodiment is provided with the organic EL device according to the exemplary embodiment. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light.

Herein, when a numerical range is represented by “a to b”, a lower limit is the value (a) and an upper limit is the value (b).

Herein, the phrase “Rx and Ry are mutually bonded to form a ring” means that Rx and Ry include a carbon atom, a nitrogen atom, an oxygen atom, a sulfur atom or a silicon atom, the atom(s) contained in Rx (a carbon atom, a nitrogen atom, an oxygen atom, a sulfur atom or a silicon atom) and the atom(s) contained in Ry (a carbon atom, a nitrogen atom, an oxygen atom, a sulfur atom or a silicon atom) are bonded via a single bond(s), a double bond(s), a triple bond, and/or a divalent linking group(s) to form a ring having 5 or more ring carbon atoms (specifically, a heterocycle or an aromatic hydrocarbon ring). x represents a numeral(s), a character(s) or a combination of a numeral(s) and character(s). y represents a numeral(s), a character(s) or a combination of a numeral(s) and character(s).

The divalent linking group is not limited. Examples of the divalent linking group include —O—, —CO—, —CO₂—, —S—, —SO—, —SO₂—, —NH—, —NRa—, and a group provided by a combination of two or more of these linking group.

Specific examples of the heterocycle include cyclic structures (heterocycles) provided by removing a bond from the “heteroaryl group having ring 5 to 30 ring atoms” exemplified in later-described “Description of Substituents in the Formula of First Compound and Second Compound.” These heterocycles may each have a substituent.

Specific examples of the aromatic hydrocarbon group include a cyclic structure (aromatic hydrocarbon ring) provided by removing a bond from the “aryl group having ring 6 to 30 ring carbon atoms” exemplified in later-described “Description of Substituents in the Formula of First Compound and Second Compound.” These aromatic hydrocarbon rings may each have a substituent.

Examples of Ra include a substituted or unsubstituted alkyl group having 1 to 30 carbon atoms, a substituted or unsubstituted aryl group having 6 to 30 ring carbon atoms, and a substituted or unsubstituted heteroaryl group having 5 to 30 ring atoms.

For instance, when “Rx and Ry are mutually bonded to form a ring,” an atom(s) contained in Rx₁ and an atom(s) contained in Ry₁ in a molecular structure represented by a formula (E1) below form a ring (cyclic structure) E represented by a formula (E2); an atom(s) contained in Rx₁ and an atom(s) contained in Ry₁ in a molecular structure represented by a formula (F1) below form a ring (cyclic structure) F represented by a formula (F2); an atom(s) contained in Rx₁ and an atom(s) contained in Ry₁ in a molecular structure represented by a formula (G1) below form a ring (cyclic structure) G represented by a formula (G2); an atom(s) contained in Rx₁ and an atom(s) contained in Ry₁ in a molecular structure represented by a formula (H1) below form a ring (cyclic structure) H represented by a formula (H2); or an atom(s) contained in Rx₁ and an atom(s) contained in Ry₁ in a molecular structure represented by a formula (11) below form a ring (cyclic structure) I represented by a formula (12).

In the formulae (El) to (11), * each independently represent a bonding position to another atom in a molecule. The two * in the formulae (E1), (F1), (G1), (H1) and (I1) correspond to two * in the formula (E2), (F2), (G2), (H2) and (I2), respectively.

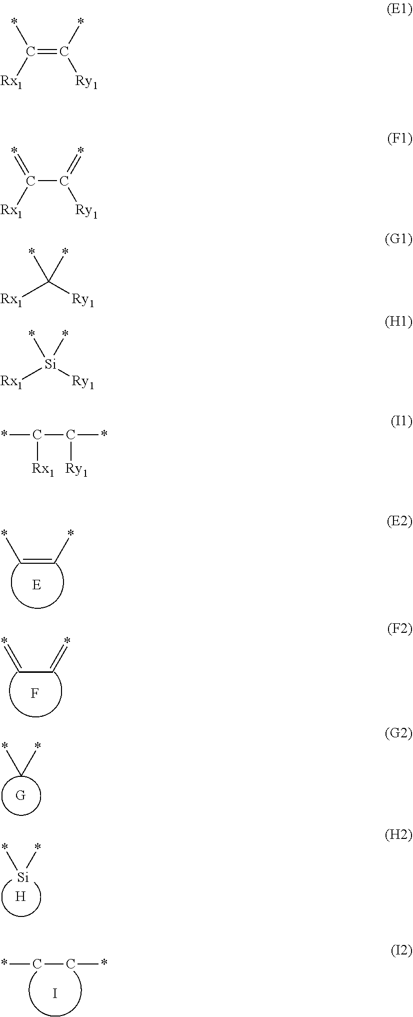

In the molecular structures represented by the formulae (E2) to (I2), E to I each represent a cyclic structure (the ring having 5 or more ring atoms). In the formulae (E2) to (I2), * each independently represent a bonding position to another atom in a molecule. The two * in the formula (E2) correspond to two * in the formula (E1). The two * in the formulae (F2) to (I2) correspond to two * in the formulae (F1) to (I1).

For instance, when Rx₁ and Ry₁ in the formula (E1) are mutually bonded to form the ring E according to the formula (E2) and the ring E is an unsubstituted benzene ring, the molecular structure represented by the formula (E1) is a molecular structure represented by a formula (E3) below. The two * in the formula (E3) correspond to two * in the formulae (E2) and (E1).

For instance, when Rx₁ and Ry₁ in the formula (E1) are mutually bonded to form the ring E according to the formula (E2) and the ring E is an unsubstituted pyrrole ring, the molecular structure represented by the formula (E1) is a molecular structure represented by a formula (E4) below. The two * in the formula (E4) correspond to two * in the formulae (E2) and (E1). In the formulae (E3) and (E4), * each independently represent a bonding position to another atom in a molecule.

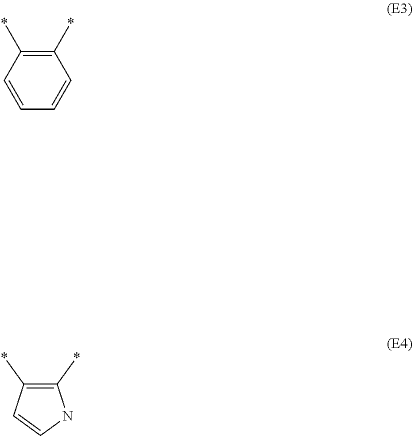 [SMILES: *c1ccccc1* ; *c1cc[nH]c1*]

Herein, the ring carbon atoms refer to the number of carbon atoms among atoms forming a ring of a compound (e.g., a monocyclic compound, fused-ring compound, crosslinking compound, carbon ring compound, and heterocyclic compound) in which the atoms are bonded to each other to form the ring. When the ring is substituted by a substituent(s), carbon atom(s) contained in the substituent(s) is not counted in the ring carbon atoms. Unless specifically described, the same applies to the “ring carbon atoms” described later. For instance, a benzene ring has 6 ring carbon atoms, a naphthalene ring has 10 ring carbon atoms, a pyridinyl group has 5 ring carbon atoms, and a furanyl group has 4 ring carbon atoms. When a benzene ring and/or a naphthalene ring is substituted by a substituent (e.g., an alkyl group), the number of carbon atoms of the alkyl group is not counted in the number of the ring carbon atoms. When a fluorene ring is substituted by a substituent (e.g., a fluorene ring) (i.e., a spirofluorene ring is included), the number of carbon atoms of the fluorene ring as the substituent is not counted in the number of the ring carbon atoms of the fluorene ring.

Herein, the ring atoms refer to the number of atoms forming a ring of a compound (e.g., a monocyclic compound, fused-ring compound, crosslinking compound, carbon ring compound, and heterocyclic compound) in which the atoms are bonded to each other to form the ring (e.g., monocyclic ring, fused ring, ring assembly). Atom(s) not forming a ring and atom(s) included in a substituent when the ring is substituted by the substituent are not counted in the number of the ring atoms. Unless specifically described, the same applies to the “ring atoms” described later. For instance, a pyridine ring has six ring atoms, a quinazoline ring has ten ring atoms, and a furan ring has five ring atoms. A hydrogen atom(s) and/or an atom(s) of a substituent which are bonded to carbon atoms of a pyridine ring and/or quinazoline ring are not counted in the ring atoms. When a fluorene ring is substituted by a substituent (e.g., a fluorene ring) (i.e., a spirofluorene ring is included), the number of atoms of the fluorene ring as the substituent is not counted in the number of the ring atoms of the fluorene ring.

### Description of Substituents in the Formula of First Compound and Second Compound (Description of the Substituents)”

Examples of the aryl group having 6 to 30 ring carbon atoms (occasionally referred to as an aromatic hydrocarbon group) in the exemplary embodiment are a phenyl group, biphenyl group, terphenyl group, naphthyl group, anthryl group, phenanthryl group, fluorenyl group, pyrenyl group, chrysenyl group, fluoranthenyl group, benz[a]anthryl group, benzo[c]phenanthryl group, triphenylenyl group, benzo[k]fluoranthenyl group, benzo[g]chrysenyl group, benzo[b]triphenylenyl group, picenyl group, and perylenyl group.

Herein, the aryl group preferably has 6 to 20 ring carbon atoms, more preferably 6 to 14 ring carbon atoms, further preferably 6 to 12 ring carbon atoms. Among the aryl group, a phenyl group, biphenyl group, naphthyl group, phenanthryl group, terphenyl group and fluorenyl group are particularly preferable. A carbon atom in a position 9 of each of 1-fluorenyl group, 2-fluorenyl group, 3-fluorenyl group and 4-fluorenyl group is preferably substituted by a substituted or unsubstituted alkyl group having 1 to 30 carbon atoms or a substituted or unsubstituted aryl group having 6 to 18 ring carbon atoms described later herein.

The heteroaryl group (occasionally referred to as heterocyclic group, heteroaromatic ring group or aromatic heterocyclic group) having 5 to 30 ring atoms herein preferably contains at least one atom selected from the group consisting of nitrogen, sulfur, oxygen, silicon, selenium atom and germanium atom, and more preferably contains at least one atom selected from the group consisting of nitrogen, sulfur and oxygen.

Examples of the heterocyclic group having 5 to 30 ring atoms in the exemplary embodiment are a pyridyl group, pyrimidinyl group, pyrazinyl group, pyridazynyl group, triazinyl group, quinolyl group, isoquinolinyl group, naphthyridinyl group, phthalazinyl group, quinoxalinyl group, quinazolinyl group, phenanthirdinyl group, acridinyl group, phenanthrolinyl group, pyrrolyl group, imidazolyl group, pyrazolyl group, triazolyl group, tetrazolyl group, indolyl group, benzimidazolyl group, indazolyl group, imidazopyridinyl group, benzotriazolyl group, carbazolyl group, furyl group, thienyl group, oxazolyl group, thiazolyl group, isoxazolyl group, isothiazolyl group, oxadiazolyl group, thiadiazolyl group, benzofuranyl group, benzothienyl group, benzoxazolyl group, benzothiazolyl group, benzisoxazolyl group, benzisothiazolyl group, benzoxadiazolyl group, benzothiadiazolyl group, dibenzofuranyl group, dibenzothienyl group, piperidinyl group, pyrrolidinyl group, piperazinyl group, morpholyl group, phenazinyl group, phenothiazinyl group, and phenoxazinyl group.

Herein, the heterocyclic group preferably has 5 to 20 ring atoms, more preferably 5 to 14 ring atoms. Among the above heterocyclic group, a 1-dibenzofuranyl group, 2-dibenzofuranyl group, 3-dibenzofuranyl group, 4-dibenzofuranyl group, 1-dibenzothienyl group, 2-dibenzothienyl group, 3-dibenzothienyl group, 4-dibenzothienyl group, 1-carbazolyl group, 2-carbazolyl group, 3-carbazolyl group, 4-carbazolyl group, and 9-carbazolyl group are further preferable. A nitrogen atom in position 9 of 1-carbazolyl group, 2-carbazolyl group, 3-carbazolyl group and 4-carbazolyl group is preferably substituted by the substituted or unsubstituted aryl group having 6 to 30 ring carbon atoms or the substituted or unsubstituted heterocyclic group having 5 to 30 ring atoms described herein.

Herein, the heterocyclic group may be a group derived from any one of moieties represented by formulae (XY-1) to (XY-18) below.

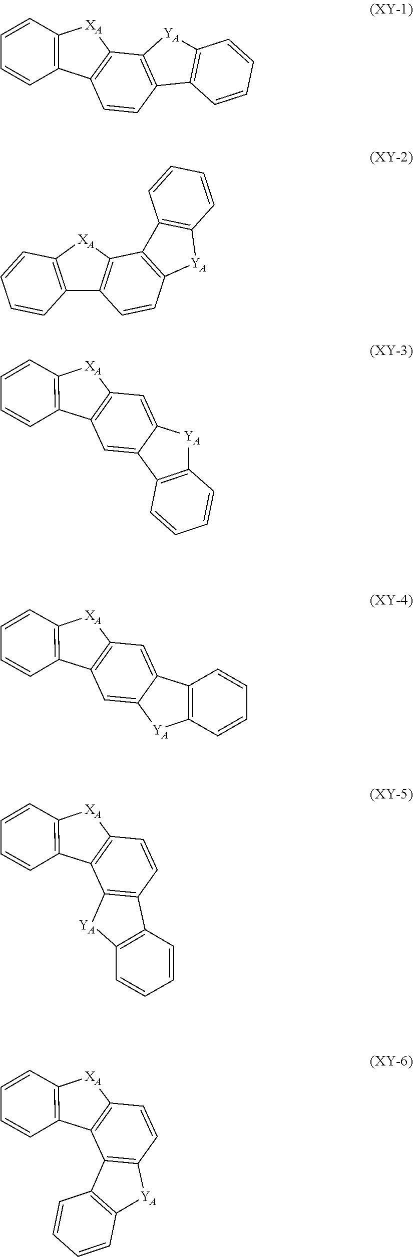

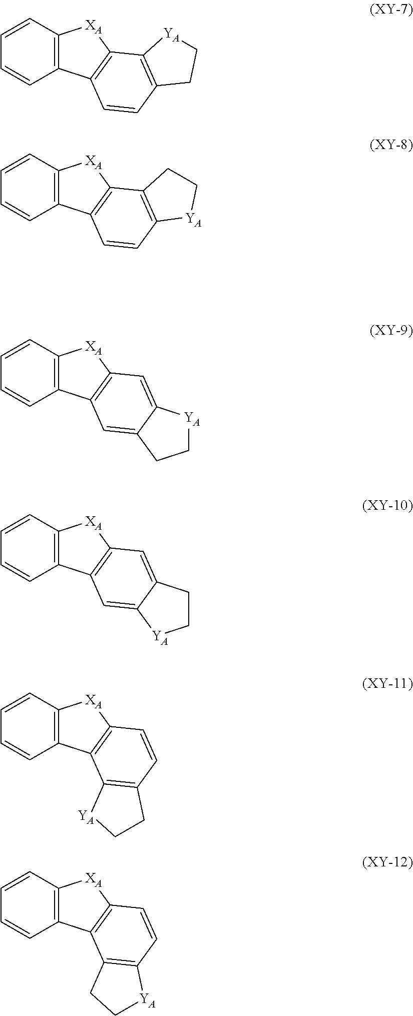

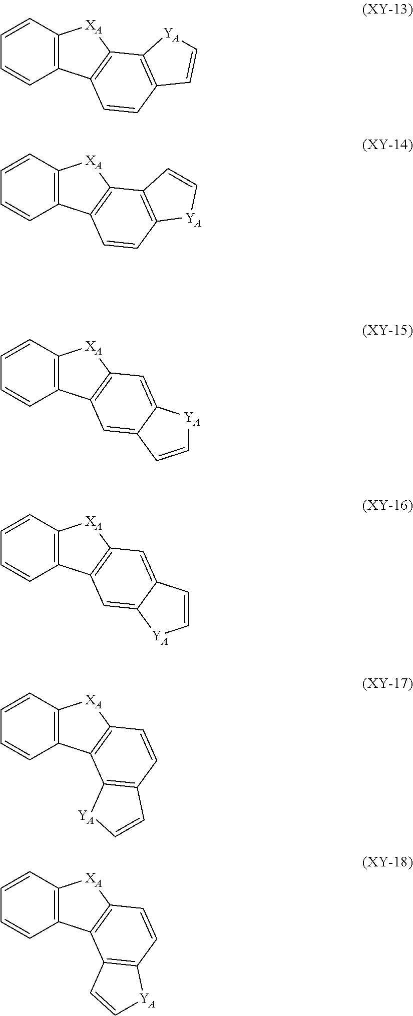

In the formulae (XY-1) to (XY-18), X_{A} and Y_{A} each independently represent a hetero atom, and preferably represent an oxygen atom, sulfur atom, selenium atom, silicon atom or germanium atom. Each of the moieties represented by the respective formulae (XY-1) to (XY-18) has a bond at any position to provide a heterocyclic group. The heterocyclic group may be substituted. Herein, examples of the substituted or unsubstituted carbazolyl group may include a group in which a carbazole ring is further fused with a ring(s) as shown in the following formulae (XY-19) to (XY-22). Such a group may have a substituent. Moreover, the position of the bond may be changed as needed

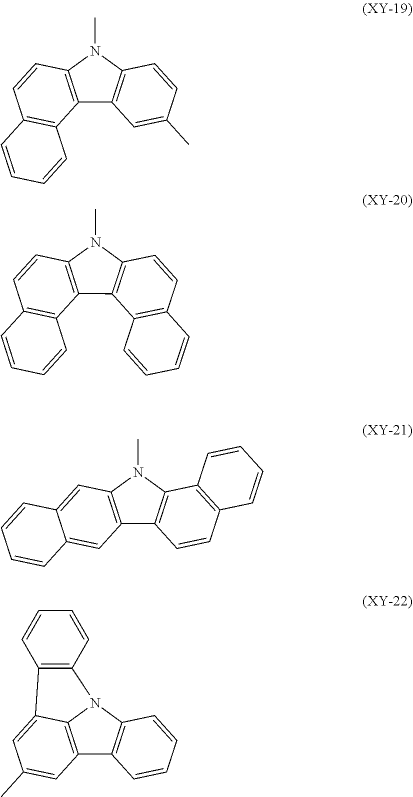

The alkyl group having 1 to 30 carbon atoms herein may be linear, branched or cyclic. Also, the alkyl group may be an alkyl halide group.

Examples of the linear or branched alkyl group include: a methyl group, ethyl group, n-propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neopentyl group, amyl group, isoamyl group, 1-methylpentyl group, 2-methylpentyl group, 1-pentylhexyl group, 1-butylpentyl group, 1-heptyloctyl group, and 3-methylpentyl group.

Herein, the linear or branched alkyl group preferably has 1 to 10 carbon atoms, more preferably 1 to 6 carbon atoms. Among the linear or branched alkyl group, a methyl group, ethyl group, propyl group, isopropyl group, n-butyl group, s-butyl group, isobutyl group, t-butyl group, n-pentyl group, n-hexyl group, amyl group, isoamyl group and neopentyl group are preferable.

Herein, examples of the cyclic alkyl group include a cycloalkyl group having 3 to 30 ring carbon atoms.

Examples of the cycloalkyl group having 3 to 30 ring carbon atoms herein are a cyclopropyl group, cyclobutyl group, cyclopentyl group, cyclohexyl group, 4-metylcyclohexyl group, adamantyl group and norbornyl group. The cycloalkyl group preferably has 3 to 10 ring carbon atoms, more preferably 5 to 8 ring carbon atoms. Among the cycloalkyl group, a cyclopentyl group and a cyclohexyl group are more preferable.

Herein, the alkyl halide group provided by substituting the alkyl group with a halogen atom is exemplified by an alkyl halide group provided by substituting the alkyl group having 1 to 30 carbon atoms with at least one halogen atom, preferably at least one fluorine atom.

Herein, examples of the alkyl halide group having 1 to 30 carbon atoms include a fluoromethyl group, difluoromethyl group, trifluoromethyl group, fluoroethyl group, trifluoromethylmethyl group, trifluoroethyl group, and pentafluoroethyl group.

Herein, examples of a substituted silyl group include an alkylsilyl group having 3 to 30 carbon atoms and an arylsilyl group having 6 to 30 ring carbon atoms.

Herein, the alkylsilyl group having 3 to 30 carbon atoms is exemplified by a trialkylsilyl group having the above examples of the alkyl group having 1 to 30 carbon atoms. Specific examples of the alkylsilyl group are a trimethylsilyl group, triethylsilyl group, tri-n-butylsilyl group, tri-n-octylsilyl group, triisobutylsilyl group, dimethylethylsilyl group, dimethylisopropylsilyl group, dimethyl-n-propylsilyl group, dimethyl-n-butylsilyl group, dimethyl-t-butylsilyl group, diethylisopropylsilyl group, vinyl dimethylsilyl group, propyldimethylsilyl group, and triisopropylsilyl group. Three alkyl groups in the trialkylsilyl group may be mutually the same or different.

Herein, examples of the arylsilyl group having 6 to 30 ring carbon atoms include a dialkylarylsilyl group, alkyldiarylsilyl group and triarylsilyl group.

The dialkylarylsilyl group is exemplified by a dialkylarylsilyl group including two of the alkyl groups listed as the examples of the alkyl group having 1 to 30 carbon atoms and one of the aryl groups listed as the examples of the aryl group having 6 to 30 ring carbon atoms. The dialkylarylsilyl group preferably has 8 to 30 carbon atoms.

The alkyldiarylsilyl group is exemplified by an alkyldiarylsilyl group including one of the alkyl groups listed as the examples of the alkyl group having 1 to 30 carbon atoms and two of the aryl groups listed as the examples of the aryl group having 6 to 30 ring carbon atoms. The alkyldiarylsilyl group preferably has 13 to 30 carbon atoms.

The triarylsilyl group is exemplified by a triarylsilyl group including three of the aryl group listed as the examples of the aryl group having 6 to 30 ring carbon atoms. The triarylsilyl group preferably has 18 to 30 carbon atoms.

Herein, the alkyl sulfonyl group is represented by —SO₂R_{w}, where R_{w} represents a substituted or unsubstituted alkyl group.

Examples of the substituted or unsubstituted alkylsulfonyl group having 1 to 30 carbon atoms herein include a group represented by the above —SO₂R_{w}, where R_{w} is substituted or unsubstituted alkyl group having 1 to 30 carbon atoms.

Herein, an aryl group in an aralkyl group (occasionally referred to as an arylalkyl group) is an aromatic hydrocarbon group or a heterocyclic group. The aralkyl group having 7 to 30 carbon atoms herein is preferably a group having an aryl group having 6 to 30 ring carbon atoms and is represented by —Z₃—Z₄. Z₃ is exemplified by an alkylene group corresponding to the above alkyl group having 1 to 30 carbon atoms. Z₄ is exemplified by the above aryl group having 6 to 30 ring carbon atoms. In this aralkyl group, an aryl moiety has 6 to 30 carbon atoms, preferably 6 to 20 carbon atoms, more preferably 6 to 12 carbon atoms and an alkyl moiety has 1 to 30 carbon atoms, preferably 1 to 20 carbon atoms, more preferably 1 to 10 carbon atoms, further preferably 1 to 6 carbon atoms. Examples of the aralkyl group are a benzyl group, 2-phenylpropane-2-yl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

The alkoxy group having 1 to 30 carbon atoms herein is represented by —OZ₁. Z₁ is exemplified by the above alkyl group having 1 to 30 carbon atoms. Examples of the alkoxy group include a methoxy group, ethoxy group, propoxy group, butoxy group, pentyloxy group and hexyloxy group. The alkoxy group preferably has 1 to 20 carbon atoms.

A halogenated alkoxy group provided by substituting an alkoxy group with a halogen atom is exemplified by one provided by substituting an alkoxy group having 1 to 30 carbon atoms with one or more fluorine atoms.

Herein, examples of an aryl group in an aryloxy group (occasionally referred to as an arylalkoxy group) include a heteroaryl group.

The arylalkoxy group having 6 to 30 ring carbon atoms herein is represented by —OZ₂. Z₂ is exemplified by the above aryl group having 6 to 30 ring carbon atoms. The arylalkoxy group preferably has 6 to 20 ring carbon atoms. The arylalkoxy group is exemplified by a phenoxy group.

Herein, the substituted amino group is represented by —NHR_{V} or —N(R_{V})₂. R_{V} is exemplified by the above alkyl group having 1 to 30 carbon atoms or aryl group having 6 to 30 ring carbon atoms.

Herein, the alkenyl group having 2 to 30 carbon atoms is linear or branched. Examples of the alkenyl group include a vinyl group, propenyl group, butenyl group, oleyl group, eicosapentaenyl group, docosahexaenyl group, styryl group, 2,2-diphenylvinyl group, 1,2,2-triphenylvinyl group, and 2-phenyl-2-propenyl group.

The alkynyl group having 2 to 30 carbon atoms herein may be linear or branched. Examples of the alkynyl group having 2 to 30 carbon atoms are an ethynyl group, a propynyl group and a 2-phenylethynyl group.

Herein, the alkylthio group having 1 to 30 ring carbon atoms and the arylthio group having 6 to 30 ring carbon atoms are represented by —SR_{V}. R_{V} is exemplified by the above alkyl group having 1 to 30 carbon atoms or the aryl group having 6 to 30 ring carbon atoms. The alkylthio group preferably has 1 to 20 carbon atoms. The arylthio group preferably has 6 to 20 ring carbon atoms.

Herein, examples of the halogen atom include a fluorine atom, a chlorine atom, a bromine atom and an iodine atom, among which a fluorine atom is preferable.

Herein, the substituted phosphanyl group is exemplified by a phenyl phosphanyl group.

Herein, the arylcarbonyl group having 6 to 30 ring carbon atoms is represented by —COY′. Y′ is exemplified by the above “aryl group having 6 to 30 ring carbon atoms.” Herein, examples of the arylcarbonyl group having 6 to 30 ring carbon atoms include a phenyl carbonyl group, diphenyl carbonyl group, naphthyl carbonyl group, and triphenyl carbonyl group.

The acyl group having 2 to 31 carbon atoms herein is represented by —COR′. R′ is exemplified by the above alkyl group having 1 to 30 carbon atoms. Herein, the acyl group having 2 to 31 carbon atoms is exemplified by an acetyl group and a propionyl group.

Herein, the substituted phosphoryl group is represented by a formula (P) below.

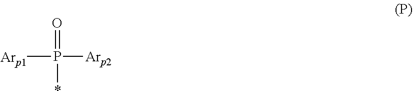

In the formula (P), examples of Ar_{P1} and Ar_{P2} include a substituent selected from the group consisting of an alkyl group having 1 to 30 (preferably 1 to 10, more preferably 1 to 6 carbon atoms), and an aryl group having 6 to 30 ring carbon atoms (preferably 6 to 20, more preferably 6 to 14 ring carbon atoms). The alkyl group having 1 to 30 carbon atoms is exemplified by the above alkyl groups having 1 to 30 carbon atoms. The aryl group having 6 to 30 ring carbon atoms is exemplified by the above aryl groups having 6 to 30 ring carbon atoms.

Herein, “carbon atoms forming a ring (ring carbon atoms)” mean carbon atoms forming a saturated ring, unsaturated ring, or aromatic ring. “Atoms forming a ring (ring atoms)” mean carbon atoms and hetero atoms forming a ring including a saturated ring, unsaturated ring, or aromatic ring.

Herein, a hydrogen atom includes isotope having different numbers of neutrons, specifically, protium, deuterium and tritium.

Herein, the substituent meant by “substituted or unsubstituted” is at least one group selected from the group consisting of an aryl group having 6 to 30 ring carbon atoms, heteroaryl group having 5 to 30 ring atoms, linear alkyl group having 1 to 30 carbon atoms, branched alkyl group having 3 to 30 carbon atoms, cycloalkyl group having 3 to 30 ring carbon atoms, alkyl halide group having 1 to 30 carbon atoms, alkylsilyl group having 3 to 30 carbon atoms, arylsilyl group having 6 to 30 ring carbon atoms, alkoxy group having 1 to 30 carbon atoms, aryloxy group having 6 to 30 carbon atoms, substituted amino group, alkylthio group having 1 to 30 carbon atoms, arylthio group having 6 to 30 ring carbon atoms, aralkyl group having 7 to 30 carbon atoms, alkenyl group having 2 to 30 carbon atoms, halogen atom, alkynyl group having 2 to 30 carbon atoms, cyano group, hydroxyl group, nitro group, and carboxy group.

Specific examples and preferable examples of the substituent meant by “substituted or unsubstituted” include the specific examples and preferable examples of the substituents in the “description of the substituents.”

Herein, the substituent meant by “substituted or unsubstituted” is preferably at least one group selected from the group consisting of an aryl group having 6 to 30 ring carbon atoms, heteroaryl group having 5 to 30 ring atoms, linear alkyl group having 1 to 30 carbon atoms, branched alkyl group having 3 to 30 carbon atoms, halogen atom, and cyano group, further preferably the specific preferable examples described in the description of the substituents.

Herein, the substituent meant by “substituted or unsubstituted” is more preferably at least one group selected from the group consisting of an aryl group having 6 to 30 ring carbon atoms, heteroaryl group having 5 to 30 ring atoms, linear alkyl group having 1 to 30 carbon atoms, branched alkyl group having 3 to 30 carbon atoms, halogen atom, and cyano group, further preferably the specific preferable examples described in the description of the substituents.

Herein, the substituent meant by “substituted or unsubstituted” may be further substituted by at least one group selected from the group consisting of an aryl group having 6 to 30 ring carbon atoms, heteroaryl group having 5 to 30 ring atoms, linear alkyl group having 1 to 30 carbon atoms, branched alkyl group having 3 to 30 carbon atoms, cycloalkyl group having 3 to 30 ring carbon atoms, alkyl halide group having 1 to 30 carbon atoms, alkylsilyl group having 3 to 30 carbon atoms, arylsilyl group having 6 to 30 ring carbon atoms, alkoxy group having 1 to 30 carbon atoms, aryloxy group having 6 to 30 carbon atoms, substituted amino group, alkylthio group having 1 to 30 carbon atoms, arylthio group having 6 to 30 ring carbon atoms, aralkyl group having 7 to 30 carbon atoms, alkenyl group having 2 to 30 carbon atoms, alkynyl group having 2 to 30 carbon atoms, halogen atom, cyano group, hydroxyl group, nitro group, and carboxy group. In addition, adjacent two or more of the substituents may be bonded to each other to form a ring.

Herein, the substituent for the substituent meant by the description of “substituted or unsubstituted” is preferably at least one group selected from the group consisting of an aryl group having 6 to 30 ring carbon atoms, heteroaryl group having 5 to 30 ring atoms, a linear alkyl group having 1 to 30 carbon atoms, a branched alkyl group having 3 to 30 carbon atoms, halogen atom, and cyano group, further preferably selected from the specific preferable examples of each of the substituents in the description.

Herein, the substituent for the substituent meant by the description of “substituted or unsubstituted” is preferably at least one group selected from the group consisting of an aryl group having 6 to 30 ring carbon atoms, heteroaryl group having 5 to 30 ring atoms, a linear alkyl group having 1 to 30 carbon atoms, a branched alkyl group having 3 to 30 carbon atoms, halogen atom, and cyano group, further preferably the preferable examples of each of the substituents in the description.

“Unsubstituted” in “substituted or unsubstituted” means that a group is not substituted by the above-described substituents but bonded with a hydrogen atom.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group.

Herein, “XX to YY atoms” in the description of “substituted or unsubstituted ZZ group having XX to YY atoms” represent atoms of an unsubstituted ZZ group and does not include atoms of a substituent(s) of the substituted ZZ group.

The same description as the above applies to “substituted or unsubstituted” in compounds or moieties thereof described herein.

Herein, when the substituents are bonded to each other to form a ring, the ring is structured to be a saturated ring, an unsaturated ring, an aromatic hydrocarbon ring or a hetero ring.

Herein, examples of the aromatic hydrocarbon group and the heterocyclic group in the linking group include a divalent or multivalent group obtained by eliminating one or more atoms from the above monovalent groups.

### Modification of Embodiment(s)

It should be noted that the invention is not limited to the above exemplary embodiments but may include any modification and improvement as long as such modification and improvement are compatible with the invention.

For instance, the emitting layer is not limited to a single layer, but may be provided by laminating a plurality of emitting layers. When the organic EL device has a plurality of emitting layers, it is only required that at least one of the emitting layers satisfies the conditions described in the above exemplary embodiment. For instance, the rest of the emitting layers may be a fluorescent emitting layer or a phosphorescent emitting layer with use of emission caused by electron transfer from the triplet excited state directly to the ground state.

When the organic EL device includes the plurality of emitting layers, the plurality of emitting layers may be adjacent to each other, or provide a so-called tandem-type organic EL device in which a plurality of emitting units are layered through an intermediate layer.

For instance, a blocking layer may be provided adjacent to at least one side of a side near the anode and a side near the cathode of the emitting layer. The blocking layer is preferably provided in contact with the emitting layer to at least block holes, electrons or excitons.

For instance, when the blocking layer is provided in contact with the cathode-side of the emitting layer, the blocking layer permits transport of electrons, but blocks holes from reaching a layer provided near the cathode (e.g., the electron transporting layer) beyond the blocking layer. When the organic EL device includes the electron transporting layer, the organic EL device preferably includes the blocking layer between the emitting layer and the electron transporting layer.

When the blocking layer is provided in contact with the anode-side of the emitting layer, the blocking layer permits transport of holes, but blocks electrons from reaching a layer provided near the anode (e.g., the hole transporting layer) beyond the blocking layer. When the organic EL device includes the hole transporting layer, the organic EL device preferably includes the blocking layer between the emitting layer and the hole transporting layer.

Moreover, the blocking layer may abut on the emitting layer so that excited energy does not leak out from the emitting layer toward neighboring layer(s). Accordingly, the blocking layer blocks excitons generated in the emitting layer from transferring to a layer(s) (e.g., the electron transporting layer and the hole transporting layer) closer to the electrode(s) beyond the blocking layer.

The emitting layer and the blocking layer preferably abut on each other.

Specific structure and shape of the components in the present invention may be designed in any manner as long as the object of the present invention can be achieved.

### EXAMPLES

Example(s) of the invention will be described below. However, the invention is not limited to Example(s).

### Compounds

Compounds used for manufacturing an organic EL device will be shown below.

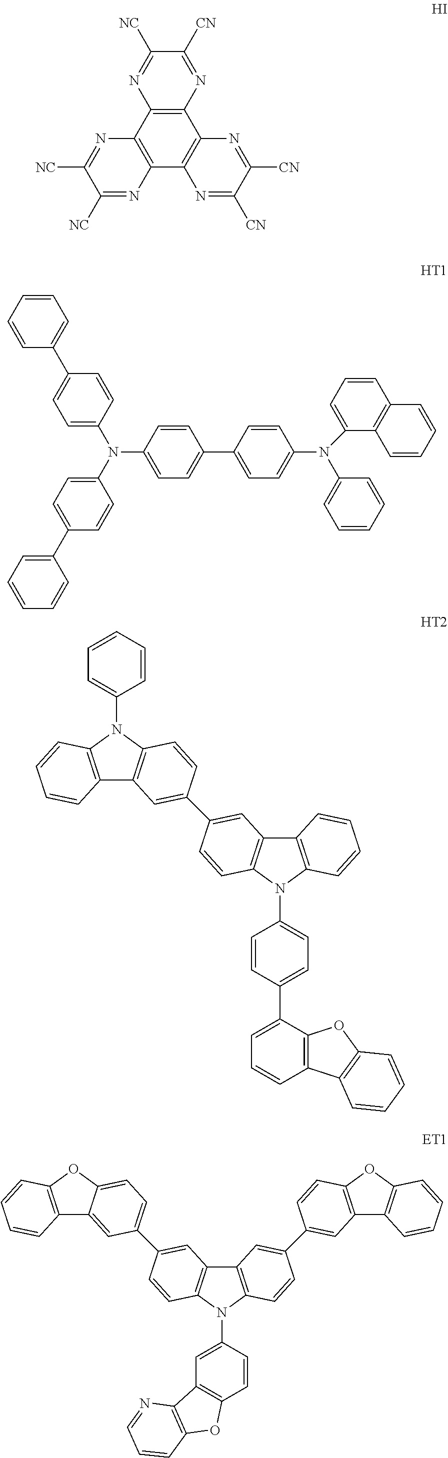 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-n2c3ccccc3c3cc(-c4ccc5c(c4)c4ccccc4n5-c4ccc(-c5cccc6c5oc5ccccc56)cc4)ccc32)cc1 ; c1ccc2c(c1)oc1ccc(-c3ccc4c(c3)c3cc(-c5ccc6oc7ccccc7c6c5)ccc3n4-c3ccc4oc5cccnc5c4c3)cc12]

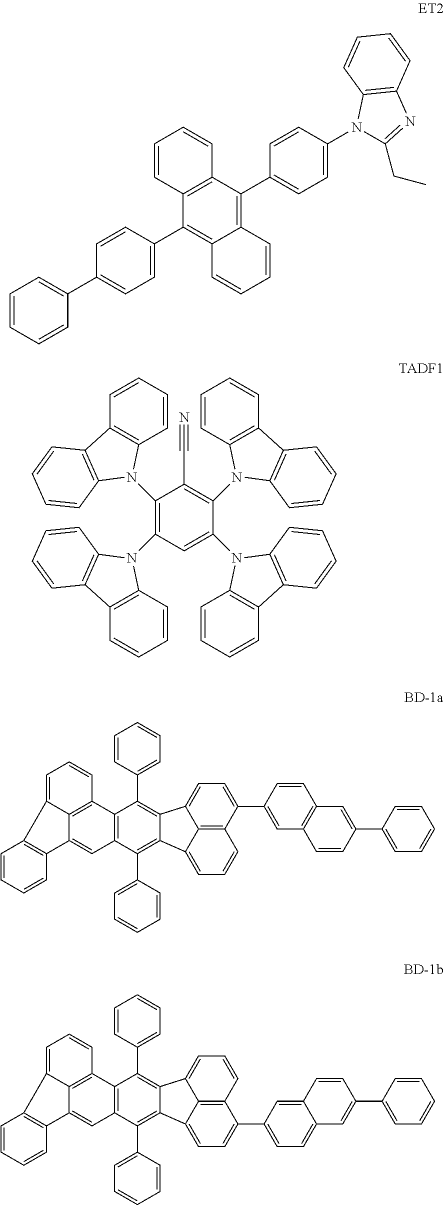

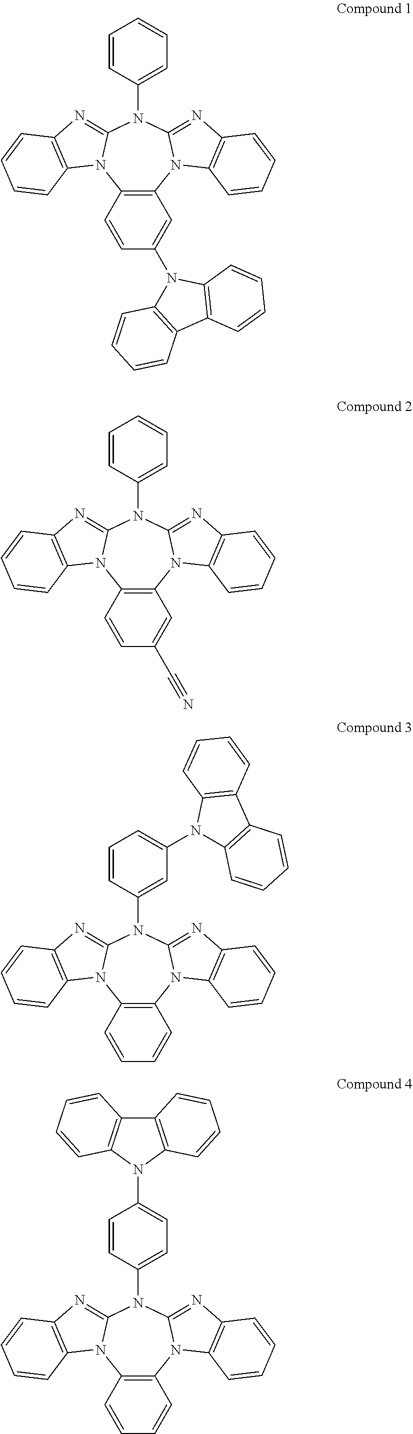

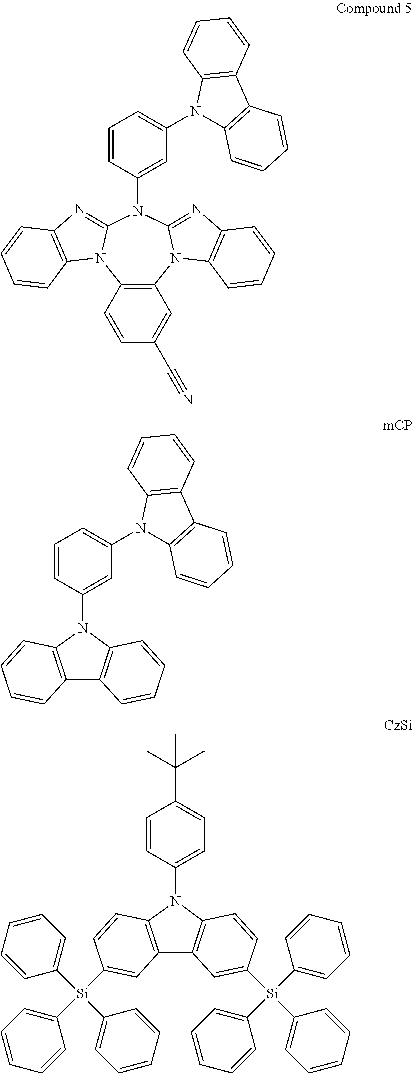

### Synthesis of Compound(s)

### (1) Synthesis Example 1: Synthesis of Compound 1

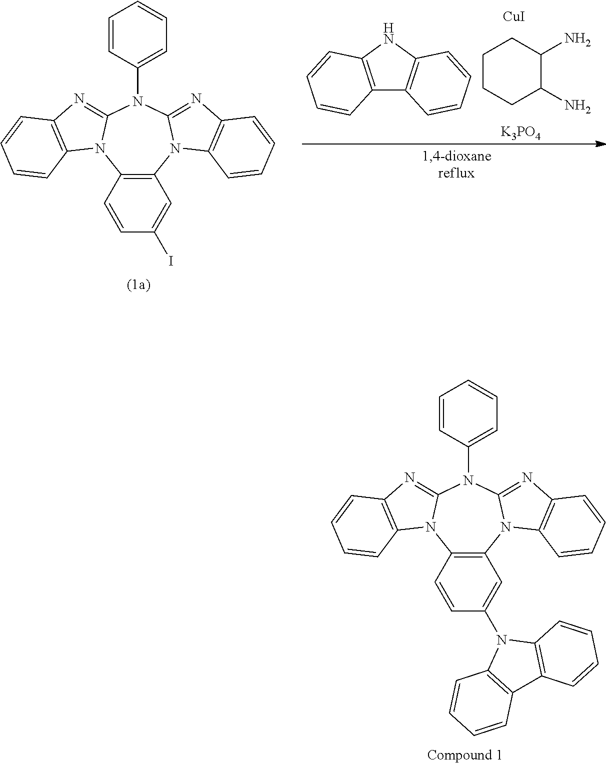

A mixture of 7.50 g (14.3 mmol) of iodine compound (compound (1a)), 2.86 g (17.1 mmol) of carbazole, 0.136 g (0.71 mmol) of copper (I) iodide, 0.2 mL (1.43 mmol) of trans-1,2-cyclohexanediamine, and 3.46 g (28.6 mmol) of tripotassium phosphate was refluxed in 200 mL of 1,4-dioxane for 24 hours.

After the reactant mixture was cooled to a room temperature (25 degrees C.), 100 mL of 1N hydrochloric acid was added to the reactant mixture. After inorganic solid was separated by filtration, filtrate was extracted using dichloromethane. An organic layer was dried using sodium sulfate, which was then concentrated under reduced pressure. With dichloromethane/ethyl acetate mixture as an eluent, a compound 1 was obtained with column chromatography filled with silica gel. Yield of the compound 1 was 6.70 g (yield rate: 83%).

¹H NMR (400 MHz,CDCl₃): δ8.22-8.12 (m,4H); 7.96 (d,J=7.9 Hz,2H); 7.84-7.77 (m,2H); 7.76-7.71 (m,2H); 7.62-7.54 (m,3H); 7.50 (t,J=7.8 Hz,4H); 7.40-7.31 (m,5H); 7.30-7.22 (m,2H).

### (2) Synthesis Example 2: Synthesis of Compound 2

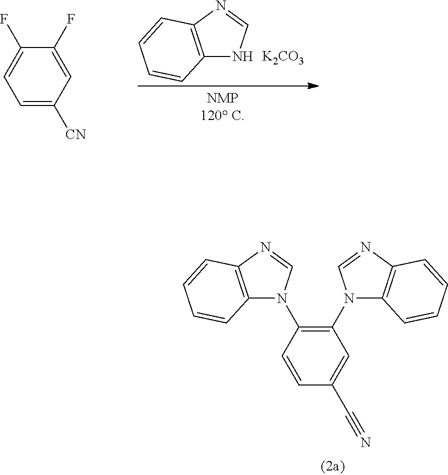

A mixture of 20.0 g (144 mmol) of 3,4-difluorobenzonitryl, 34.0 g (288 mmol) of benzimidazole, and 49.7 g (360 mmol) of potassium carbide was agitated in 340 mL of N-methyl pyrrolidone (NMP) at 120 degrees C. for 24 hours.

After the reactant mixture was cooled to a room temperature (25 degrees C.), water was added to the reactant mixture. After precipitates were separated and removed by filtration, the mixture was dried to obtain a product containing a compound (2a). An yield of the compound (2a) was 43 g (yield rate 89%).

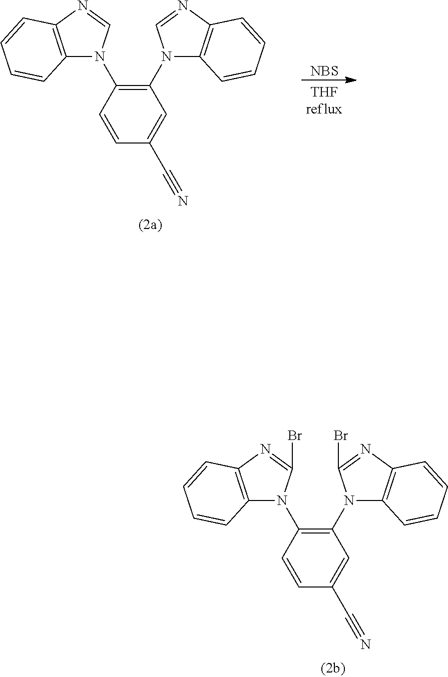

A mixture of 10.0 g (39.8 mmol) of benzimidazole compound (the compound (2a)) and 15.9 g (89.5 mmol) of N-bromosuccinimide (NBS) was refluxed in 100 mL of tetrahydrofuran for 1 hour.

After the reactant mixture was cooled to a room temperature (25 degrees C.), water was added to the reactant mixture. The product was extracted using dichloromethane. An organic layer was dried using sodium sulfate, which was then concentrated under reduced pressure. With dichloromethane/ethyl acetate mixture as an eluent, a product containing an isomer mixture of a compound (2b) was obtained with column chromatography filled with silica gel. Yield of the isomer mixture of the compound (2b) was 8.51 g (yield rate: 58%).

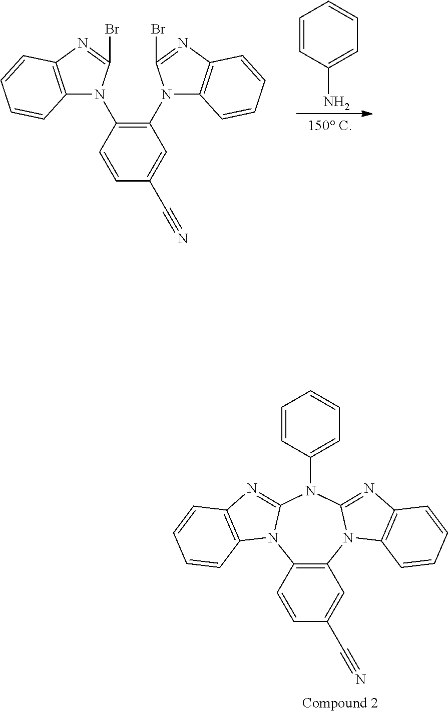

A mixture of 12.3 g (25 mmol) of an iodine compound (isomer mixture of compound (2b)) and 11.4 mL (125 mmol) of aniline was agitated in 10 mL of NMP at 150 degrees C. for 2 hours.

After the reactant mixture was cooled to a room temperature (25 degrees C.), 100 mL of 1N hydrochloric acid was added to the reactant mixture. The product was extracted using dichloromethane. An organic layer was dried using sodium sulfate, which was then concentrated under reduced pressure. With dichloromethane/ethyl acetate mixture as an eluent, a compound 2 was obtained with column chromatography filled with silica gel. Yield of the compound 2 was 6.8 g (yield rate: 64%).

¹H NMR (400 MHz, CDCl₃): δ8.23 (d,J=1.8 Hz, 1H); 8.06 (d,J=8.3 Hz, 1H); 7.87-7.81 (m, 3H); 7.76-7.71 (m, 2H); 7.60-7.54 (m, 2H); 7.51-7.45 (m, 2H); 7.40-7.31 (m, 5H).

### (3) Synthesis Example 3: Synthesis of Compound 3

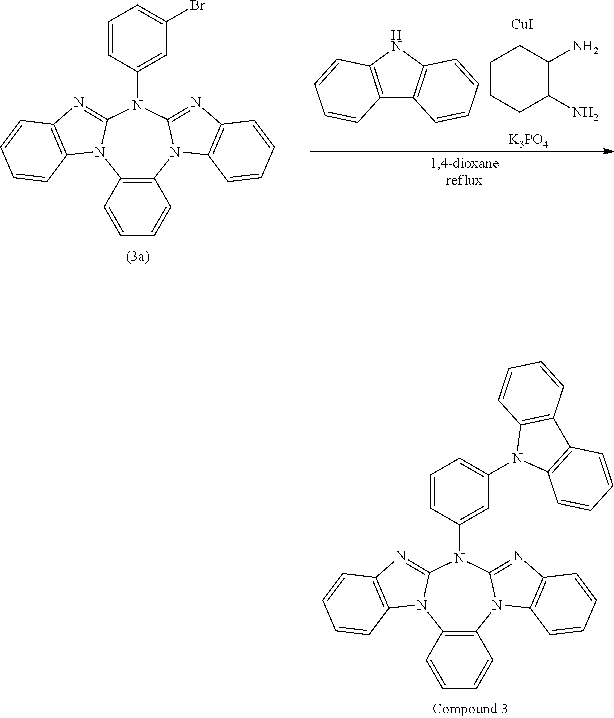

A mixture of 4.3 g (8.9 mmol) of Iodine compound (compound (3a)), 1.8 g (10.8 mmol) of carbazole, 0.51 g (2.7 mmol) of copper (I) iodide, 0.46 g (4.0 mmol) of trans-1,2-cyclohexanediamine, and 5.7 g (27 mmol) of tripotassium phosphate was refluxed for 24 hours in 70 mL of 1,4-dioxane.

After the reactant mixture was cooled to a room temperature (25 degrees C.), 50 mL of 1N hydrochloric acid was added to the reactant mixture. After inorganic solid was separated by filtration, filtrate was extracted using dichloromethane. An organic layer was dried using sodium sulfate, which was then concentrated under reduced pressure. With dichloromethane/ethyl acetate mixture as an eluent, a compound 3 was obtained with column chromatography filled with silica gel. Yield of the compound 3 was 4.6 g (yield rate: 91%).

¹H NMR (400 MHz, CDCl₃): δ8.16-8.08 (m, 3H); 8.06 (dd,J=8.4, 2.2 Hz, 1H); 7.97-7.90 (m, 2H); 7.82-7.75 (m, 2H); 7.68-7.59 (m, 5H); 7.59-7.53 (m, 2H); 7.48 (dd,J=7.8, 1.8 Hz, 1H); 7.41 (t,J=7.7 Hz, 2H); 7.36-7.30 (m, 4H); 7.29-7.23 (m, 2H).

### (4) Synthesis Example 4: Synthesis of Compound 4

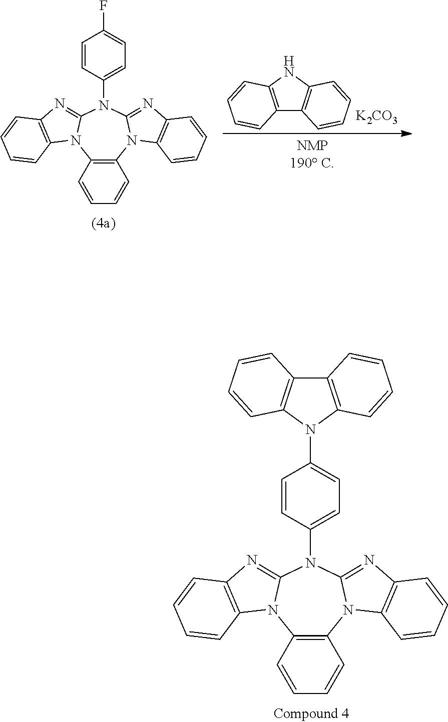

A mixture of 0.50 g (1.20 mmol) of fluorine compound (compound (4a)), 0.22 g (1.32 mmol) of carbazole, and 0.20 g (1.44 mmol) of potassium carbide was agitated in 10 mL of N-methyl pyrrolidone (NMP) at 190 degrees C. for 48 hours.

After the reactant mixture was cooled to a room temperature (25 degrees C.), water was added to the reactant mixture. After inorganic solid was separated by filtration, filtrate was extracted using dichloromethane. An organic layer was dried using sodium sulfate, which was then concentrated under reduced pressure. With dichloromethane/ethyl acetate mixture as an eluent, a compound 4 was obtained with column chromatography filled with silica gel. Yield of the compound 4 was 0.15 g (yield rate: 22%).

¹H NMR (400 MHz, CDCl₃): δ8.20-8.12 (m, 4H); 8.06-7.98 (m, 2H); 7.89-7.81 (m, 2H); 7.73-7.60 (m, 6H); 7.49 (dt,J=8.3, 1.1 Hz, 2H); 7.46-7.35 (m, 6H); 7.34-7.27 (m, 2H).

### (5) Synthesis Example 5: Synthesis of Compound 5

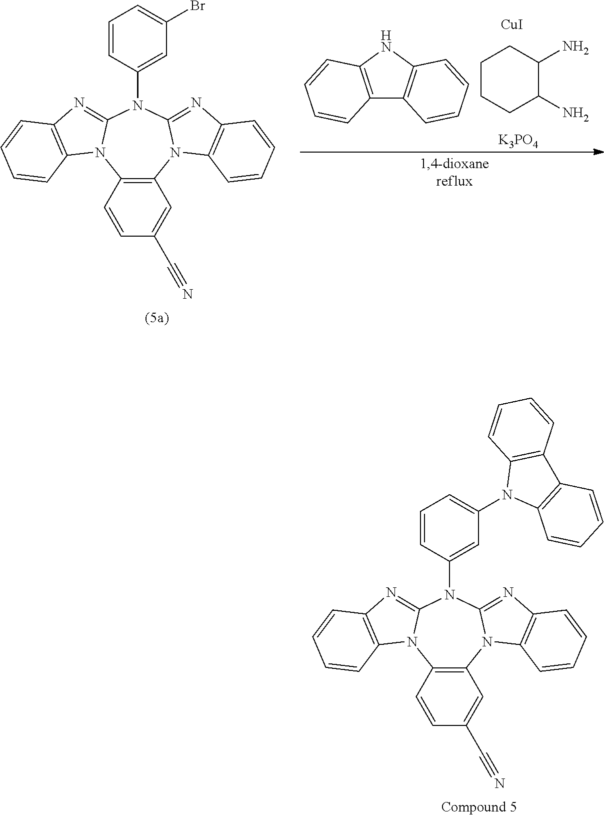

A mixture of 5.3 g (10.5 mmol) of Iodine compound (compound (5a)), 3.2 g (18.9 mmol) of carbazole, 0.90 g (8.5 mmol) of copper (I) iodide, 0.9 mL (7.1 mmol) of trans-1,2-cyclohexanediamine, and 10.0 g (47.3 mmol) of tripotassium phosphate was refluxed for 24 hours in 90 mL of 1,4-dioxane.

After the reactant mixture was cooled to a room temperature (25 degrees C.), 25 mL of 1N hydrochloric acid was added to the reactant mixture. After inorganic solid was separated by filtration, filtrate was extracted using dichloromethane. An organic layer was dried using sodium sulfate, which was then concentrated under reduced pressure. With dichloromethane/ethyl acetate mixture as an eluent, a compound 5 was obtained with column chromatography filled with silica gel. Yield of the compound 5 was 3.55 g (yield rate: 57%).

¹H NMR (400 MHz, CDCl₃): δ8.24 (d,J=1.9 Hz, 1H); 8.14-8.10 (m, 3H); 8.07 (d,J=8.4 Hz, 1H); 8.01 (dd,J=8.4, 2.1 Hz, 1H); 7.84 (dd,J=8.3, 1.9 Hz, 1H); 7.80-7.76 (m, 2H); 7.67 (dd,J=16.8, 8.2 Hz, 3H); 7.60-7.56 (m, 3H); 7.44-7.35 (m, 6H); 7.29 (d,J=7.4 Hz, 2H).

### (5) Synthesis Example 6: Synthesis of Compound BD-1

A compound BD-1 synthesized as below in Synthesis Example 6 was a mixture of a compound BD-1a and compound BD-1b.

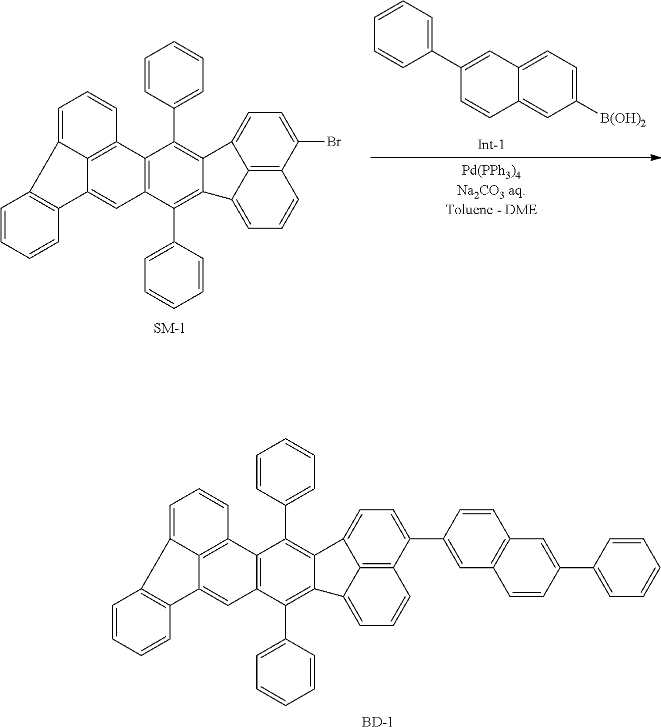

To a three-necked flask, 2.0 g (3.29 mmol) of SM-1 (isomer mixture), 1.31 g (5.28 mmol) of boronic acid (Int-1), 3.3 mL of an aqueous solution of 2M sodium carbonate, 22 mL of 1,2-dimethoxyethane (DME) and 11 mL of toluene were added. Next, tetrakis(triphenylphosphine)palladium (0.08 g, 0.07 mmol) was further added thereto and heated to reflux with stirring under a nitrogen atmosphere for 24 hours. After heated with stirring, the mixture solution was cooled to the room temperature and a deposited solid was filtrated. The obtained solid was suspended in and washed with toluene-methanol mixture solvent and subsequently with ethyl acetate to obtain a target substance (compound BD-1). A yield of the compound BD-1 was 0.77 g and a yield rate thereof was 32%. A result of FD-MS (Field Desorption Mass Spectrometry) analysis showed m/e=730 relative to a molecular weight of 730. It should be noted that the compound BD-1 was a mixture of BD-1a and BD-1b, since the starting material (SM-1) was the isomer mixture containing SM-1a and SM-1b. It should be noted that, in a reaction formula of Synthesis Example 6, the structure of “SM-1” was exemplarily shown only by the structure of SM-1a. The structure of “BD-1” was also exemplarily shown only by the structure of the BD-1a.

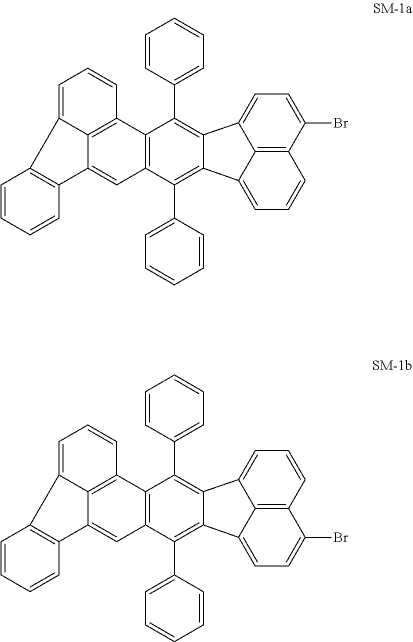 [SMILES: Brc1ccc2c3c(-c4ccccc4)c4c(cc5c6ccccc6c6cccc4c65)c(-c4ccccc4)c3c3cccc1c32 ; Brc1ccc2c3c(-c4ccccc4)c4cc5c6ccccc6c6cccc(c4c(-c4ccccc4)c3c3cccc1c23)c65]

### Evaluation of Compounds

A method of measuring characteristics of the compounds is shown below.

### Delayed Fluorescence

Delayed fluorescence characteristics were checked by measuring transient photoluminescence (PL) using a device shown in FIG. 5. A sample was prepared by co-depositing the compounds TADF1 and TH-2 on a quartz substrate at a ratio of the compound TADF1 of 12 mass % to form a 100-nm-thick thin film. Prompt emission was observed immediately when the excited state was achieved by exciting the compound TADF1 with a pulse beam (i.e., a beam emitted from a pulse laser) having a wavelength to be absorbed by the compound TADF1, and Delay emission was observed not immediately when the excited state was achieved but after the excited state was achieved. Delayed fluorescence in Examples means that, provided that the amount of Prompt emission is denoted by X_{P} and the amount of Delay emission is denoted by X_{D}, a value of X_{D}/X_{P} is 0.05 or more.

It was also found that the value of X_{D}/X_{P} was 0.05 or more in the compound TADF1.

The amount of Prompt emission and the amount of Delay emission can be obtained according to the same method as a method described in “Nature 492, 234-238, 2012.” A device used for calculating the amounts of Prompt emission and Delay emission is not limited to the device of FIG. 5 and a device described in the above document.

### Singlet Energy S₁

Singlet energies S₁ of the compounds 1 to 5, TADF1, and BD-1 were measured by the above-described solution method.

The singlet energy S₁ of the compound 1 was 3.58 eV.

The singlet energy S₁ of the compound 2 was 3.44 eV.

The singlet energy S₁ of the compound 3 was 3.56 eV.

The singlet energy S₁ of the compound 4 was 3.54 eV.

The singlet energy S₁ of the compound 5 was 3.56 eV.

The singlet energy S₁ of the TADF1 was 2.90 eV.

The singlet energy S₁ of the BD-1 was 2.68 eV.

### Energy Gap T_{77K} at 77 [K]

Energy gaps T_{77K} of the compounds 1 to 5, TADF1, BD-1, mCP, and CzSi at 77[K] were measured according to the measurement method of energy gap T_{77K} described in the above “Relationship between Triplet Energy and Energy Gap at 77[K].”

T_{77K} of the compound 1 was 3.07 eV.

T_{77K} of the compound 2 was 3.14 eV.

T_{77K} of the compound 3 was 3.07 eV.

T_{77K} of the compound 4 was 3.07 eV.

T_{77K} of the compound 5 was 3.07 eV.

T_{77K} of TADF1 was 2.87 eV. Accordingly, ΔST of the TADF1 was 0.03 eV.

T_{77K} of BD-1 was 2.11 eV.

T_{77K} of mCP was 3.07 eV.

T_{77K} of CzSi was 3.06 eV.

### Main Peak Wavelength of Compounds

A 5 μmol/L toluene solution of a measurement target compound was prepared and put in a quartz cell. A fluorescence spectrum (ordinate axis: fluorescence intensity, abscissa axis: wavelength) of the thus-obtained sample was measured at a normal temperature (300K). In Examples, the fluorescence spectrum was measured using a spectrophotometer (F-7000 manufactured by Hitachi, Ltd.). It should be noted that the fluorescence spectrum measuring device may be different from the above device. A peak wavelength of the fluorescence spectrum exhibiting the maximum fluorescence intensity was defined as a main peak wavelength.

The main peak wavelength of the compound BD-1 was 462 nm.

### Preparation of Organic EL Device

The organic EL device was prepared and evaluated as follows.

### Example 1

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. A film of ITO was 130 nm thick.

After the glass substrate having the transparent electrode line was cleaned, the glass substrate was mounted on a substrate holder of a vacuum evaporation apparatus. Initially, a compound HI was vapor-deposited on a surface of the glass substrate where the transparent electrode line was provided in a manner to cover the transparent electrode, thereby forming a 5-nm-thick hole injecting layer.

Next, the compound HT1 was vapor-deposited on the hole injecting layer to form an 80-nm-thick first hole transporting layer on the HI film.

Next, the compound HT2 was vapor-deposited on the first hole transporting layer to form a 10-nm-thick second hole transporting layer.

Further, mCP was vapor-deposited on the second hole transporting layer to form a 5-nm-thick third hole transporting layer.

Further, the compound TADF1 (the second compound), the compound BD-1 (the first compound) and the compound 1 (the third compound) were co-deposited on the third hole transporting layer to form a 25-nm-thick emitting layer. A concentration of the compound TADF1 was 24 mass %, a concentration of the compound BD-1 was 1 mass %, and a concentration of the compound 1 was 75 mass % in the emitting layer.

Next, a compound ET1 was deposited on the emitting layer to form a 5-nm-thick first electron transporting layer.

The compound ET2 was then vapor-deposited on the first electron transporting layer to form a 20-nm-thick second electron transporting layer.

Next, lithium fluoride (LiF) was vapor-deposited on the second electron transporting layer to form a 1-nm-thick electron injecting electrode (cathode).

A metal aluminum (Al) was then deposited on the electron injecting electrode to form an 80-nm-thick metal Al cathode.

A device arrangement of the organic EL device in Example 1 is schematically shown as follows.

ITO (130)/HI (5)/HT1 (80)/HT2 (10)/mCP (5)/compound 1:TADF1:BD-1 (25, 75%:24%:1%)/ET1 (5)/ET2 (20)/LiF (1)/Al (80)

Numerals in parentheses represent a film thickness (unit: nm). The numerals represented by percentage in the same parentheses indicate a ratio (mass %) of the third compound, the second compound and the first compound in the emitting layer. The above is also applicable to the description below.

### Example 2

An organic EL device of Example 2 was prepared in the same manner as the organic EL device of Example 1 except that a compound 2 was used in place of the compound 1 in the emitting layer of Example 1.

A device arrangement of the organic EL device in Example 2 is schematically shown as follows.

ITO (130)/HI (5)/HT1 (80)/HT2 (10)/mCP (5)/compound 2:TADF1:BD-1 (25, 75%:24%:1%)/ET1 (5)/ET2 (20)/LiF (1)/Al (80)

### Example 3

An organic EL device of Example 3 was prepared in the same manner as the organic EL device of Example 1 except that a compound 3 was used in place of the compound 1 in the emitting layer of Example 1.

A device arrangement of the organic EL device in Example 3 is schematically shown as follows.

ITO (130)/HI (5)/HT1 (80)/HT2 (10)/mCP (5)/compound 3:TADF1:BD-1 (25, 75%:24%:1%)/ET1 (5)/ET2 (20)/LiF (1)/Al (80)

### Example 4

An organic EL device of Example 4 was prepared in the same manner as the organic EL device of Example 1 except that a compound 4 was used in place of the compound 1 in the emitting layer of Example 1.

A device arrangement of the organic EL device in Example 4 is schematically shown as follows.

ITO (130)/HI (5)/HT1 (80)/HT2 (10)/mCP (5)/compound 4:TADF1:BD-1 (25, 75%:24%:1%)/ET1 (5)/ET2 (20)/LiF (1)/AI (80)

### Example 5

An organic EL device of Example 5 was prepared in the same manner as the organic EL device of Example 1 except that a compound 5 was used in place of the compound 1 in the emitting layer of Example 1.

A device arrangement of the organic EL device in Example 5 is schematically shown as follows.

ITO (130)/HI (5)/HT1 (80)/HT2 (10)/mCP (5)/compound 5:TADF1:BD-1 (25, 75%:24%:1%)/ET1 (5)/ET2 (20)/LiF (1)/Al (80)

### Comparative 1

An organic EL device of Comparative 1 was prepared in the same manner as the organic EL device of Example 1 except that mCP was used in place of the compound 1 in the emitting layer of Example 1.

A device arrangement of the organic EL device in Comparative 1 is schematically shown as follows.

ITO (130)/HI (5)/HT1 (80)/HT2 (10)/mCP (5)/mCP:TADF1:BD-1 (25, 75%:24%:1%)/ET1 (5)/ET2 (20)/LiF (1)/Al (80)

### Comparative 2

An organic EL device of Comparative 2 was prepared in the same manner as the organic EL device of Example 1 except that CzSi was used in place of the compound 1 in the emitting layer of Example 1.

A device arrangement of the organic EL device in Comparative 2 is schematically shown as follows.

ITO (130)/HI (5)/HT1 (80)/HT2 (10)/mCP (5)/CzSi:TADF1:BD-1 (25, 75%:24%:1%)/ET1 (5)/ET2 (20)/LiF (1)/Al (80)

### Evaluation of Organic EL Devices

The organic EL devices prepared in Examples 1 to 5 and Comparatives 1 to 2 were evaluated as follows. The evaluation results are shown in Table 1.

### External Quantum Efficiency EQE and Main Peak Wavelength λₚ

Voltage was applied on each of the organic EL devices such that a current density was 0.1 mA/cm², where spectral radiance spectra were measured by a spectroradiometer CS-1000 (manufactured by Konica Minolta, Inc.).

The external quantum efficiency EQE (unit: %) was calculated based on the obtained spectral-radiance spectra, assuming that the spectra were provided under a Lambertian radiation.

The main peak wavelength λₚ (unit: nm) was calculated based on the obtained spectral-radiance spectra.

TABLE 1

| | Material of Emitting Layer | | | | | |
|---|---|---|---|---|---|---|
| | First | Second | Third Compound | | | |
| | Compound | Compound | (Third Component) | | EQE | λp |
| | (Fluorescent) | (TADF) | Type | T_{77K} [eV] | (%) | (nm) |
| Ex. 1 | BD-1 | TADF1 | Compound 1 | 3.07 | 11.2 | 468 |
| Ex. 2 | BD-1 | TADF1 | Compound 2 | 3.14 | 14.0 | 468 |
| Ex. 3 | BD-1 | TADF1 | Compound 3 | 3.07 | 11.0 | 468 |
| Ex. 4 | BD-1 | TADF1 | Compound 4 | 3.07 | 10.5 | 468 |
| Ex. 5 | BD-1 | TADF1 | Compound 5 | 3.07 | 11.1 | 468 |
| Comp. 1 | BD-1 | TADF1 | mCP | 3.07 | 8.9 | 468 |
| Comp. 2 | BD-1 | TADF1 | CzSi | 3.06 | 8.4 | 468 |

It is found that Examples 1 to 5 for an organic EL device including an emitting layer containing a fluorescent compound (first compound), a delayed fluorescent compound (second compound), and a third component (third compound), which is the compound represented by the formula (3), are superior to Comparatives 1 and 2, whose third components are mCP and CzSi, respectively, in terms of luminous efficiency.

As shown in Table 1, though the energy gaps T_{77K} of the third components at 77[K] used for Examples 1 to 5 and Comparatives 1, 2 were substantially the same, Examples 1 to 5 exhibited larger EQE than Comparatives 1, 2. Accordingly, It is believed that triplet energy of the delayed fluorescent compound can be effectively trapped in the emitting layer due to the greatly distorted structure of the third compound (the compound represented by the formula (3)) in Examples, resulting an improvement in a luminous efficiency.

1. An organic electroluminescence device comprising:
an anode:
an emitting layer; and
a cathode, wherein
the emitting layer comprises a first compound, a second compound, and a third compound,
the first compound is a fluorescent compound,
the second compound is a delayed fluorescent compound,
the third compound is a compound represented by a formula (3) below, and
a singlet energy S₁(M1) of the first compound, a singlet energy S₁(M2) of the second compound and a singlet energy S₁(M3) of the third compound satisfy a relationship of a Numerical Formula 1 below, 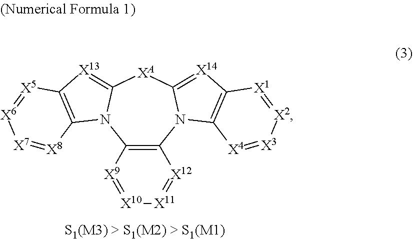
where:
X¹ to X¹⁴ each independently represent a nitrogen atom or CR⁸⁰:
X¹ represents NR⁹⁵, a sulfur atom, or an oxygen atom;
R⁸⁰ is a hydrogen atom or a substituent, R⁸⁰ as the substituent being each independently a fluorine atom, a cyano group, a substituted or unsubstituted alkyl group having 1 to 25 carbon atoms, a substituted or unsubstituted alkyl group having 1 to 25 carbon atoms with a linking group D interposed, a substituted or unsubstituted aryl group having 6 to 24 ring carbon atoms, a substituted or unsubstituted heteroaryl group having 2 to 30 ring carbon atoms, or a group represented by -(A⁵)s-(A⁶)t-(A⁷)u-(A⁸)v-R¹⁷;
R⁹⁵ in NR⁹⁵ is a group represented by -(A¹)o-(A²)p-(A³)q-(A⁴)r-R¹⁶, such that s, t, u, v, o, p, q and r are each independently 0 or 1, in which a plurality of R⁸⁰ are mutually the same or different;
R¹⁶ and R¹⁷ each independently represent a hydrogen atom or a substituent, R¹⁶ and R¹⁷ as the substituent being each independently —NR¹⁰R¹¹, —SiR¹²R¹³R¹⁴, —C(═O)R¹⁵, —CN, a substituted or unsubstituted aryl group having 6 to 24 ring carbon atoms, or a substituted or unsubstituted heteroaryl group having 2 to 30 ring carbon atoms;
R¹⁰, R¹¹ and R¹⁵ each independently represent a substituted or unsubstituted aryl group having 6 to 24 ring carbon atoms, or a substituted or unsubstituted heteroaryl group having 2 to 30 ring carbon atoms;
A¹ to A⁸ are each independently —SiR^{12A}R^{13A}—, a substituted or unsubstituted arylene group having 6 to 24 ring carbon atoms, or a substituted or unsubstituted heteroarylene group having 2 to 30 ring carbon atoms;
R¹², R¹³, R^{12A}, R^{13A} and R¹⁴ each independently represent a substituted or unsubstituted alkyl group having 1 to 25 carbon atoms, a substituted or unsubstituted alkyl group having 1 to 25 carbon atoms with a linking group D interposed, a substituted or unsubstituted aryl group having 6 to 24 ring carbon atoms, or a substituted or unsubstituted heteroaryl group having 2 to 30 ring carbon atoms;
the linking group D is —CO—, —COO—, —S—, —SO—, —SO₂—, —O—, —NR⁶⁵—, —SiR⁷⁰R⁷¹—, —POR⁷²—, —CR⁶³═CR⁶⁴—, or —C═C—;
R⁶³ and R⁶⁴ each independently represent a hydrogen atom or a substituent, R⁶³ and R⁶⁴ as the substituent being each independently an unsubstituted aryl group having 6 to 18 ring carbon atoms, an aryl group having 6 to 18 ring carbon atoms substituted by a substituted or unsubstituted alkyl group having 1 to 18 carbon atoms, an aryl group having 6 to 18 ring carbon atoms substituted by a substituted or unsubstituted alkoxy group having 1 to 18 carbon atoms, a substituted or unsubstituted alkyl group having 1 to 18 carbon atoms, or a substituted or unsubstituted alkyl group having 1 to 18 carbon atoms with an oxygen atom interposed;
R⁶⁵ is an unsubstituted aryl group having 6 to 18 ring carbon atoms, a substituted or unsubstituted heteroaryl group having 2 to 30 ring carbon atoms, an aryl group having 6 to 18 ring carbon atoms substituted by a substituted or unsubstituted alkyl group having 1 to 18 carbon atoms, an aryl group having 6 to 18 ring carbon atoms substituted by a substituted or unsubstituted alkoxy group having 1 to 18 carbon atoms, a substituted or unsubstituted alkyl group having 1 to 18 carbon atoms, or a substituted or unsubstituted alkyl group having 1 to 18 carbon atoms with an oxygen atom interposed;
R⁷⁰ to R⁷¹ and R⁷² each independently represent a substituted or unsubstituted alkyl group having 1 to 18 carbon atoms, an unsubstituted aryl group having 6 to 18 ring carbon atoms, or an aryl group having 6 to 18 ring carbon atoms substituted by a substituted or unsubstituted alkyl group having 1 to 18 carbon atoms;
in the formula (3), when 0 or 1 of X¹ to X⁴ is a nitrogen atom, 0 or 1 of X⁵ to X⁸ is a nitrogen atom and o, p, q, and r are 0, R¹⁶ is neither a hydrogen atom nor —NR¹⁰R¹¹; and when a plurality of substituents are present, the plurality of substituents are mutually the same or different.

2. The organic electroluminescence device according to claim 1, wherein the third compound is a compound represented by a formula (31) below, 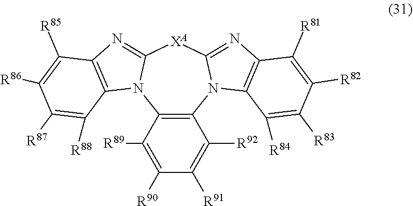
where:
X^{A} represents the same as X^{A} in the formula (3); and
R⁸¹ to R⁹² each independently represent the same as R⁸⁰ in the formula (3).

3. The organic electroluminescence device according to claim 1, wherein the third compound is a compound represented by a formula (32) below, 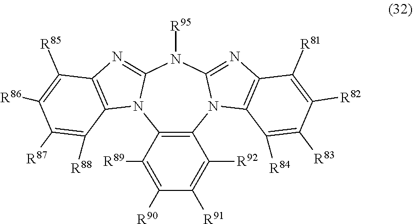
where:
R⁹⁵ represents the same as R⁹⁵ in the formula (3); and
R⁸¹ to R⁹² each independently represent the same as R⁸⁰ in the formula (3).

4. The organic electroluminescence device according to claim 1, wherein, in the formula (3), X¹ to X⁹ and X¹² are CR⁸⁰ and R⁸⁰ for CR⁸⁰ is a hydrogen atom.

5. The organic electroluminescence device according to claim 1, wherein, when X¹⁰ and X¹¹ are CR⁸⁰ in the formula (3), R⁸⁰ for CR⁸⁰ are each independently a hydrogen atom or a cyano group.

6. The organic electroluminescence device according to claim 1, wherein R⁹⁵ is a group represented by -(A¹)o-(A²)p-(A³)q-(A⁴)r-R¹⁶ and R¹⁶ is a group selected from groups represented by formulae (A1) and (A2) below, 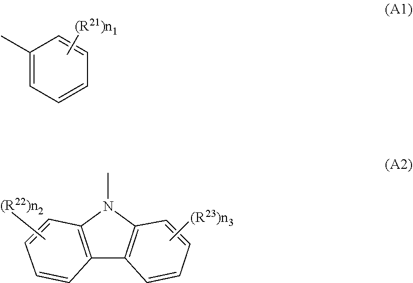
where:
in the formula (A1):
R²¹ is a hydrogen atom or a substituent, R²¹ as the substituent being each independently an unsubstituted alkyl group having 1 to 18 carbon atoms, an unsubstituted aryl group having 6 to 24 ring carbon atoms, an unsubstituted heteroaryl group having 2 to 30 ring carbon atoms, an aryl group having 6 to 24 ring carbon atoms substituted by a substituted or unsubstituted alkyl group having 1 to 18 carbon atoms, a heteroaryl group having 2 to 30 ring carbon atoms substituted by a substituted or unsubstituted alkyl group having 1 to 18 carbon atoms, a heteroaryl group having 2 to 30 ring carbon atoms substituted by a substituted or unsubstituted aryl group having 6 to 24 ring carbon atoms, or an aryl group having 6 to 24 ring carbon atoms substituted by a substituted or unsubstituted heteroaryl group having 2 to 30 ring carbon atoms;
n₁ is 5; and
a plurality of R²¹ are mutually the same or different,
in the formula (A2):
R²² and R²³ each independently represent a hydrogen atom or a substituent; R²² and R²³ as the substituent each independently represent the same as R²¹ in the formula (A1);
n₂ and n₃ are each 4; and
a plurality of R²² are mutually the same or different; and
a plurality of R²³ are mutually the same or different.

7. The organic electroluminescence device according to claim 1, wherein the third compound is a compound represented by a formula (33) below, 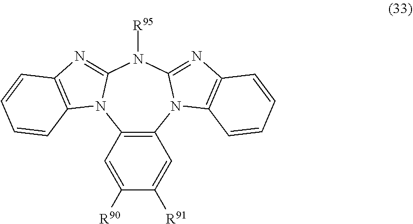
where:
R⁹⁵ represents the same as R⁹⁵ in the formula (3); and
R⁹⁰ and R⁹¹ are hydrogen atoms, R⁹⁰ and R⁹¹ are cyano groups, one of R⁹⁰ and R⁹¹ is a hydrogen atom and the other is a cyano group, or one of R⁹⁰ and R⁹¹ is a hydrogen atom and the other is a group represented by -(A⁵)s-(A⁶)t-(A⁷)u-(A⁸)v-R¹⁷;
s, t, u and v are each independently 0 or 1;
A⁵ to A⁸ are each independently a group selected from groups represented by formulae (A11) to (A23) below; and
R¹⁷ is a group selected from the group consisting of a cyano group, and groups represented by formulae (B11) to (B25) below, 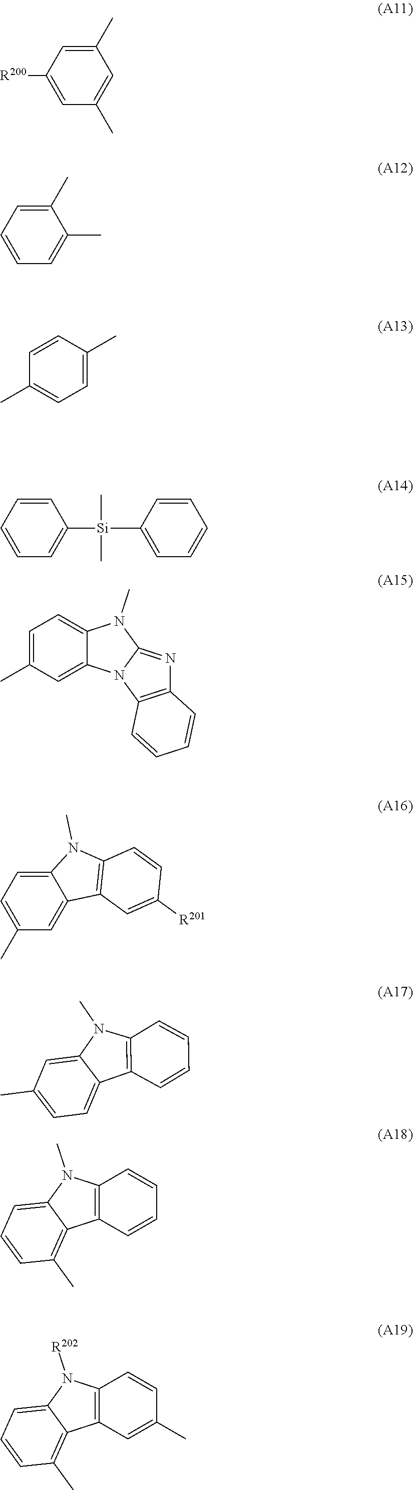 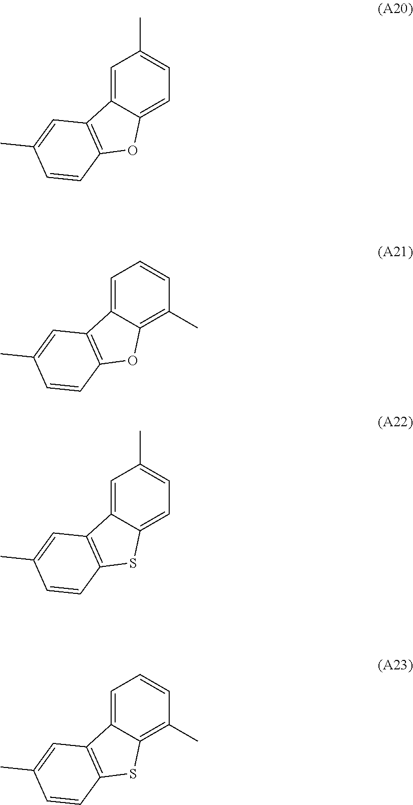
where R²⁰⁰ in the formula (A11) is a hydrogen atom, S₁(Ph)³ with Ph being a phenyl group, or a group represented by a formula (A24) below, R²⁰¹ in the formula (A16) is a hydrogen atom or a cyano group, and
R²⁰² in the formula (A19) is a phenyl group, 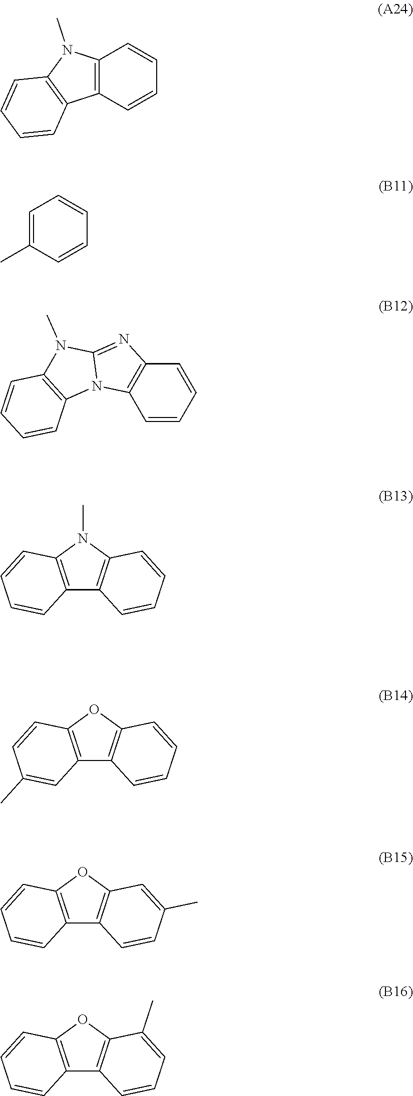 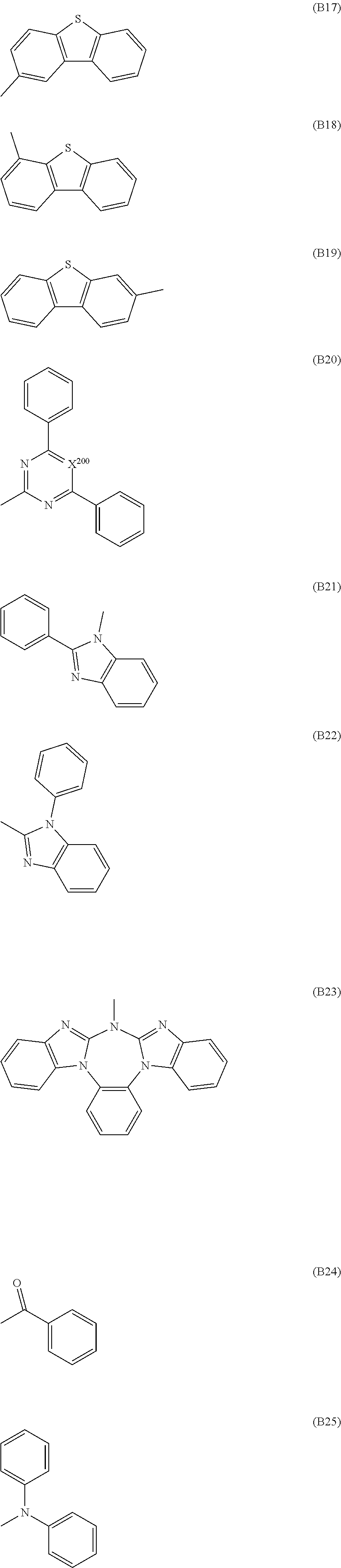
where X²⁰⁰ in the formula (B20) is a nitrogen atom or CH.

8. The organic electroluminescence device according to claim 7, wherein, in the formula (33), R⁹⁵ is a group represented by a formula (33a) below, or a group represented by a formula (33b) below; and
R⁹⁰ and R⁹¹ are hydrogen atoms, R⁹⁰ and R⁹¹ are cyano groups, one of R⁹⁰ and R⁹¹ is a hydrogen atom and the other is a cyano group, or one of R⁹⁰ and R⁹¹ is a hydrogen atom and the other is a group represented by -(A⁵)s-(A⁶)t-(A⁷)u-(A⁸) -R¹⁷, the group represented by the formula -(A⁵)s-(A⁶)t-(A⁷)u-(A⁸)v-R¹⁷ being represented by a formula (33b) below, 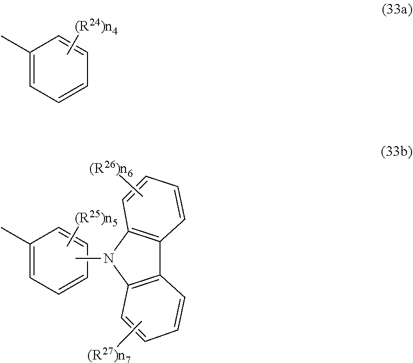
where:
R²⁴ to R²⁷ each independently represent a hydrogen atom or a substituent;
R²⁴ to R²⁷ as the substituents are each independently an unsubstituted alkyl group having 1 to 18 carbon atoms, an unsubstituted aryl group having 6 to 24 ring carbon atoms, an unsubstituted heteroaryl group having 2 to 30 ring carbon atoms, an aryl group having 6 to 24 ring carbon atoms substituted by a substituted or unsubstituted alkyl group having 1 to 18 carbon atoms, a heteroaryl group having 2 to 30 ring carbon atoms substituted by a substituted or unsubstituted alkyl group having 1 to 18 carbon atoms, a heteroaryl group having 2 to 30 ring carbon atoms substituted by a substituted or unsubstituted aryl group having 6 to 24 ring carbon atoms, or an aryl group having 6 to 24 ring carbon atoms substituted by a substituted or unsubstituted heteroaryl group having 2 to 30 ring carbon atoms;
n₄ is 5 and n₅, n₆ and n₇ are each 4;
a plurality of R²⁴ are mutually the same or different;
a plurality of R²⁵ are mutually the same or different;
a plurality of R²⁶ are mutually the same or different; and
a plurality of R²⁷ are mutually the same or different.

9-10. (canceled)

11. The organic electroluminescence device according to claim 1, wherein the first compound is a compound represented by a formula (1) below, 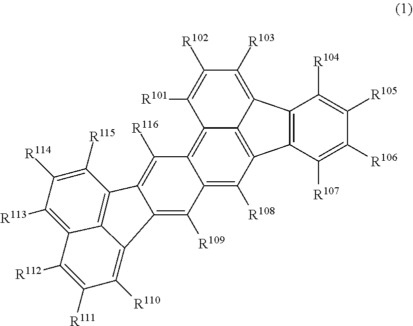
where, in the formula (1):
R¹⁰¹ to R¹¹⁶ are each independently a hydrogen atom or a substituent, or at least one of a pair of R¹⁰¹ and R¹⁰², a pair of R¹⁰² and R¹⁰³, a pair of R¹⁰³ and R¹⁰⁴, a pair of R¹⁰⁴ and R¹⁰⁵, a pair of R¹⁰⁵ and R¹⁰⁶, a pair of R¹⁰⁶ and R¹⁰⁷, a pair of R¹⁰⁷ and R¹⁰⁸, a pair of R¹⁰⁸ and R¹⁰⁹, a pair of R¹⁰⁹ and R¹¹⁰, a pair of R¹¹⁰ and R¹¹¹, a pair of R¹¹¹ and R¹¹², a pair of R¹¹² and R¹¹³, a pair of R¹¹³ and R¹¹⁴, a pair of R¹¹⁴ and R¹¹⁵, a pair of R¹¹⁵ and R¹¹⁶, and a pair of R¹¹⁶ and R¹⁰¹ are mutually bonded to form a ring; and
R¹⁰¹ to R¹⁰⁶ as the substituents are each independently a group selected from the group consisting of a substituted or unsubstituted alkyl group having 1 to 30 carbon atoms, a substituted or unsubstituted alkoxy group having 1 to 30 carbon atoms, a substituted or unsubstituted alkylthio group having 1 to 30 carbon atoms, a substituted or unsubstituted amino group, a substituted or unsubstituted aryl group having 6 to 30 ring carbon atoms, a substituted or unsubstituted heteroaryl group having 5 to 30 ring atoms, a substituted or unsubstituted alkenyl group having 2 to 30 carbon atoms; a substituted or unsubstituted aryloxy group having 6 to 30 ring carbon atoms, a substituted or unsubstituted arylthio group having 6 to 30 ring carbon atoms, a substituted or unsubstituted phosphino group, a substituted or unsubstituted phosphoryl group; a substituted or unsubstituted silyl group; a substituted or unsubstituted arylcarbonyl group having 6 to 30 ring carbon atoms, a cyano group, a nitro group, a carboxy group, a halogen atom, and a substituted or unsubstituted acyl group having 2 to 31 carbon atoms.

12. The organic electroluminescence device according to claim 11, wherein, in the compound represented by the formula (1), one of R¹¹¹ to R¹¹⁴ is a group represented by a formula (1a) below, 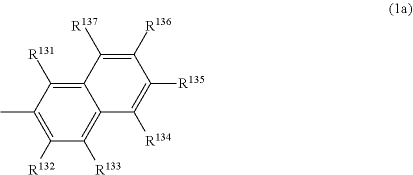
where, in the formula (1a):
R¹³¹ to R¹³⁴ and R¹³⁶ each independently represent a hydrogen atom or a substituent, R¹³¹ to R¹³⁴ and R¹³⁶ as the substituent being each independently selected from the group consisting of a substituted or unsubstituted alkyl group having 1 to 30 carbon atoms, a substituted or unsubstituted alkoxy group having 1 to 30 carbon atoms, a substituted or unsubstituted alkylthio group having 1 to 30 carbon atoms, a substituted or unsubstituted amino group, a substituted or unsubstituted aryl group having 6 to 30 ring carbon atoms, a substituted or unsubstituted heteroaryl group having 5 to 30 ring atoms, a substituted or unsubstituted alkenyl group having 2 to 30 carbon atoms; a substituted or unsubstituted aryloxy group having 6 to 30 ring carbon atoms, a substituted or unsubstituted arylthio group having 6 to 30 ring carbon atoms, a substituted or unsubstituted phosphino group, a substituted or unsubstituted phosphoryl group; a substituted or unsubstituted silyl group; a substituted or unsubstituted arylcarbonyl group having 6 to 30 ring carbon atoms, a cyano group, a nitro group, a carboxy group, and a halogen atom; and
R¹³⁵ and R¹³⁷ are each independently a substituent selected from the group consisting of a substituted or unsubstituted aryl group having 6 to 30 ring carbon atoms, a substituted or unsubstituted heteroaryl group having 5 to 30 ring atoms, and a cyano group, or are each independently selected from the group consisting of a hydrogen atom, a substituted or unsubstituted alkyl group having 1 to 30 carbon atoms, a substituted or unsubstituted alkoxy group having 1 to 30 carbon atoms, a substituted or unsubstituted alkylthio group having 1 to 30 carbon atoms, a substituted or unsubstituted amino group, a substituted or unsubstituted aryl group having 6 to 30 ring carbon atoms, a substituted or unsubstituted heteroaryl group having 5 to 30 ring atoms, a substituted or unsubstituted alkenyl group having 2 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted phosphanyl group, a substituted or unsubstituted phosphoryl group, a substituted or unsubstituted silyl group, substituted or unsubstituted arylcarbonyl group having 6 to 30 ring carbon atoms, a cyano group, a nitro group, a carboxy group, and a halogen atom, R¹³⁵ and R¹³⁷ being mutually the same or different.

13. The organic electroluminescence device according to claim 1, wherein a difference ΔST(M2) between the singlet energy S₁(M2) of the second compound and an energy gap T_{77K}(M2) at 77[K] of the second compound satisfies a relationship of a Numerical Formula 2 below,
ΔST(M2)=S₁(M2)−T_{77K}(M2)<0.1 [eV] (Numerical Formula 2).

14. The organic electroluminescence device according to claim 1, wherein an energy gap T_{77K}(M3) at 77[K] of the third compound, an energy gap T_{77K}(M2) at 77[K] of the second compound and an energy gap T_{77K}(M1) at 77[K] of the first compound satisfy a relationship of a Numerical Formula 3 below,
T_{77K}(M3)>T_{77K}(M2)>T_{77K}(M1) (Numerical Formula 3).

15. The organic electroluminescence device according to claim 1, wherein a substituent meant by “substituted or unsubstituted” is a substituent selected from the group consisting of a substituted or unsubstituted aromatic hydrocarbon group having 6 to 30 ring carbon atoms, a substituted or unsubstituted heterocyclic group having 5 to 30 ring atoms, a linear alkyl group having 1 to 30 carbon atoms, a branched alkyl group having 3 to 30 carbon atoms, a cycloalkyl group having 3 to 30 ring carbon atoms, an alkyl halide group provided by substituting an alkyl group of the linear alkyl group, the branched alkyl group, or the cycloalkyl group with one or more halogen atoms, a cyano group, an amino group, a substituted amino group, a halogen atom, an alkoxy group having 1 to 30 carbon atoms, an aryloxy group having 6 to 30 ring carbon atoms, an arylthio group having 6 to 30 carbon atoms, an aralkyl group having 7 to 30 carbon atoms, a substituted phosphoryl group, a substituted silyl group, a nitro group, a carboxy group, an alkenyl group having 2 to 30 carbon atoms, an alkynyl group having 2 to 30 carbon atoms, an alkylthio group having 1 to 30 carbon atoms, an alkylsilyl group having 3 to 30 carbon atoms, an arylsilyl group having 6 to 30 ring carbon atoms, and a hydroxyl group.

16. The organic electroluminescence device according to claim 1, wherein a substituent meant by “substituted or unsubstituted” is a substituent selected from the group consisting of a substituted or unsubstituted aromatic hydrocarbon group having 6 to 30 ring carbon atoms, a substituted or unsubstituted heterocyclic group having 5 to 30 ring atoms, a linear alkyl group having 1 to 30 carbon atoms, a branched alkyl group having 3 to 30 carbon atoms, a cycloalkyl group having 3 to 30 ring carbon atoms, an alkyl halide group provided by substituting an alkyl group of the linear alkyl group, the branched alkyl group, or the cycloalkyl group with one or more halogen atoms, a halogen atom, an alkylsilyl group having 3 to 30 carbon atoms, an arylsilyl group having 6 to 30 ring carbon atoms, and a cyano group.

17. An electronic device comprising the organic electroluminescence device according to claim 1.

18. The organic electroluminescence device according to claim 1, wherein R⁹⁵ in the formula (3) is a group represented by -(A¹)o-(A²)p-(A³)q-(A⁴)r-R¹⁶, R¹⁶ being —CN or a group represented by any one of formulae (B11) to (B27) below 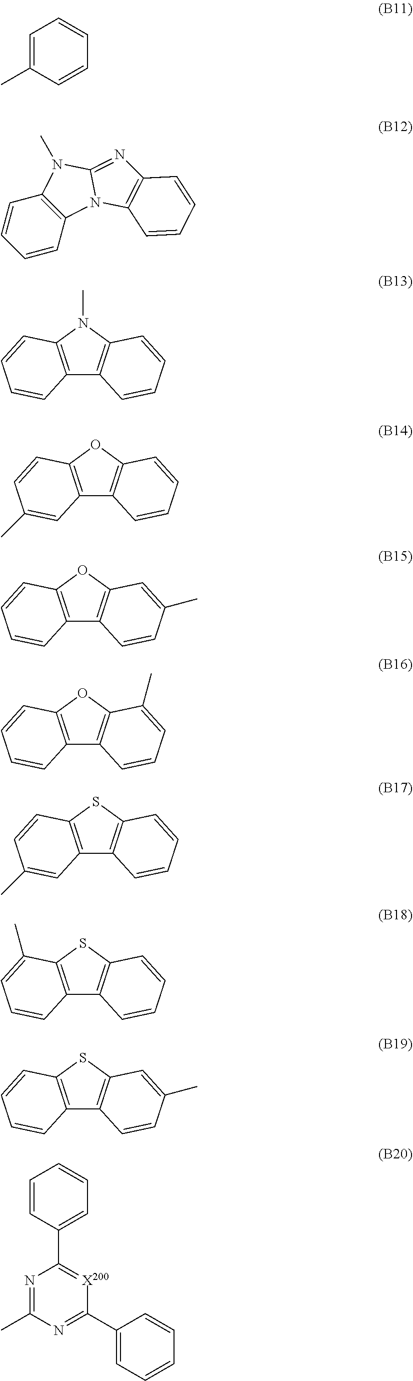 [chemical structure]
